(19) United States
(12) Patent Application Publication
(10) Pub. No.: US 2025/0028243 A1
(43) Pub. Date: Jan. 23, 2025

(54) RESIST COMPOSITION AND PATTERN FORMING PROCESS

(71) Applicant: Shin-Etsu Chemical Co., Ltd., Tokyo (JP)

(72) Inventors: Jun Hatakeyama, Joetsu-shi (JP); Tomomi Watanabe, Joetsu-shi (JP); Takayuki Fujiwara, Joetsu-shi (JP)

(73) Assignee: Shin-Etsu Chemical Co., Ltd., Tokyo (JP)

(21) Appl. No.: 18/756,270

(22) Filed: Jun. 27, 2024

(30) Foreign Application Priority Data
Jul. 4, 2023 (JP) 2023-109737
Jul. 28, 2023 (JP) 2023-123393

(51) Int. Cl. G03F 7/039; C08F 212/14; C08F 220/18; C08F 220/22

(52) U.S. Cl. CPC G03F 7/039; C08F 212/22; C08F 212/24; C08F 220/1806; C08F 220/22

(57) ABSTRACT

The resist composition exhibits higher sensitivity and improved LWR or CDU. The resist composition comprises a base polymer containing repeat units (a) containing a substituted or unsubstituted arylsulfonic acid anion bonded to a polymer backbone having a group containing an iodine atom or a bromine atom and an onium cation.

### CROSS-REFERENCE TO RELATED APPLICATIONS

This non-provisional application claims priority under 35 U.S.C. § 119(a) on Patent Application Nos. 2023-109737 and 2023-123393 filed in Japan on Jul. 4, 2023 and Jul. 28, 2023, respectively, the entire contents of which are hereby incorporated by reference.

### TECHNICAL FIELD

The present invention relates to a resist composition and a pattern forming process.

### BACKGROUND ART

To meet the demand for higher integration density and higher operating speed of LSIs, the effort to reduce the pattern rule is in rapid progress. As the use of 5G high-speed communications and artificial intelligence (AI) is widely spreading, high-performance devices are needed for their processing. As the most advanced miniaturization technology, mass production of microelectronic devices at the 5-nm node by the lithography using extreme ultraviolet (EUV) having a wavelength of 13.5 nm has been implemented. Studies are made on the application of EUV lithography to 3-nm node devices of the next generation and 2-nm node devices of the next-but-one generation. IMEC in Belgium announced its successful development of 1-nm and 0.7-nm node devices.

As the feature size reduces, image blurs due to acid diffusion become a problem. To ensure resolution for fine patterns of sub-45-nm size, not only an improvement in dissolution contrast is important as previously reported, but also the control of acid diffusion is important as reported in Non-Patent Document 1. Since chemically amplified resist compositions are designed such that sensitivity and contrast are enhanced by acid diffusion, an attempt to minimize acid diffusion by reducing the temperature and/or time of post exposure bake (PEB) fails, resulting in drastic reductions of sensitivity and contrast.

A triangular tradeoff relationship among sensitivity, resolution, and edge roughness (LWR) has been pointed out. Specifically, a resolution improvement requires to reduce acid diffusion whereas a short acid diffusion distance leads to a decline of sensitivity.

The addition of an acid generator capable of generating a bulky acid is an effective means for reducing acid diffusion. It was then proposed to incorporate repeat units derived from an onium salt having a polymerizable unsaturated bond in a polymer. Since this polymer functions as an acid generator, it is referred to as polymer-bound acid generator. Patent Document 1 discloses a sulfonium salt having a sulfonic acid directly bonded to the backbone.

A resist composition containing a polymer having an onium salt structure having an iodine atom or a bromine atom in a linker moiety between a polymer backbone and fluorosulfonic acid has been proposed (Patent Documents 2 and 3). The iodine atom has high absorption in EUV light, and the bromine atom is ionized by EUV irradiation, both of which improve sensitivity and physical contrast.

A mechanism for generating an acid with high-energy radiation represented by EB and EUV light has been proposed (Non-Patent Document 2). According to this, in the EB or EUV exposure, the polymer is ionized to generate and diffuse secondary electrons, which transfer energy to the acid generator to generate an acid. According to the resist pattern transfer result and simulation, the distance from a light absorption point to a point at which an acid is generated is estimated to be 2.4 nm (Non-Patent Document 3). This distance includes a diffusion distance of secondary electrons. In this document, the total of the acid diffusion distance and the diffusion distance from the light absorption point to the point at which an acid is generated is described as 4 to 8 nm if the PEB temperature is changed, and thus if the acid diffusion is suppressed by the application of the low temperature PEB or the anion-bound PAG polymer, half the distance of the diffusion is occupied by the diffusion from the light absorption point to the point at which an acid is generated. That is, it can be said that it is important to control not only the acid diffusion but also the diffusion from the light absorption point to the point at which an acid is generated, that is, the diffusion of secondary electrons in miniaturization.

The health impact of perfluoroalkyl compounds (PFAS) has been pointed out, and there is a movement to place limits on the production and sale of PFAS under the European REACH. Many compounds, including PFAS, are currently used in the context of semiconductor lithography. For example, a material having a structure containing such a compound is applied to a surfactant, an acid generator, and the like.

### CITATION LIST

Patent Document 1: JP-A 2006-178317
Patent Document 2: JP-A 2018-197853
Patent Document 3: JP-A 2019-008280
Non-Patent Document 1: SPIE Vol. 6520 65203L-1 (2007)
Non-Patent Document 2: SPIE Vol. 5753 361 (2005)
Non-Patent Document 3: SPIE Vol. 7969 796904-1 (2011)

### SUMMARY OF THE INVENTION

For resist compositions, it is desired to develop an acid generator capable of improving the LWR of line patterns or the critical dimension uniformity (CDU) of hole patterns and enhancing sensitivity. For this purpose, it is necessary that a resist composition have high decomposition efficiency in exposure, reduce acid diffusion, and have high affinity with an alkaline developer.

The present invention has been made in view of the above circumstances, and an object of the present invention is to provide a resist composition, especially a positive resist composition which exhibits higher sensitivity and improved LWR or CDU, and a pattern forming process using the resist composition.

As a result of intensive studies to achieve the above object, the present inventors have found that by using a base polymer containing repeat units (a) containing a substituted or unsubstituted arylsulfonic acid anion bonded to a polymer backbone having a group containing an iodine atom or a bromine atom and an onium cation, an acid generator is directly excited by absorption of the iodine atom or the bromine atom during exposure to generate an acid. In the case of the direct excitation mechanism, since the direct excitation mechanism is not affected by diffusion of secondary electrons,
diffusion becomes lower. The present inventors have found that low acid diffusibility due to generation of a sulfonic acid bonded to a polymer backbone by exposure, and decomposition efficiency due to direct excitation by exposure due to absorption or ionization by an iodine atom or a bromine atom are high, and at the same time, acid diffusion can be suppressed, and affinity with an alkaline developer is high, so that characteristics of high sensitivity, low acid diffusion, high contrast, and low swelling can be obtained, whereby a resist composition having improved LWR and CDU, high sensitivity, excellent resolution, and a wide process margin can be obtained, thereby completing the present invention.

That is, the present invention provides the following resist composition and pattern forming process.
1. A resist composition comprising a base polymer containing repeat units (a) containing a substituted or unsubstituted arylsulfonic acid anion bonded to a polymer backbone having a group containing an iodine atom or a bromine atom and an onium cation.
2. The resist composition of item 1, wherein the repeat units (a) have formula (a1) or (a2):

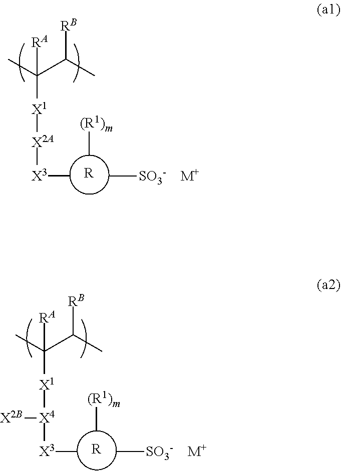

wherein m is an integer of 0 to 5,
R^{A} is a hydrogen atom or a methyl group,
R^{B} is a hydrogen atom or may bond with X¹ to form a ring,
X¹ is a single bond, a phenylene group, a naphthylene ring, an ester bond, or an amide bond,
X^{2A} is a C₁-C₂₄ divalent organic group having at least one iodine atom or bromine atom, which may have at least one selected from an oxygen atom, a nitrogen atom, and a sulfur atom,
X^{2B} is a C₁-C₁₀ monovalent organic group having at least one iodine atom or bromine atom, which may have at least one selected from an oxygen atom, a nitrogen atom, and a sulfur atom,
X³ is a single bond, an ether bond, an ester bond, a thioether bond, or a C₁-C₆ alkanediyl group,
X⁴ is a C₁-C₁₂ trivalent organic group, which may have at least one selected from an oxygen atom, a nitrogen atom, and a sulfur atom,
circle R is a C₆-C₁₀ (m+2)-valent aromatic hydrocarbon group,
R¹ is a C₁-C₁₀ saturated hydrocarbyl group, a C₆-C₁₀ aryl group, a fluorine atom, a trifluoromethoxy group, a difluoromethoxy group, a cyano group, or a nitro group, and
M⁺ is a sulfonium cation or an iodonium cation.
3. The resist composition of item 1 or 2, wherein the base polymer further contains repeat units having formula (b1) or repeat units having formula (b2):

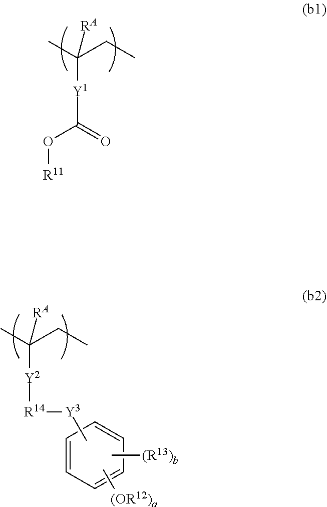

wherein R^{A} is each independently a hydrogen atom or a methyl group,
Y¹ is a single bond, a phenylene group, a naphthylene group, or a C₁-C₁₂ linking group containing at least one moiety selected from an ester bond, an ether bond, a lactone ring, a hydroxy group, and a halogen atom,
Y² is a single bond or an ester bond,
Y³ is a single bond, an ether bond, or an ester bond,
R¹¹ and R¹² are each independently an acid labile group,
R¹³ is a fluorine atom, a chlorine atom, a bromine atom, an iodine atom, a trifluoromethyl group, a cyano group, a C₁-C₆ saturated hydrocarbyl group, a C₁-C₆ saturated hydrocarbyloxy group, a C₂-C₇ saturated hydrocarbylcarbonyl group, a C₂-C₇ saturated hydrocarbylcarbonyloxy group, or a C₂-C₇ saturated hydrocarbyloxycarbonyl group,
R¹⁴ is a single bond or a C₁-C₆ alkanediyl group in which some constituent —CH₂— may be substituted with an ether bond or an ester bond,
a is 1 or 2, and b is an integer of 0 to 4, provided that 1≤a+b≤5.
4. The resist composition of item 3, which is a chemically amplified positive resist composition.
5. The resist composition of any one of items 1 to 4, further comprising an organic solvent.
6. The resist composition of any one of items 1 to 5, further comprising a surfactant.
7. A pattern forming process comprising the steps of: applying the resist composition of any one of items 1 to 6 onto a substrate to form a resist film thereon, exposing the resist film to high-energy radiation, and developing the exposed resist film in a developer.
8. The pattern forming process of item 7, wherein the high-energy radiation is KrF excimer laser, ArF excimer laser, electron beam (EB), or EUV having a wavelength of 3 to 15 nm.

### Advantageous Effects of Invention

In a resist composition containing a base polymer containing repeat units (a) containing a substituted or unsubstituted arylsulfonic acid anion bonded to a polymer backbone having a group containing an iodine atom or a bromine atom and an onium cation, sensitivity and contrast are improved by the iodine atom or the bromine atom, an acid diffusion distance is short because the arylsulfonic acid anion is bonded to the polymer backbone, and an alkali dissolution rate is improved by generation of a carboxy group. Accordingly, a resist composition having improved LWR and CDU is formulated.

### DETAILED DESCRIPTION OF THE INVENTION

### [Resist Composition]

A resist composition of the present invention comprises a base polymer containing repeat units (a) containing a substituted or unsubstituted arylsulfonic acid anion bonded to a polymer backbone having a group containing an iodine atom or a bromine atom and an onium cation. Since the repeat unit (a) functions as an acid generator, the base polymer is a polymer-bound acid generator.

### [Base Polymer]

The repeat units (a) preferably have formula (a1) (hereinafter, the repeat units are also referred to as repeat units (a1)) or formula (a2) (hereinafter, the repeat units are also referred to as repeat units (a2)).

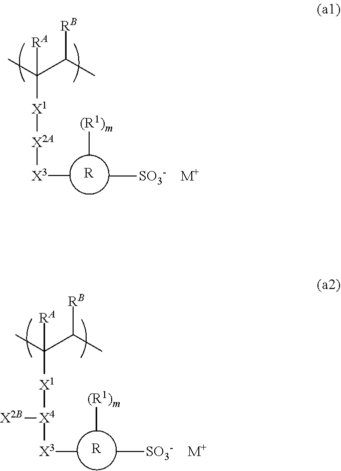

In formulae (a1) and (a2), m is an integer of 0 to 5.

In formulae (a1) and (a2), R^{A} is a hydrogen atom or a methyl group. R^{B} is a hydrogen atom or may bond with X¹ to form a ring.

In formulae (a1) and (a2), X¹ is a single bond, a phenylene group, a naphthylene ring, an ester bond, or an amide bond.

In formula (a1), X^{2A} is a C₁-C₂₄ divalent organic group having at least one iodine atom or bromine atom, which may have at least one selected from an oxygen atom, a nitrogen atom, and a sulfur atom.

The divalent organic group represented by X^{2A} may be saturated or unsaturated, and may be straight, branched, or cyclic. Specific examples thereof include a C₁-C₂₄ hydrocarbylene group in which some or all of hydrogen atoms are substituted with an iodine atom or a bromine atom. Examples of the C₁-C₂₄ hydrocarbylene group include alkanediyl groups such as a methanediyl group, an ethane-1,1-diyl group, an ethane-1,2-diyl group, a propane-1,3-diyl group, a butane-1,4-diyl group, a pentane-1,5-diyl group, a hexane-1,6-diyl group, a heptane-1,7-diyl group, an octane-1,8-diyl group, a nonane-1,9-diyl group, a decane-1,10-diyl group, an undecane-1,11-diyl group, a dodecane-1,12-diyl group, a tridecane-1,13-diyl group, a tetradecane-1,14-diyl group, a pentadecane-1,15-diyl group, a hexadecane-1,16-diyl group, a heptadecane-1,17-diyl group, an octadecane-1,18-diyl group, a nonadecane-1,19-diyl group, and an eicosane-1,20-diyl group; cyclic saturated hydrocarbylene groups such as a cyclopentanediyl group, a methylcyclopentanediyl group, a dimethylcyclopentanediyl group, a trimethylcyclopentanediyl group, a tetramethylcyclopentanediyl group, a cyclohexanediyl group, a methylcyclohexanediyl group, a dimethylcyclohexanediyl group, a trimethylcyclohexanediyl group, a tetramethylcyclohexanediyl group, a norbornanediyl group, and an adamantanediyl group; arylene groups such as a phenylene group, a methylphenylene group, an ethylphenylene group, a n-propylphenylene group, an isopropylphenylene group, a n-butylphenylene group, an isobutylphenylene group, a sec-butylphenylene group, a tert-butylphenylene group, a naphthylene group, a methylnaphthylene group, an ethylnaphthylene group, a n-propylnaphthylene group, an isopropylnaphthylene group, a n-butylnaphthylene group, an isobutylnaphthylene group, a sec-butylnaphthylene group, a tert-butylnaphthylene group, a biphenyldiyl group, a methylbiphenyldiyl group, and a dimethylbiphenyldiyl group; and groups obtained by combining the foregoing. Some or all of hydrogen atoms of X^{2A} may be substituted with a group containing at least one selected from an oxygen atom, a nitrogen atom, and a sulfur atom, and some of —CH₂— of X^{2A} may be substituted with a group containing at least one selected from an oxygen atom, a nitrogen atom, and a sulfur atom, so that the group may contain a hydroxy group, an ester bond, an ether bond, an amide bond, a carbamate bond, a urea bond, or the like.

In formula (a2), X^{2B} is a C₁-C₁₀ monovalent organic group having at least one iodine atom or bromine atom, which may have at least one selected from an oxygen atom, a nitrogen atom, and a sulfur atom.

The monovalent organic group represented by X^{2B} may be saturated or unsaturated, and may be straight, branched, or cyclic. Specific examples thereof include a C₁-C₁₀ hydrocarbyl group in which some or all of hydrogen atoms are substituted with an iodine atom or a bromine atom. Examples of the C₁-C₁₀ hydrocarbyl group include C₁-C₁₀ alkyl groups such as a methyl group, an ethyl group, a n-propyl group, an isopropyl group, a n-butyl group, an isobutyl group, a sec-butyl group, a tert-butyl group, a n-pentyl group, an isopentyl group, a sec-pentyl group, a 3-pentyl group, a tert-pentyl group, a neopentyl group, a n-hexyl group, a n-octyl group, a n-nonyl group, and a n-decyl group; C₃-C₁₀ cyclic saturated hydrocarbyl groups such as a cyclopropyl group, a cyclobutyl group, a cyclopentyl group, a cyclohexyl group, an adamantyl group, a norbornyl group, a cyclopropylmethyl group, a cyclopropylethyl group, a cyclobutylmethyl group, a cyclobutylethyl group, a cyclopentylmethyl group, a cyclopentylethyl group, a cyclohexylmethyl group, a cyclohexylethyl group, a methylcyclopropyl group, a methylcyclobutyl group, a methylcyclopentyl group, a methylcyclohexyl group, an ethylcyclopropyl group, an ethylcyclobutyl group, an ethylcyclopentyl group, and an ethylcyclohexyl group; C₂-C₁₀ alkenyl groups such as a vinyl group, a 1-propenyl group, a 2-propenyl group, a butenyl group, a pentenyl group, a hexenyl group, a heptenyl group, a nonenyl group, and a decenyl group; C₂-C₁₀ alkynyl groups such as an ethynyl group, a propynyl group, a butynyl group, a pentynyl group, a hexynyl group, a heptynyl group, an octynyl group, a nonynyl group, and a decynyl group; C₃-C₁₀ cyclic unsaturated aliphatic hydrocarbyl groups such as a cyclopentenyl group, a cyclohexenyl group, a methylcyclopentenyl group, a methylcyclohexenyl group, an ethylcyclopentenyl group, an ethylcyclohexenyl group, and a norbornenyl group; C₆-C₁₀ aryl groups such as a phenyl group, a methylphenyl group, an ethylphenyl group, a n-propylphenyl group, an isopropylphenyl group, a n-butylphenyl group, an isobutylphenyl group, a sec-butylphenyl group, a tert-butylphenyl group, and a naphthyl group; C₇-C₁₀ aralkyl groups such as a benzyl group, a phenethyl group, a phenylpropyl group, and a phenylbutyl group; and groups obtained by combining the foregoing. Some or all of hydrogen atoms of X^{2B} may be substituted with a group containing at least one selected from an oxygen atom, a nitrogen atom, and a sulfur atom, and some of —CH₂— of X^{2B} may be substituted with a group containing at least one selected from an oxygen atom, a nitrogen atom, and a sulfur atom, so that the group may contain a hydroxy group, an ester bond, an ether bond, an amide bond, a carbamate bond, a urea bond, or the like.

In formulae (a1) and (a2), X³ is a single bond, an ether bond, an ester bond, a thioether bond, or a C₁-C₆ alkanediyl group.

In formula (a2), X⁴ is a C₁-C₁₂ trivalent organic group, which may have at least one selected from an oxygen atom, a nitrogen atom, and a sulfur atom, The trivalent organic group represented by X⁴ may be saturated or unsaturated, and may be straight, branched, or cyclic. Specific examples thereof include a group obtained by further removing one hydrogen atom from a C₁-C₁₂ hydrocarbylene group. Examples of the C₁-C₁₂ hydrocarbylene group include those having 1 to 12 carbon atoms among the C₁-C₂₄ hydrocarbylene groups described above. Some or all of hydrogen atoms of X⁴ may be substituted with a group containing at least one selected from an oxygen atom, a nitrogen atom, and a sulfur atom, and some of —CH₂— of X⁴ may be substituted with a group containing at least one selected from an oxygen atom, a nitrogen atom, and a sulfur atom, so that the group may contain a hydroxy group, an ester bond, an ether bond, an amide bond, a carbamate bond, a urea bond, or the like.

In formulae (a1) and (a2), circle R is a C₆-C₁₀ (m+2)-valent aromatic hydrocarbon group. Specific examples of the (m+2)-valent aromatic hydrocarbon group include a group obtained by removing (m+2) hydrogen atoms from an aromatic hydrocarbon such as benzene or naphthalene.

In formulae (a1) and (a2), R¹ is a C₁-C₁₀ saturated hydrocarbyl group, a C₆-C₁₀ aryl group, a fluorine atom, a trifluoromethoxy group, a difluoromethoxy group, a cyano group, or a nitro group.

Specific examples of the anion of the repeat units (a) include those shown below, but are not limited thereto. In the formula, X^{BI} is an iodine atom or a bromine atom.

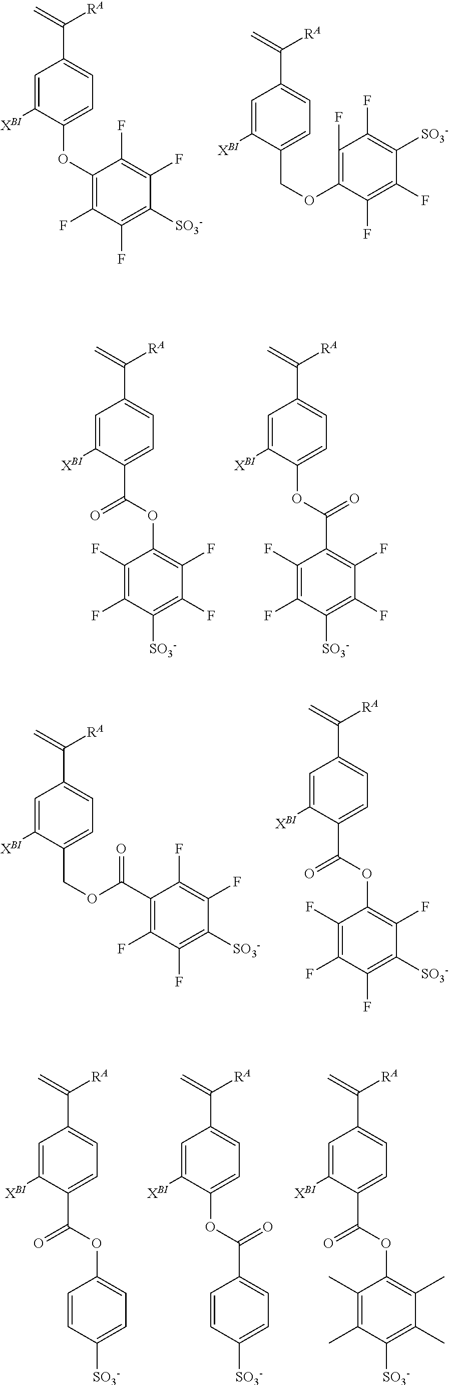

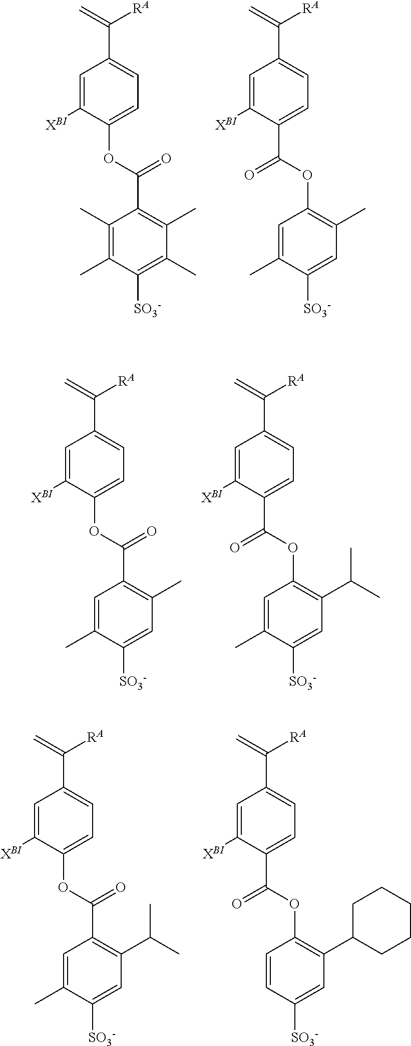

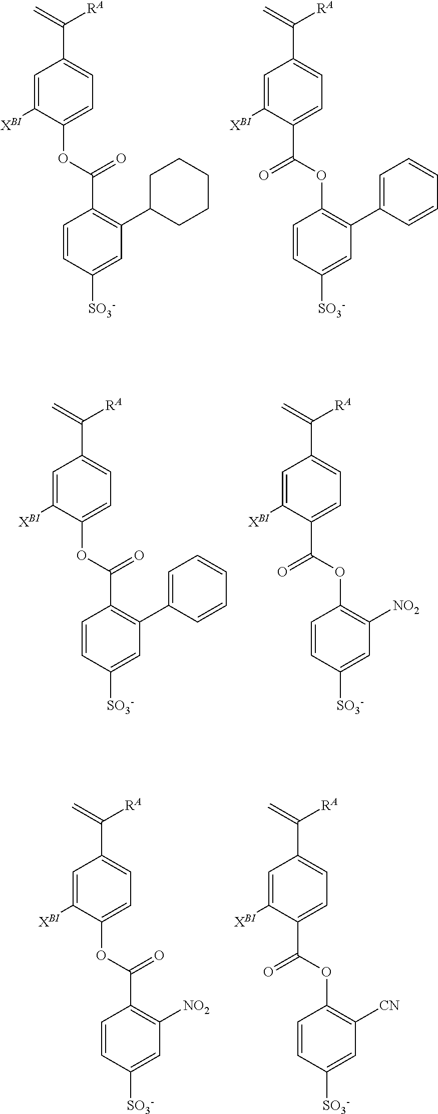

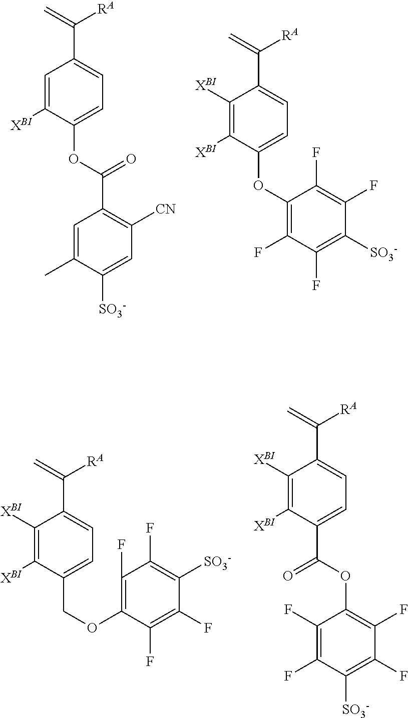

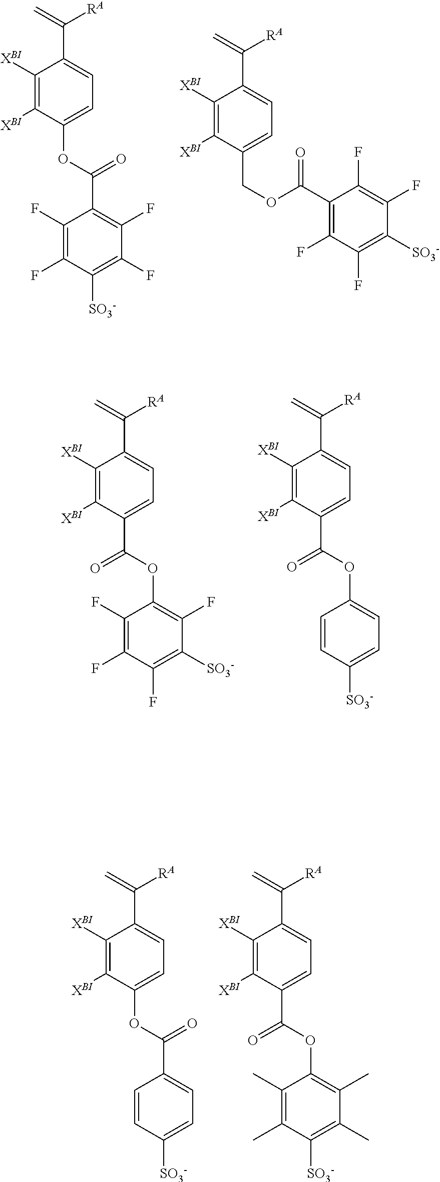

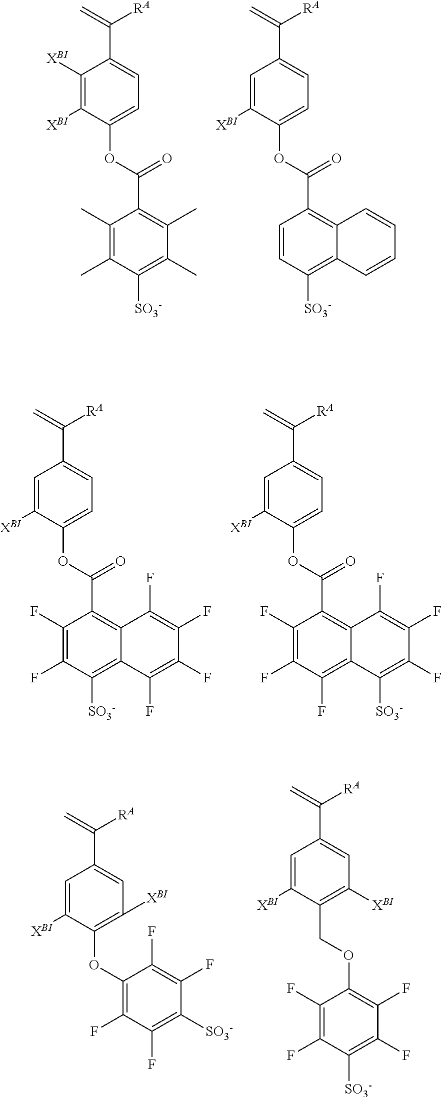

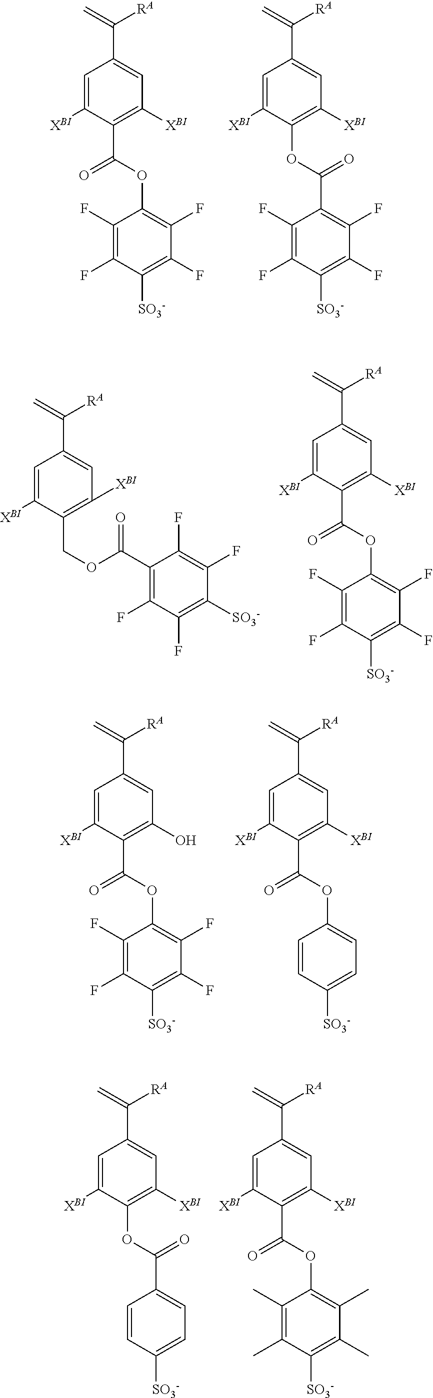

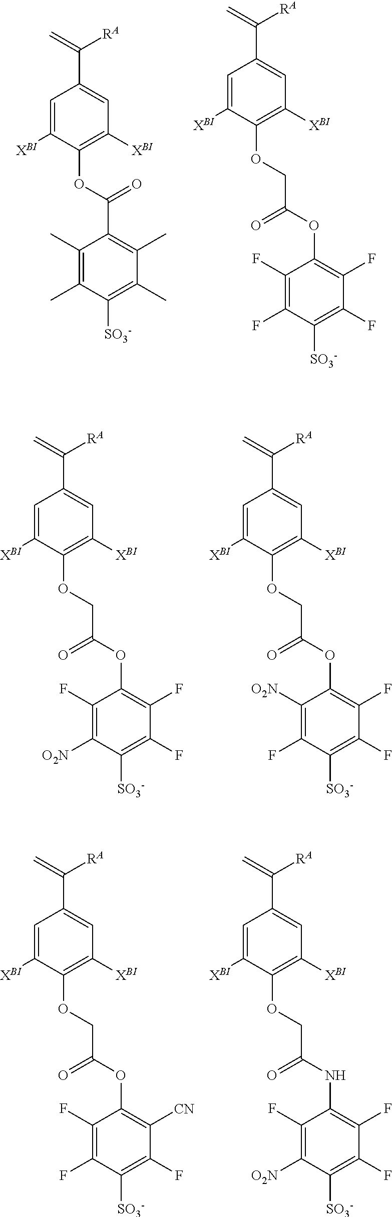

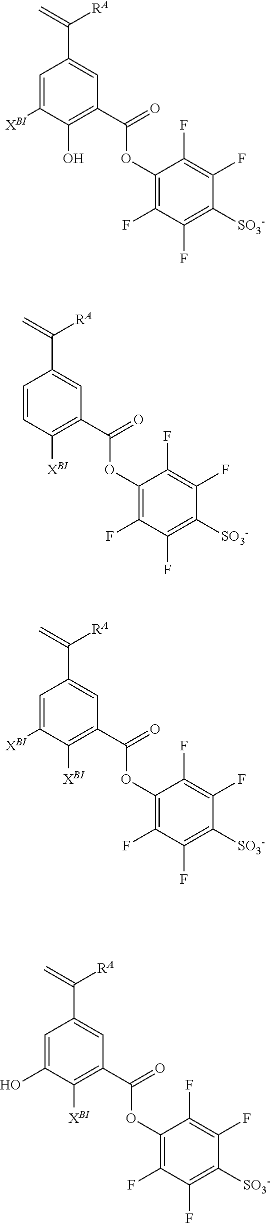

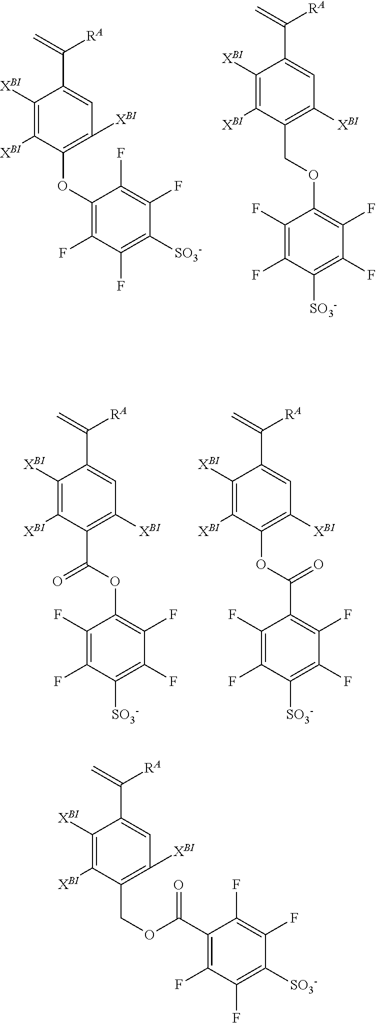

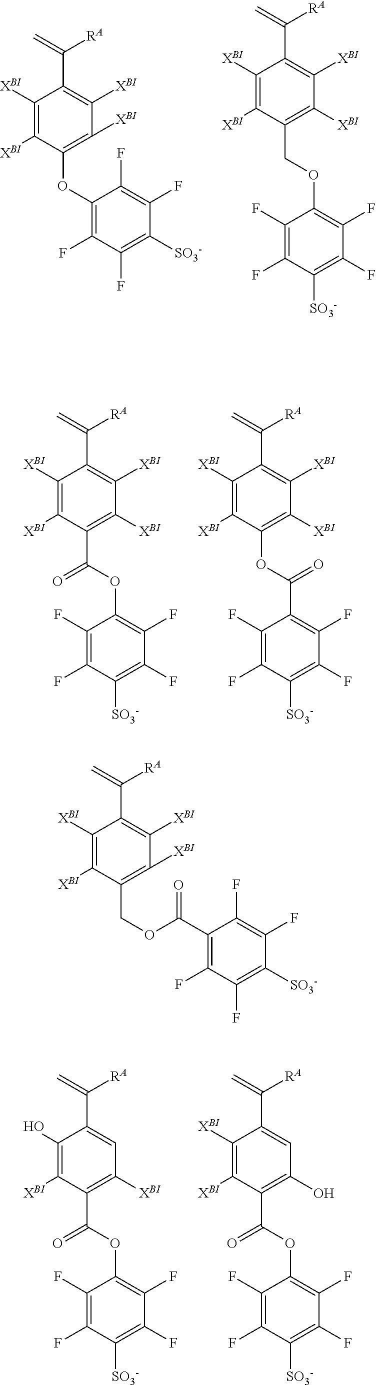

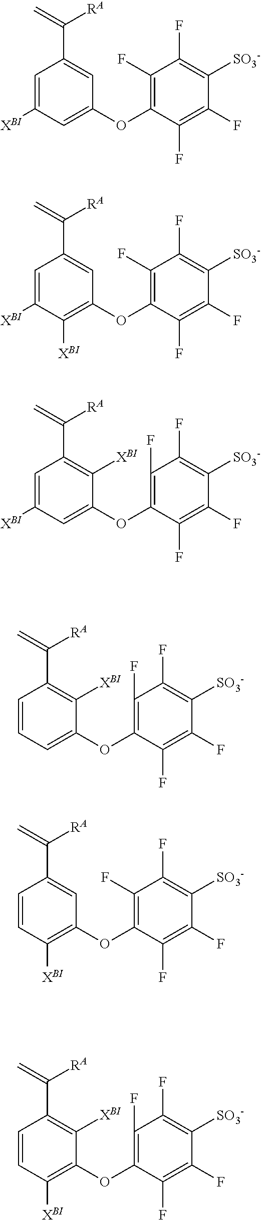

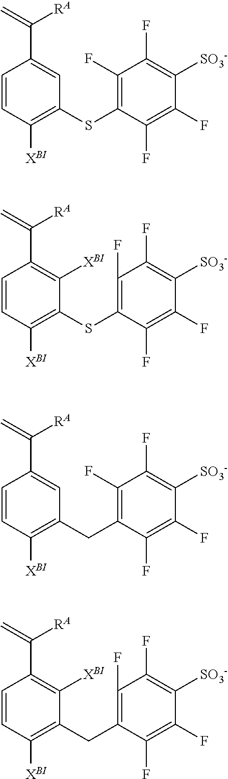

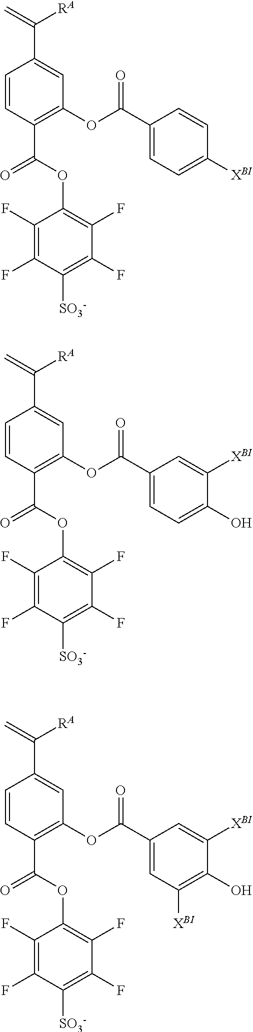

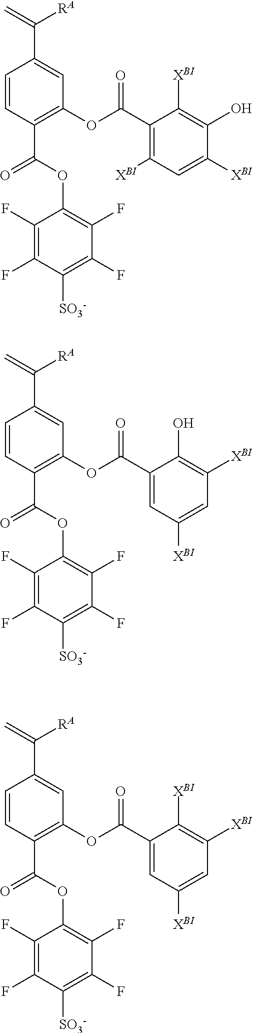

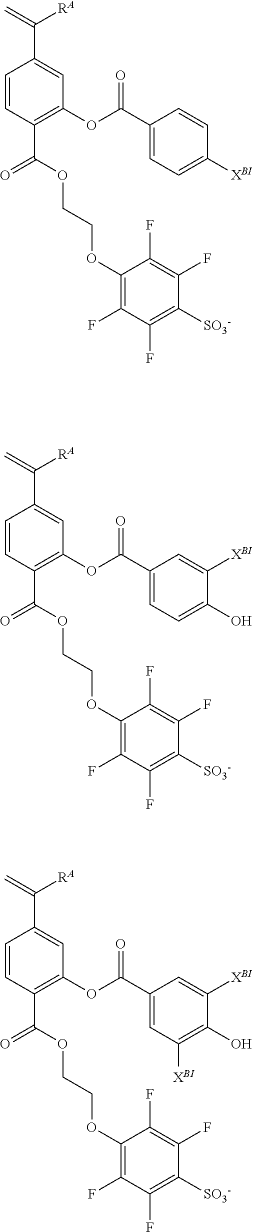

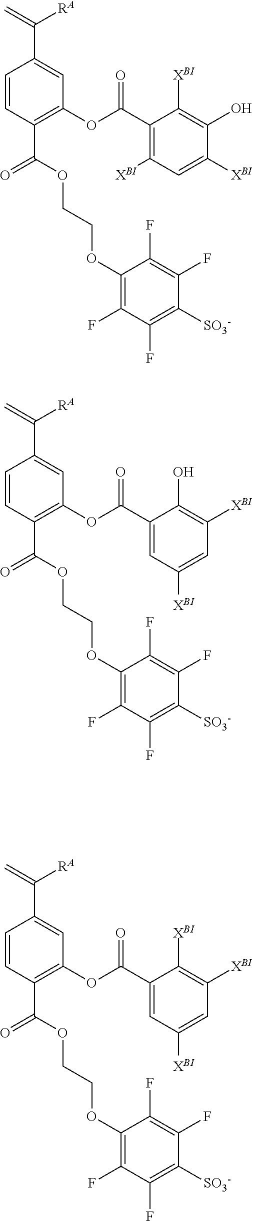

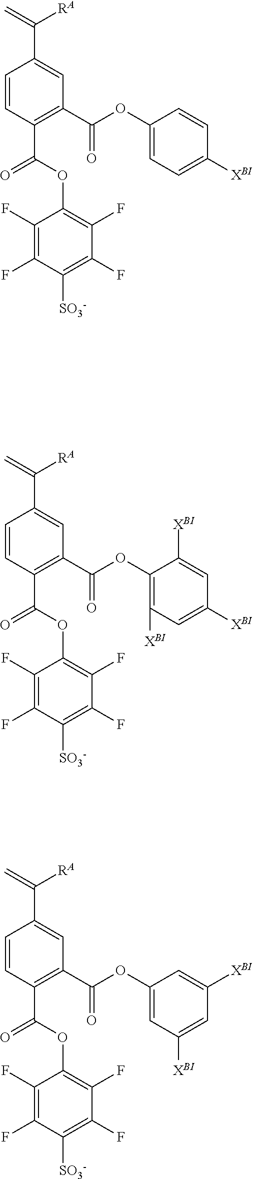

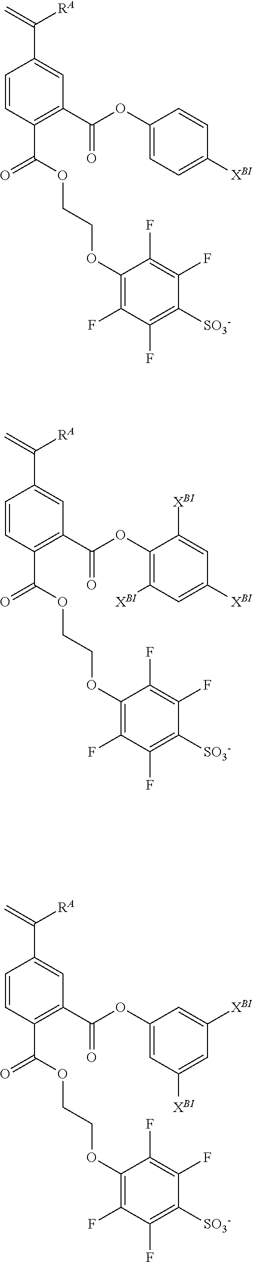

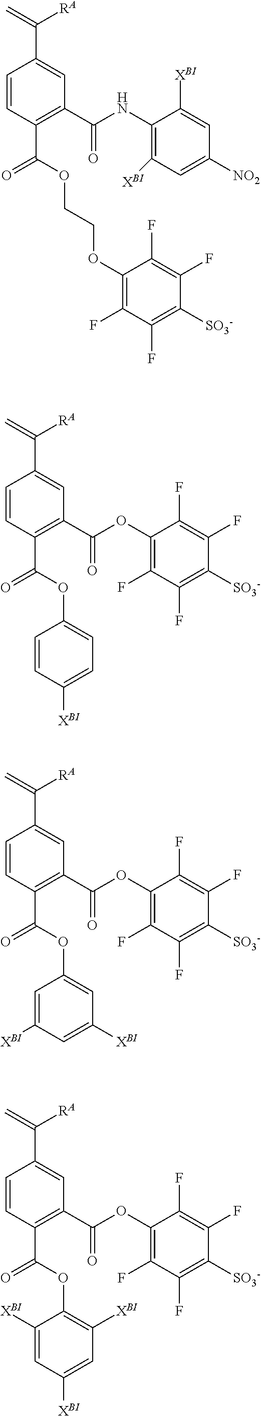

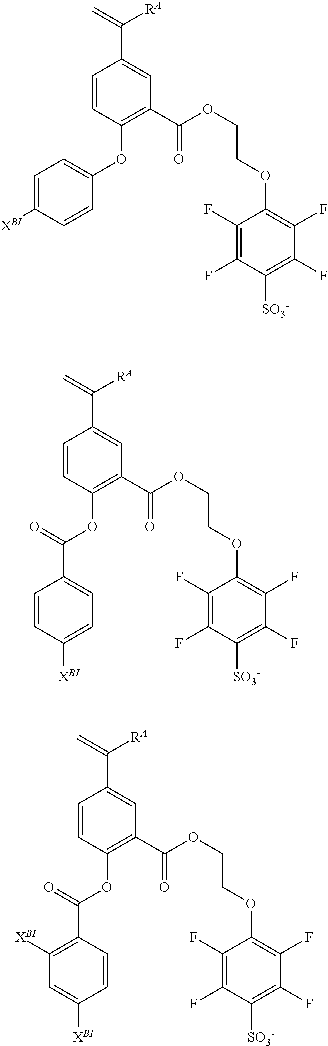

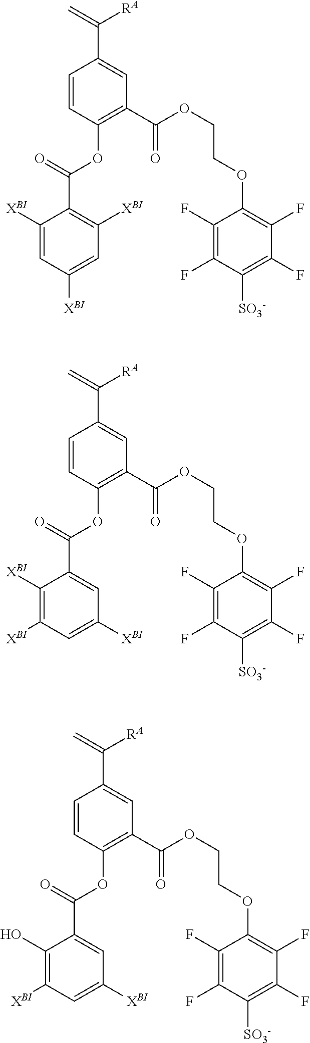

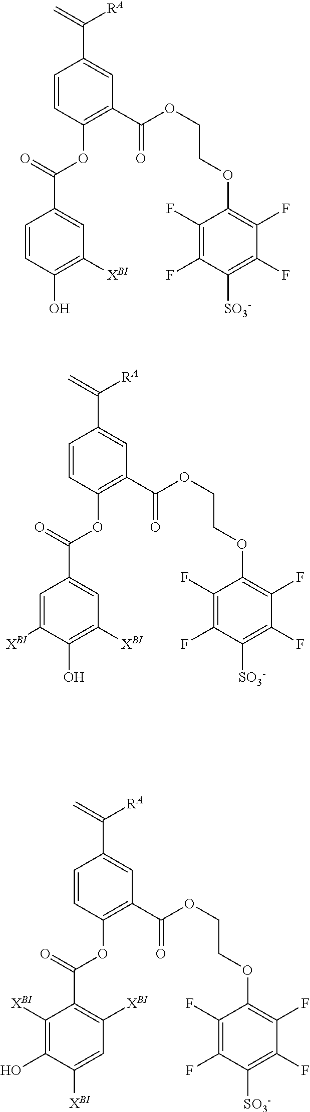

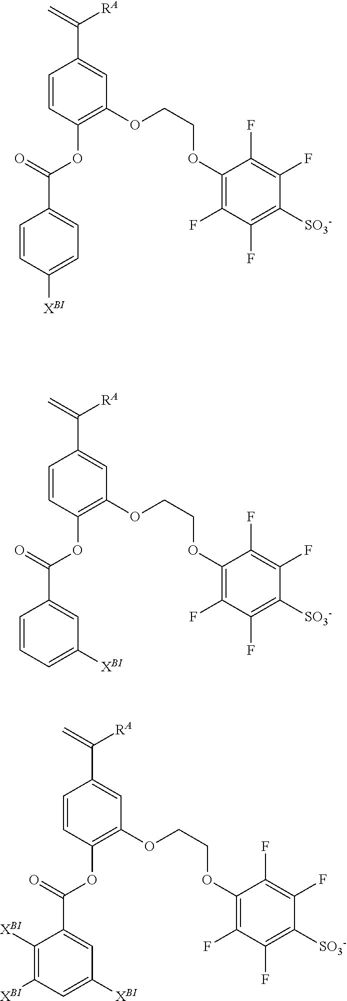

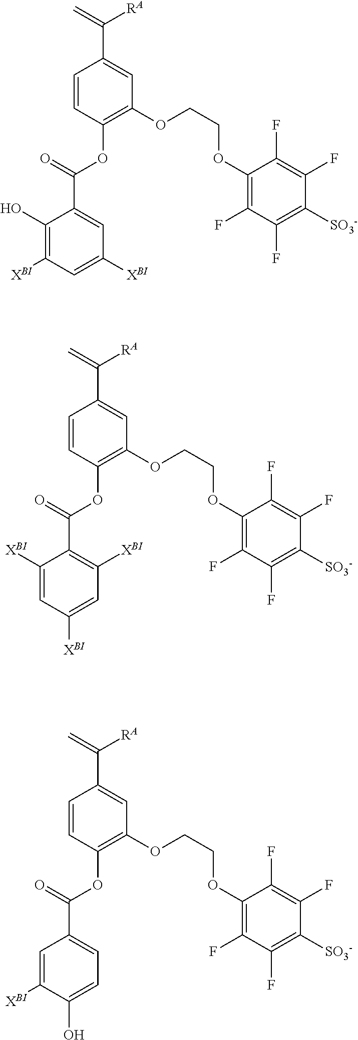

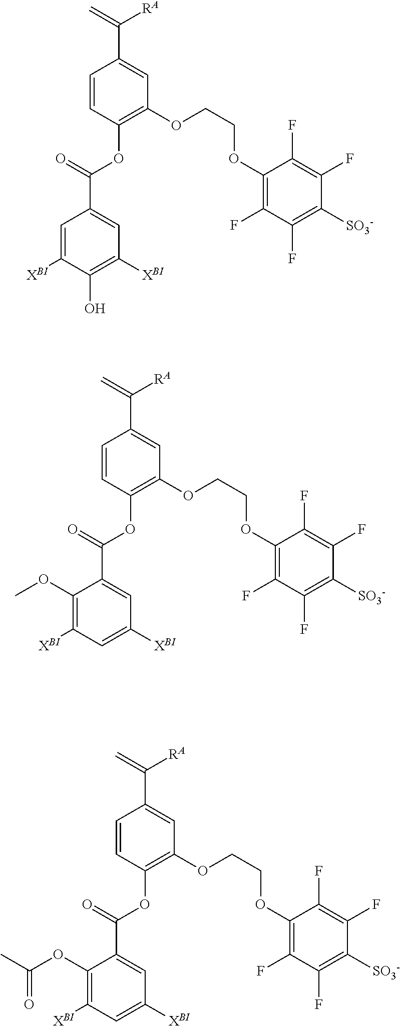

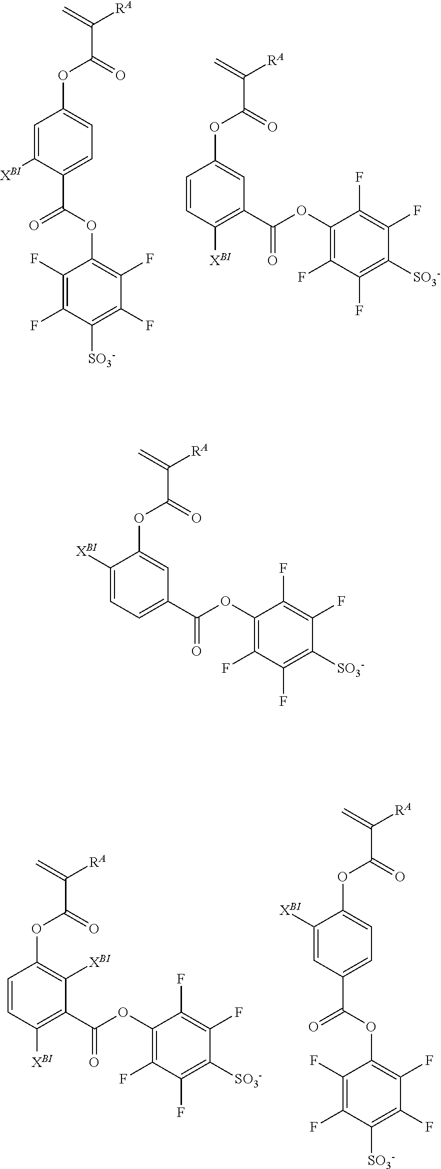

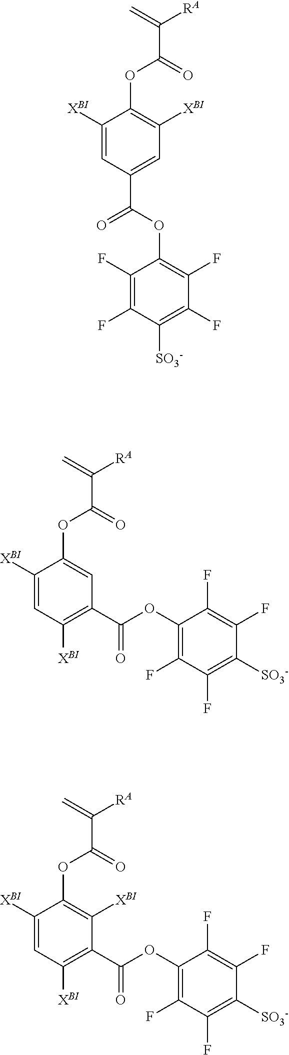

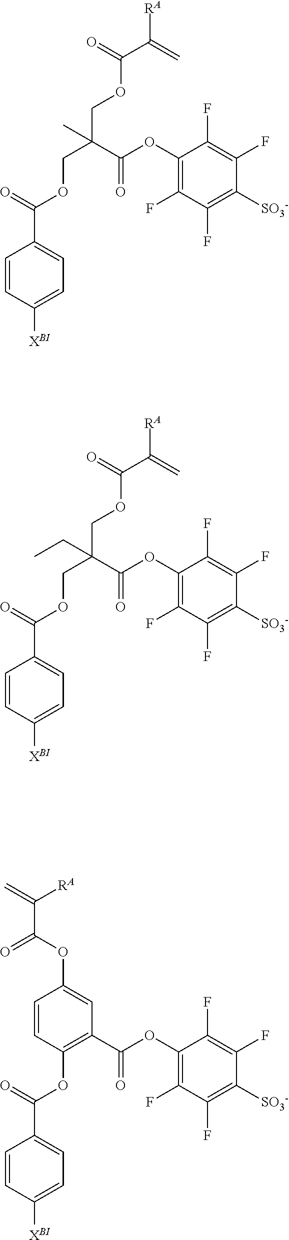

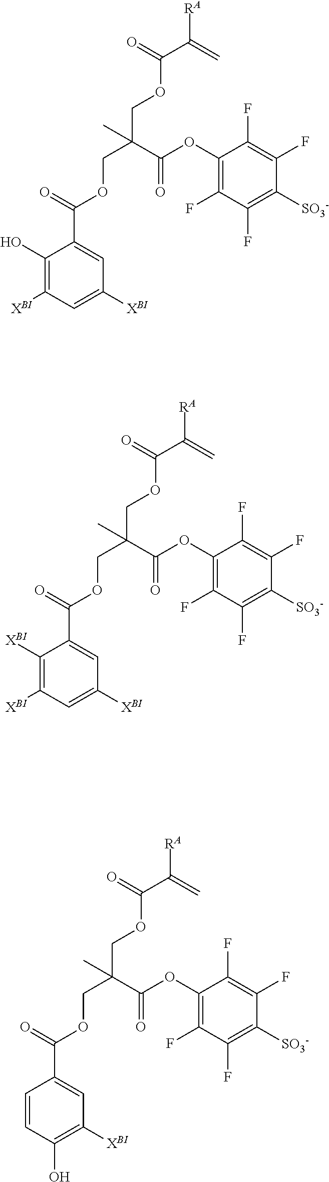

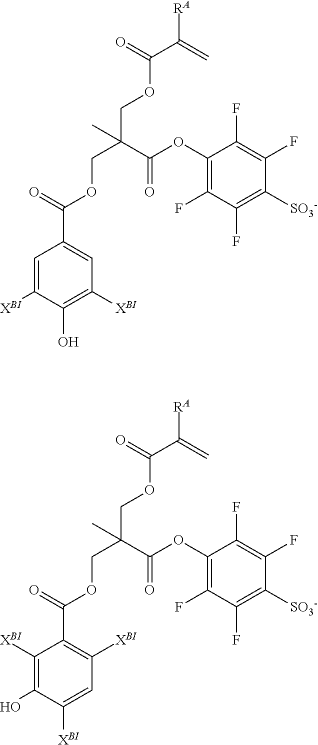

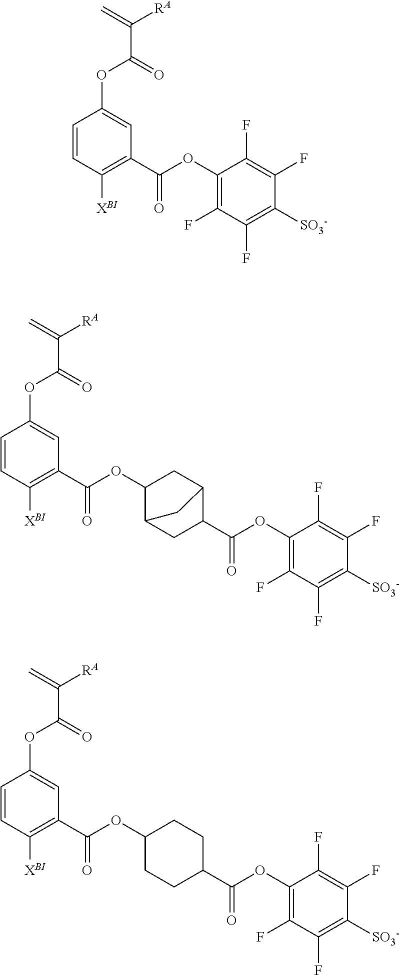

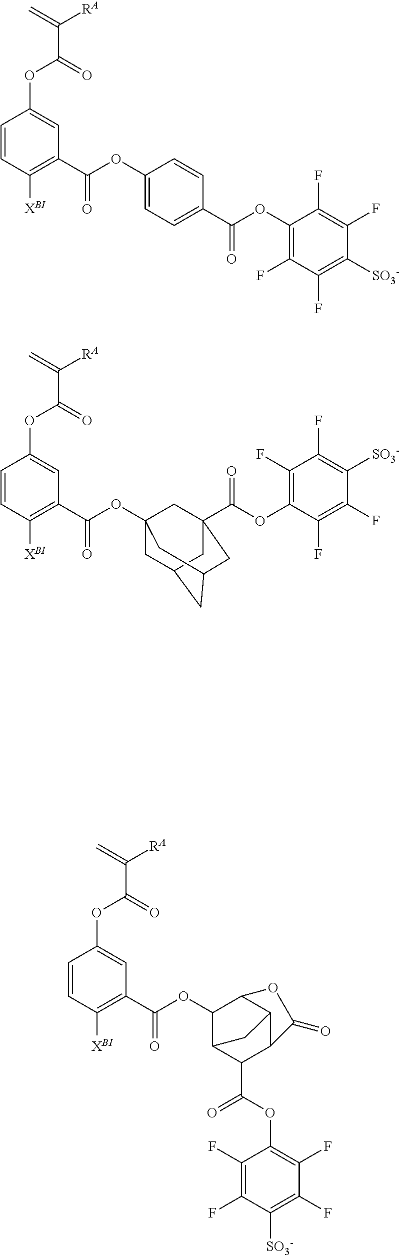

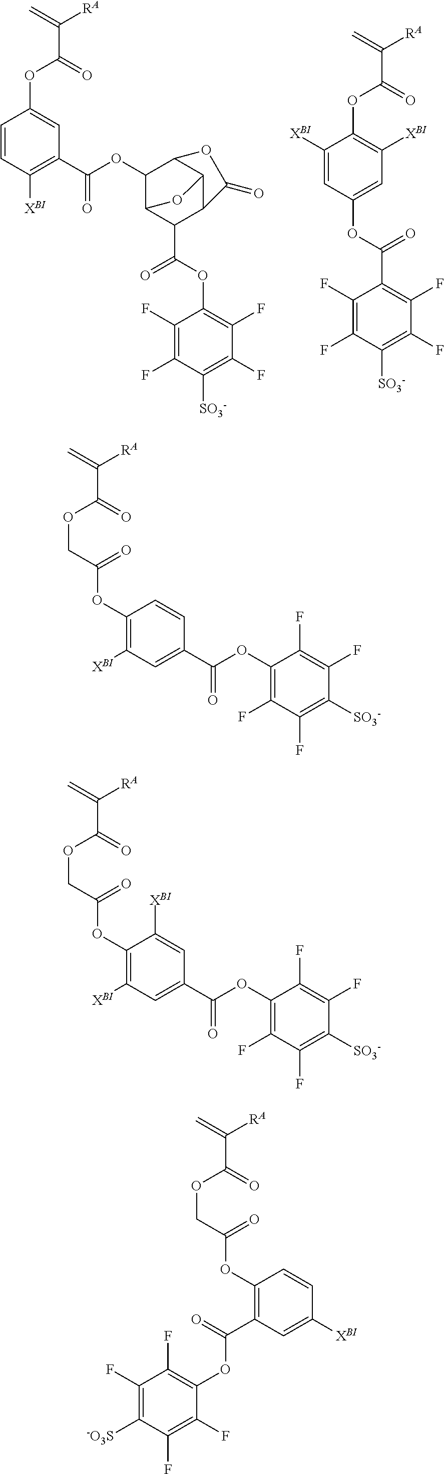

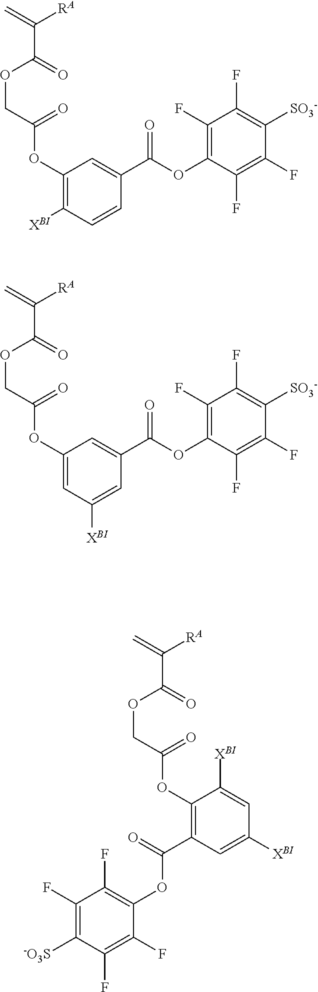

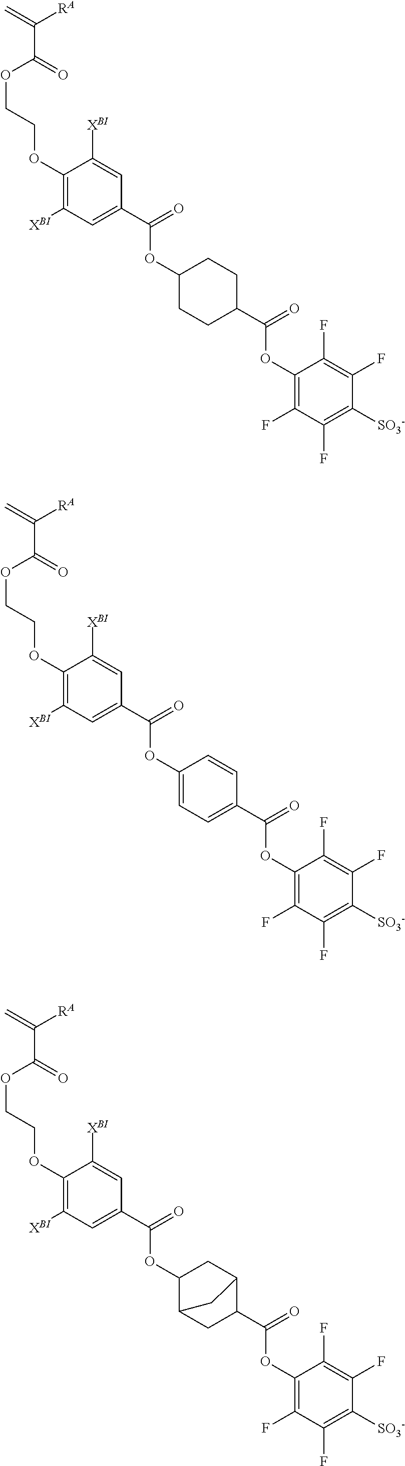

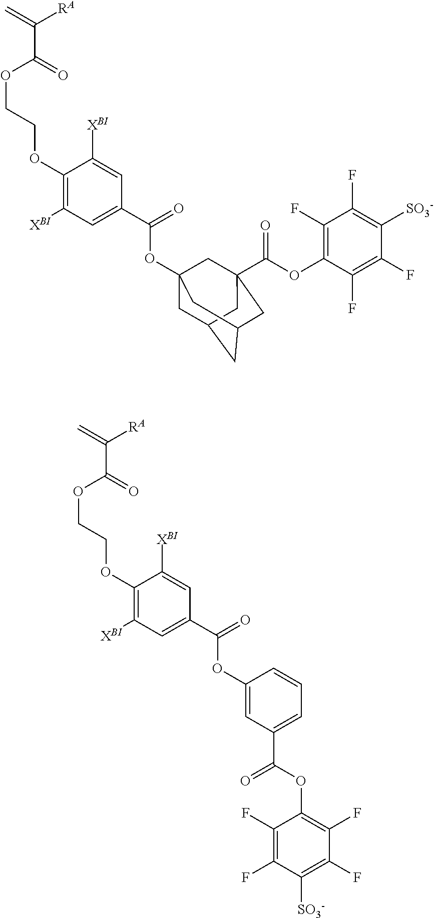

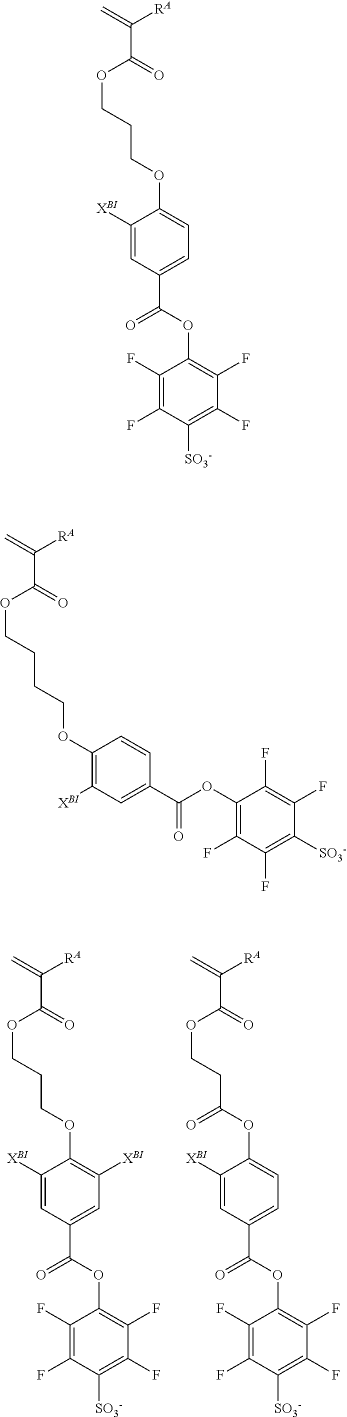

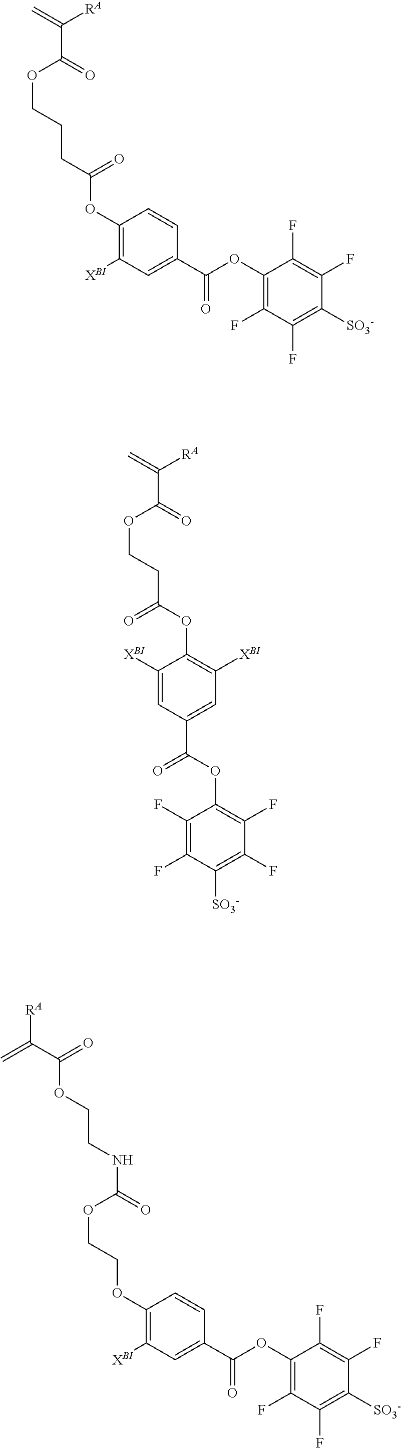

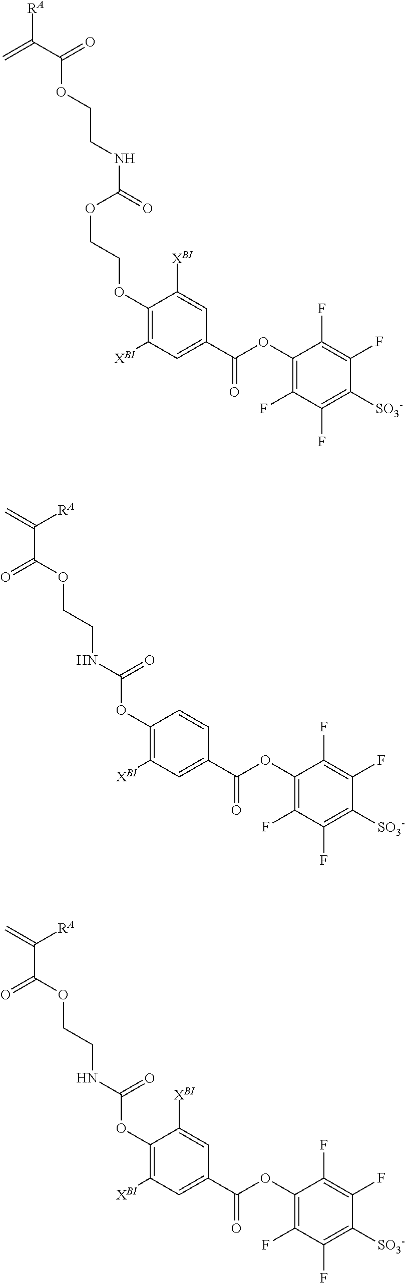

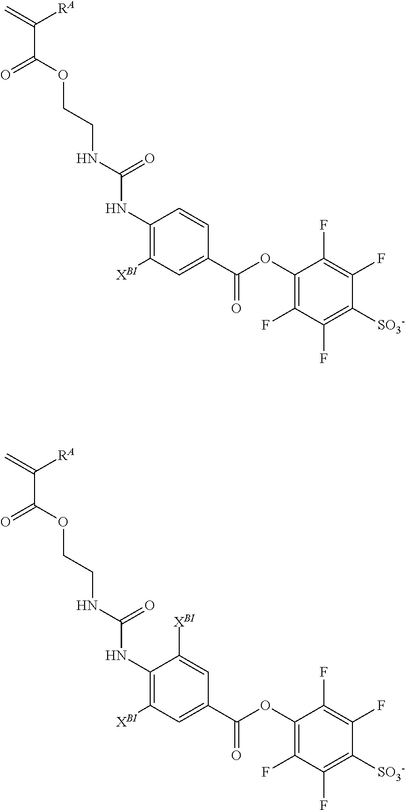

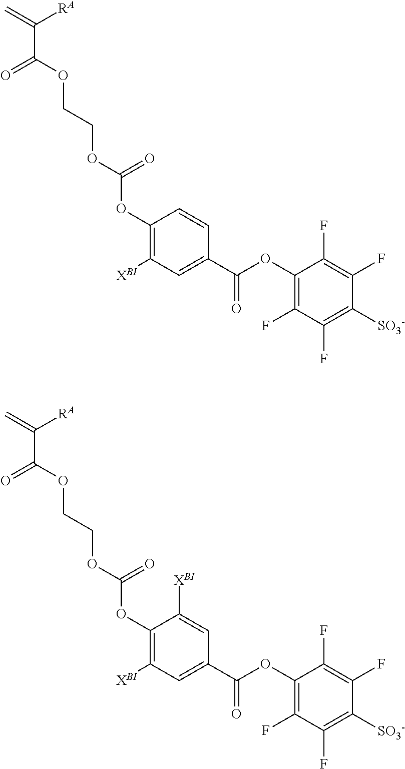

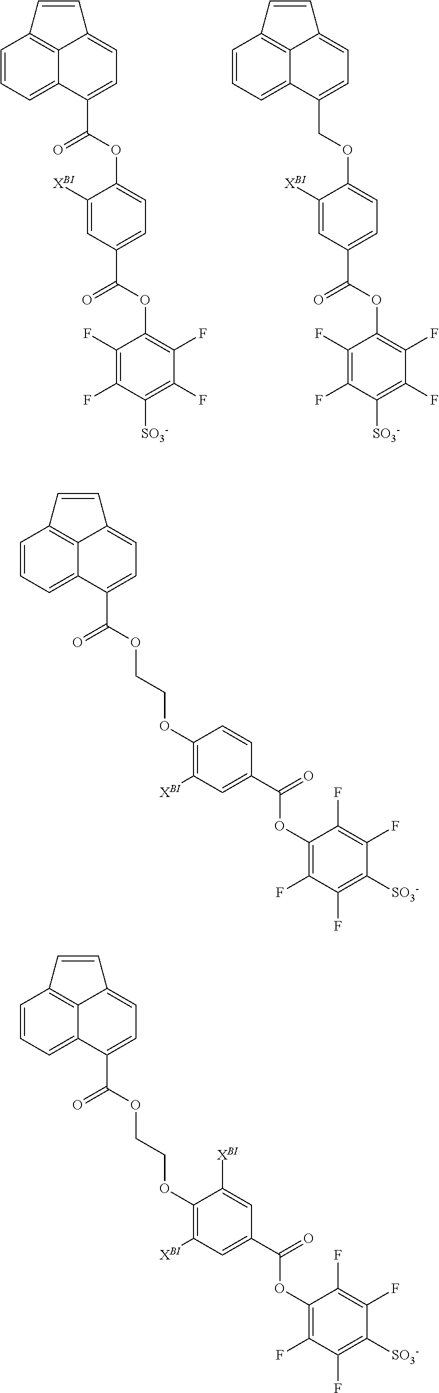

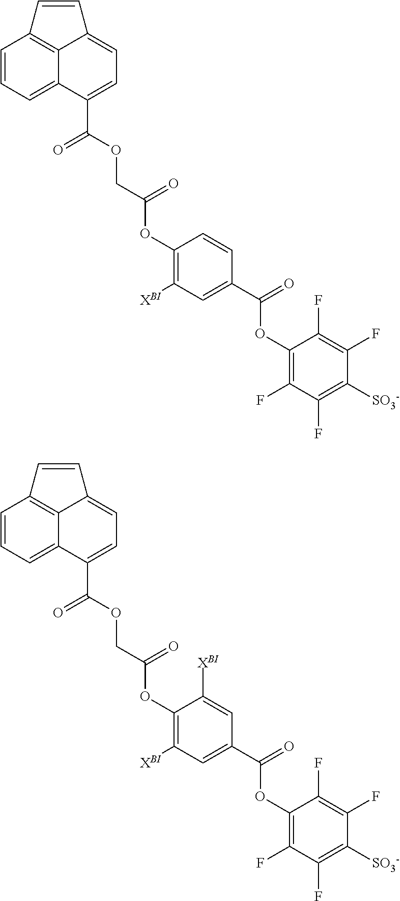

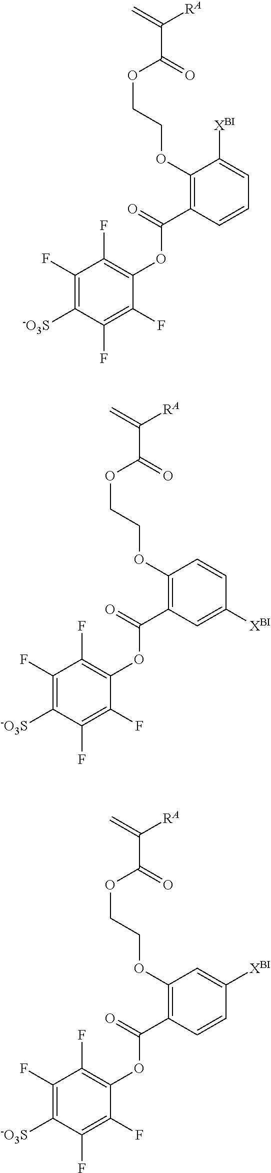

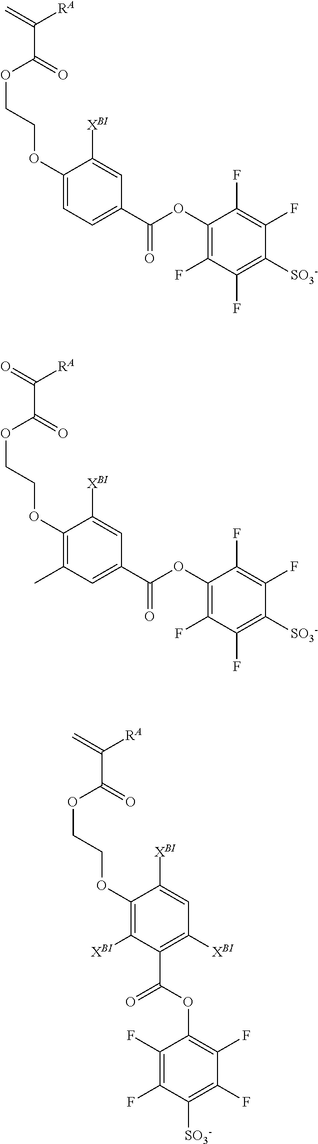

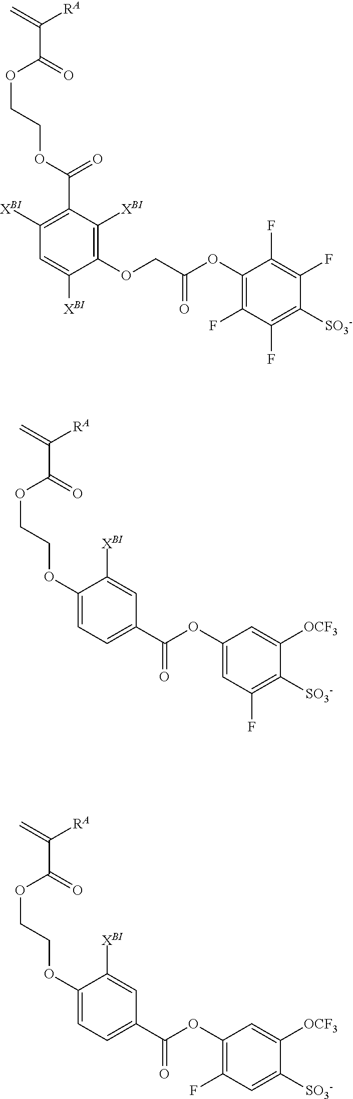

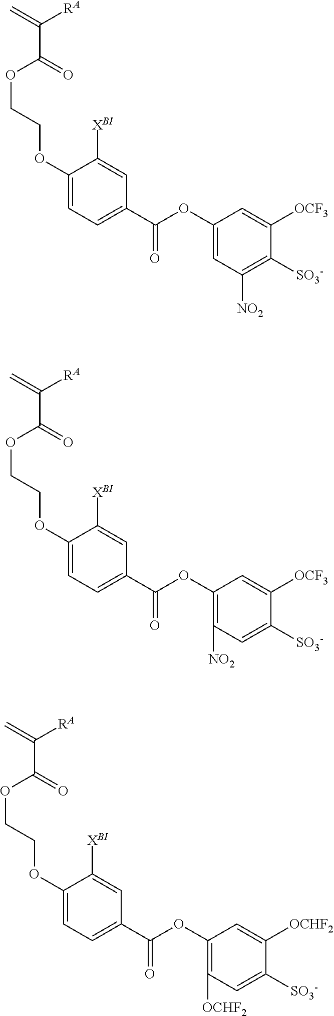

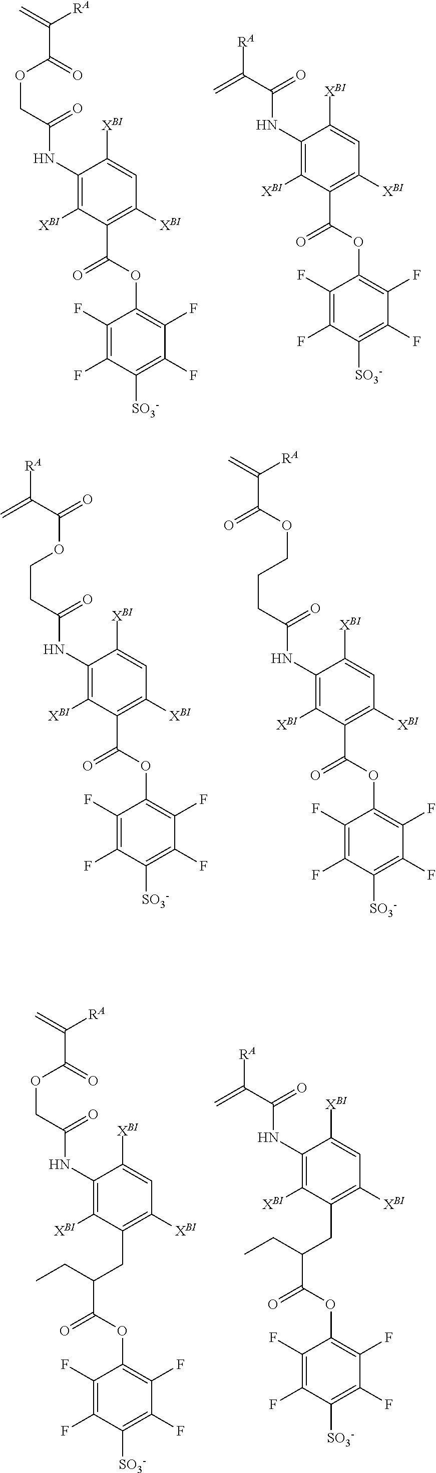

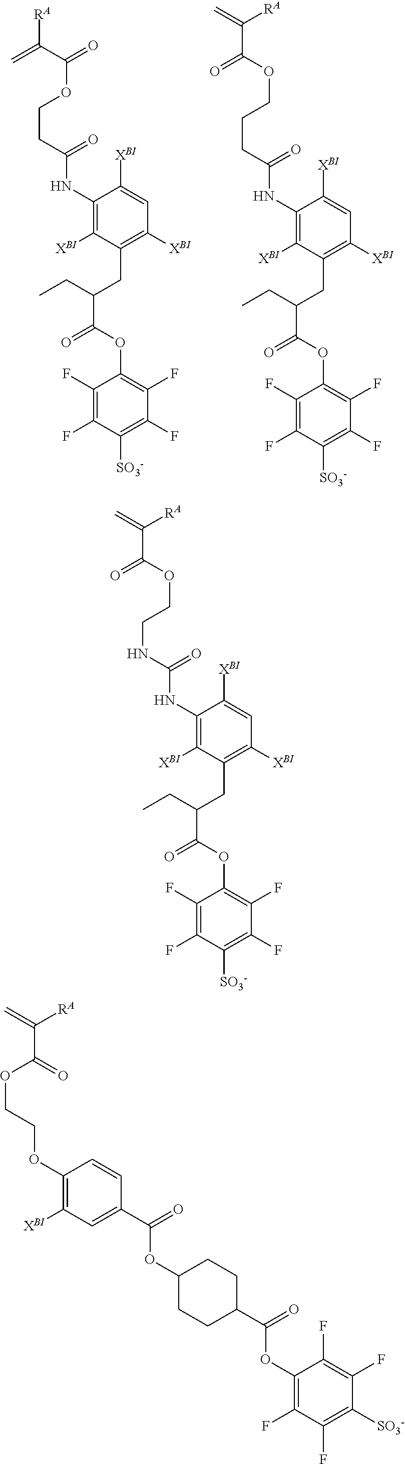

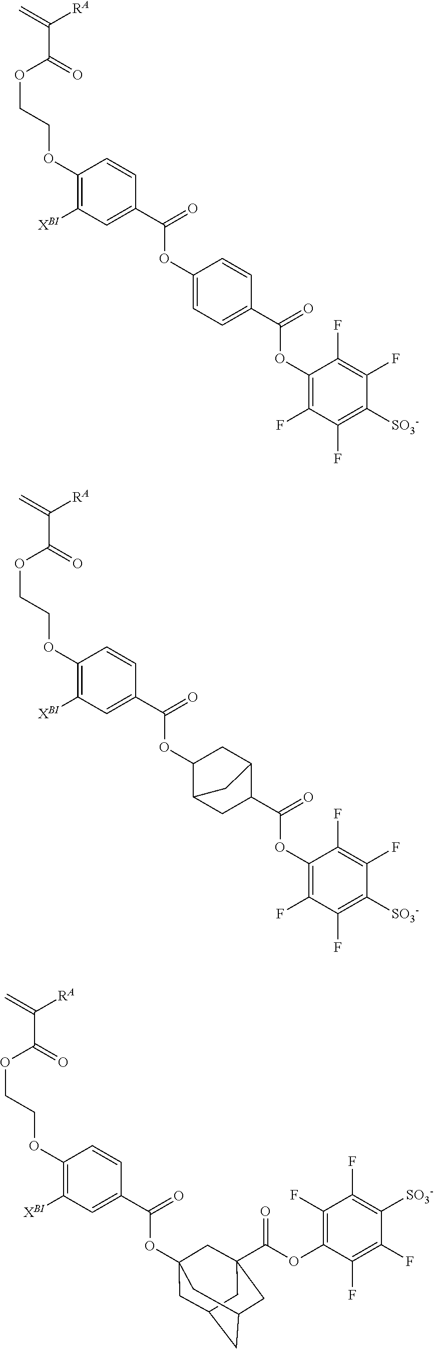

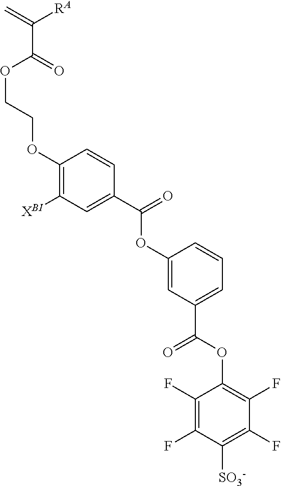

In formulae (a1) and (a2), M⁺ is a sulfonium cation or an iodonium cation. The sulfonium cation preferably has formula (M-1), and the iodonium cation preferably has formula (M-2).

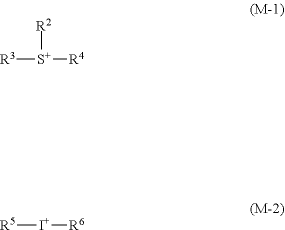

In formulae (M-1) and (M-2), R² to R⁶ are each independently a halogen atom, or a C₁-C₂₀ hydrocarbyl group which may contain a heteroatom.

Examples of the halogen atom represented by R² to R⁶ include a fluorine atom, a chlorine atom, a bromine atom, and an iodine atom.

The C₁-C₂₀ hydrocarbyl group represented by R² to R⁶ may be saturated or unsaturated, and may be straight, branched, or cyclic. Specific examples thereof include C₁-C₂₀ alkyl groups such as a methyl group, an ethyl group, a n-propyl group, an isopropyl group, a n-butyl group, an isobutyl group, a sec-butyl group, a tert-butyl group, a n-pentyl group, a n-hexyl group, a n-octyl group, a n-nonyl group, a n-decyl group, an undecyl group, a dodecyl group, a tridecyl group, a tetradecyl group, a pentadecyl group, a heptadecyl group, an octadecyl group, a nonadecyl group, and an icosyl group; C₃-C₂₀ cyclic saturated hydrocarbyl groups such as a cyclopropyl group, a cyclopentyl group, a cyclohexyl group, a cyclopropylmethyl group, a 4-methylcyclohexyl group, a cyclohexylmethyl group, a norbornyl group, and an adamantyl group; C₂-C₂₀ alkenyl groups such as a vinyl group, a propenyl group, a butenyl group, and a hexenyl group; C₂-C₂₀ alkynyl groups such as an ethynyl group, a propynyl group, and a butynyl group; C₃-C₂₀ cyclic unsaturated aliphatic hydrocarbyl groups such as a cyclohexenyl group and a norbornenyl group; C₆-C₂₀ aryl groups such as a phenyl group, a methylphenyl group, an ethylphenyl group, a n-propylphenyl group, an isopropylphenyl group, a n-butylphenyl group, an isobutylphenyl group, a sec-butylphenyl group, a tert-butylphenyl group, a naphthyl group, a methylnaphthyl group, an ethylnaphthyl group, a n-propylnaphthyl group, an isopropylnaphthyl group, a n-butylnaphthyl group, an isobutylnaphthyl group, a sec-butylnaphthyl group, and a tert-butylnaphthyl group; C₇-C₂₀ aralkyl groups such as a benzyl group and a phenethyl group; and groups obtained by combining the foregoing.

Some or all of hydrogen atoms of the hydrocarbyl group may be substituted with a group containing a heteroatom such as an oxygen atom, a sulfur atom, a nitrogen atom, or a halogen atom, and some of —CH₂— of the hydrocarbyl group may be substituted with a group containing a heteroatom such as an oxygen atom, a sulfur atom, or a nitrogen atom, so that the group may contain a hydroxy group, a fluorine atom, a chlorine atom, a bromine atom, an iodine atom, a cyano group, a nitro group, a mercapto group, a carbonyl group, an ether bond, an ester bond, a sulfonic ester bond, a carbonate bond, a lactone ring, a sultone ring, a carboxylic anhydride (—C(═O)—O—C(═O)—), or a haloalkyl group.

R² and R³ may bond together to form a ring together with the sulfur atom to which they are bonded. In the case, the ring preferably has the following structure.

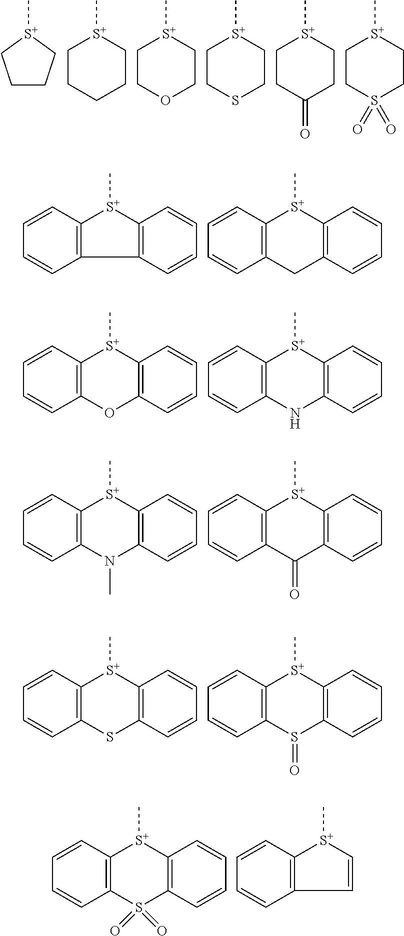

In the formulae, a broken line designates a bond.

Specific examples of the sulfonium cation include those shown below, but are not limited thereto.

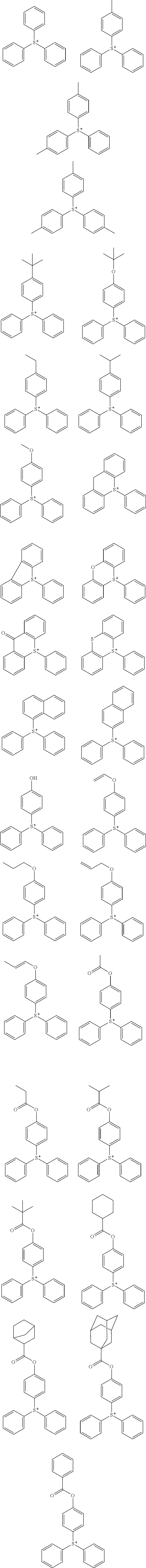

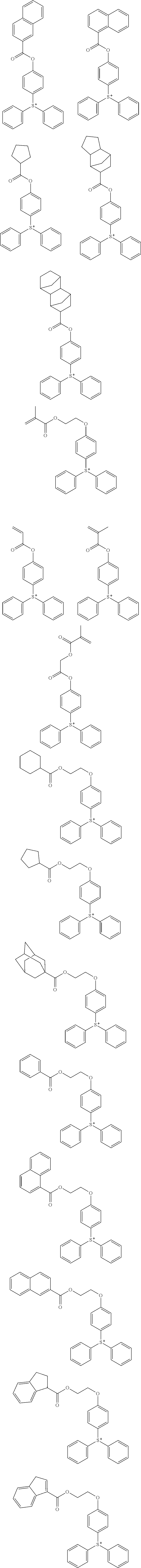

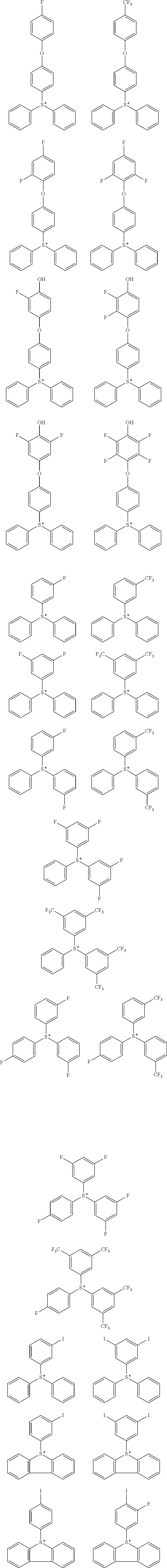

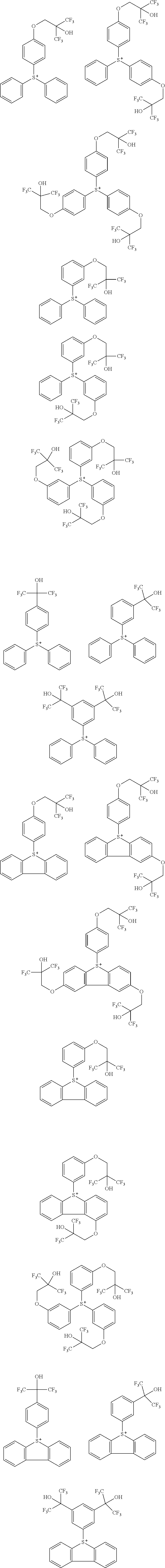

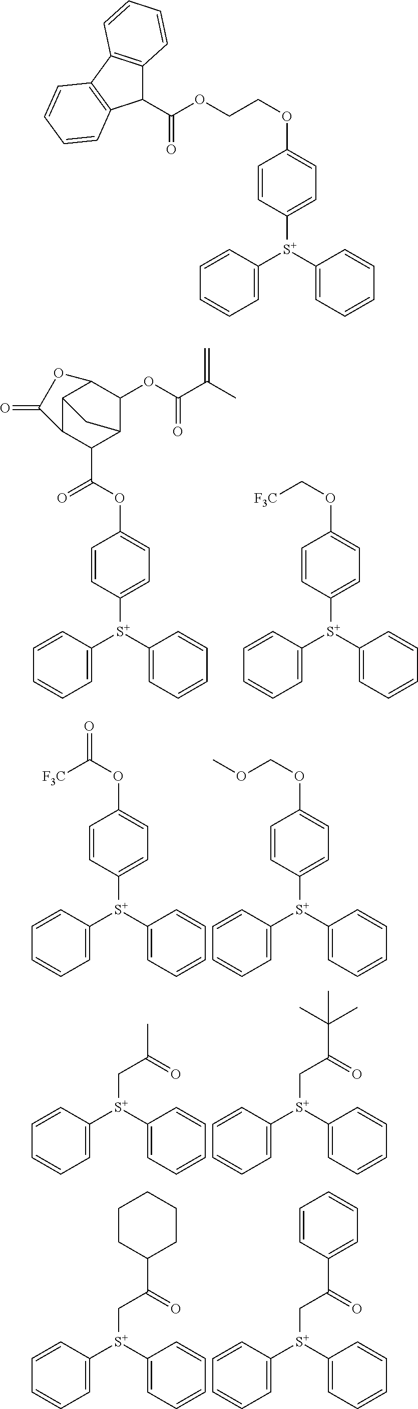

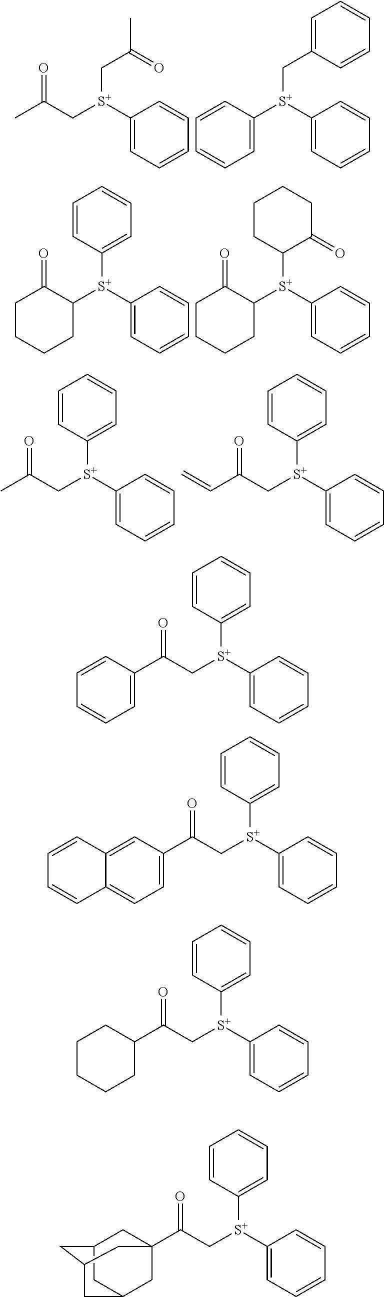

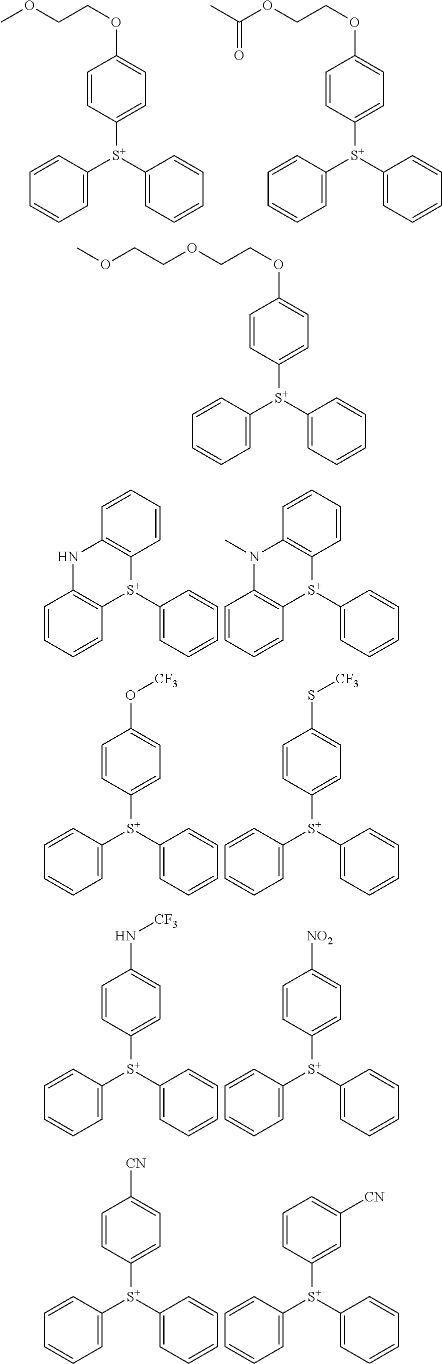

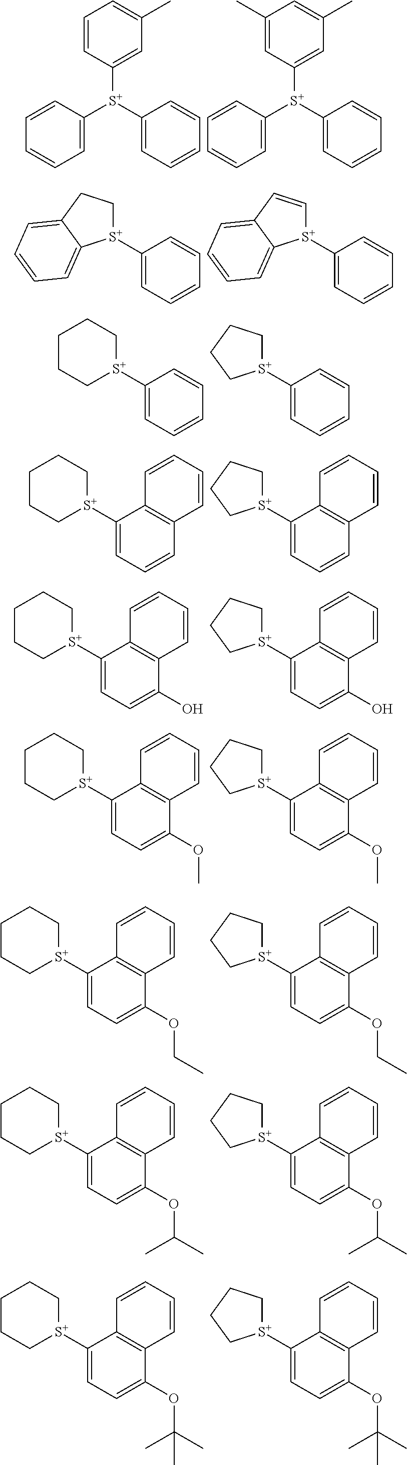

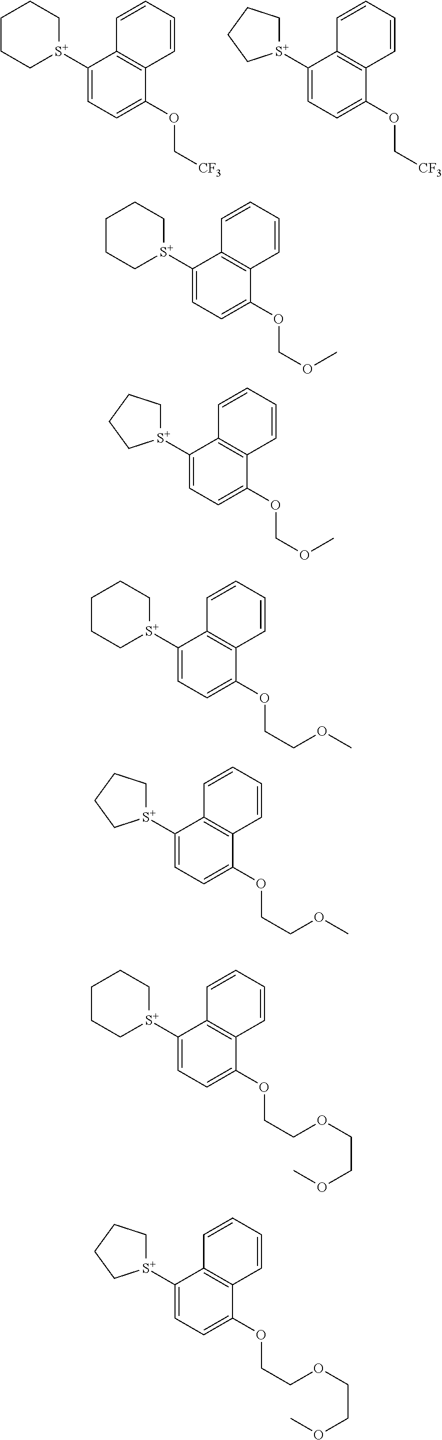

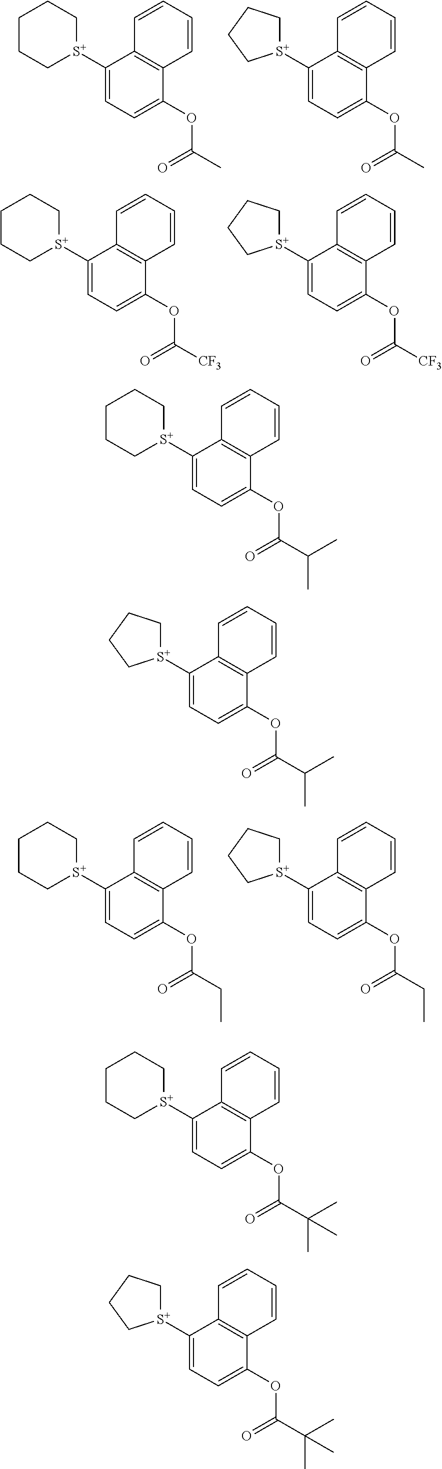

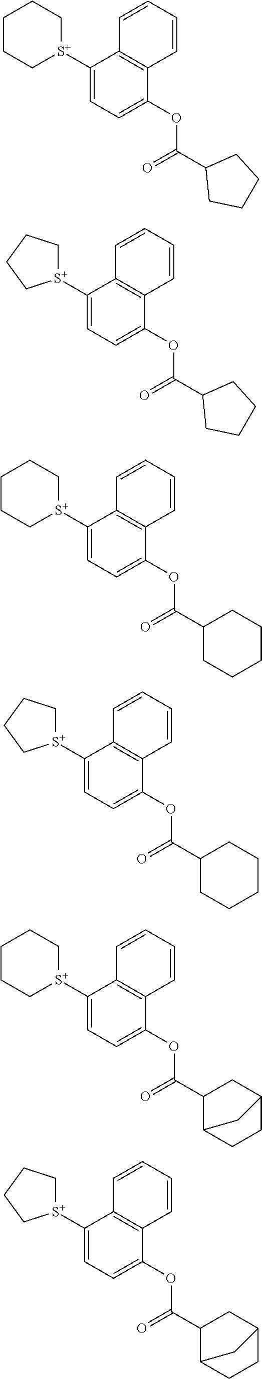 [SMILES: O=C(Oc1ccc([S+]2CCCCC2)c2ccccc12)C1CCCC1 ; O=C(Oc1ccc([S+]2CCCC2)c2ccccc12)C1CCCC1 ; O=C(Oc1ccc([S+]2CCCCC2)c2ccccc12)C1CCCCC1 ; O=C(Oc1ccc([S+]2CCCC2)c2ccccc12)C1CCCCC1 ; O=C(Oc1ccc([S+]2CCCCC2)c2ccccc12)C1CC2CCC1C2 ; O=C(Oc1ccc([S+]2CCCC2)c2ccccc12)C1CC2CCC1C2]

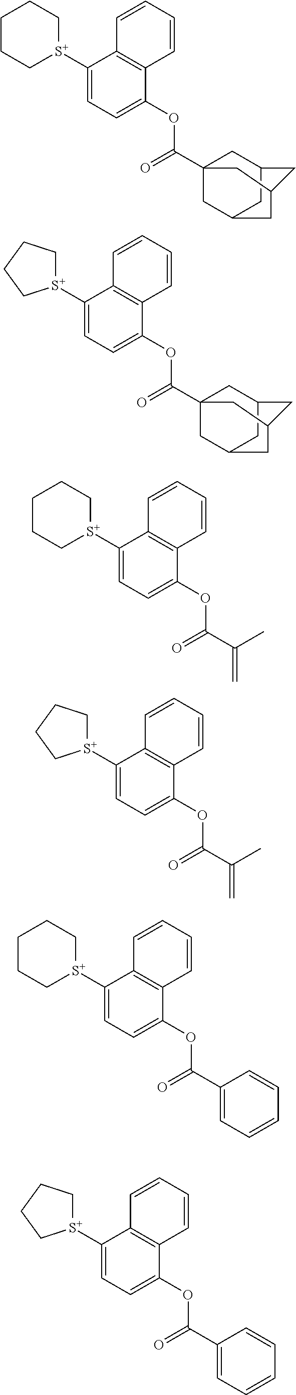 [SMILES: O=C(Oc1ccc([S+]2CCCCC2)c2ccccc12)C12CC3CC(CC(C3)C1)C2 ; O=C(Oc1ccc([S+]2CCCC2)c2ccccc12)C12CC3CC(CC(C3)C1)C2 ; C=C(C)C(=O)Oc1ccc([S+]2CCCCC2)c2ccccc12 ; C=C(C)C(=O)Oc1ccc([S+]2CCCC2)c2ccccc12 ; O=C(Oc1ccc([S+]2CCCCC2)c2ccccc12)c1ccccc1 ; O=C(Oc1ccc([S+]2CCCC2)c2ccccc12)c1ccccc1]

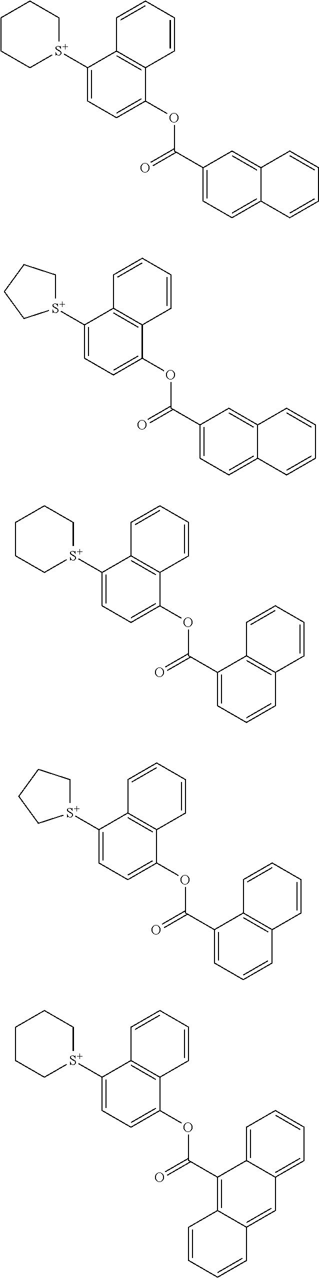 [SMILES: O=C(Oc1ccc([S+]2CCCCC2)c2ccccc12)c1ccc2ccccc2c1 ; O=C(Oc1ccc([S+]2CCCC2)c2ccccc12)c1ccc2ccccc2c1 ; O=C(Oc1ccc([S+]2CCCCC2)c2ccccc12)c1cccc2ccccc12 ; O=C(Oc1ccc([S+]2CCCC2)c2ccccc12)c1cccc2ccccc12 ; O=C(Oc1ccc([S+]2CCCCC2)c2ccccc12)c1c2ccccc2cc2ccccc12]

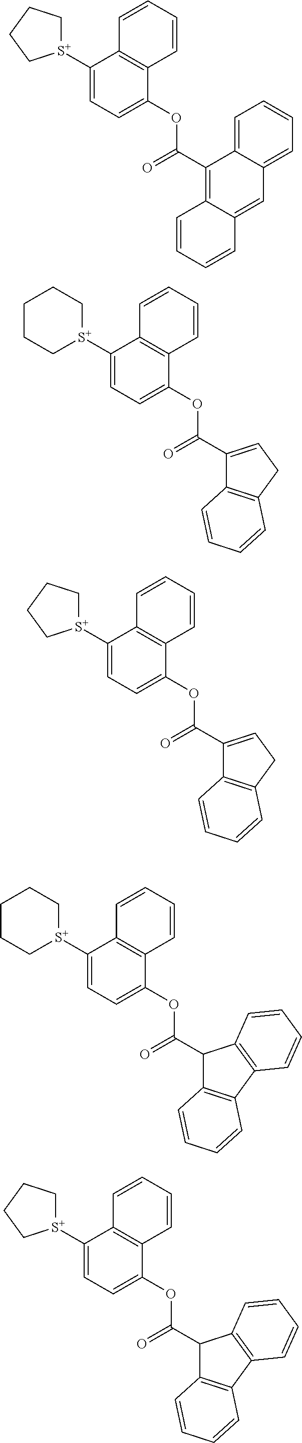 [SMILES: O=C(Oc1ccc([S+]2CCCC2)c2ccccc12)c1c2ccccc2cc2ccccc12 ; O=C(Oc1ccc([S+]2CCCCC2)c2ccccc12)C1=CCc2ccccc21 ; O=C(Oc1ccc([S+]2CCCC2)c2ccccc12)C1=CCc2ccccc21 ; O=C(Oc1ccc([S+]2CCCCC2)c2ccccc12)C1c2ccccc2-c2ccccc21 ; O=C(Oc1ccc([S+]2CCCC2)c2ccccc12)C1c2ccccc2-c2ccccc21]

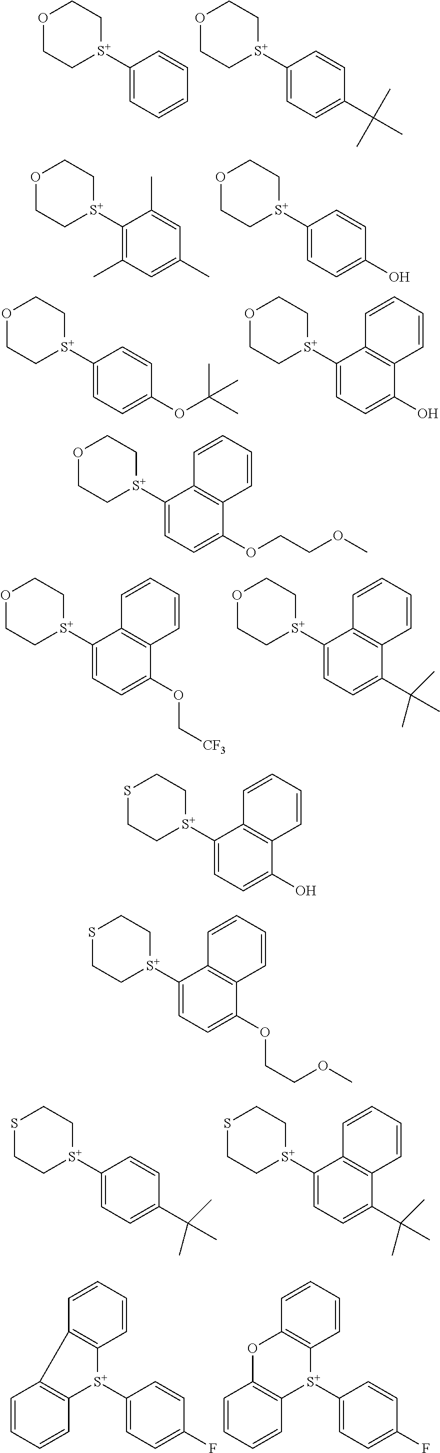

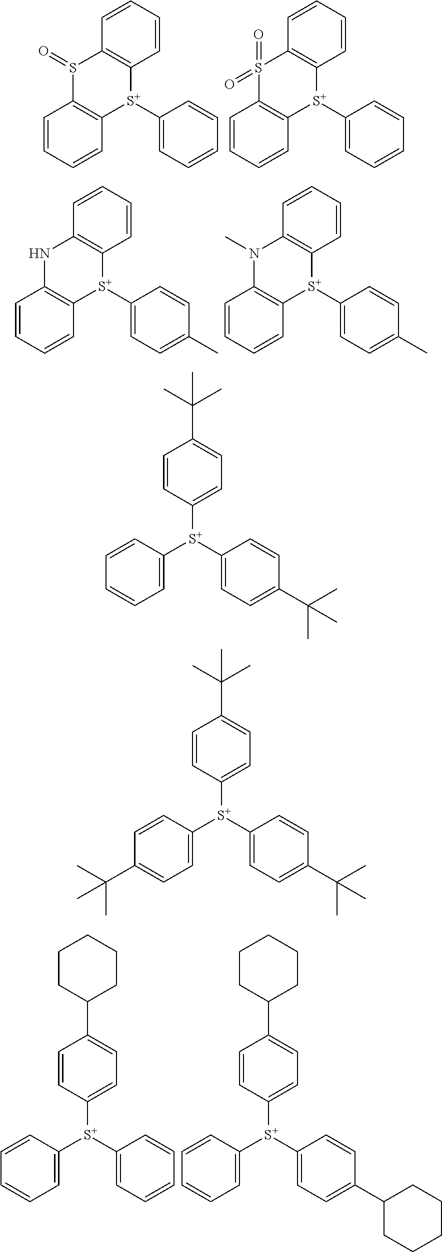

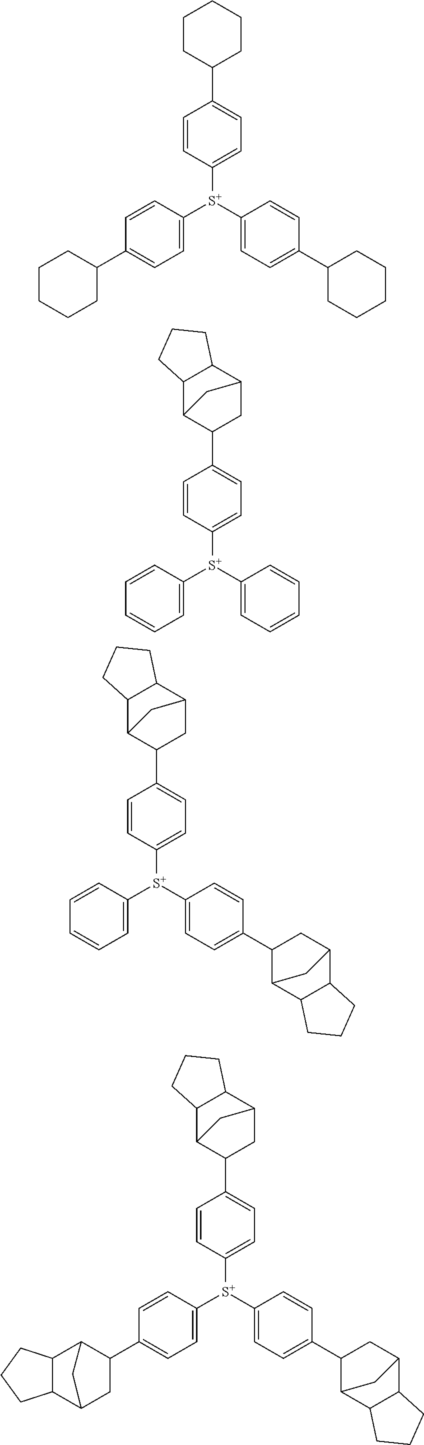 [SMILES: c1cc([S+](c2ccc(C3CCCCC3)cc2)c2ccc(C3CCCCC3)cc2)ccc1C1CCCCC1 ; c1ccc([S+](c2ccccc2)c2ccc(C3CC4CC3C3CCCC43)cc2)cc1 ; c1ccc([S+](c2ccc(C3CC4CC3C3CCCC43)cc2)c2ccc(C3CC4CC3C3CCCC43)cc2)cc1 ; c1cc([S+](c2ccc(C3CC4CC3C3CCCC43)cc2)c2ccc(C3CC4CC3C3CCCC43)cc2)ccc1C1CC2CC1C1CCCC21]

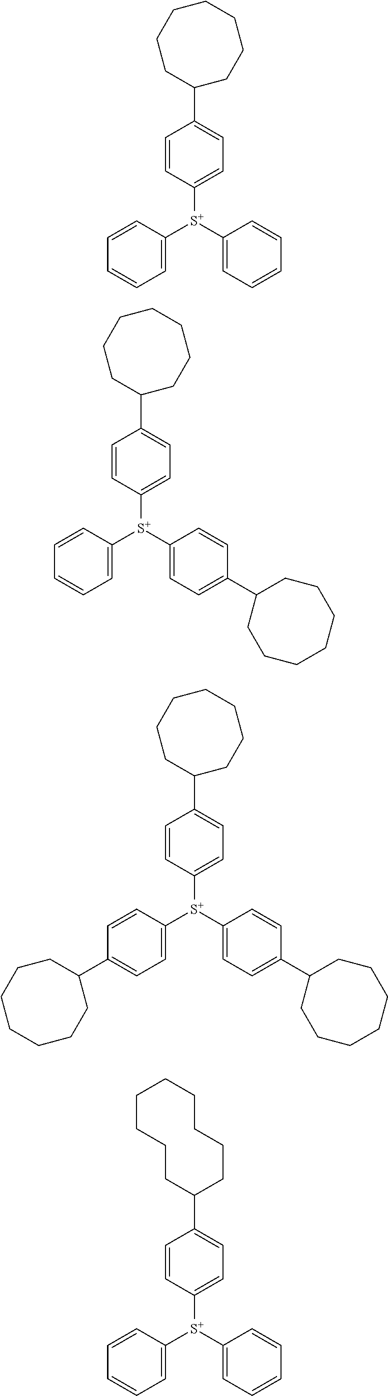 [SMILES: c1ccc([S+](c2ccccc2)c2ccc(C3CCCCCCC3)cc2)cc1 ; c1ccc([S+](c2ccc(C3CCCCCCC3)cc2)c2ccc(C3CCCCCCC3)cc2)cc1 ; c1cc([S+](c2ccc(C3CCCCCCC3)cc2)c2ccc(C3CCCCCCC3)cc2)ccc1C1CCCCCCC1 ; c1ccc([S+](c2ccccc2)c2ccc(C3CCCCCCCCC3)cc2)cc1]

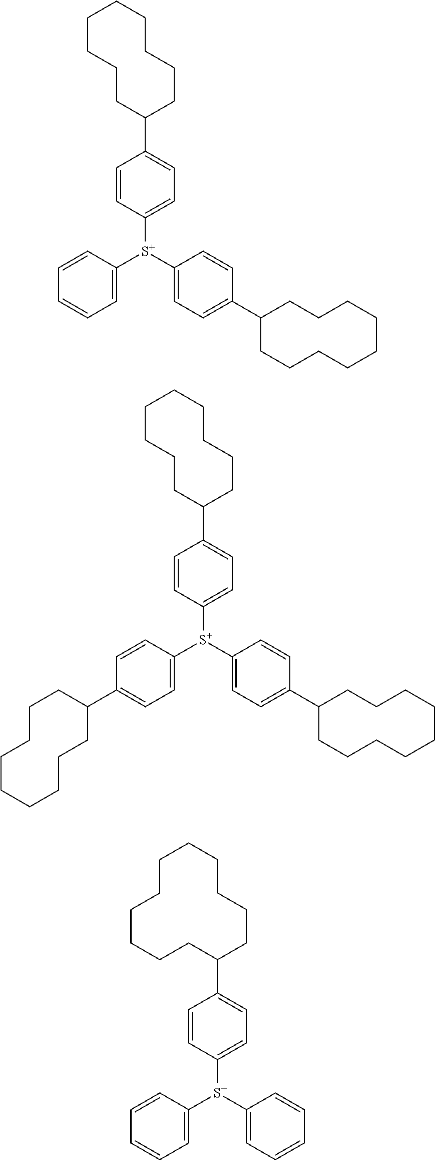 [SMILES: c1ccc([S+](c2ccc(C3CCCCCCCCC3)cc2)c2ccc(C3CCCCCCCCC3)cc2)cc1 ; c1cc([S+](c2ccc(C3CCCCCCCCC3)cc2)c2ccc(C3CCCCCCCCC3)cc2)ccc1C1CCCCCCCCC1 ; c1ccc([S+](c2ccccc2)c2ccc(C3CCCCCCCCCCC3)cc2)cc1]

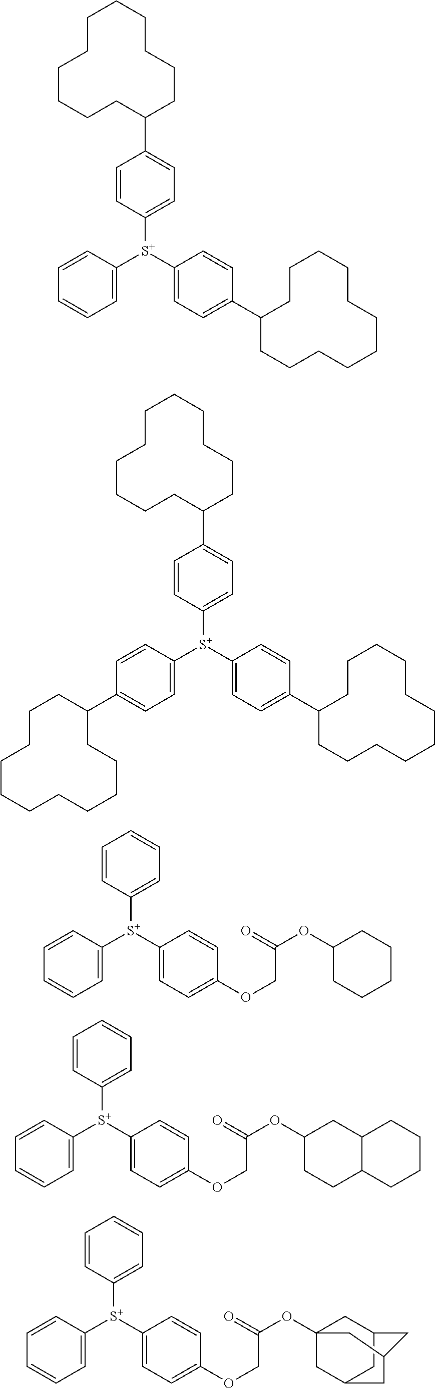 [SMILES: c1ccc([S+](c2ccc(C3CCCCCCCCCCC3)cc2)c2ccc(C3CCCCCCCCCCC3)cc2)cc1 ; c1cc([S+](c2ccc(C3CCCCCCCCCCC3)cc2)c2ccc(C3CCCCCCCCCCC3)cc2)ccc1C1CCCCCCCCCCC1 ; O=C(COc1ccc([S+](c2ccccc2)c2ccccc2)cc1)OC1CCCCC1 ; O=C(COc1ccc([S+](c2ccccc2)c2ccccc2)cc1)OC1CCC2CCCCC2C1 ; O=C(COc1ccc([S+](c2ccccc2)c2ccccc2)cc1)OC12CC3CC(CC(C3)C1)C2]

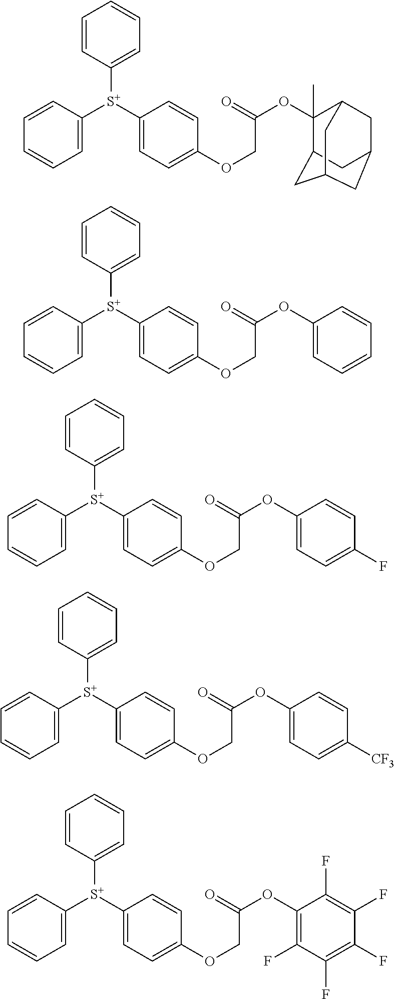 [SMILES: CC1(OC(=O)COc2ccc([S+](c3ccccc3)c3ccccc3)cc2)C2CC3CC(C2)CC1C3 ; O=C(COc1ccc([S+](c2ccccc2)c2ccccc2)cc1)Oc1ccccc1 ; O=C(COc1ccc([S+](c2ccccc2)c2ccccc2)cc1)Oc1ccc(F)cc1 ; O=C(COc1ccc([S+](c2ccccc2)c2ccccc2)cc1)Oc1ccc(C(F)(F)F)cc1 ; O=C(COc1ccc([S+](c2ccccc2)c2ccccc2)cc1)Oc1c(F)c(F)c(F)c(F)c1F]

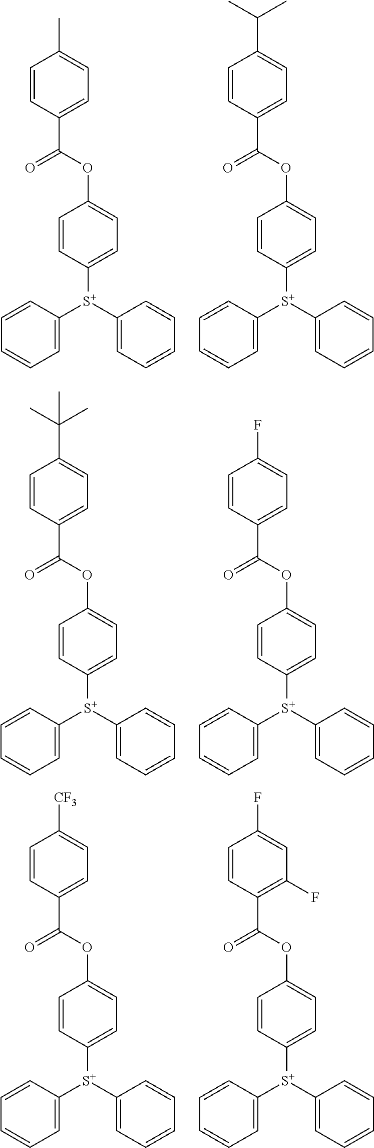 [SMILES: Cc1ccc(C(=O)Oc2ccc([S+](c3ccccc3)c3ccccc3)cc2)cc1 ; CC(C)c1ccc(C(=O)Oc2ccc([S+](c3ccccc3)c3ccccc3)cc2)cc1 ; CC(C)(C)c1ccc(C(=O)Oc2ccc([S+](c3ccccc3)c3ccccc3)cc2)cc1 ; O=C(Oc1ccc([S+](c2ccccc2)c2ccccc2)cc1)c1ccc(F)cc1 ; O=C(Oc1ccc([S+](c2ccccc2)c2ccccc2)cc1)c1ccc(C(F)(F)F)cc1 ; O=C(Oc1ccc([S+](c2ccccc2)c2ccccc2)cc1)c1ccc(F)cc1F]

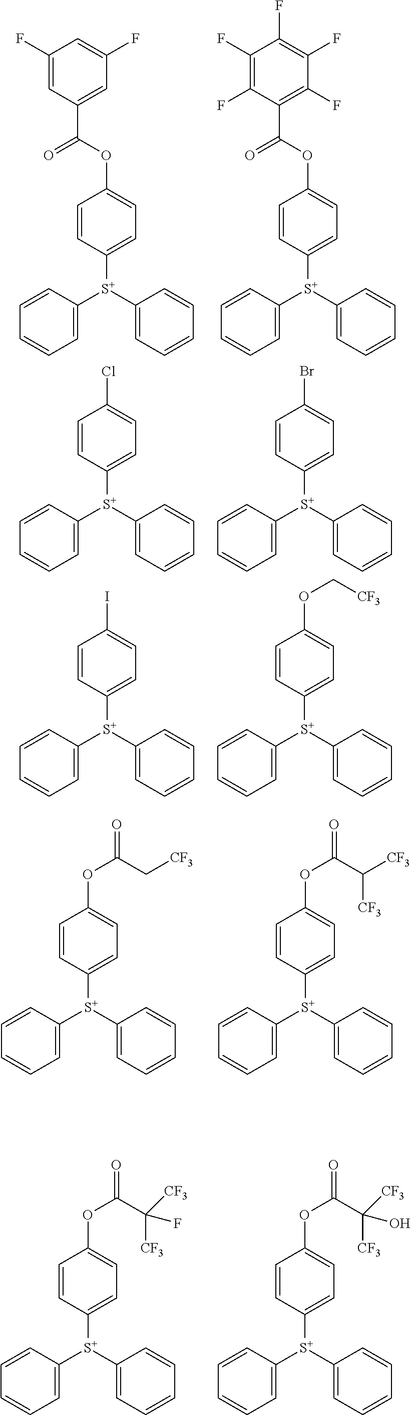

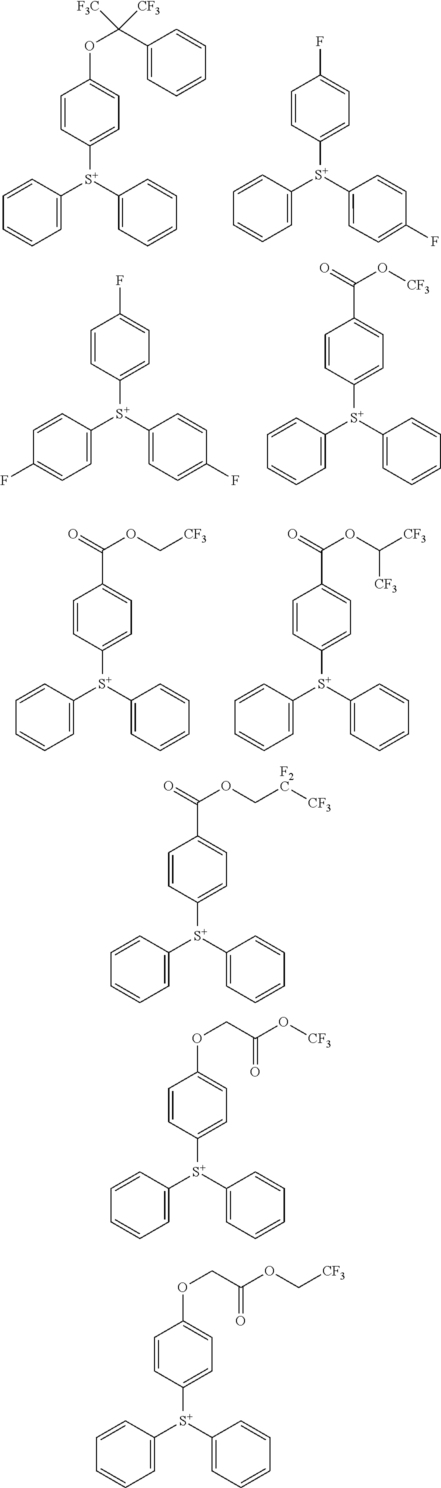

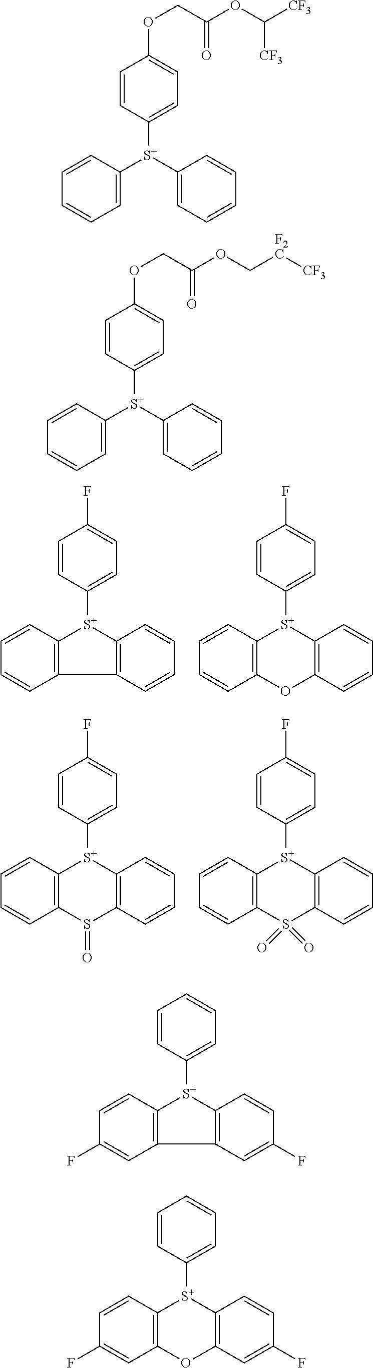

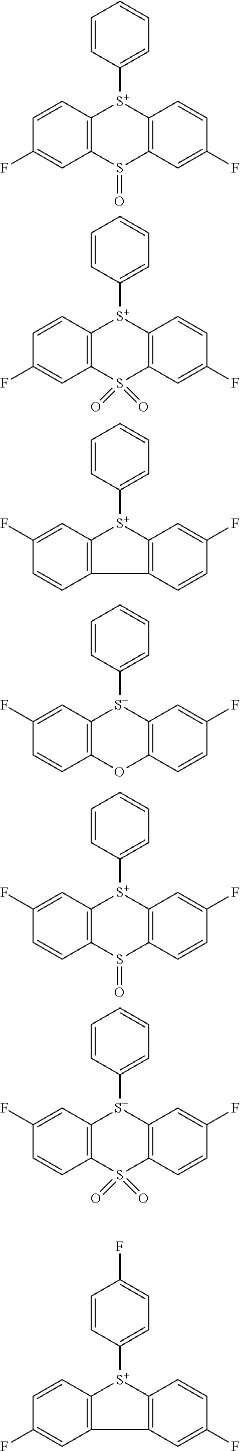

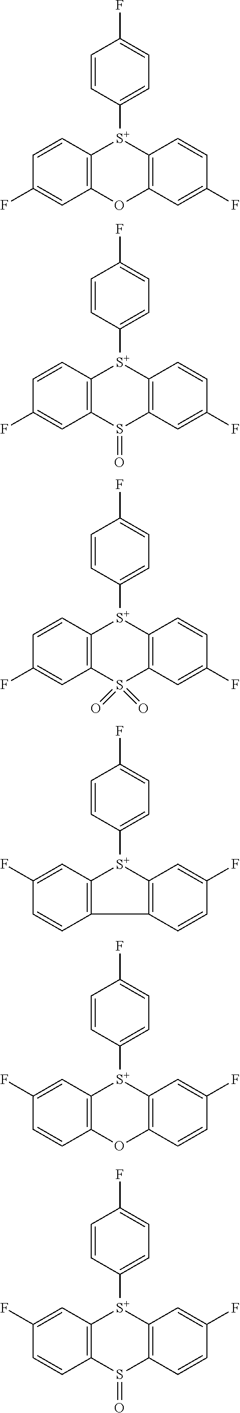 [SMILES: Fc1ccc([S+]2c3ccc(F)cc3Oc3cc(F)ccc32)cc1 ; O=S1c2cc(F)ccc2[S+](c2ccc(F)cc2)c2ccc(F)cc21 ; O=S1(=O)c2cc(F)ccc2[S+](c2ccc(F)cc2)c2ccc(F)cc21 ; Fc1ccc(-[s+]2c3cc(F)ccc3c3ccc(F)cc32)cc1 ; Fc1ccc([S+]2c3cc(F)ccc3Oc3ccc(F)cc32)cc1 ; O=S1c2ccc(F)cc2[S+](c2ccc(F)cc2)c2cc(F)ccc21]

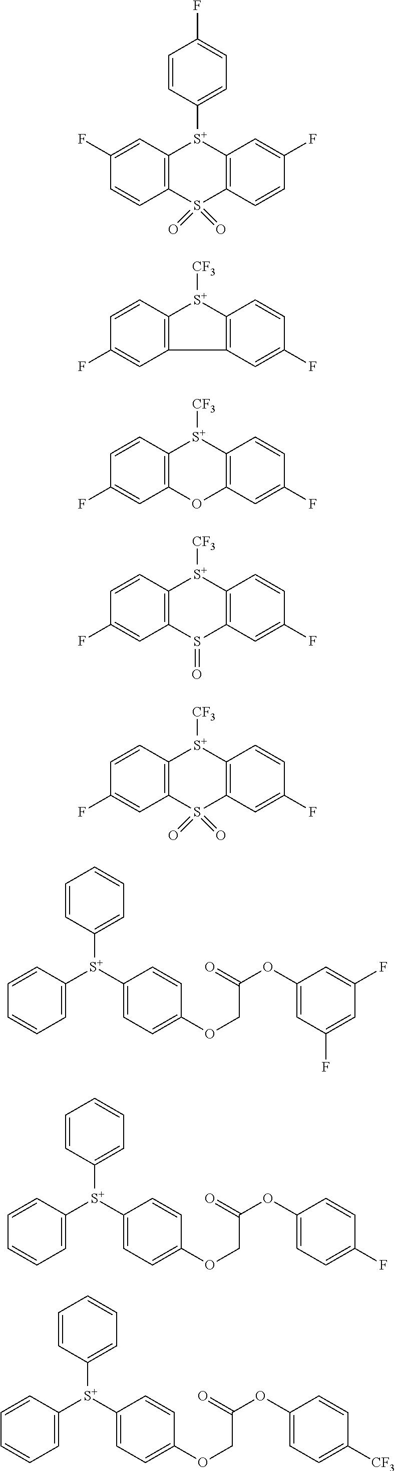

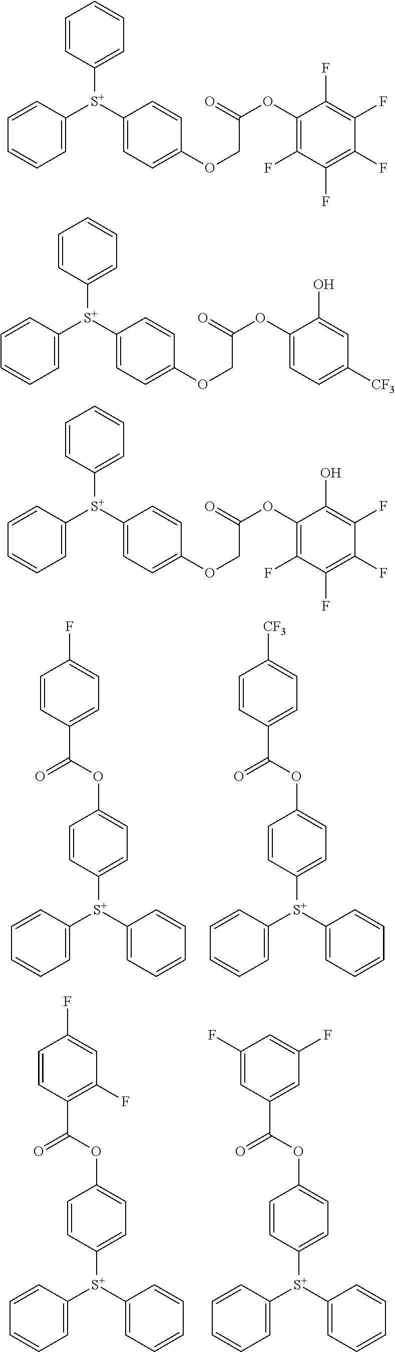

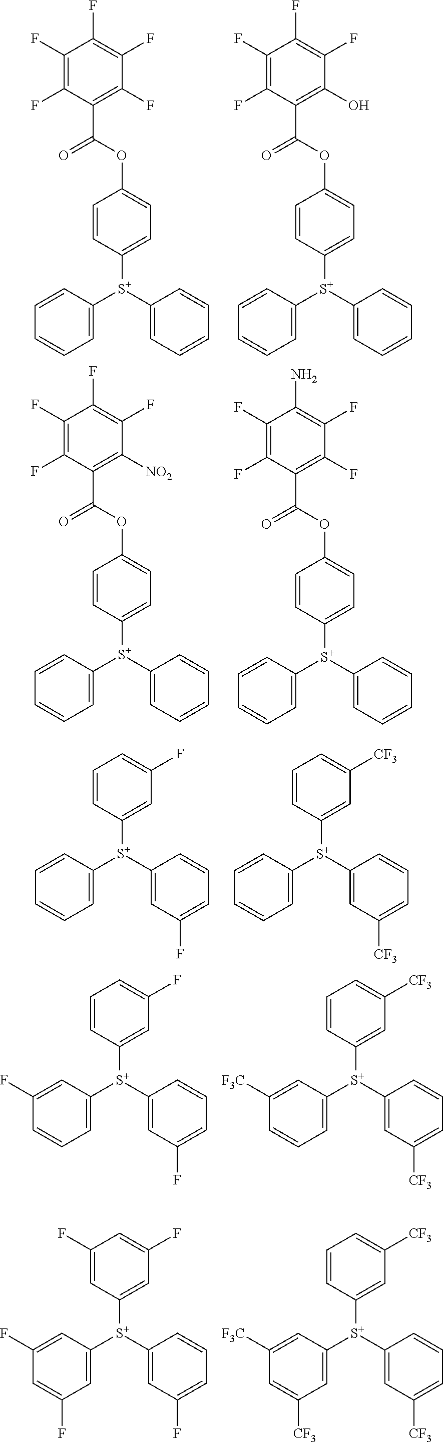

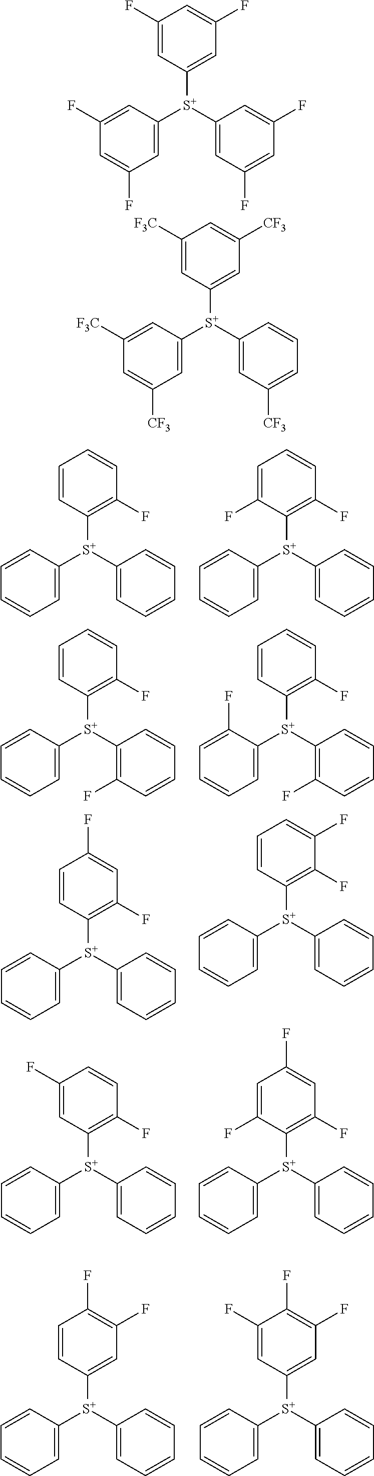

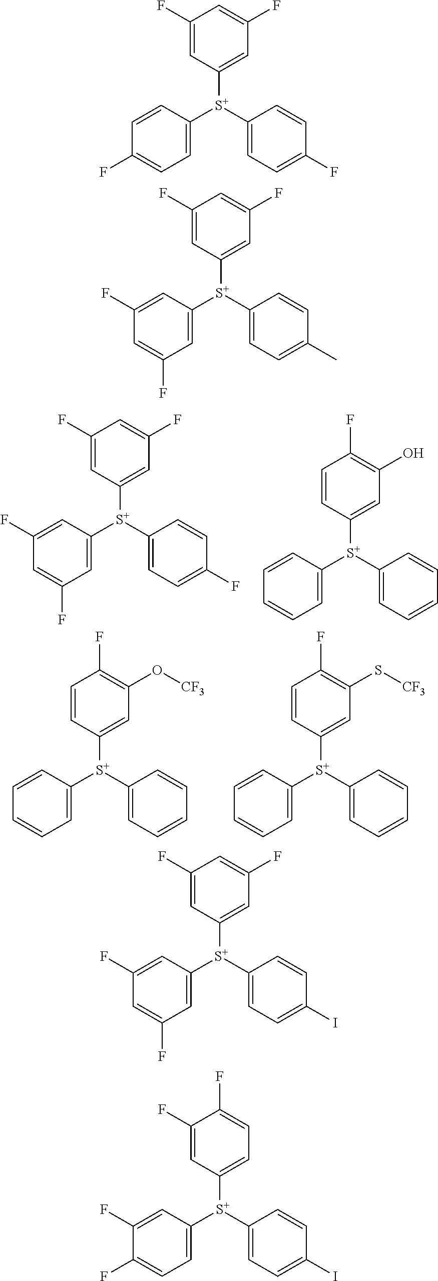

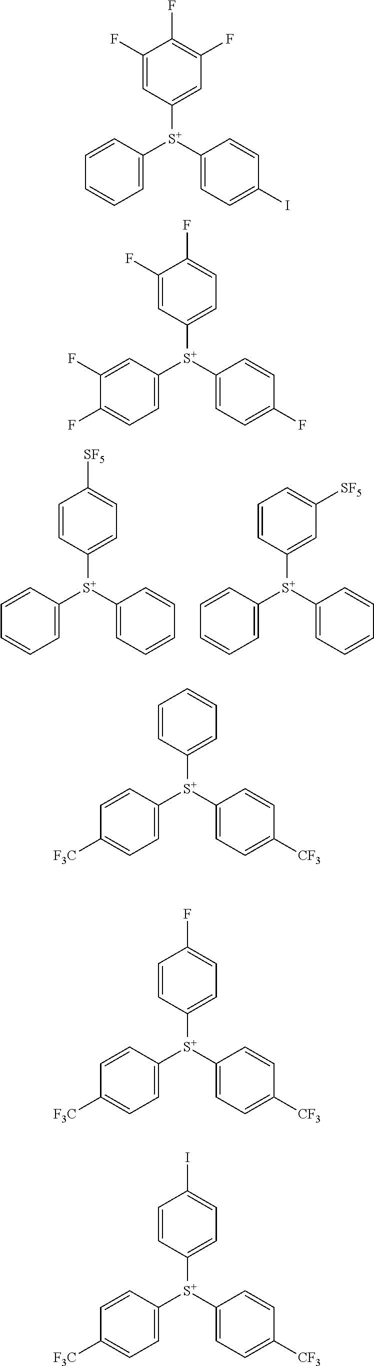

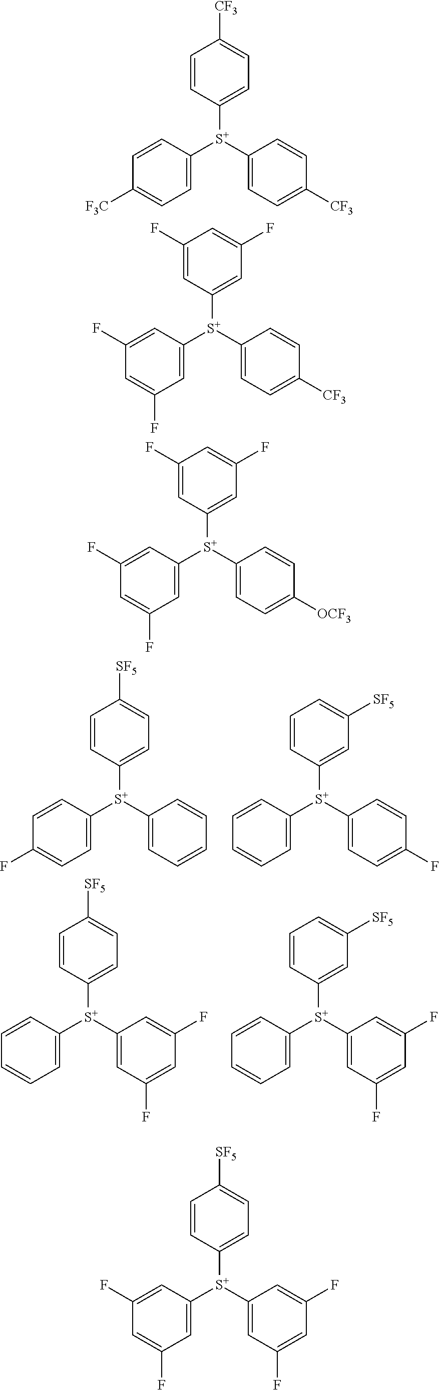

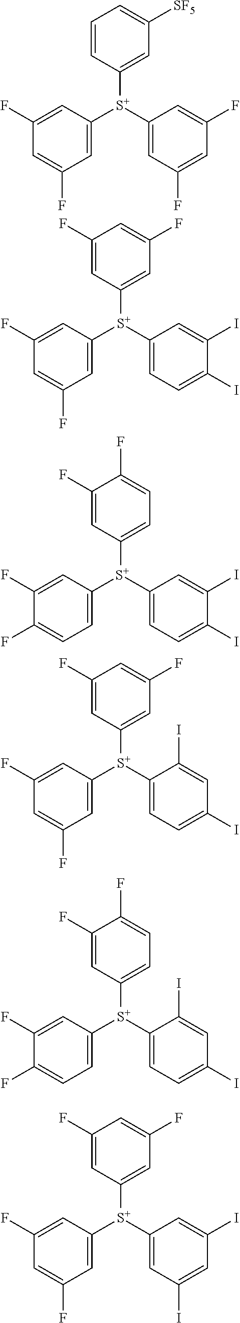

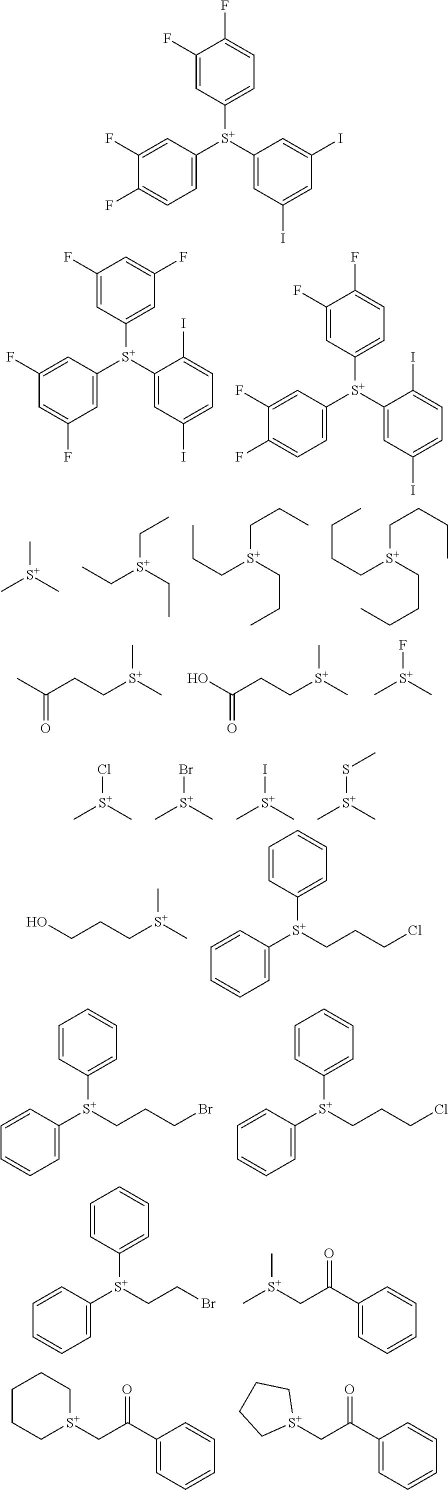

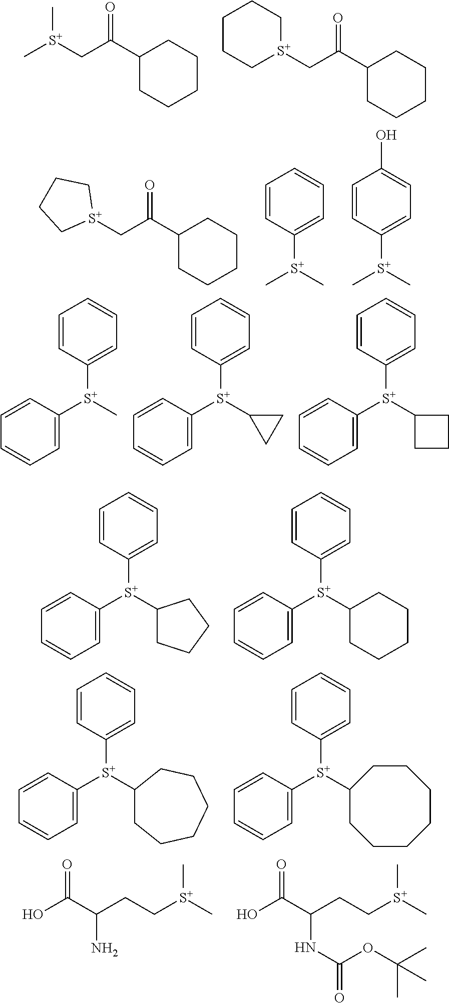

Examples of the iodonium cation include those shown below, but are not limited thereto.

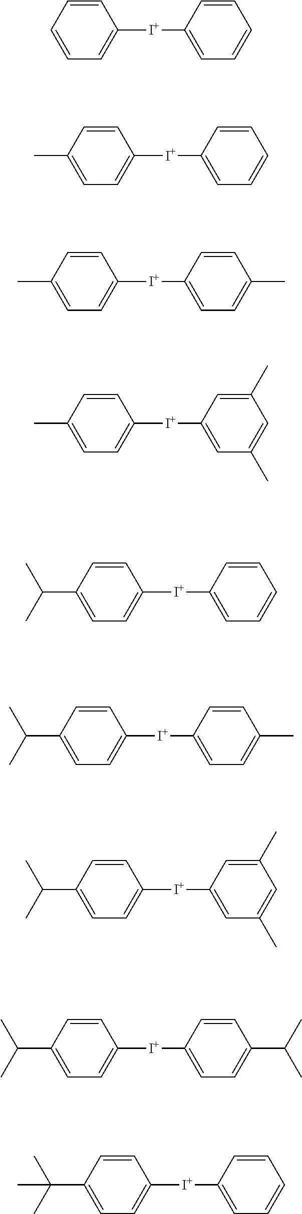

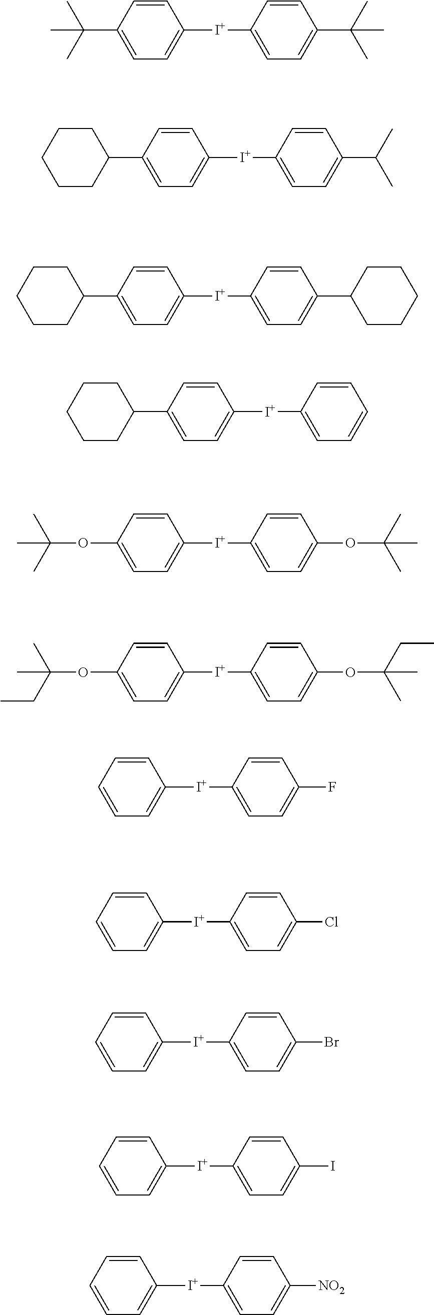

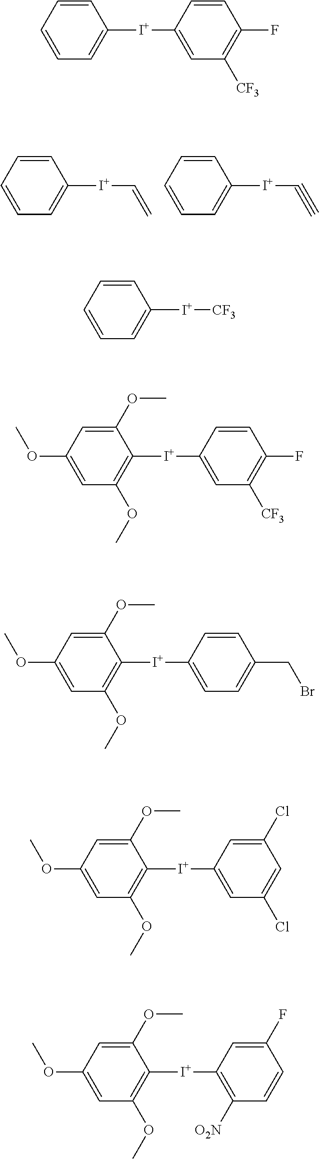

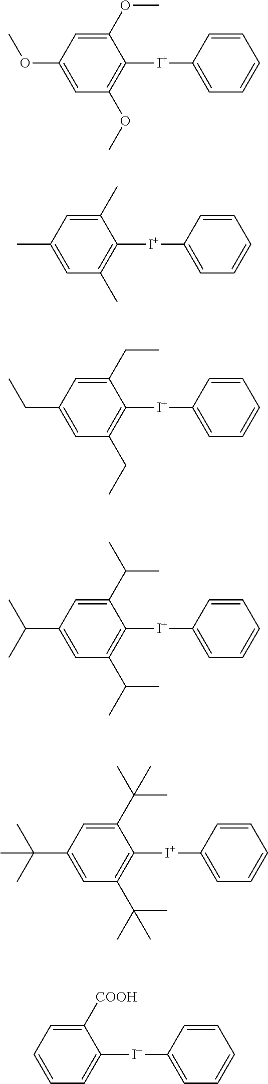 [SMILES: COc1cc(OC)c([I+]c2ccccc2)c(OC)c1 ; Cc1cc(C)c([I+]c2ccccc2)c(C)c1 ; CCc1cc(CC)c([I+]c2ccccc2)c(CC)c1 ; CC(C)c1cc(C(C)C)c([I+]c2ccccc2)c(C(C)C)c1 ; CC(C)(C)c1cc(C(C)(C)C)c([I+]c2ccccc2)c(C(C)(C)C)c1 ; O=C(O)c1ccccc1[I+]c1ccccc1]

The sulfonium salt type monomer from which the repeat units (a) are derived may be synthesized, for example, by ion exchange between a salt containing the sulfonium cation and a weak acid anion and an ammonium salt having the above anion. The sulfonium cation can be obtained, for example, by the method described in paragraphs [0094] to [0097] of JP-A 2022-068394. In the case of an iodonium salt type monomer, the same ion exchange method as described above can be mentioned.

When the resist composition is of positive tone, the base polymer preferably further contains repeat units containing an acid labile group. The repeat units containing an acid labile group are preferably repeat units having formula (b1) (hereinafter, the repeat units are also referred to as repeat units (b1)) or repeat units having formula (b2) (hereinafter, the repeat units are also referred to as repeat units (b2)). In the exposed region, not only the repeat units (b1) and (b2) each containing an acid labile group, but also the repeat units (a) containing an acid generator in the base polymer undergo catalytic reaction, whereby the dissolution rate in the developer is accelerated. Thus, a positive resist composition having very high sensitivity is obtained.

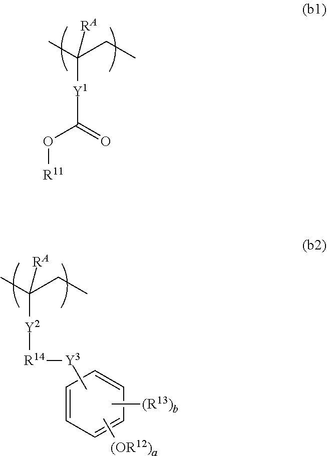

In formulae (b1) and (b2), R^{A} is each independently a hydrogen atom or a methyl group. Y¹ is a single bond, a phenylene group, a naphthylene group, or a C₁-C₁₂ linking group containing at least one moiety selected from an ester bond, an ether bond, a lactone ring, a hydroxy group, and a halogen atom. Y² is a single bond or an ester bond. Y³ is a single bond, an ether bond, or an ester bond. R¹¹ and R¹² are each independently an acid labile group. R¹³ is a fluorine atom, a chlorine atom, a bromine atom, an iodine atom, a trifluoromethyl group, a cyano group, a C₁-C₆ saturated hydrocarbyl group, a C₁-C₆ saturated hydrocarbyloxy group, a C₂-C₇ saturated hydrocarbylcarbonyl group, a C₂-C₇ saturated hydrocarbylcarbonyloxy group, or a C₂-C₇ saturated hydrocarbyloxycarbonyl group. R¹⁴ is a single bond or a C₁-C₆ alkanediyl group in which some constituent —CH₂— may be substituted with an ether bond or an ester bond. a is 1 or 2. b is an integer of 0 to 4. Provided that 1≤a+b≤5.

Examples of the monomer from which the repeat units (b1) are derived include those shown below, but are not limited thereto. In the formulae, R^{A} and R¹¹ are as defined above.

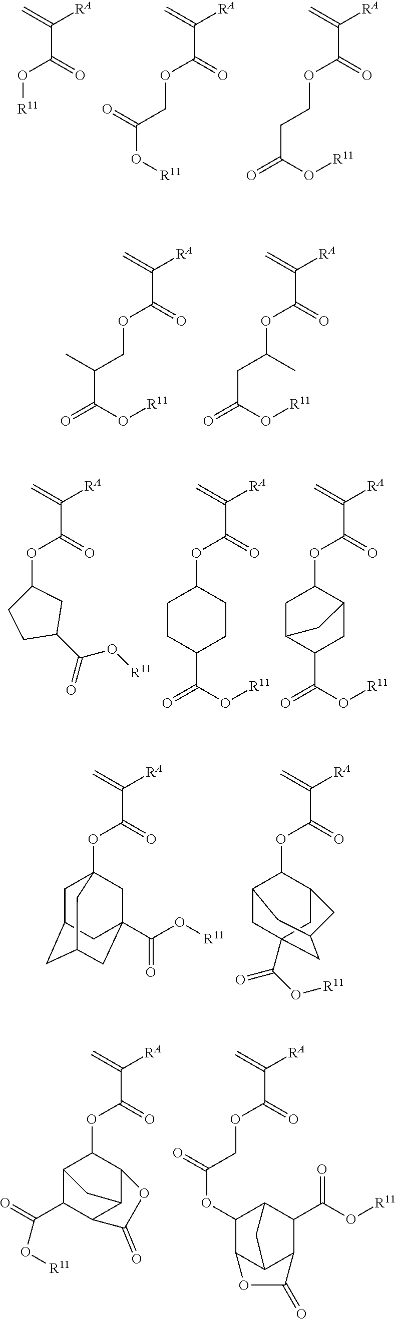

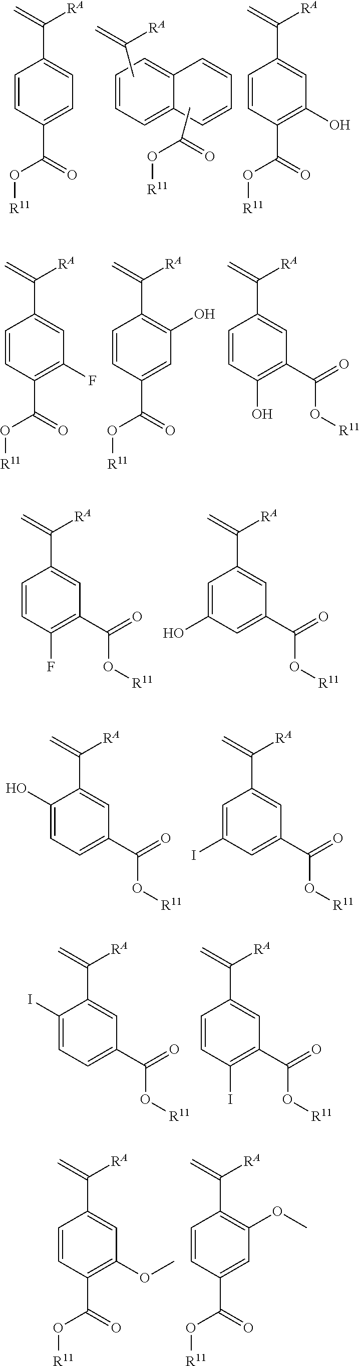

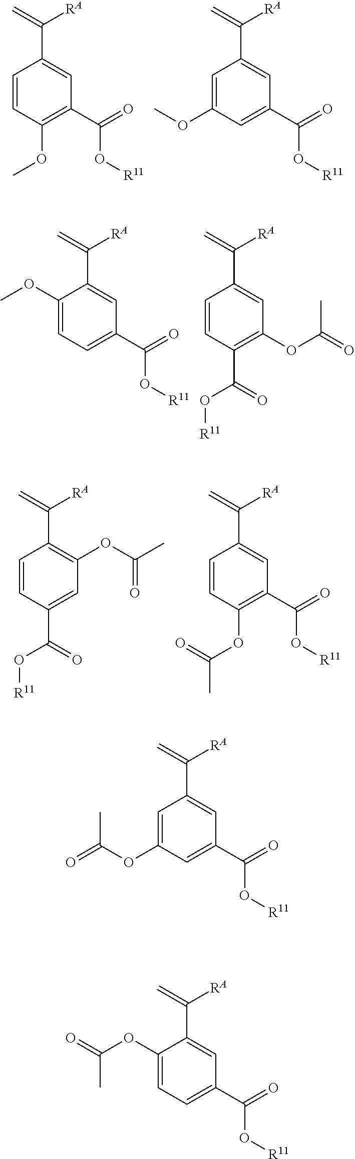

Examples of the monomer from which the repeat units (b2) are derived include hose shown below, but are not limited hereto. In the formulae, R^{A} and R¹² are as defined above.

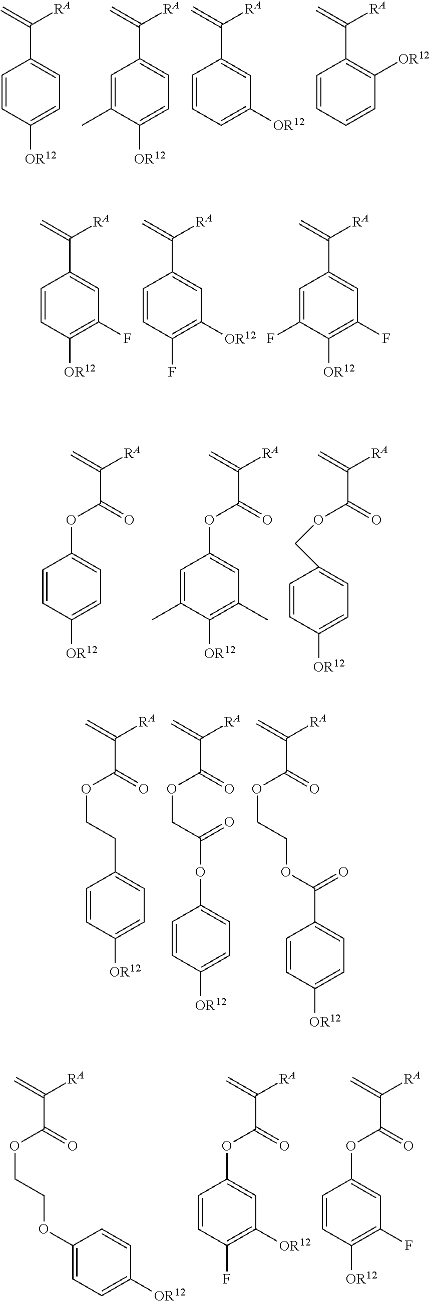

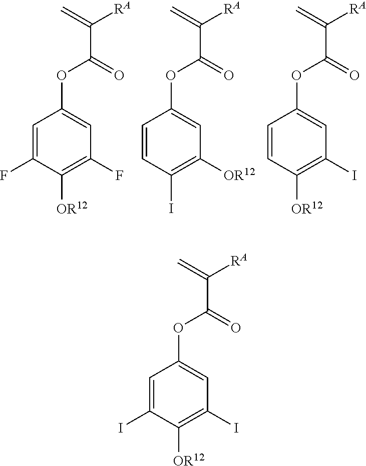

Examples of the acid labile groups represented by R¹¹ and R¹² in formulae (b1) and (b2) include those described in JP-A 2013-080033 and JP-A 2013-083821.

Typical examples of the acid labile groups include those represented by formulae (AL-1) to (AL-3).

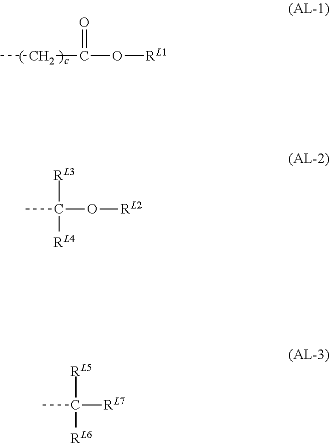

In the formulae, a broken line designates a bond.

In formulae (AL-1) and (AL-2), R^{L1} and R^{L2} are each independently a C₁-C₄₀ hydrocarbyl group which may contain a heteroatom such as an oxygen atom, a sulfur atom, a nitrogen atom, or a fluorine atom. The hydrocarbyl group may be saturated or unsaturated, and may be straight, branched, or cyclic. Preferred are C₁-C₄₀ saturated or C₂-C₄₀ unsaturated hydrocarbyl groups, especially C₁-C₂₀ saturated or C₂-C₂₀ unsaturated hydrocarbyl groups.

In formula (AL-1), c is an integer of 0 to 10, preferably an integer of 1 to 5.

In formula (AL-2), R^{L3} and R^{L4} are each independently a hydrogen atom or a C₁-C₂₀ hydrocarbyl group which may contain a heteroatom such as an oxygen atom, a sulfur atom, a nitrogen atom, or a fluorine atom. The hydrocarbyl group may be saturated or unsaturated, and may be straight, branched, or cyclic. Preferred are C₁-C₂₀ saturated hydrocarbyl groups. Any two of R^{L2}, R^{L3}, and R^{L4} may bond together to form a ring with the carbon atom or carbon and oxygen atoms to which they are bonded, the ring containing 3 to 20 carbon atoms. The ring is preferably a ring containing 4 to 16 carbon atoms, and particularly preferably an alicyclic ring.

In formula (AL-3), R^{L5}, R^{L6}, and R^{L7} are each independently a C₁-C₂₀ hydrocarbyl group which may contain a heteroatom such as an oxygen atom, a sulfur atom, a nitrogen atom, or a fluorine atom. The hydrocarbyl group may be saturated or unsaturated, and may be straight, branched, or cyclic. Preferred are C₁-C₂₀ saturated hydrocarbyl groups. Any two of R^{L5}, R^{L6}, and R^{L7} may bond together to form a ring with the carbon atom to which they are bonded, the ring containing 3 to 20 carbon atoms. The ring is preferably a ring containing 4 to 16 carbon atoms and particularly preferably an alicyclic ring, and may have a double bond or a triple bond in the ring.

Also useful as the acid labile group having formula (AL-3) are aromatic group-containing acid labile groups as described in JP 5655754, JP 5655755, JP 5655756, JP 5407941, JP 5434983, JP 5565293, and JP-A 2007-279699; triple bond-containing acid labile groups as described in JP-A 2008-268741; and double or triple bond-containing acid labile groups as described in JP-A 2021-050307.

The base polymer may further contain repeat units (c) having a phenolic hydroxy group as an adhesive group. Examples of the monomer from which the repeat units (c) are derived include those shown below, but are not limited thereto. In the formulae, R^{A} is as defined above.

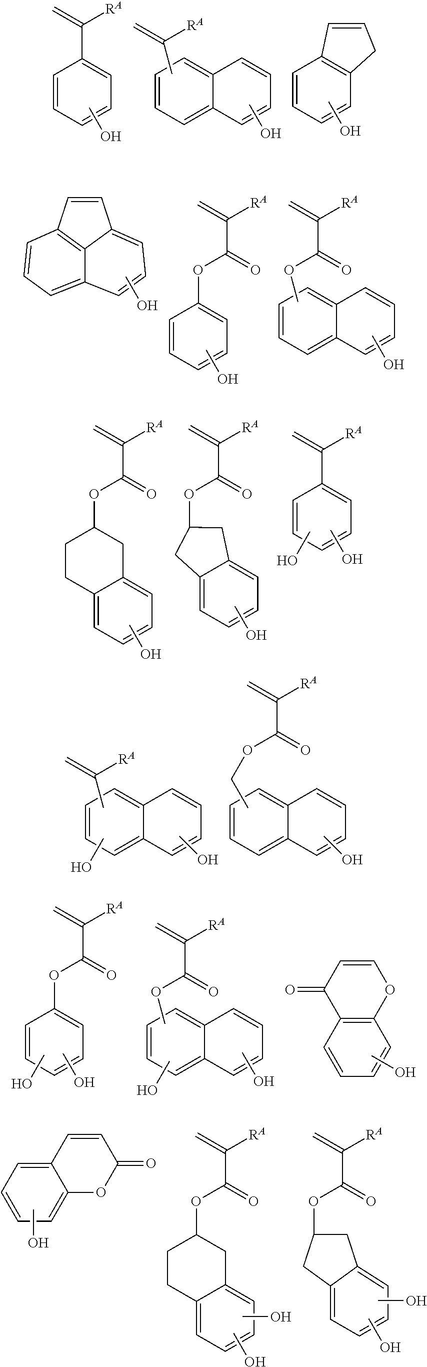

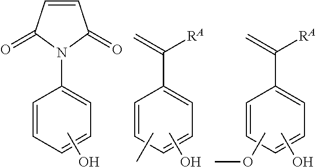

The base polymer may further contain repeat units (d) having another adhesive group selected from a hydroxy group other than the phenolic hydroxy group, a lactone ring, a sultone ring, an ether bond, an ester bond, a sulfonic ester bond, a carbonyl group, a sulfonyl group, a cyano group, and a carboxy group. Examples of the monomer from which the repeat units (d) are derived include those shown below, but are not limited thereto. In the formulae, R^{A} is as defined above.

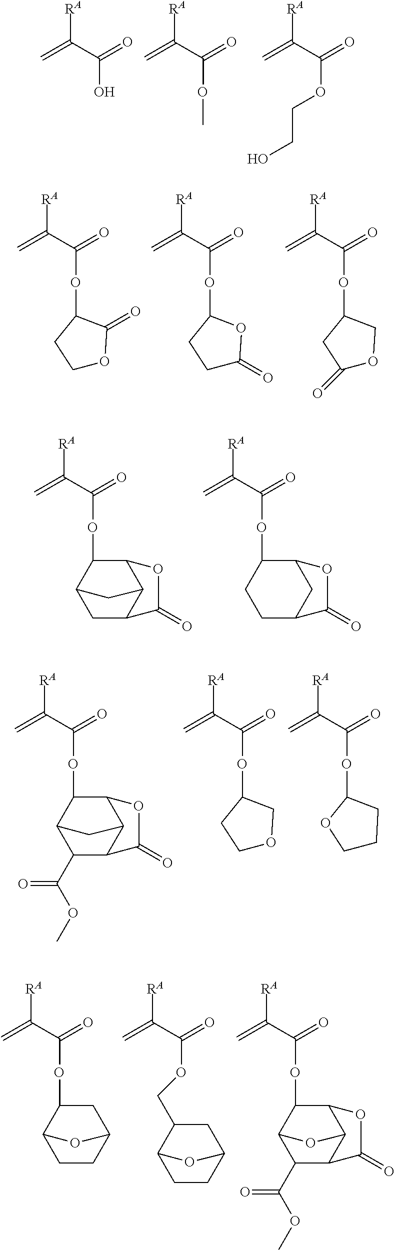

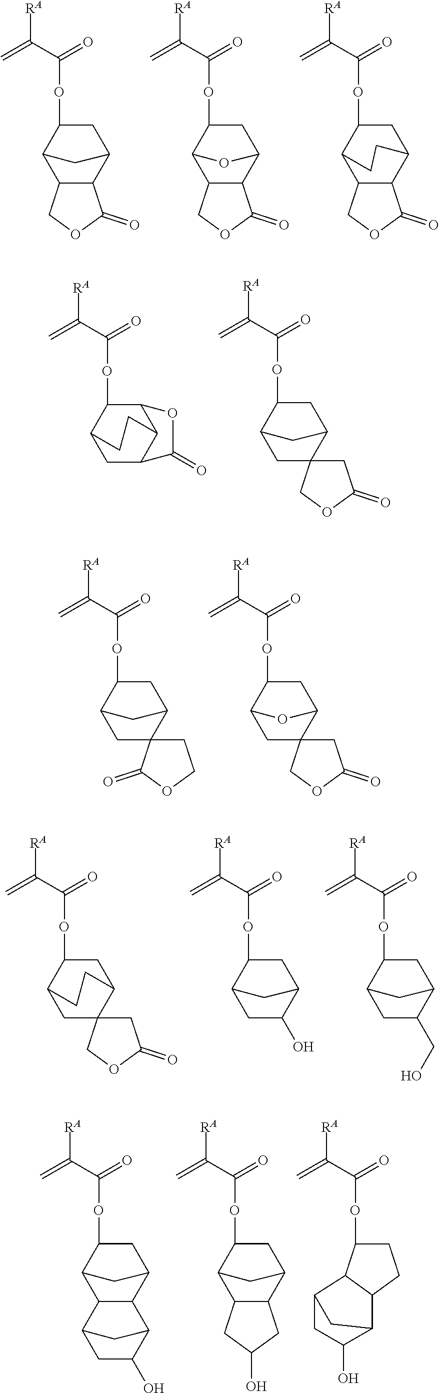

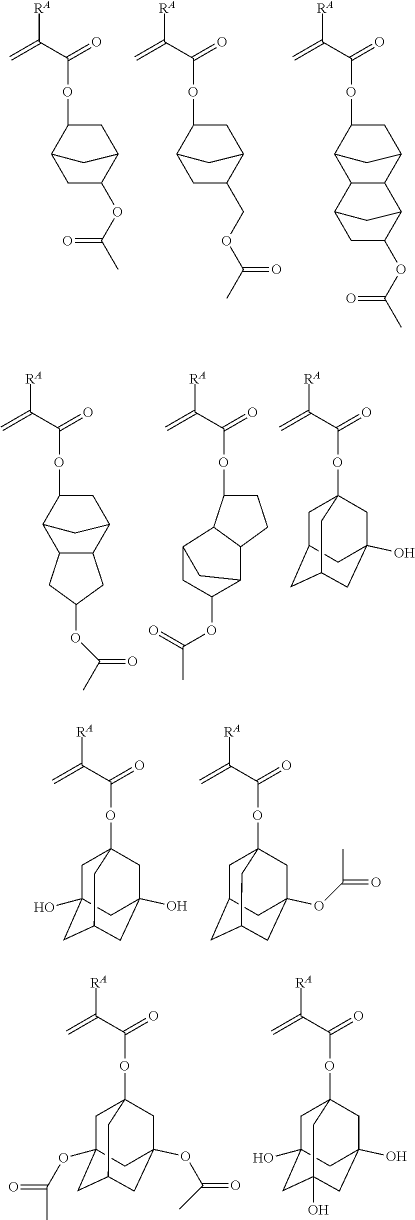

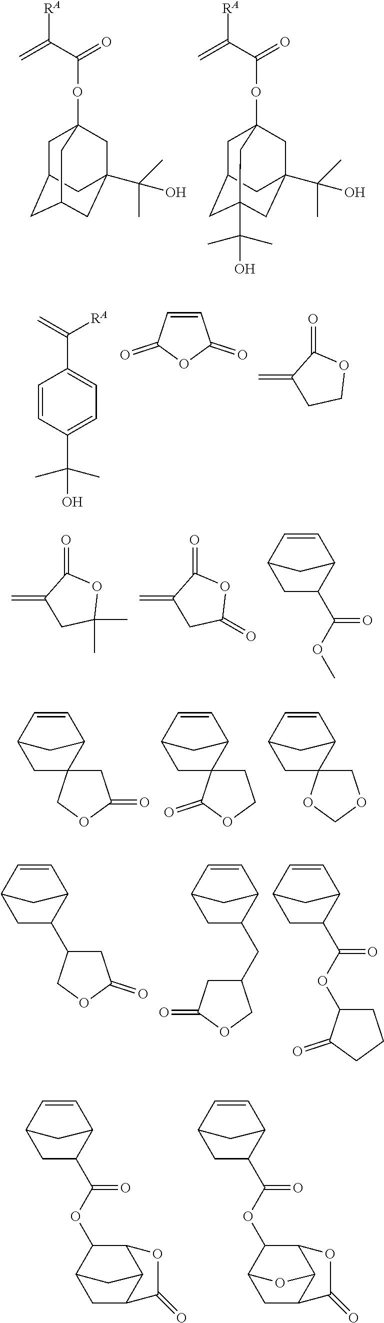

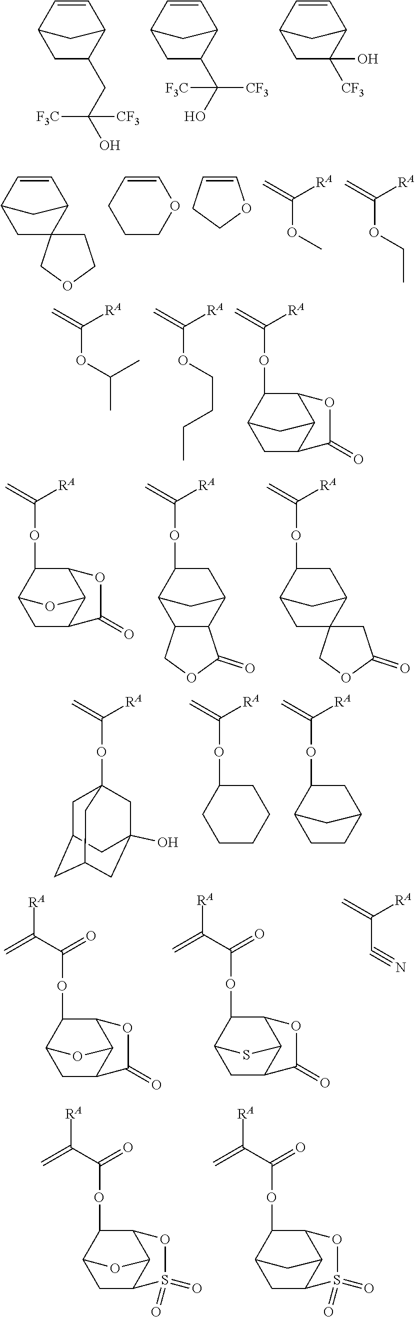

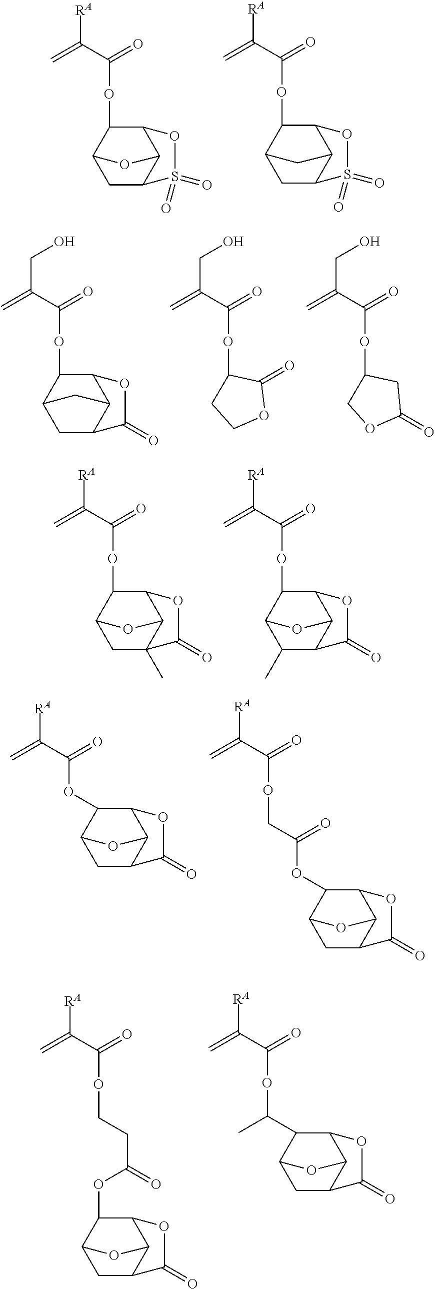

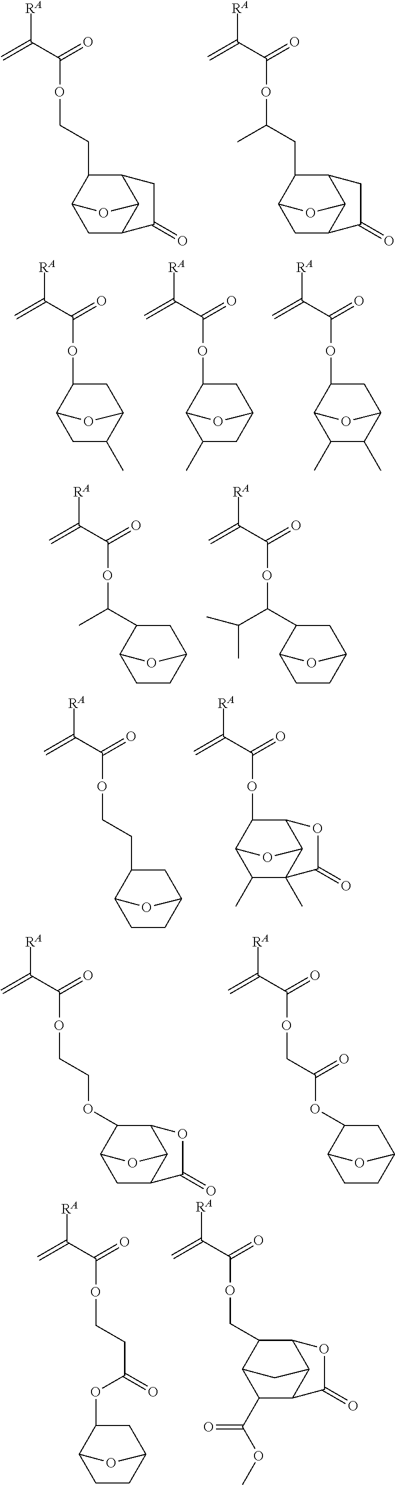

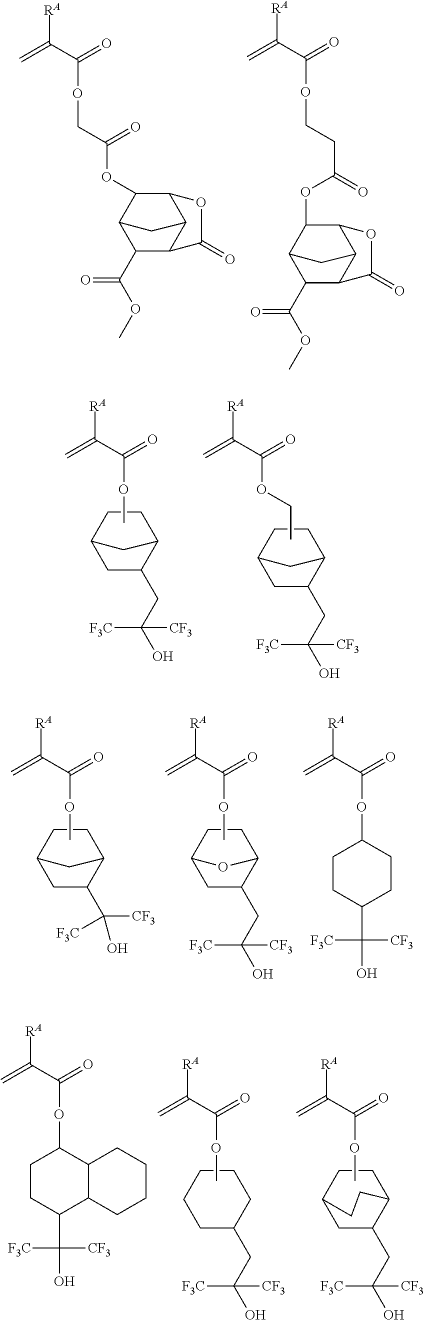

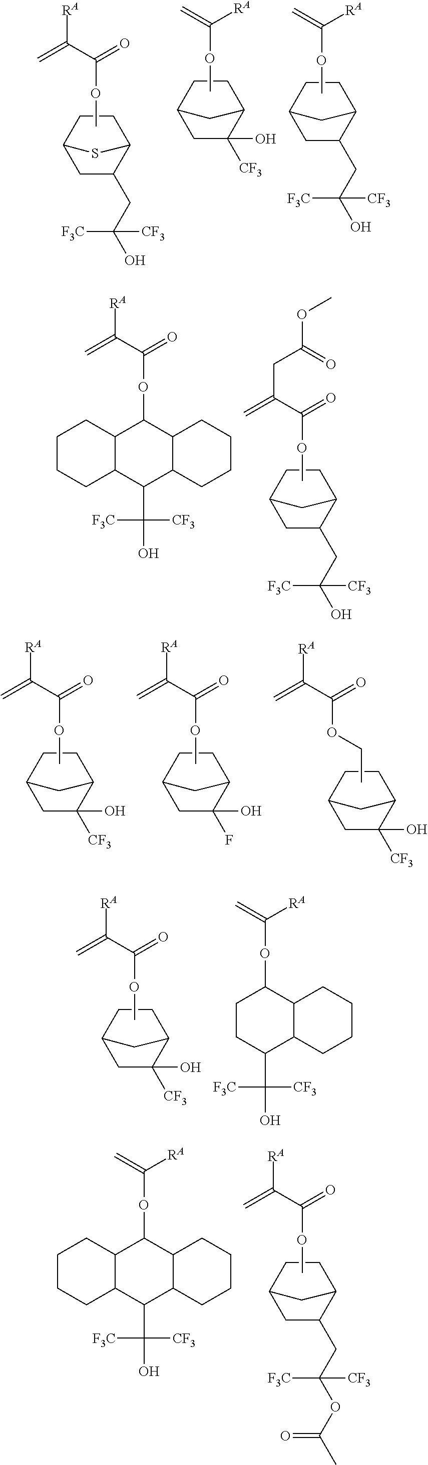

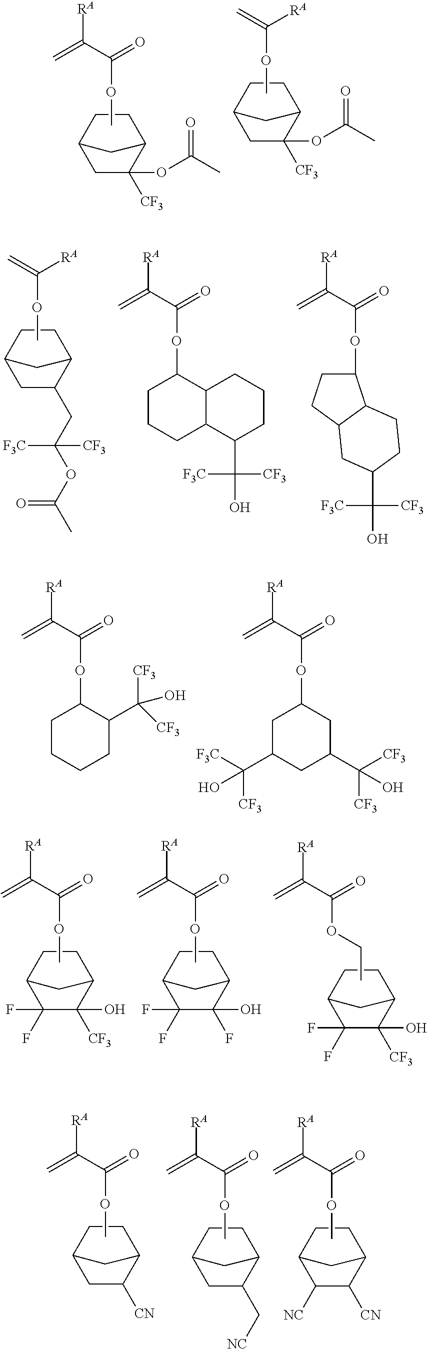

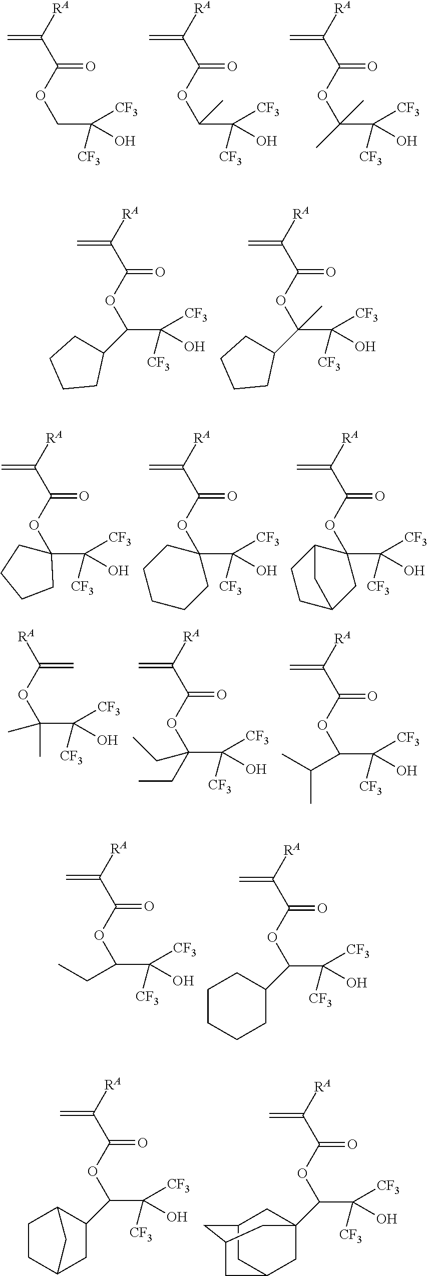

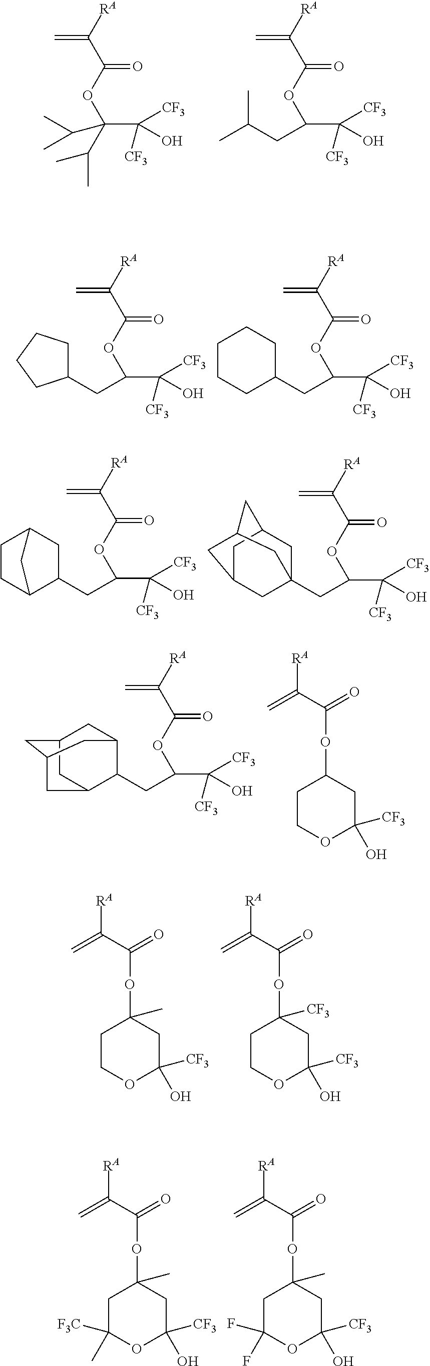

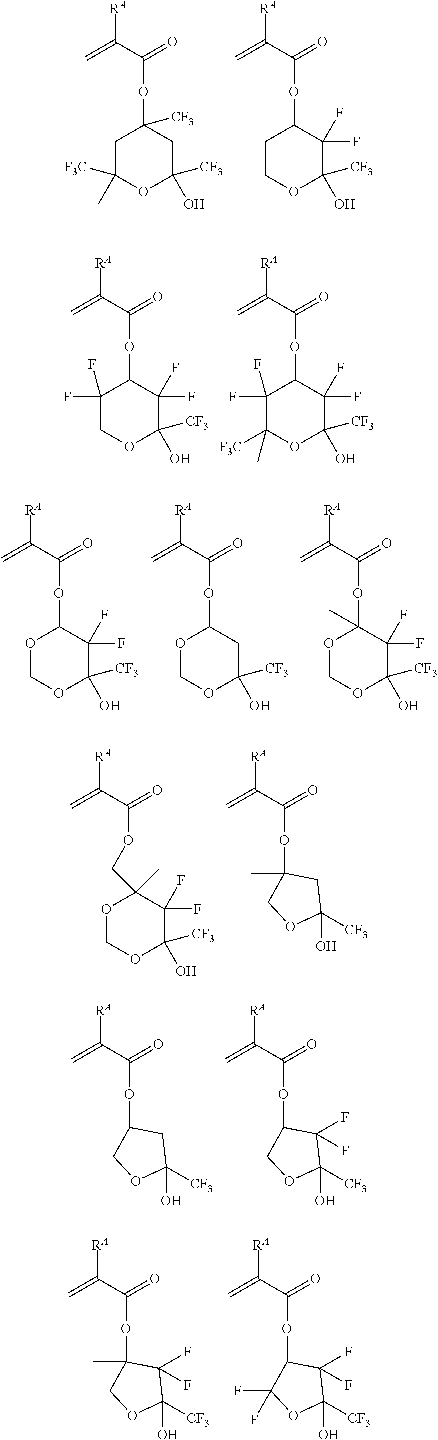

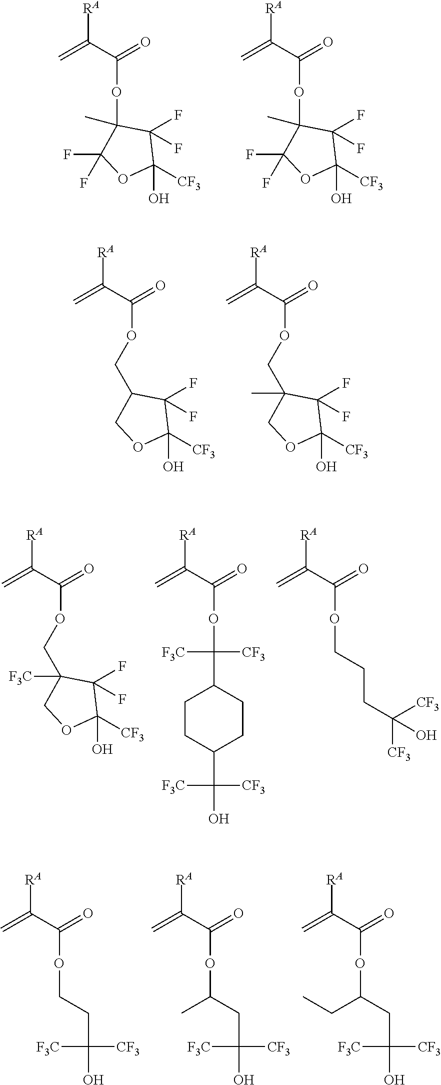

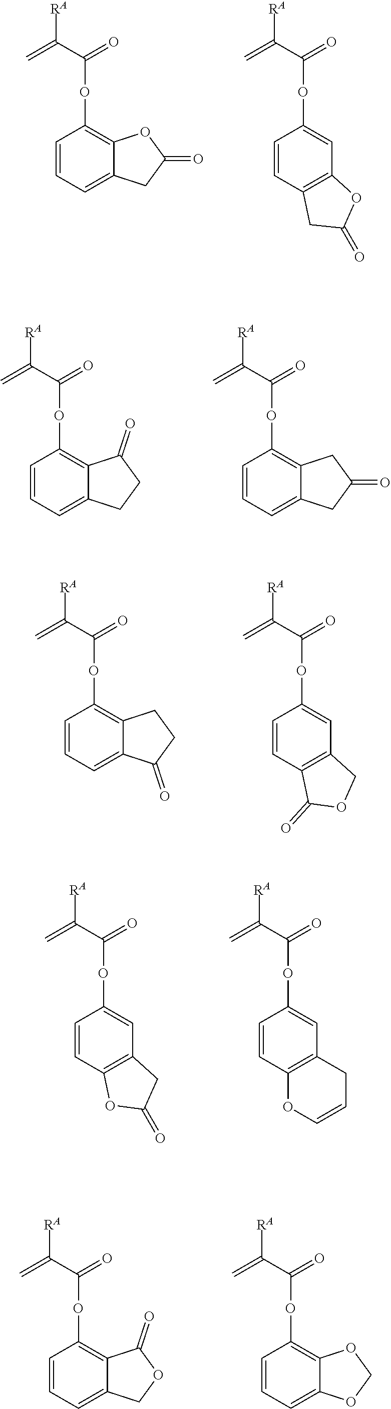

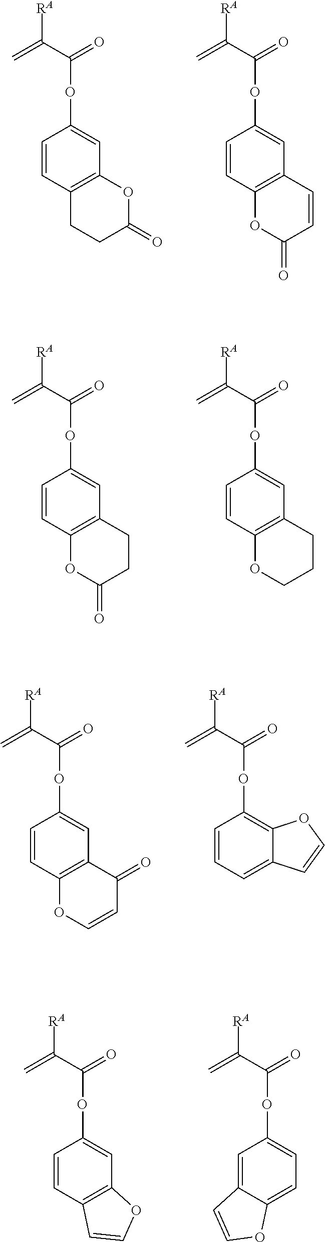

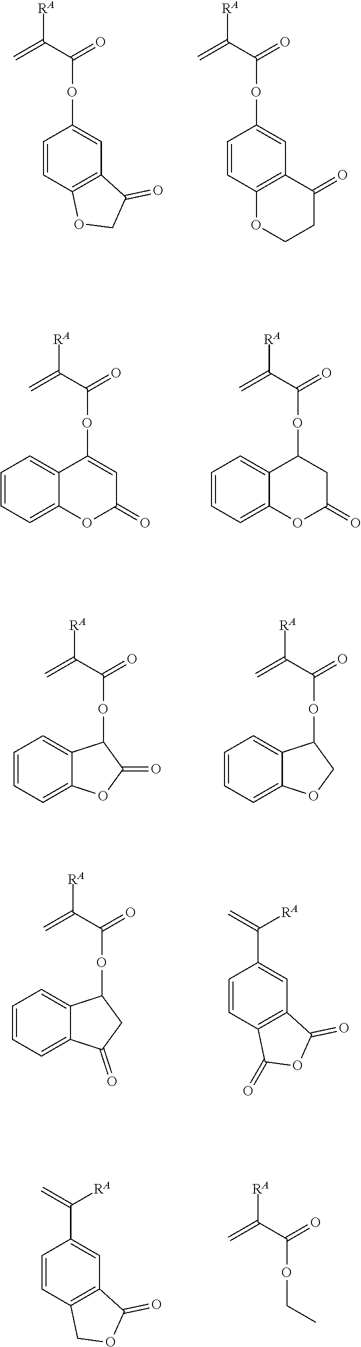

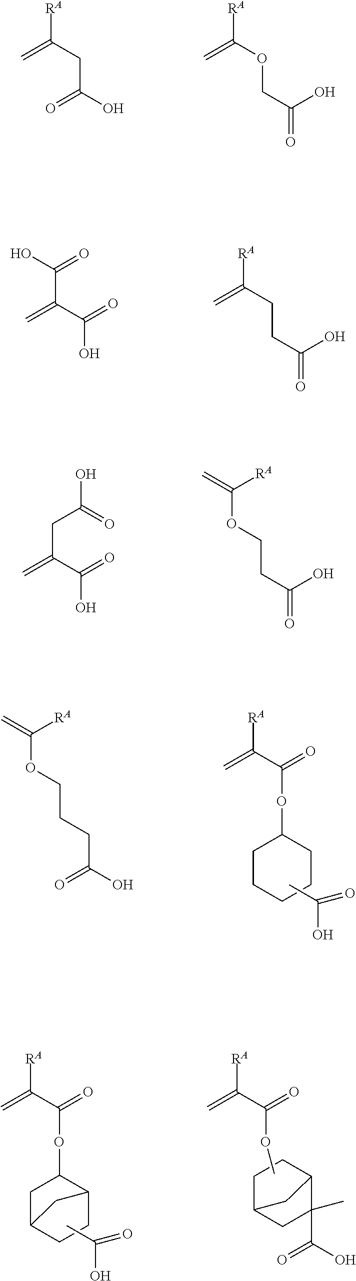

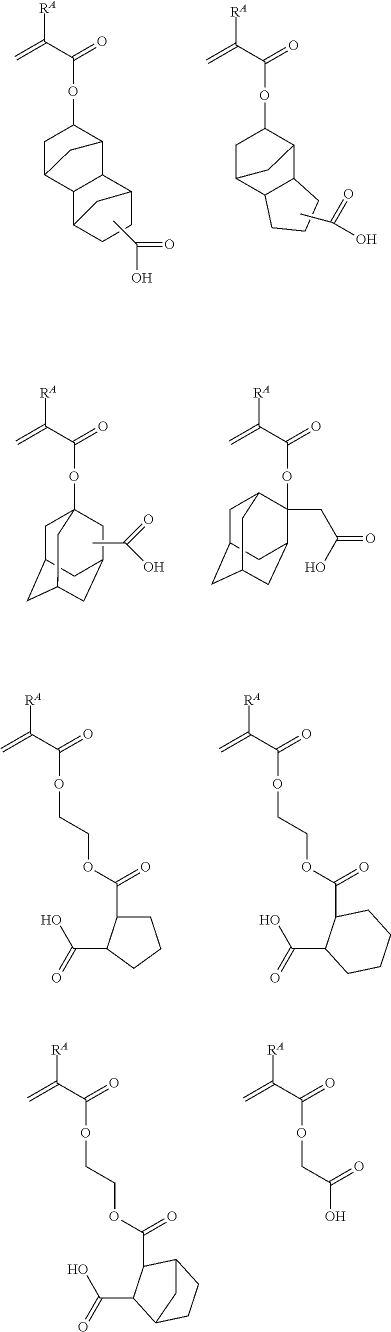

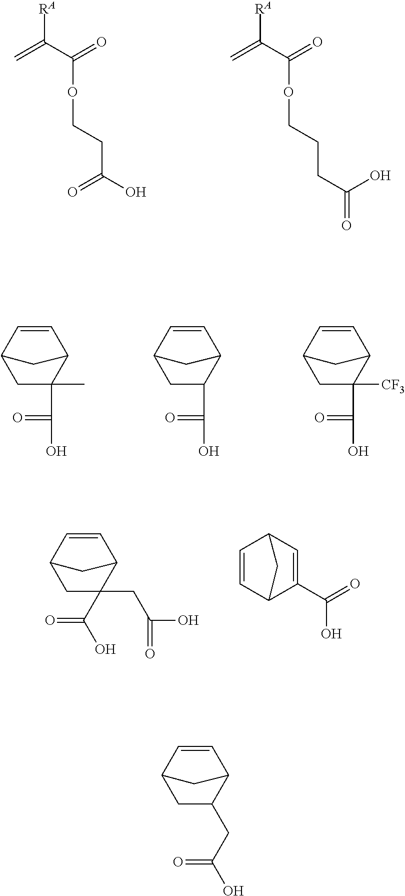

The base polymer may further contain repeat units (e) derived from indene, benzofuran, benzothiophene, acenaphthylene, chromone, coumarin, norbornadiene, or a derivative thereof. Examples of the monomer from which the repeat units (e) are derived include those shown below, but are not limited thereto.

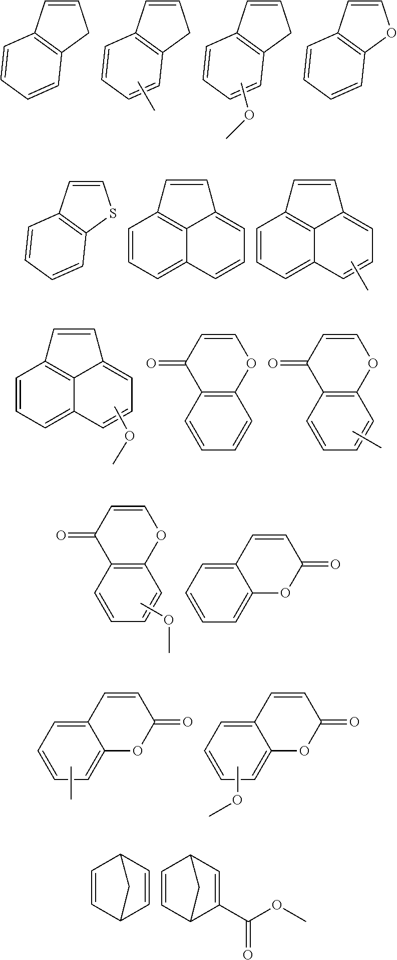

The base polymer may further contain repeat units (f) derived from styrene, vinylnaphthalene, vinylanthracene, vinylpyrene, methyleneindane, vinylpyridine, or vinylcarbazole.

The base polymer contains repeat units (a) as an essential component. If the repeat units (a) are repeat units (a1) or (a2), the fractions of the repeat units (a1), (a2), (b), (c), (d), (e), and (f) are preferably 0≤(a1)≤0.5, 0≤(a2)≤0.5, 0≤(a1)+(a2)≤0.5, 0≤(b1)≤0.8, 0≤(b2)≤0.8, 0.1≤(b1)+(b2)≤0.8, 0≤(c)≤0.9, 0≤(d)≤0.8, 0≤(e)≤0.8, and 0≤(f)≤0.5, more preferably 0≤(a1)≤0.4, 0≤(a2)≤0.4, 0.02≤(a1)+(a2)≤0.4, 0≤(b1)≤0.7, 0≤(b2)≤0.7, 0.15≤(b1)+(b2)≤0.7, 0≤(c)≤0.8, 0≤(d)≤0.7, 0≤(e)≤0.7, and 0≤(f)≤0.4, and even more preferably 0≤(a1)≤0.35, 0≤(a2)≤0.35, 0.05≤(a1)+(a2)≤0.35, 0≤(b1)≤0.65, 0≤(b2)≤0.65, 0.2≤(b1)+(b2)≤0.65, 0≤(c)≤0.7, 0≤(d)≤0.6, 0≤(e)≤0.6, and 0≤(f)≤0.3. Note that (a1)+(a2)+(b1)+(b2)+(c)+(d)+(e)+(f)=1.0.

The base polymer may be synthesized, for example, by heating a monomer from which the repeat units are derived in an organic solvent with the addition of a radical polymerization initiator to perform polymerization.

Examples of the organic solvent used in the polymerization include toluene, benzene, tetrahydrofuran (THF), diethyl ether, and dioxane. Examples of the polymerization initiator include 2,2′-azobisisobutyronitrile (AIBN), 2,2′-azobis(2,4-dimethylvaleronitrile), dimethyl-2,2-azobis(2-methylpropionate), benzoyl peroxide, and lauroyl peroxide. The temperature during polymerization is preferably 50 to 80° C. The reaction time is preferably 2 to 100 hours, and more preferably 5 to 20 hours.

When a monomer having a hydroxy group is copolymerized, the hydroxy group may be substituted with an acetal group susceptible to deprotection with an acid such as an ethoxyethoxy group prior to polymerization, and the polymerization be followed by deprotection with a weak acid and water. Alternatively, the hydroxy group may be substituted with an acetyl group, a formyl group, a pivaloyl group or the like prior to polymerization, and the polymerization be followed by alkaline hydrolysis.

When hydroxystyrene or hydroxyvinylnaphthalene is copolymerized, acetoxystyrene or acetoxyvinylnaphthalene may be used instead of hydroxystyrene or hydroxyvinylnaphthalene, and after polymerization, the acetoxy group may be deprotected by alkaline hydrolysis for converting the polymer product to hydroxystyrene or hydroxyvinylnaphthalene.

For alkaline hydrolysis, a base such as aqueous ammonia or triethylamine may be used. The reaction temperature is preferably −20 to 100° C., and more preferably 0 to 60° C. The reaction time is preferably 0.2 to 100 hours, and more preferably 0.5 to 20 hours.

The base polymer preferably has a weight average molecular weight (Mw) in the range of 1,000 to 500,000, and more preferably 2,000 to 30,000, as measured by gel permeation chromatography (GPC) versus polystyrene standards using a THF solvent. A Mw in the range ensures that the resist film has heat resistance and high solubility in an alkaline developer.

If the base polymer has a wide molecular weight distribution (Mw/Mn), which indicates the presence of lower and higher molecular weight polymer fractions, there is a possibility that foreign matters are left on the pattern or the pattern profile is degraded after exposure. The influences of Mw and Mw/Mn tend to be stronger as the pattern rule becomes finer. Therefore, the base polymer should preferably have a narrow dispersity (Mw/Mn) of 1.0 to 2.0, especially 1.0 to 1.5, in order to provide a resist composition suitable for micropatterning to a small feature size.

In order to obtain a narrowly dispersed polymer, not only normal radical polymerization but also living radical polymerization can be used. Examples of the living radical polymerization include living radical polymerization using a nitroxide radical (Nitroxide-Mediated radical Polymerization: NMP), atom transfer radical polymerization (ATRP), and reversible addition-fragmentation chain transfer (RAFT) polymerization.

The base polymer may contain two or more polymers having different compositional ratios, Mw, and Mw/Mn.

### [Organic Solvent]

The resist composition of the present invention may contain an organic solvent. The organic solvent is not particularly limited as long as the components described above and below are soluble therein. Examples of the organic solvent are described in paragraphs [0144] to [0145] of JP-A 2008-111103, and include ketones such as cyclohexanone, cyclopentanone, methyl-2-n-pentyl ketone, and 2-heptanone; alcohols such as 3-methoxybutanol, 3-methyl-3-methoxybutanol, 1-methoxy-2-propanol, 1-ethoxy-2-propanol, and diacetone alcohol (DAA); ethers such as propylene glycol monomethyl ether (PGME), ethylene glycol monomethyl ether, propylene glycol monoethyl ether, ethylene glycol monoethyl ether, propylene glycol dimethyl ether, and diethylene glycol dimethyl ether; esters such as propylene glycol monomethyl ether acetate (PGMEA), propylene glycol monoethyl ether acetate, ethyl lactate, ethyl pyruvate, butyl acetate, methyl 3-methoxypropionate, ethyl 3-ethoxypropionate, tert-butyl acetate, tert-butyl propionate, propylene glycol mono-tert-butyl ether acetate, methyl 2-hydroxyisobutyrate, ethyl 2-hydroxyisobutyrate, propyl 2-hydroxyisobutyrate, and butyl 2-hydroxyisobutyrate; and lactones such as γ-butyrolactone.

The organic solvent is preferably added to the resist composition of the present invention in an amount of 100 to 10,000 parts by weight, and more preferably 200 to 8,000 parts by weight per 100 parts by weight of the base polymer. The organic solvent may be used singly or as a mixture of two or more kinds thereof.

### [Acid Generator]

A positive resist composition of the present invention may further contain an acid generator (hereinafter, also referred to as an additive acid generator) capable of generating a strong acid. The strong acid as used herein means a compound having an acidity sufficient to cause a deprotection reaction of the acid labile group of the base polymer. Examples of the acid generator include a compound that generates an acid in response to actinic rays or radiation (the compound is referred to as photoacid generator, PAG). Although the PAG may be any compound capable of generating an acid upon exposure to high-energy radiation, those compounds capable of generating a sulfonic acid, imide acid (imidic acid), or methide acid are preferred. Suitable PAGs include sulfonium salts, iodonium salts, sulfonyldiazomethane, N-sulfonyloxyimide, and oxime-O-sulfonate acid generators. Examples of the PAG include those described in paragraphs [0122] to [0142] of JP-A 2008-111103.

As the PAG, a sulfonium salt having formula (1-1) and an iodonium salt having formula (1-2) can also be suitably used.

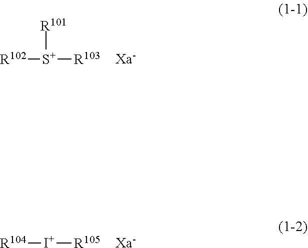

In formulae (1-1) and (1-2), R¹⁰¹ to R¹⁰⁵ are each independently a halogen atom, or a C₁-C₂₀ hydrocarbyl group which may contain a heteroatom. The hydrocarbyl group may be saturated or unsaturated, and may be straight, branched, or cyclic. Specific examples thereof include those groups mentioned as the hydrocarbyl group represented by R² to R⁶ in the descriptions of formulae (M-1) and (M-2). R¹⁰¹ and R¹⁰² may bond together to form a ring together with the sulfur atom to which they are bonded. In the case, examples of the ring include the same rings as those mentioned as the ring that R² and R³, taken together, form with the sulfur atom to which they are bonded, in the description of formulae (M-1) and (M-2).

In formulae (1-1) and (1-2), Xa⁻ is an anion selected from formulae (1A) to (1D).

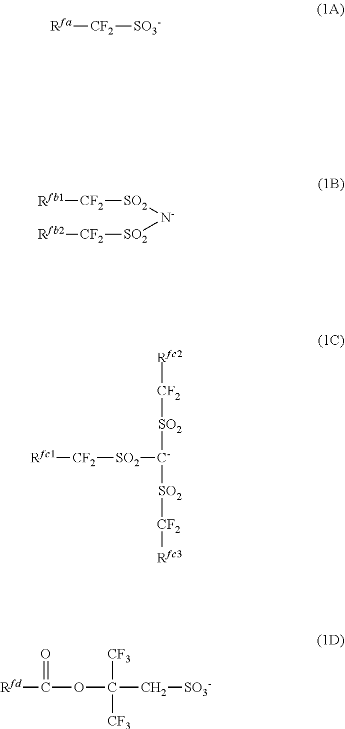

In formula (1A), R^{fa} is a fluorine atom or a C₁-C₄₀ hydrocarbyl group which may contain a heteroatom. The hydrocarbyl group may be saturated or unsaturated, and may be straight, branched, or cyclic. Specific examples thereof include those groups mentioned as the hydrocarbyl group represented by R^{fa} in formula (1A′) described later.

As the anion having formula (1A), an anion having formula (1A′) is preferable.

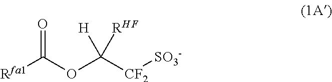

In formula (1A′), R^{HF} is a hydrogen atom or a trifluoromethyl group, preferably a trifluoromethyl group. R^{fa1} is a C₁-C₃₈ hydrocarbyl group which may contain a heteroatom. The heteroatom is preferably an oxygen atom, a nitrogen atom, a sulfur atom, a halogen atom, or the like, and more preferably an oxygen atom. The hydrocarbyl group is particularly preferably a C₆-C₃₀ hydrocarbyl group from the viewpoint of obtaining high resolution in fine pattern formation.

The hydrocarbyl group represented by R^{fa1} may be saturated or unsaturated, and may be straight, branched, or cyclic. Specific examples thereof include C₁-C₃₈ alkyl groups such as a methyl group, an ethyl group, a n-propyl group, an isopropyl group, a n-butyl group, an isobutyl group, a sec-butyl group, a tert-butyl group, a pentyl group, a neopentyl group, a hexyl group, a heptyl group, a 2-ethylhexyl group, a nonyl group, an undecyl group, a tridecyl group, a pentadecyl group, a heptadecyl group, and an icosyl group; C₃-C₃₈ cyclic saturated hydrocarbyl groups such as a cyclopentyl group, a cyclohexyl group, a 1-adamantyl group, a 2-adamantyl group, a 1-adamantylmethyl group, a norbornyl group, a norbornylmethyl group, a tricyclodecyl group, a tetracyclododecyl group, a tetracyclododecylmethyl group, and a dicyclohexylmethyl group; C₂-C₃₈ unsaturated hydrocarbyl groups such as an allyl group and a 3-cyclohexenyl group; C₆-C₃₈ aryl groups such as a phenyl group, a 1-naphthyl group, and a 2-naphthyl group; C₇-C₃₈ aralkyl groups such as a benzyl group and a diphenylmethyl group; and groups obtained by combining the foregoing.

Some or all of hydrogen atoms of the hydrocarbyl group may be substituted with a group containing a heteroatom such as an oxygen atom, a sulfur atom, a nitrogen atom, or a halogen atom, and some of —CH₂— of the hydrocarbyl group may be substituted with a group containing a heteroatom such as an oxygen atom, a sulfur atom, or a nitrogen atom, so that the group may contain a hydroxy group, a fluorine atom, a chlorine atom, a bromine atom, an iodine atom, a cyano group, a nitro group, a carbonyl group, an ether bond, an ester bond, a sulfonic ester bond, a carbonate bond, a lactone ring, a sultone ring, a carboxylic anhydride (—C(═O)—O—C(═O)—), or a haloalkyl group. Examples of the hydrocarbyl group containing a heteroatom include a tetrahydrofuryl group, a methoxymethyl group, an ethoxymethyl group, a methylthiomethyl group, an acetamidemethyl group, a trifluoroethyl group, a (2-methoxyethoxy)methyl group, an acetoxymethyl group, a 2-carboxy-1-cyclohexyl group, a 2-oxopropyl group, a 4-oxo-1-adamantyl group, and a 3-oxocyclohexyl group.

With respect to the synthesis of the sulfonium salt containing an anion having formula (1A′), reference may be made to JP-A 2007-145797, JP-A 2008-106045, JP-A 2009-7327, JP-A 2009-258695, and the like. Also useful are the sulfonium salts described in JP-A 2010-215608, JP-A 2012-41320, JP-A 2012-106986, JP-A 2012-153644, and the like.

Examples of the anion having formula (1A) include the same anions mentioned as the anion having formula (1A) of JP-A 2018-197853.

In formula (1B), R^{fb1} and R^{fb2} are each independently a fluorine atom or C₁-C₄₀ hydrocarbyl group which may contain a heteroatom. The hydrocarbyl group may be saturated or unsaturated, and may be straight, branched, or cyclic. Specific examples thereof include those groups mentioned as the hydrocarbyl group represented by R^{fa1} in formula (1A′). R^{fb1} and R^{fb2} are preferably a fluorine atom or C₁-C₄ straight fluorinated alkyl group. R^{fb1} and R^{fb2} may bond together to form a ring with a group (—CF₂—SO₂—N—SO₂—CF₂—) to which they are bonded, and in this case, the group obtained by bonding R^{fb1} and R^{fb2} to each other is preferably a fluorinated ethylene group or a fluorinated propylene group.

In formula (1C), R^{fc1}, R^{fc2}, and R^{fc3} are each independently a fluorine atom or C₁-C₄₀ hydrocarbyl group which may contain a heteroatom. The hydrocarbyl group may be saturated or unsaturated, and may be straight, branched, or cyclic. Specific examples thereof include those groups mentioned as the hydrocarbyl group represented by R^{fa1} in formula (1A′). R^{fc1}, R^{fc2}, and R^{fc3} are preferably a fluorine atom or a C₁-C₄ straight fluorinated alkyl group. R^{fc1} and R^{fc2} may bond together to form a ring with a group (—CF₂—SO₂—C—SO₂—CF₂—) to which they are bonded, and in this case, the group obtained by bonding R^{fc1} and R^{fc2} to each other is preferably a fluorinated ethylene group or a fluorinated propylene group.

In formula (1D), R^{fd} is a C₁-C₄₀ hydrocarbyl group which may contain a heteroatom. The hydrocarbyl group may be saturated or unsaturated, and may be straight, branched, or cyclic. Specific examples thereof include those groups mentioned as the hydrocarbyl group represented by R^{fa1} in formula (1A′).

With respect to the synthesis of the sulfonium salt containing an anion having formula (1D), reference may be made to JP-A 2010-215608 and JP-A 2014-133723.

Examples of the anion having formula (1D) include the same anions mentioned as the anion having formula (1D) of JP-A 2018-197853.

The PAG containing the anion having formula (1D) does not have a fluorine atom at the α-position of the sulfo group, but has two trifluoromethyl groups at the β-position, and thus has an acidity sufficient for cleaving the acid labile group in the base polymer. Therefore, the compound can be used as a PAG.

As the PAG, a PAG having formula (2) can also be suitably used.

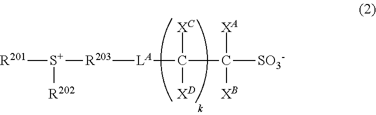

In formula (2), R²⁰¹ and R²⁰² are each independently a halogen atom, or a C₁-C₃₀ hydrocarbyl group which may contain a heteroatom. R²⁰³ is a C₁-C₃₀ hydrocarbylene group which may contain a heteroatom. Any two of R²⁰¹, R²⁰², and R²⁰³ may bond together to form a ring with the sulfur atom to which they are bonded. In the case, examples of the ring include the same rings as those mentioned as the ring that R² and R³, taken together, form with the sulfur atom to which they are bonded, in the description of formulae (M-1) and (M-2).

The hydrocarbyl group represented by R²⁰¹ and R²⁰² may be saturated or unsaturated, and may be straight, branched, or cyclic. Specific examples thereof include C₁-C₃₀ alkyl groups such as a methyl group, an ethyl group, a n-propyl group, an isopropyl group, a n-butyl group, an isobutyl group, a sec-butyl group, a tert-butyl group, a n-pentyl group, a tert-pentyl group, a n-hexyl group, a n-octyl group, a 2-ethylhexyl group, a n-nonyl group, and a n-decyl group; C₃-C₃₀ cyclic saturated hydrocarbyl groups such as a cyclopentyl group, a cyclohexyl group, a cyclopentylmethyl group, a cyclopentylethyl group, a cyclopentylbutyl group, a cyclohexylmethyl group, a cyclohexylethyl group, a cyclohexylbutyl group, a norbornyl group, a tricyclo[5.2.1.0^{2,6}]decyl group, and an adamantyl group; C₆-C₃₀ aryl groups such as a phenyl group, a methylphenyl group, an ethylphenyl group, a n-propylphenyl group, an isopropylphenyl group, a n-butylphenyl group, an isobutylphenyl group, a sec-butylphenyl group, a tert-butylphenyl group, a naphthyl group, a methylnaphthyl group, an ethylnaphthyl group, a n-propylnaphthyl group, an isopropylnaphthyl group, a n-butylnaphthyl group, an isobutylnaphthyl group, a sec-butylnaphthyl group, a tert-butylnaphthyl group, and an anthracenyl group; and groups obtained by combining the foregoing. Some or all of hydrogen atoms of the hydrocarbyl group may be substituted with a group containing a heteroatom such as an oxygen atom, a sulfur atom, a nitrogen atom, or a halogen atom, and some of —CH₂— of the hydrocarbyl group may be substituted with a group containing a heteroatom such as an oxygen atom, a sulfur atom, or a nitrogen atom, so that the group may contain a hydroxy group, a fluorine atom, a chlorine atom, a bromine atom, an iodine atom, a cyano group, a carbonyl group, an ether bond, an ester bond, a sulfonic ester bond, a carbonate bond, a lactone ring, a sultone ring, a carboxylic anhydride (—C(═O)—O—C(═O)—), or a haloalkyl group.

The hydrocarbylene group represented by R²⁰³ may be saturated or unsaturated, and may be straight, branched, or cyclic. Specific examples thereof include C₁-C₃₀ alkanediyl groups such as a methanediyl group, an ethane-1,1-diyl group, an ethane-1,2-diyl group, a propane-1,3-diyl group, a butane-1,4-diyl group, a pentane-1,5-diyl group, a hexane-1,6-diyl group, a heptane-1,7-diyl group, an octane-1,8-diyl group, a nonane-1,9-diyl group, a decane-1,10-diyl group, an undecane-1,11-diyl group, a dodecane-1,12-diyl group, a tridecane-1,13-diyl group, a tetradecane-1,14-diyl group, a pentadecane-1,15-diyl group, a hexadecane-1,16-diyl group, and a heptadecane-1,17-diyl group; C₃-C₃₀ cyclic saturated hydrocarbylene groups such as a cyclopentanediyl group, a cyclohexanediyl group, a norbornanediyl group, and an adamantanediyl group; C₆-C₃₀ arylene groups such as a phenylene group, a methylphenylene group, an ethylphenylene group, a n-propylphenylene group, an isopropylphenylene group, a n-butylphenylene group, an isobutylphenylene group, a sec-butylphenylene group, a tert-butylphenylene group, a naphthylene group, a methylnaphthylene group, an ethylnaphthylene group, a n-propylnaphthylene group, an isopropylnaphthylene group, a n-butylnaphthylene group, an isobutylnaphthylene group, a sec-butylnaphthylene group, and a tert-butylnaphthylene group; and groups obtained by combining the foregoing. Some or all of hydrogen atoms of the hydrocarbylene group may be substituted with a group containing a heteroatom such as an oxygen atom, a sulfur atom, a nitrogen atom, or a halogen atom, and some of —CH₂— of the hydrocarbylene group may be substituted with a group containing a heteroatom such as an oxygen atom, a sulfur atom, or a nitrogen atom, so that the group may contain a hydroxy group, a fluorine atom, a chlorine atom, a bromine atom, an iodine atom, a cyano group, a nitro group, a carbonyl group, an ether bond, an ester bond, a sulfonic ester bond, a carbonate bond, a lactone ring, a sultone ring, a carboxylic anhydride (—C(═O)—O—C(═O)—), or a haloalkyl group. The heteroatom is preferably an oxygen atom.

In formula (2), L^{A} is a single bond, an ether bond, or a C₁-C₂₀ hydrocarbylene group which may contain a heteroatom. The hydrocarbylene group may be saturated or unsaturated, and may be straight, branched, or cyclic. Specific examples thereof include those groups mentioned as the hydrocarbylene group represented by R²⁰³.

In formula (2), X^{A}, X^{B}, X^{C}, and X^{D} are each independently a hydrogen atom, a fluorine atom, or a trifluoromethyl group. Provided that, at least one of X^{A}, X^{B}, X^{C}, and X^{D} is a fluorine atom or a trifluoromethyl group.

In formula (2), k is an integer of 0 to 3.

As the PAG having formula (2), a PAG having formula (2′) is preferable.

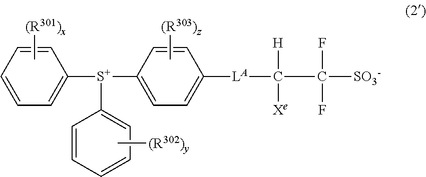

In formula (2′), L^{A} is as defined above. X^{e} is a hydrogen atom or a trifluoromethyl group, preferably a trifluoromethyl group. R³⁰¹, R³⁰², and R³⁰³ are each independently a hydrogen atom or a C₁-C₂₀ hydrocarbyl group which may contain a heteroatom. The hydrocarbyl group may be saturated or unsaturated, and may be straight, branched, or cyclic. Specific examples thereof include those groups mentioned as the hydrocarbyl group represented by R^{fa1} in formula (1A′). x and y are each independently an integer of 0 to 5, and z is an integer of 0 to 4.

Examples of the PAG having formula (2) include those mentioned as the PAG having formula (2) of JP-A 2017-026980.

Among the PAGs, the PAG containing the anion having formula (1A′) or (1D) has small acid diffusion and excellent solubility in a solvent, which is particularly preferable. The PAG having formula (2′) has extremely small acid diffusion, which is particularly preferable.

As the PAG, a sulfonium salt or iodonium salt having an iodized or brominated aromatic ring-containing anion can also be used. Examples of such a salt include those having formula (3-1) or (3-2).

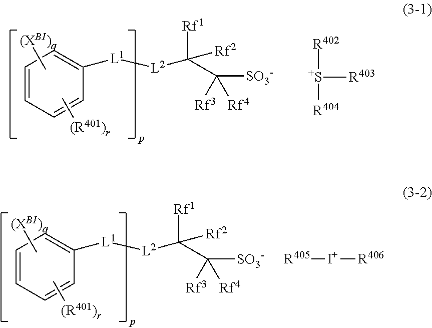

In the formulae (3-1) and (3-2), p is an integer satisfying 1≤p≤3. q and r is an integer satisfying 1≤q≤5, 0≤r≤3, and 1≤q+r≤5. q is preferably an integer satisfying 1≤q≤3, and more preferably 2 or 3. r is an integer satisfying 0≤r≤2.

In the formulae (3-1) and (3-2), X^{BI} is an iodine atom or a bromine atom, and may be identical or different if p and/or q is 2 or more.

In the formulae (3-1) and (3-2), L¹ is a single bond, an ether bond, an ester bond, or a C₁-C₆ saturated hydrocarbylene group which may contain an ether bond or an ester bond. The saturated hydrocarbylene group may be straight, branched, or cyclic.

In the formulae (3-1) and (3-2), L² is a single bond or a C₁-C₂₀ divalent linking group if p is 1, and a C₁-C₂₀ (p+1)-valent linking group if p is 2 or 3, and the linking group may contain an oxygen atom, a sulfur atom, or a nitrogen atom.

In the formulae (3-1) and (3-2), R⁴⁰¹ is a hydroxy group, a carboxy group, a fluorine atom, a chlorine atom, a bromine atom, an amino group, or a C₁-C₂₀ hydrocarbyl group, a C₁-C₂₀ hydrocarbyloxy group, a C₂-C₂₀ hydrocarbylcarbonyl group, a C₂-C₁₀ hydrocarbyloxycarbonyl group, a C₂-C₂₀ hydrocarbylcarbonyloxy group, or a C₁-C₂₀ hydrocarbylsulfonyloxy group, which may contain a fluorine atom, a chlorine atom, a bromine atom, a hydroxy group, an amino group, or an ether bond, —N(R^{401A})(R^{401B}), —N(R^{401C})—C(═O)—R^{401D}, or —N(R^{401C})—C(═O)—O—R^{401D}. R^{401A} and R^{401B} are each independently a hydrogen atom or a C₁-C₆ saturated hydrocarbyl group. R^{401C} is a hydrogen atom or a C₁-C₆ saturated hydrocarbyl group, which may contain a halogen atom, a hydroxy group, a C₁-C₆ saturated hydrocarbyloxy group, a C₂-C₆ saturated hydrocarbylcarbonyl group, or a C₂-C₆ saturated hydrocarbylcarbonyloxy group. R^{401D} is a C₁-C₁₆ aliphatic hydrocarbyl group, a C₆-C₁₄ aryl group, or a C₇-C₁₅ aralkyl group, which may contain a halogen atom, a hydroxy group, a C₁-C₆ saturated hydrocarbyloxy group, a C₂-C₆ saturated hydrocarbylcarbonyl group, or a C₂-C₆ saturated hydrocarbylcarbonyloxy group. The aliphatic hydrocarbyl group may be saturated or unsaturated, and may be straight, branched, or cyclic. The hydrocarbyl group, the hydrocarbyloxy group, the hydrocarbyloxycarbonyl group, hydrocarbylcarbonyl group, the hydrocarbylcarbonyloxy group, and the hydrocarbylsulfonyloxy group may be straight, branched, or cyclic. Groups R⁴⁰¹ may be identical or different if p and/or r is 2 or more.

Among them, R⁴⁰¹ is preferably a hydroxy group, —N(R^{401C})—C(═O)—R^{401D}, —N(R^{401C})—C(═O)—O—R^{401D}, a fluorine atom, a chlorine atom, a bromine atom, a methyl group, a methoxy group, or the like.

In the formulae (3-1) and (3-2), Rf¹ to Rf⁴ are each independently a hydrogen atom, a fluorine atom, or a trifluoromethyl group, and at least one of these is a fluorine atom or a trifluoromethyl group. Rf¹ and Rf², taken together, may form a carbonyl group. In particular, both Rf³ and Rf⁴ are preferably a fluorine atom.

In formulae (3-1) and (3-2), R⁴⁰² to R⁴⁰⁶ are each independently a halogen atom, or a C₁-C₂₀ hydrocarbyl group which may contain a heteroatom. The hydrocarbyl group may be saturated or unsaturated, and may be straight, branched, or cyclic. Specific examples thereof include those groups mentioned as the hydrocarbyl group represented by R² to R⁶ in the descriptions of formulae (M-1) and (M-2). In these hydrocarbyl groups, some or all of hydrogen atoms may be substituted with a hydroxy group, a carboxy group, a halogen atom, a cyano group, a nitro group, a mercapto group, a sultone group, a sulfo group, or a sulfonium salt-containing group, and some constituent —CH₂— may be substituted with an ether bond, an ester bond, a carbonyl group, an amide bond, a carbonate bond, or a sulfonic ester bond. R⁴⁰² and R⁴⁰³ may bond together to form a ring together with the sulfur atom to which they are bonded. In the case, examples of the ring include the same rings as those mentioned as the ring that R² and R³, taken together, form with the sulfur atom to which they are bonded, in the description of formulae (M-1) and (M-2).

Examples of the cation of the sulfonium salt having formula (3-1) include those mentioned as the sulfonium cation represented by M⁺ in formulae (a1) and (a2). Examples of the cation of the iodonium salt having formula (3-2) include those mentioned as the iodonium cation represented by M⁺ in formulae (a1) and (a2).

Examples of the anion of the onium salt having formula (3-1) or (3-2) include those shown below, but are not limited thereto. In the formulae, X^{BI} is as defined above.

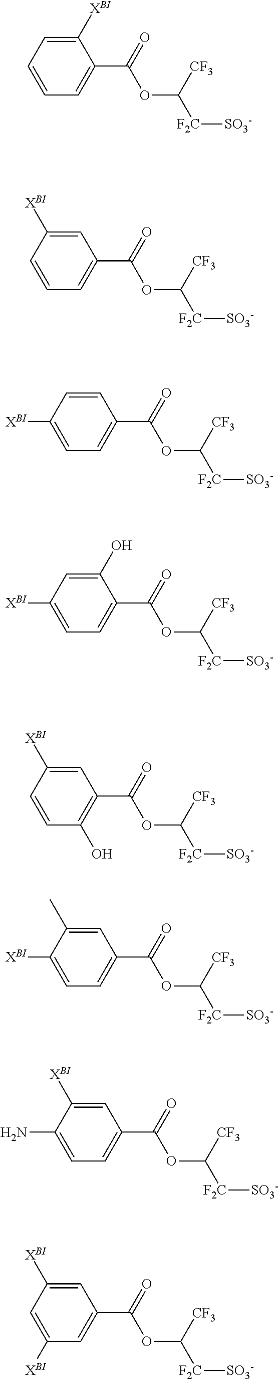

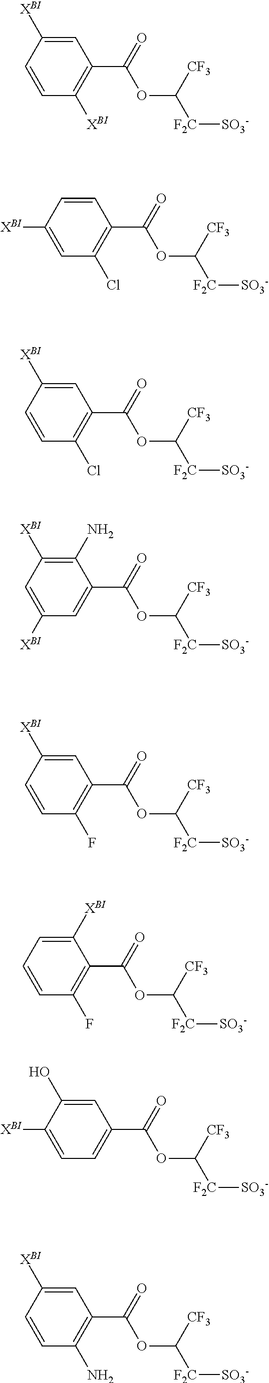

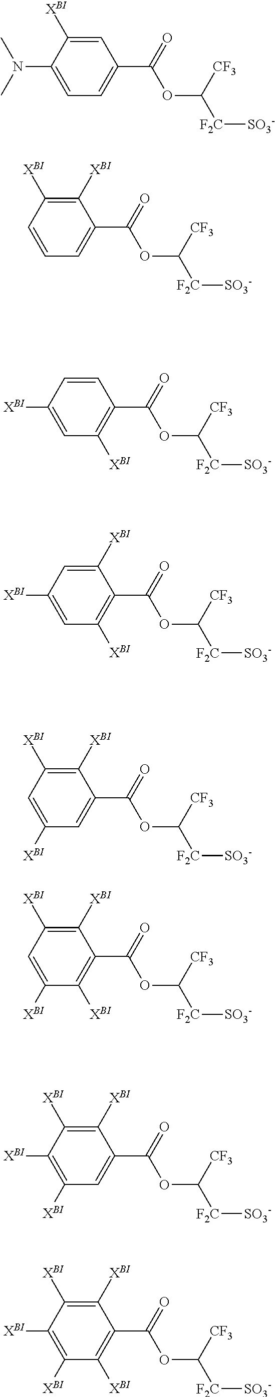

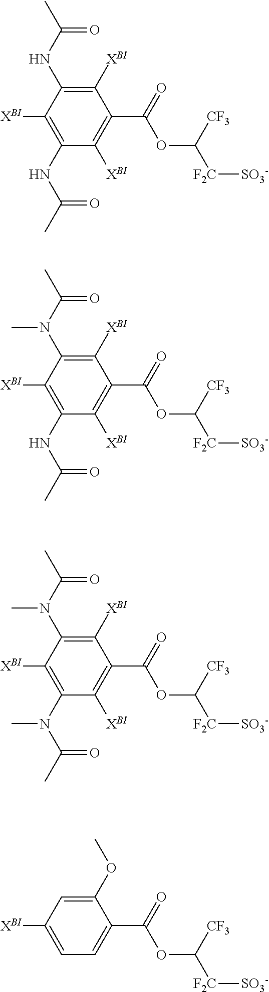

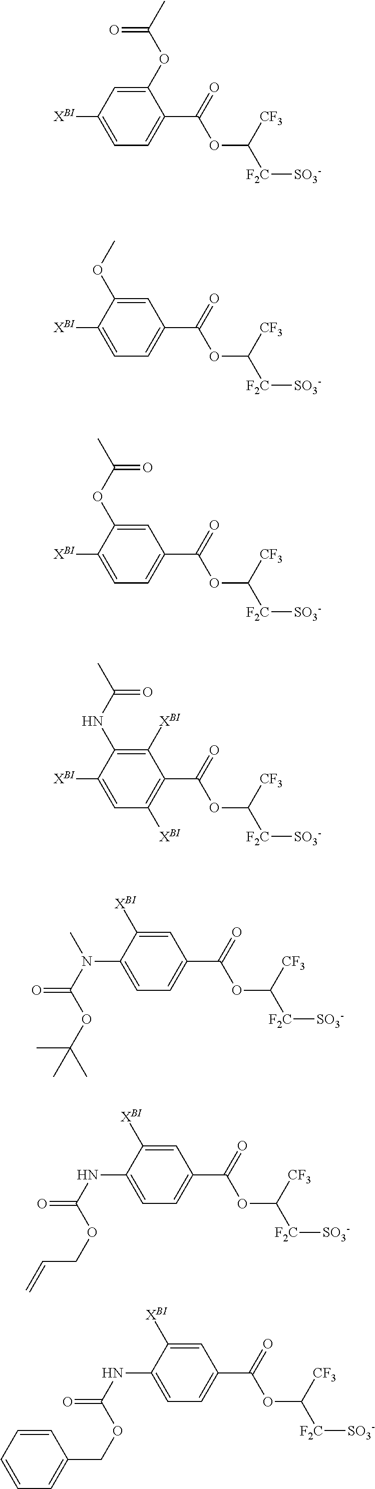

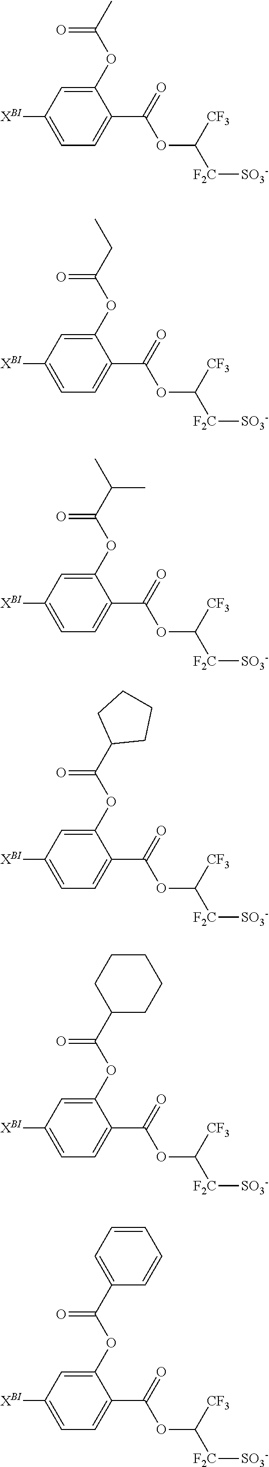

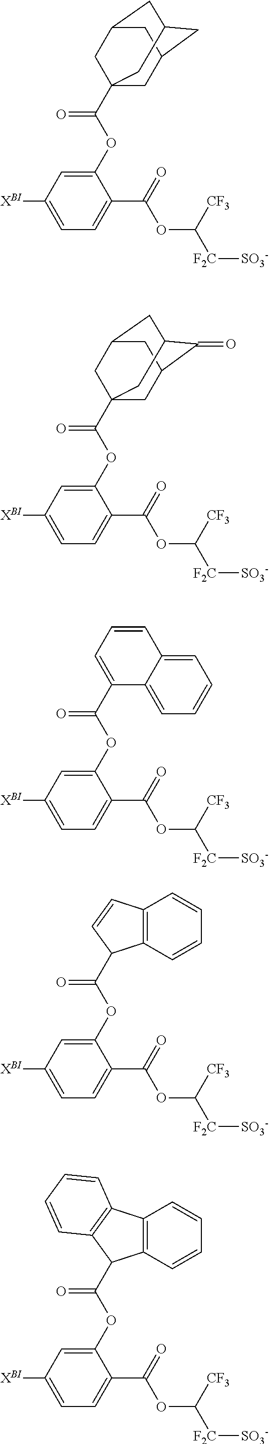

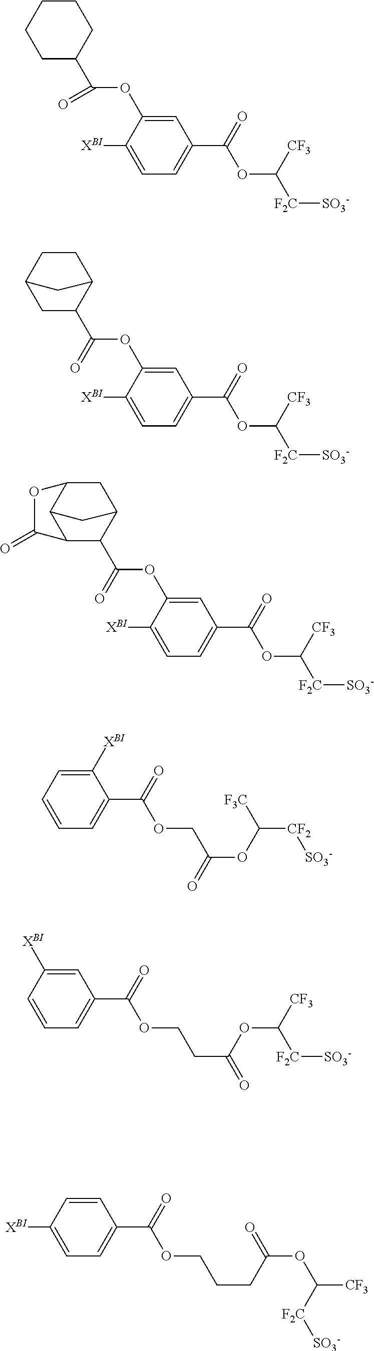

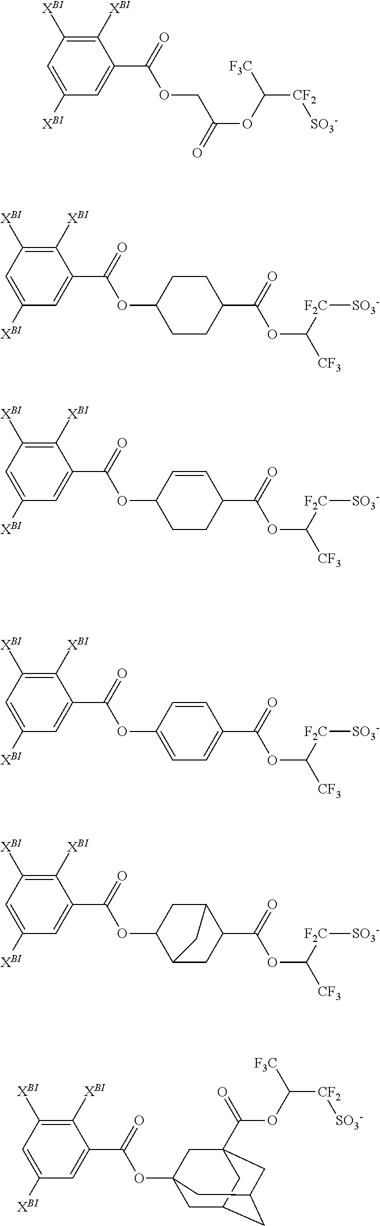

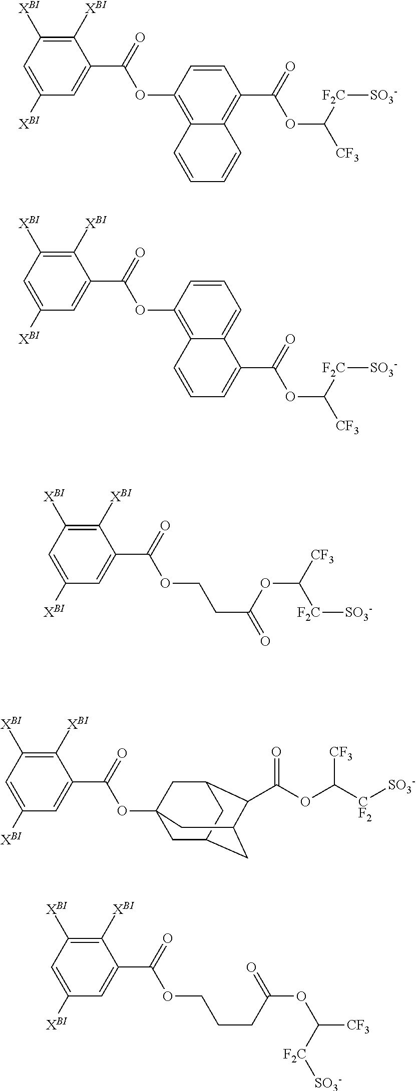

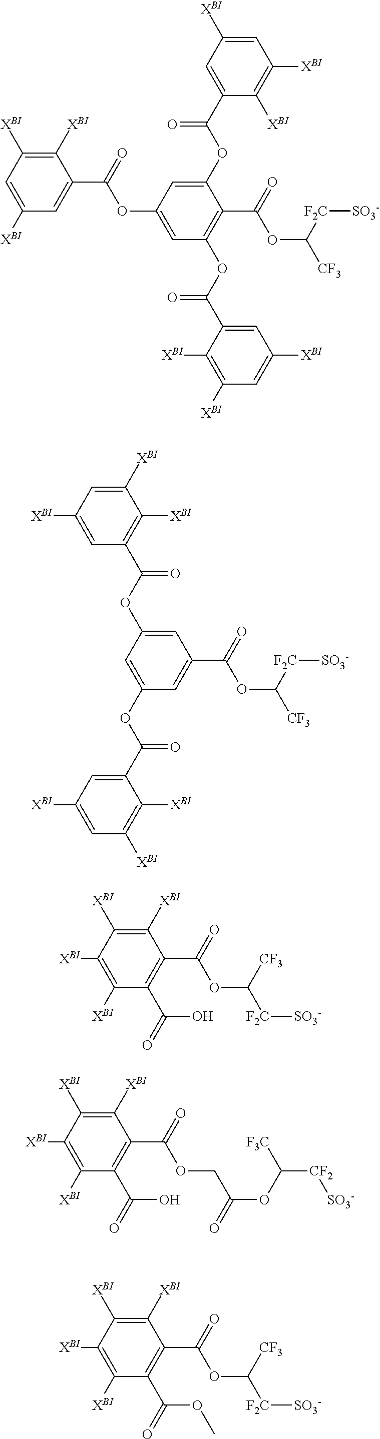

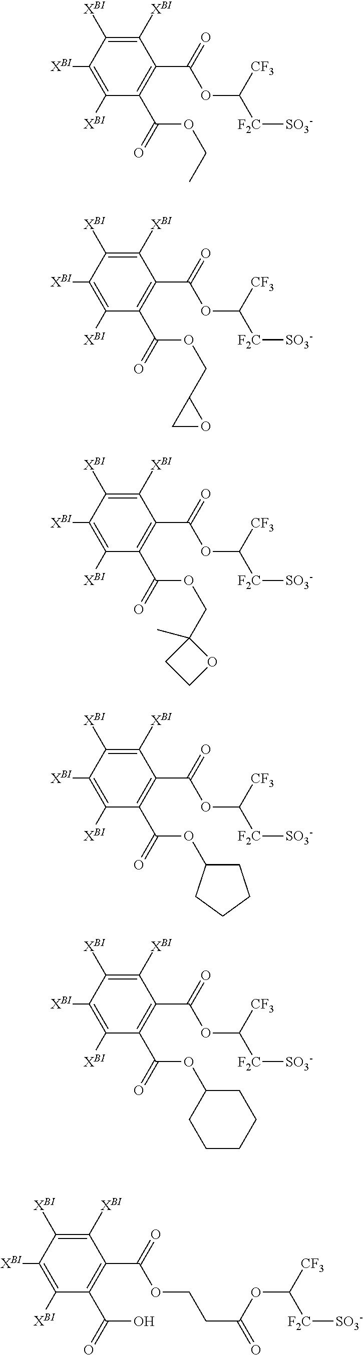

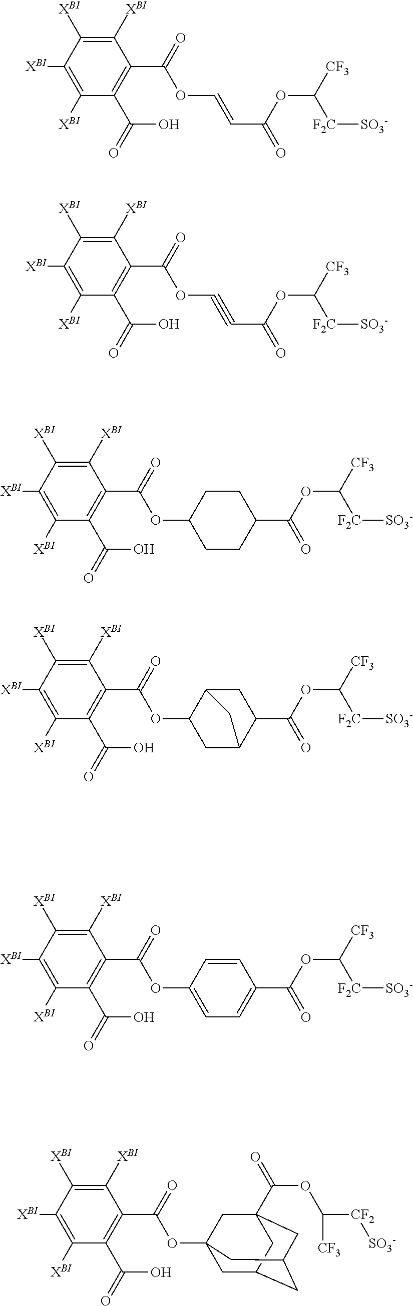

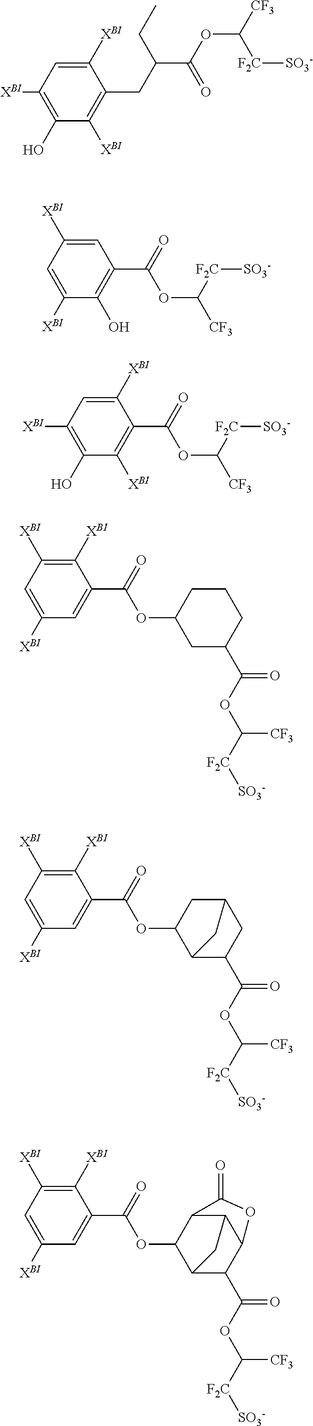

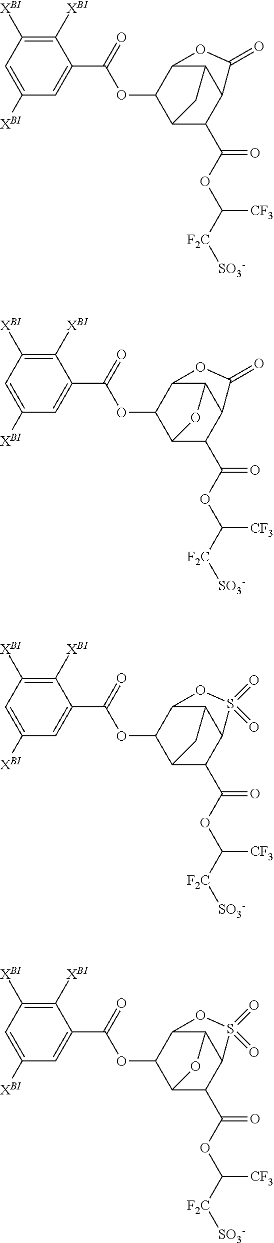

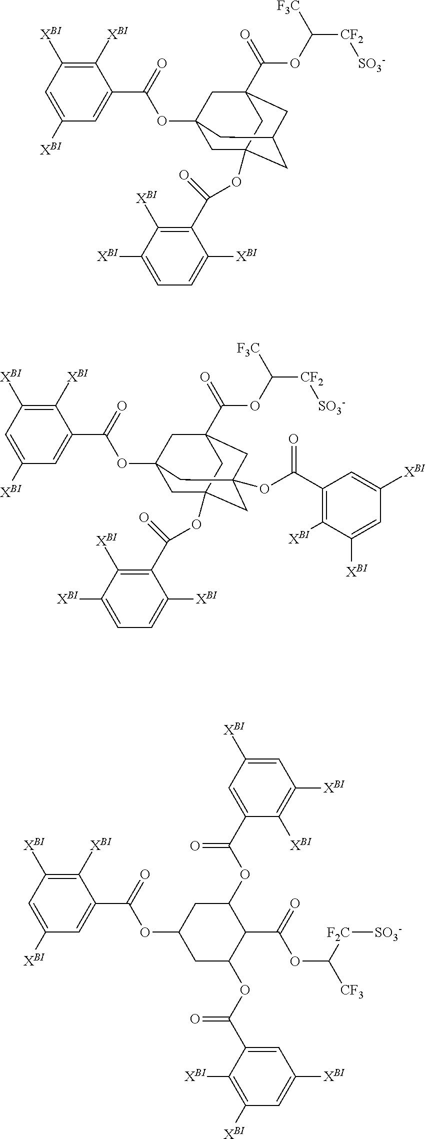

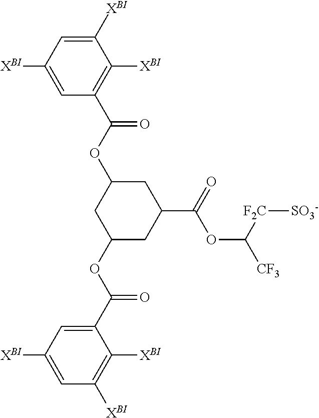

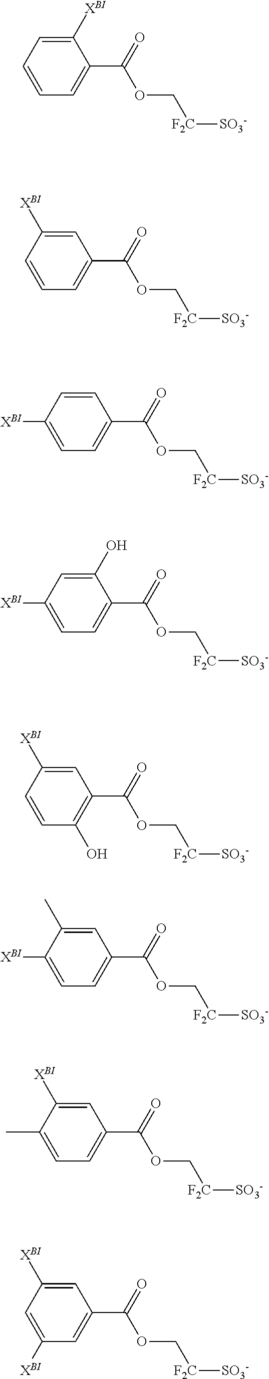

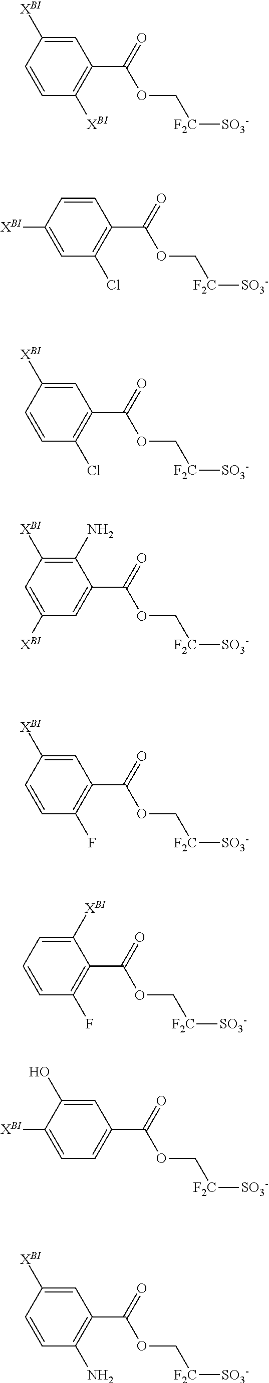

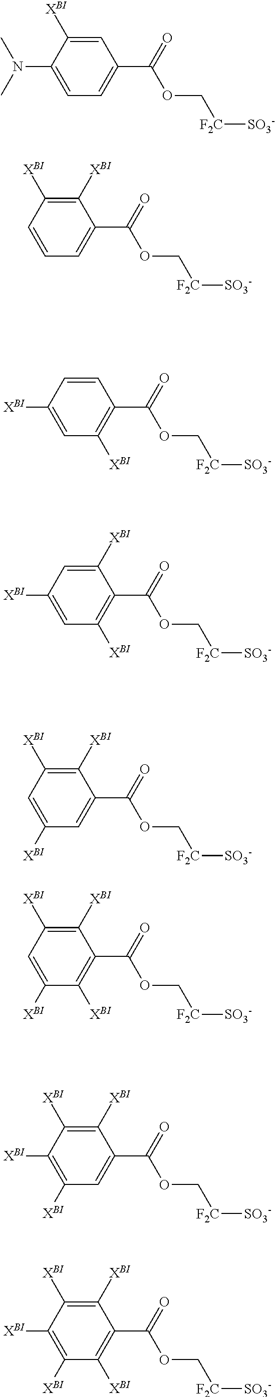

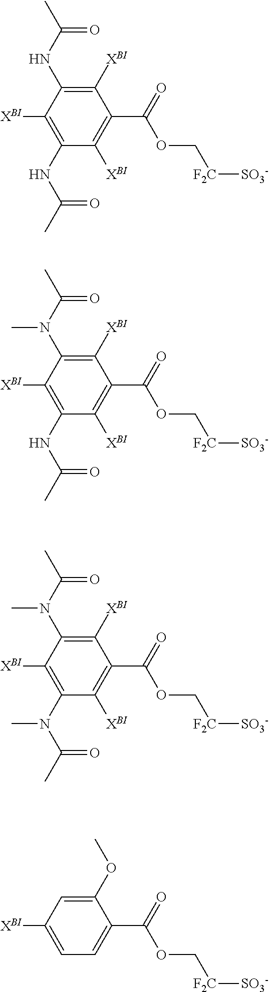

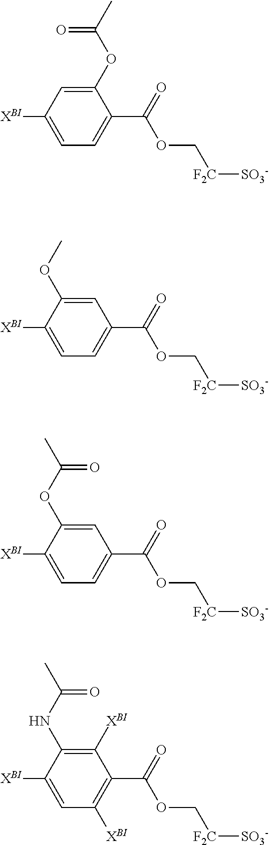

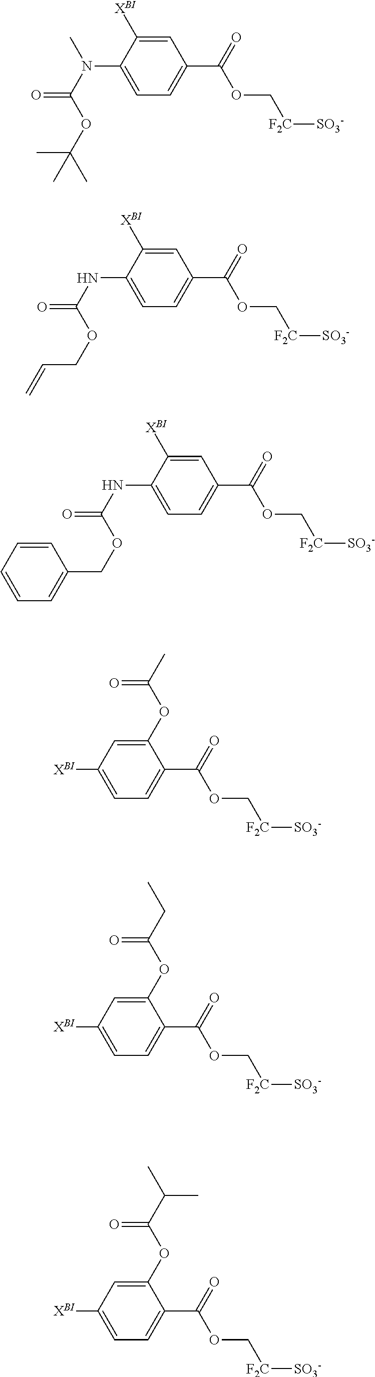

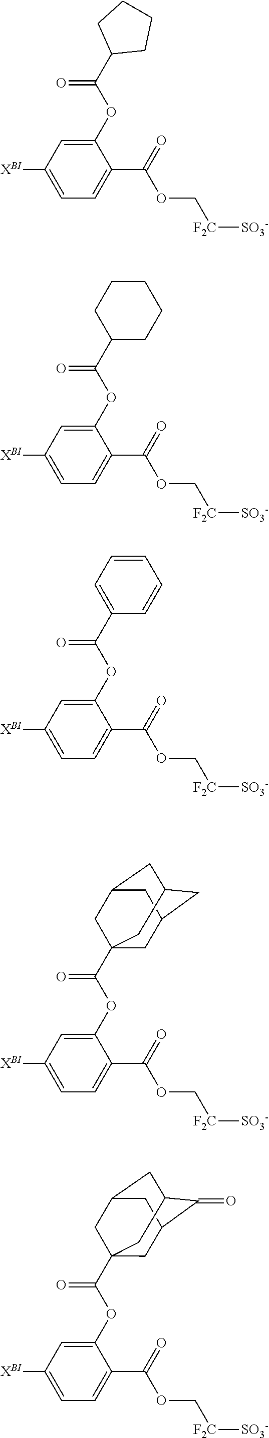

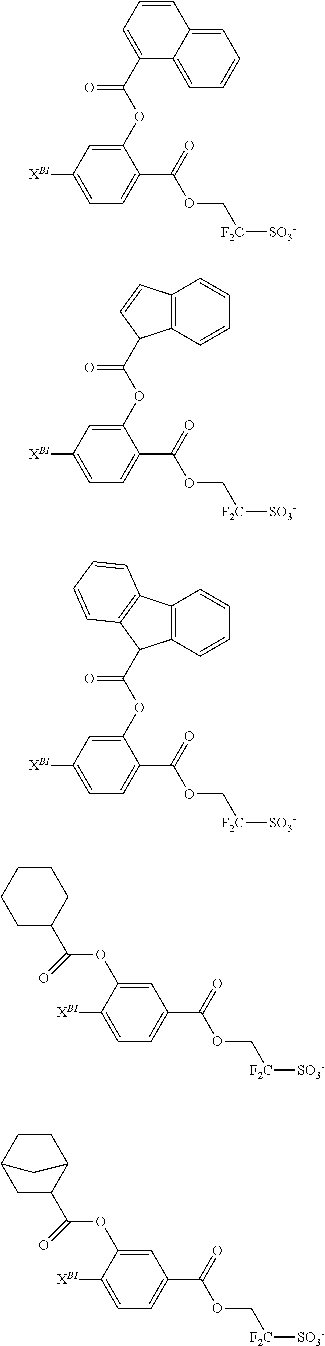

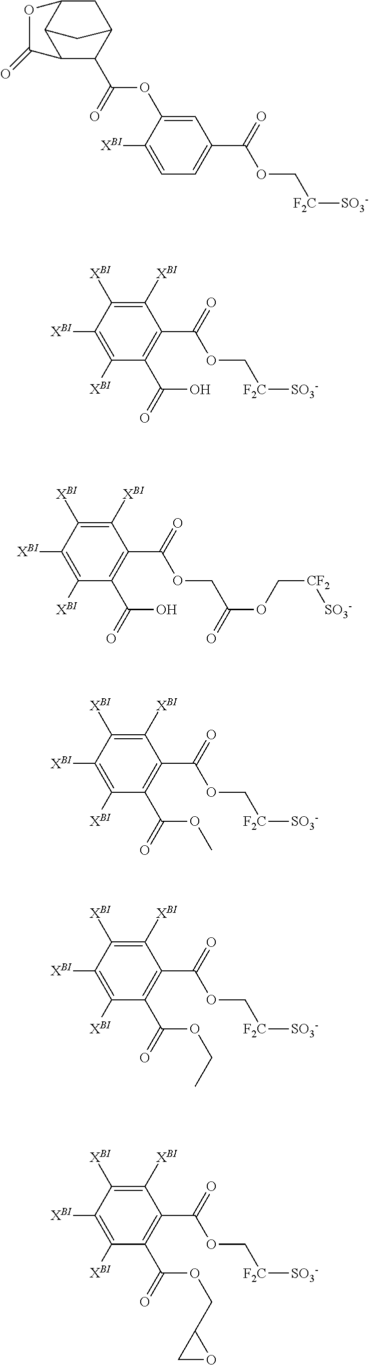

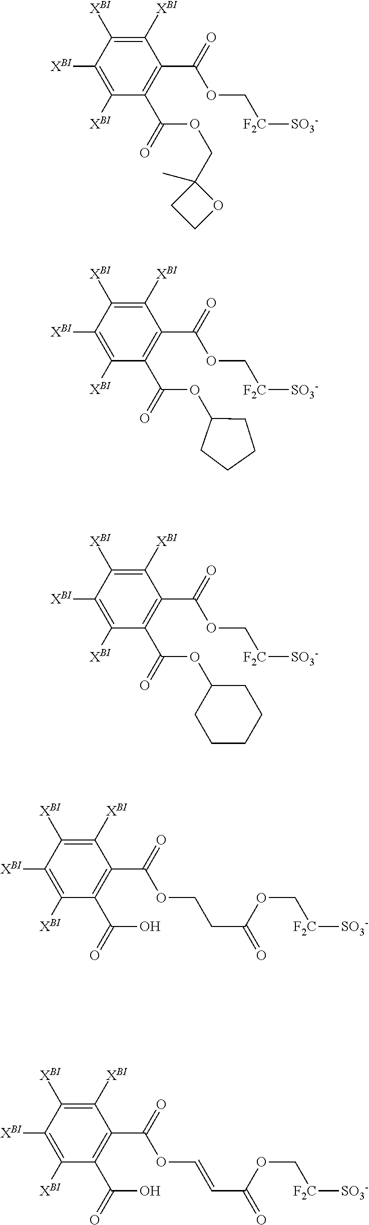

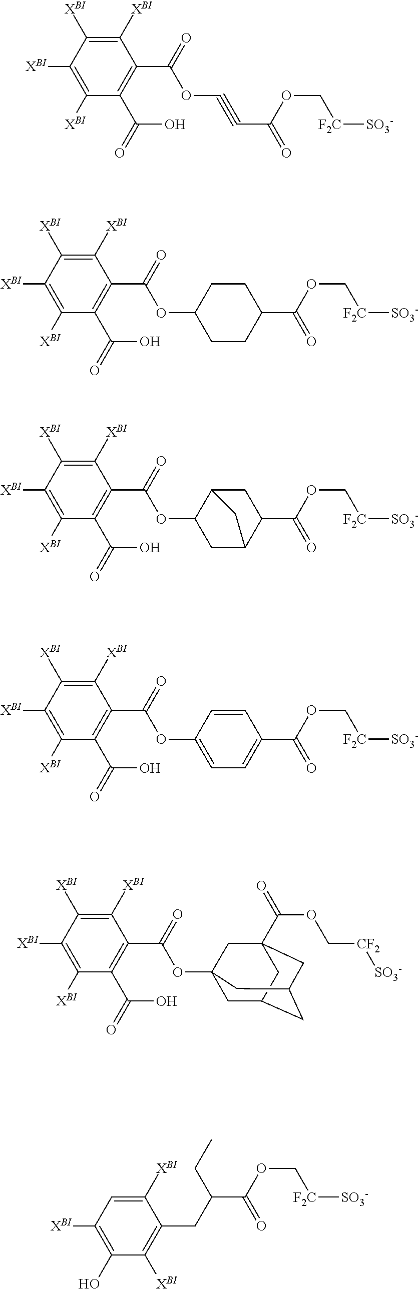

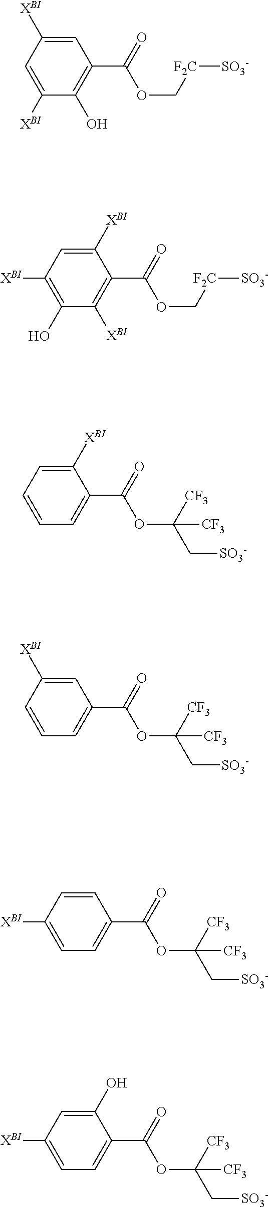

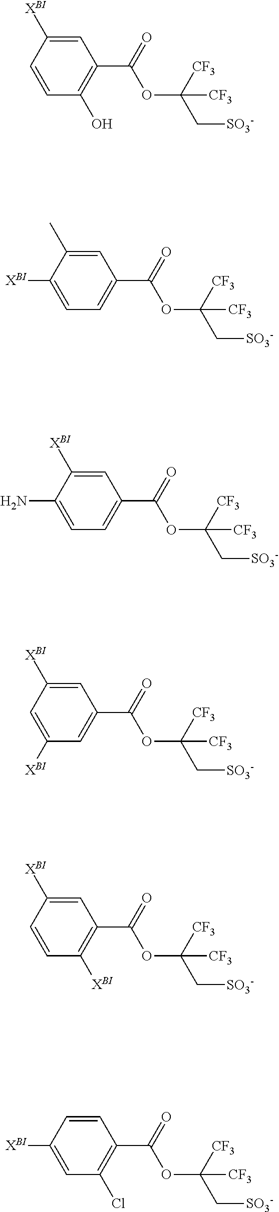

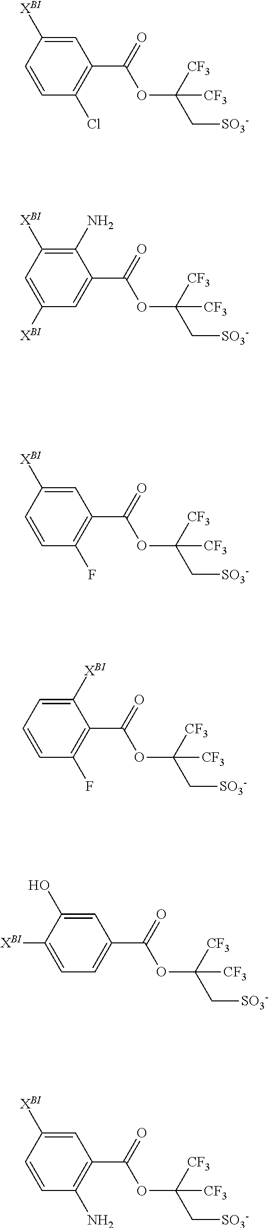

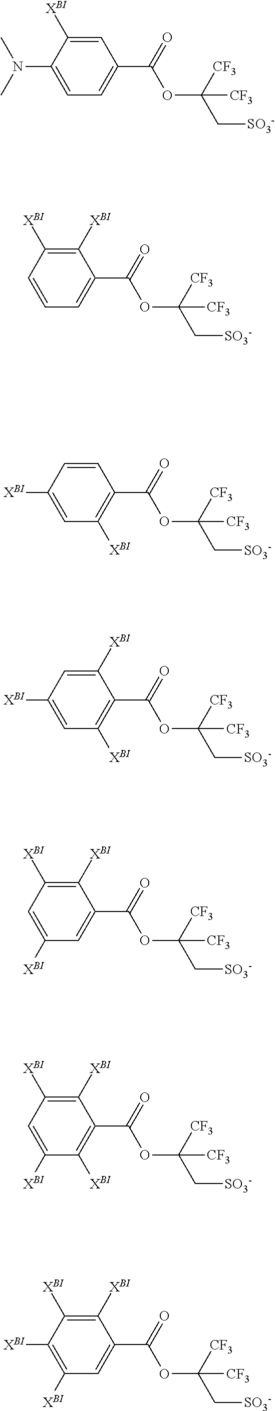

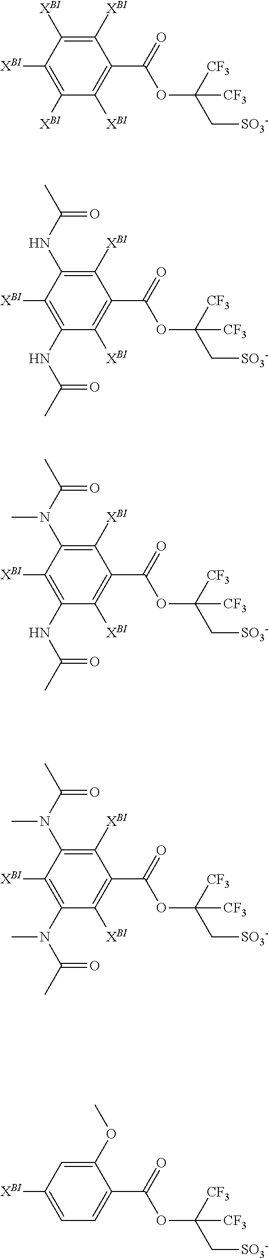

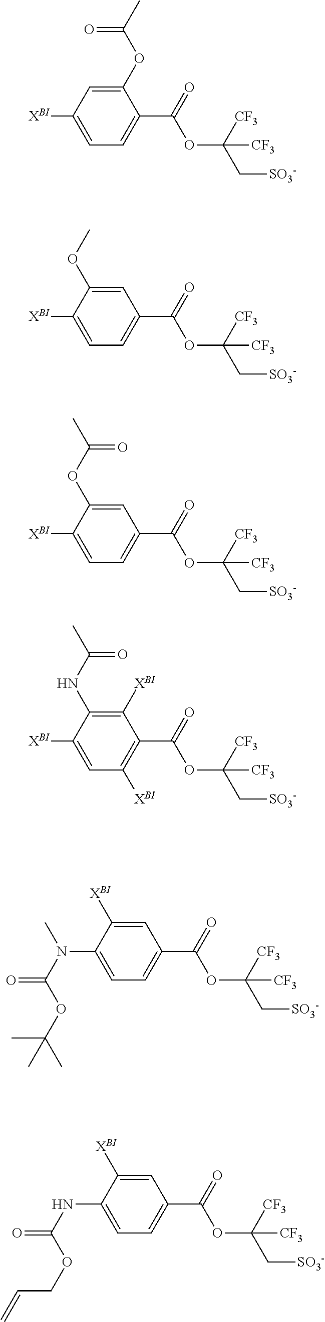

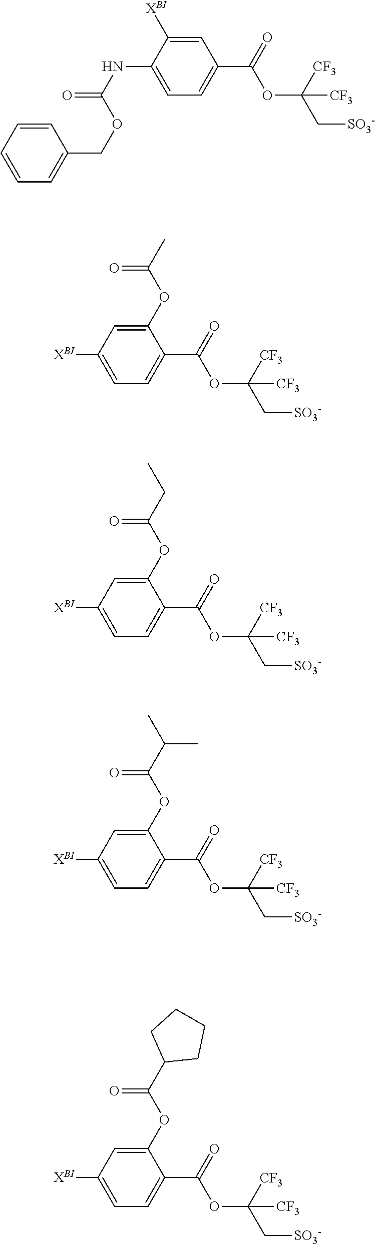

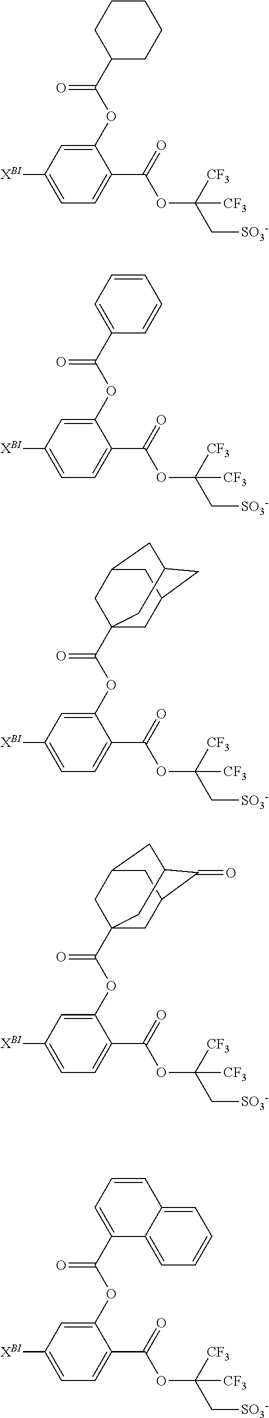

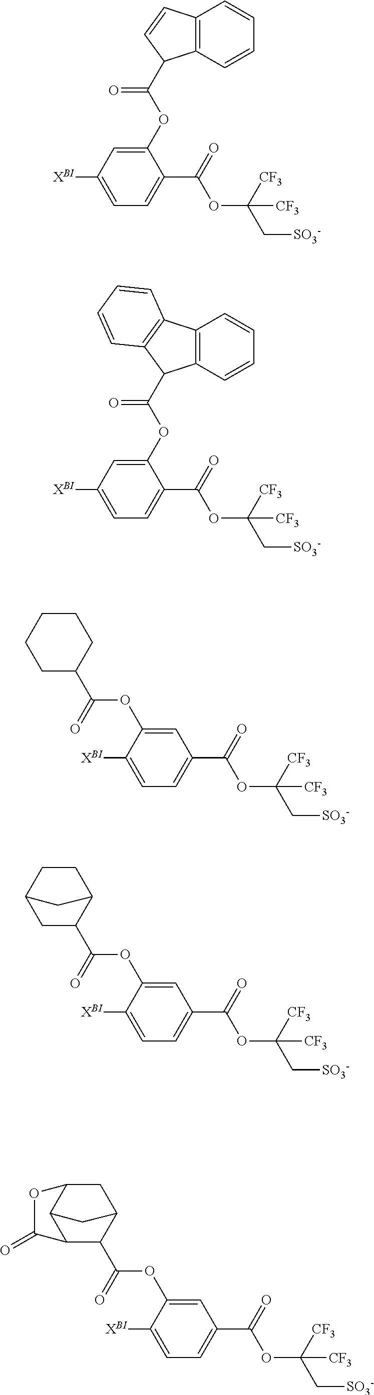

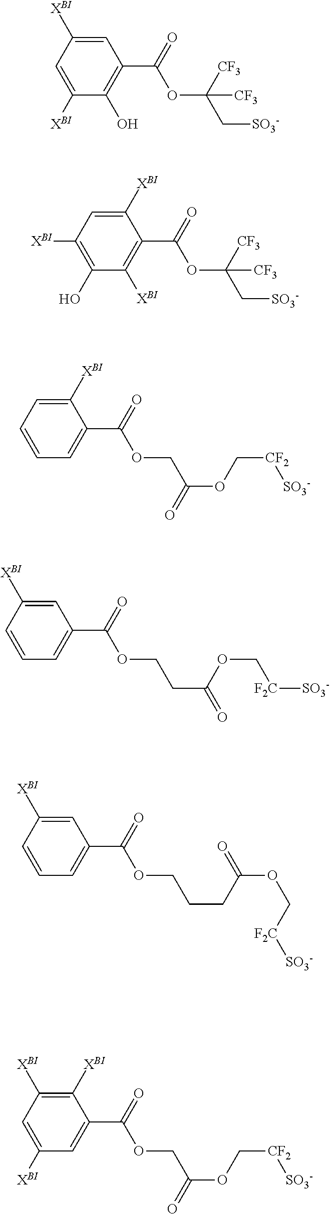

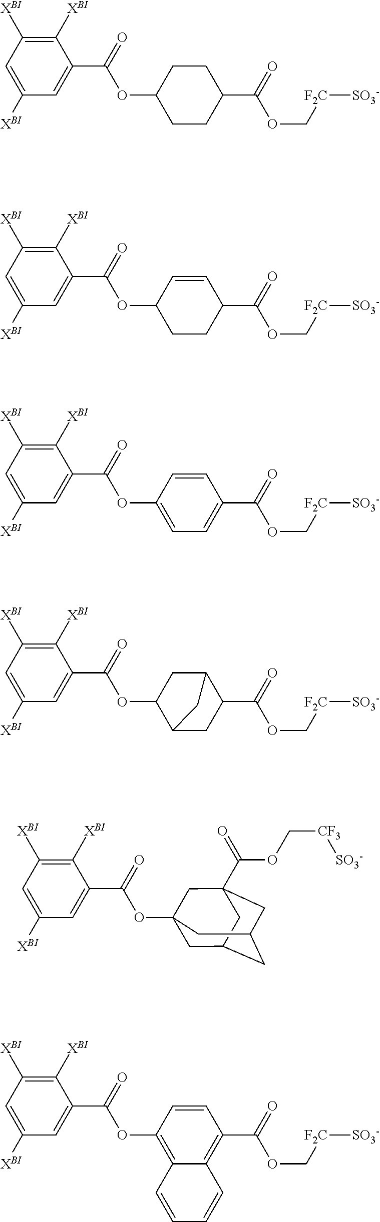

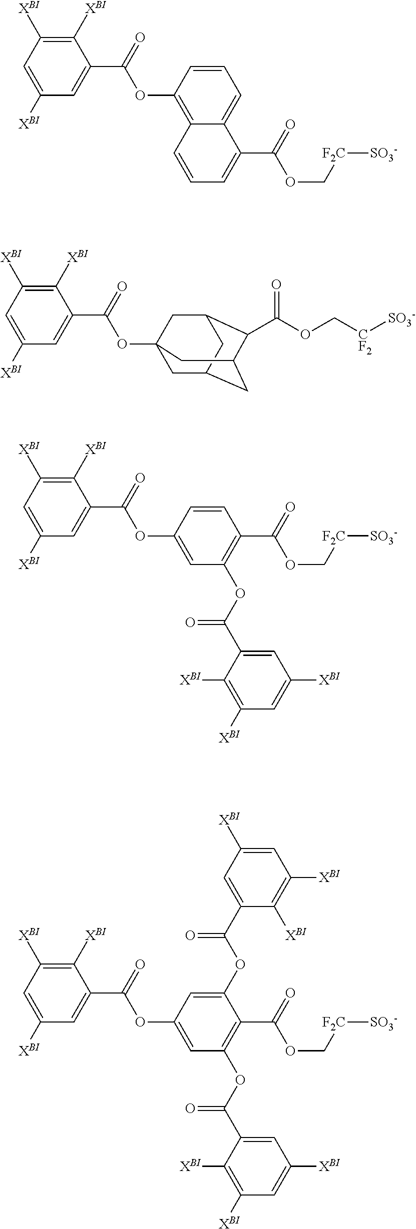

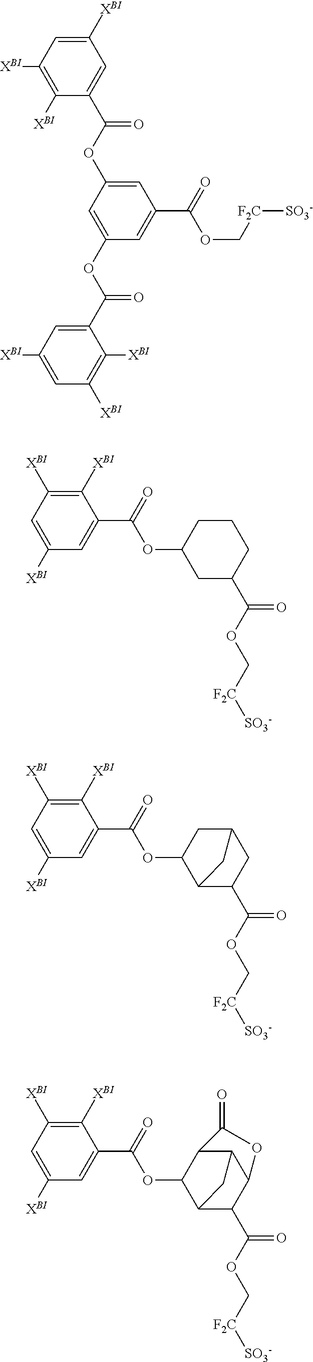

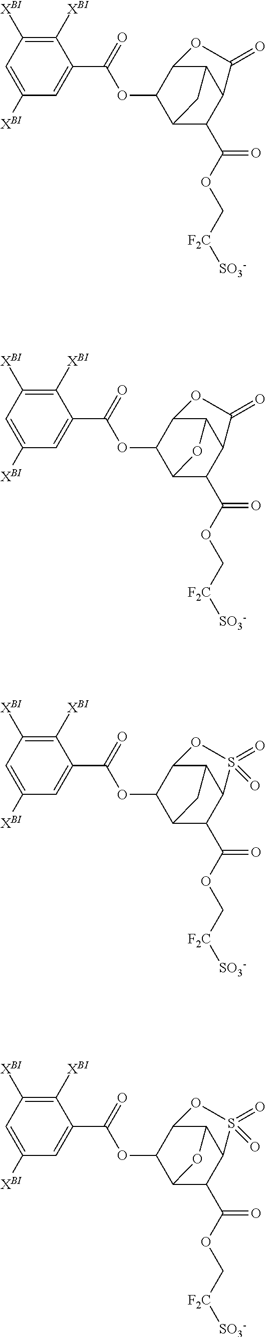

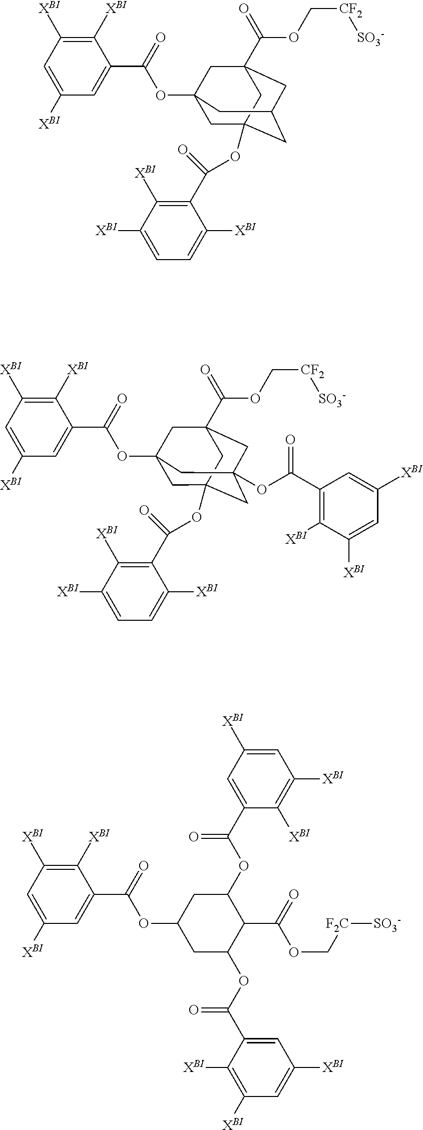

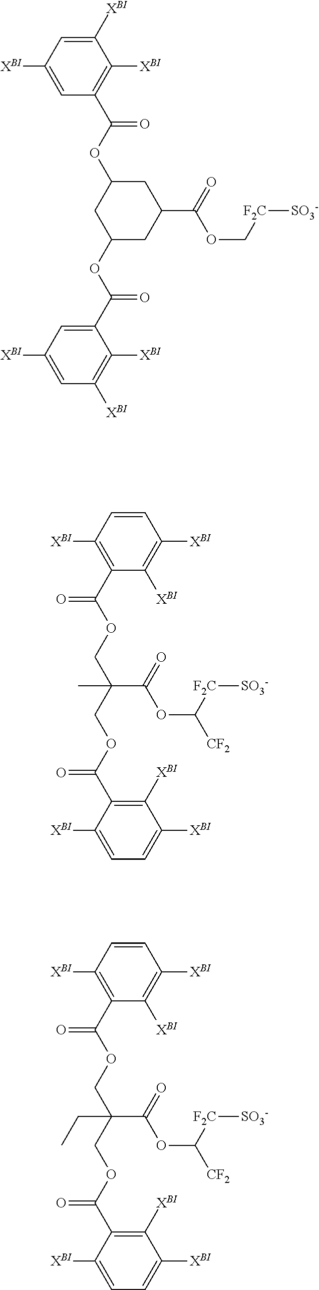

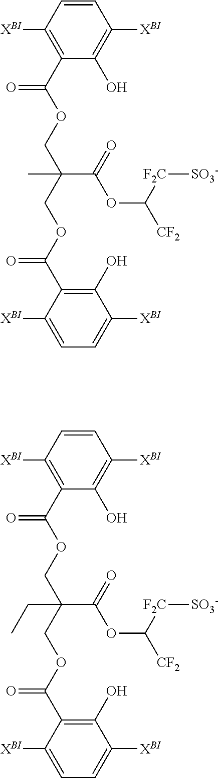

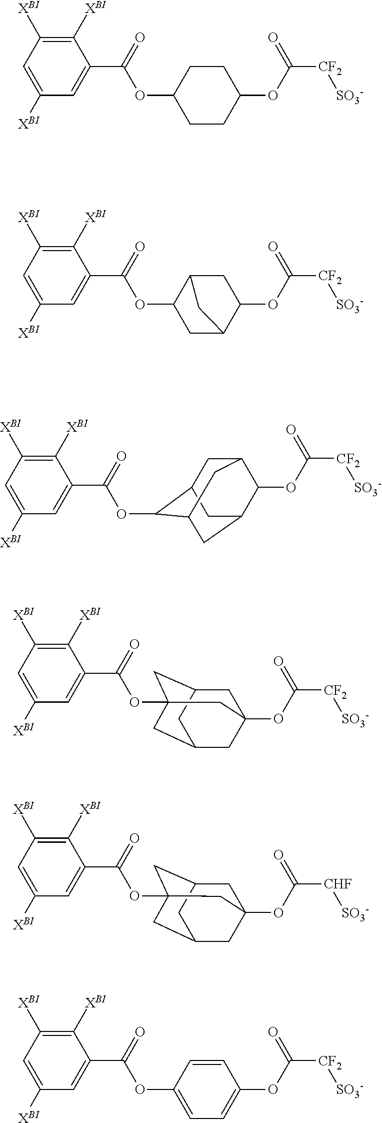

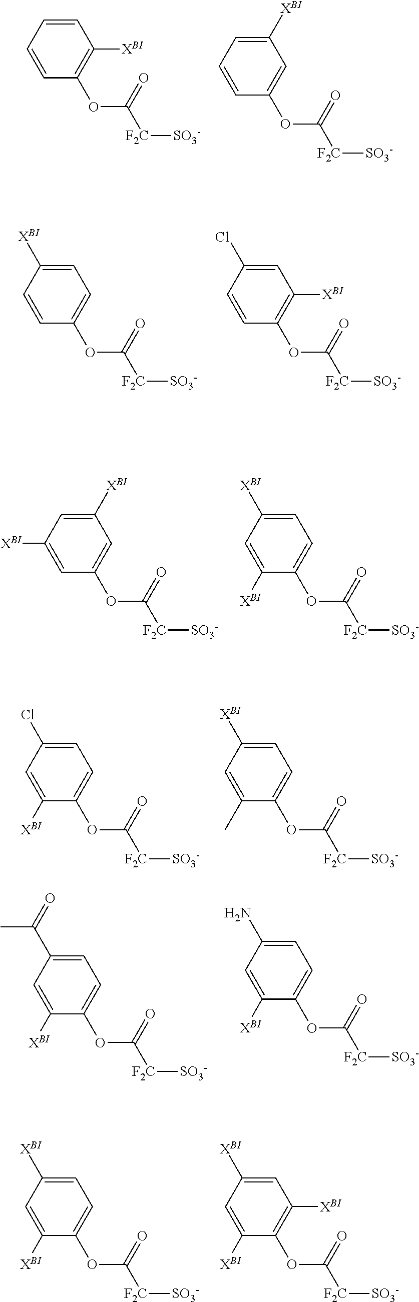

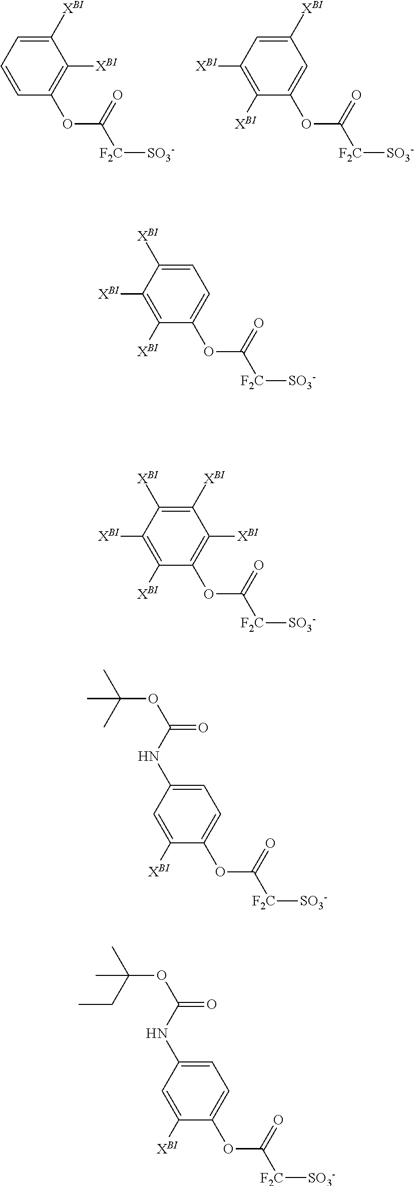

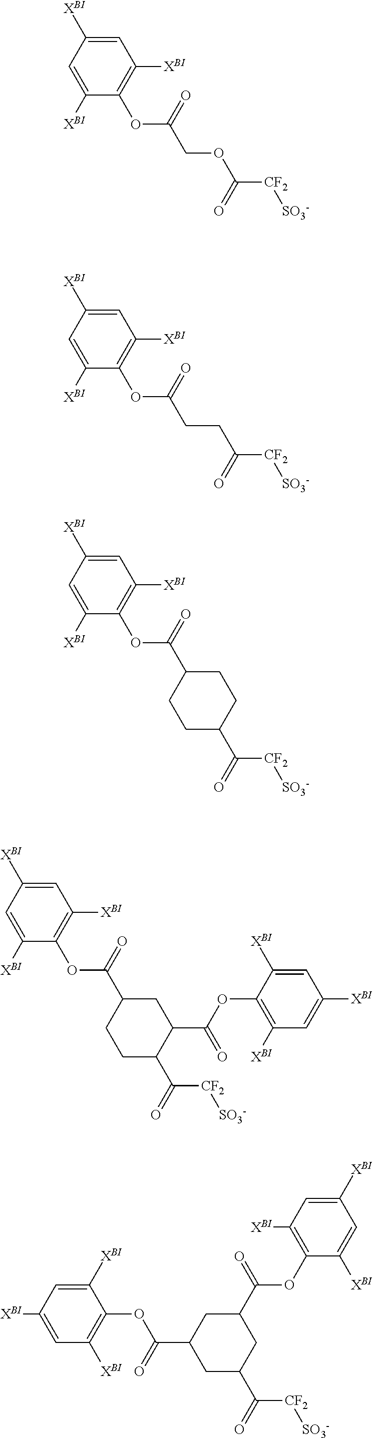

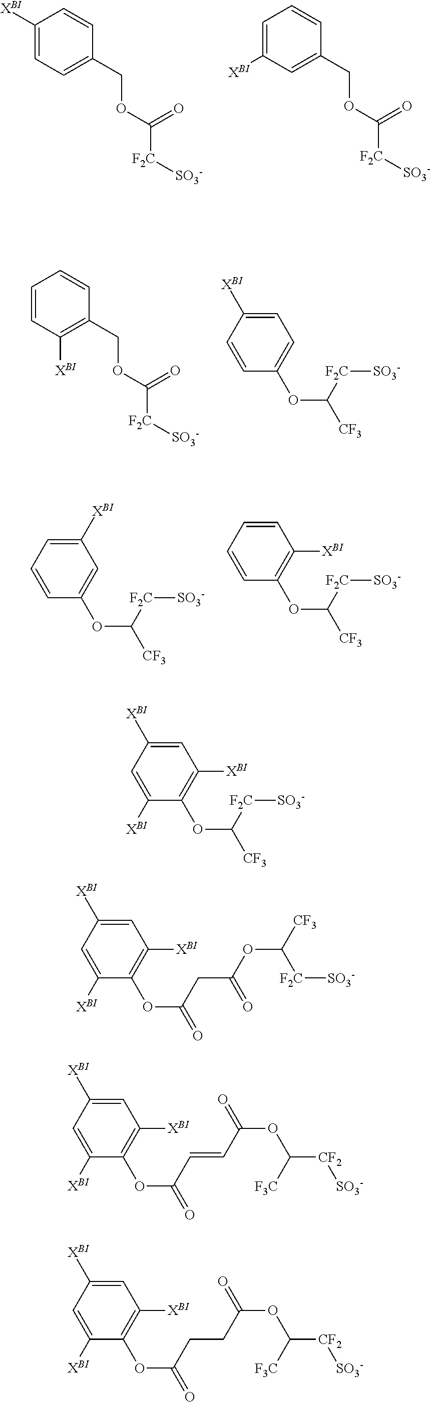

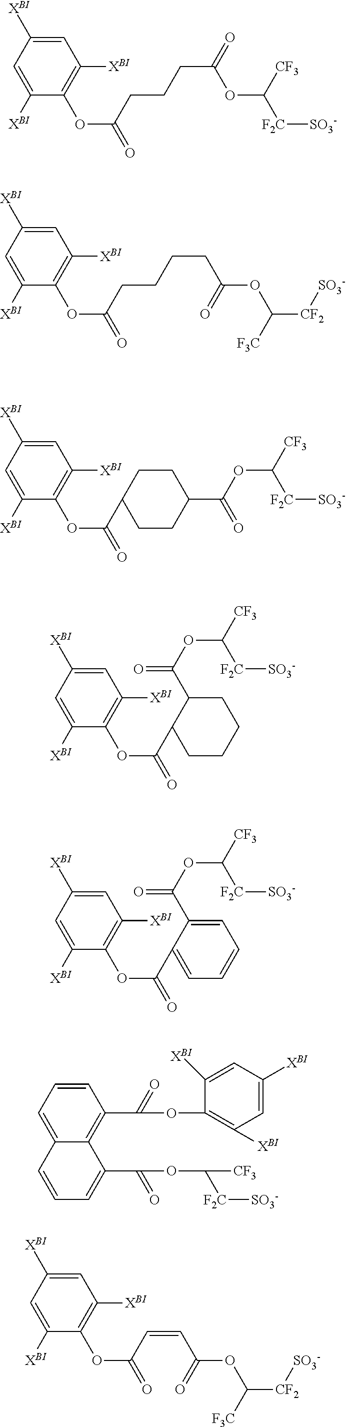

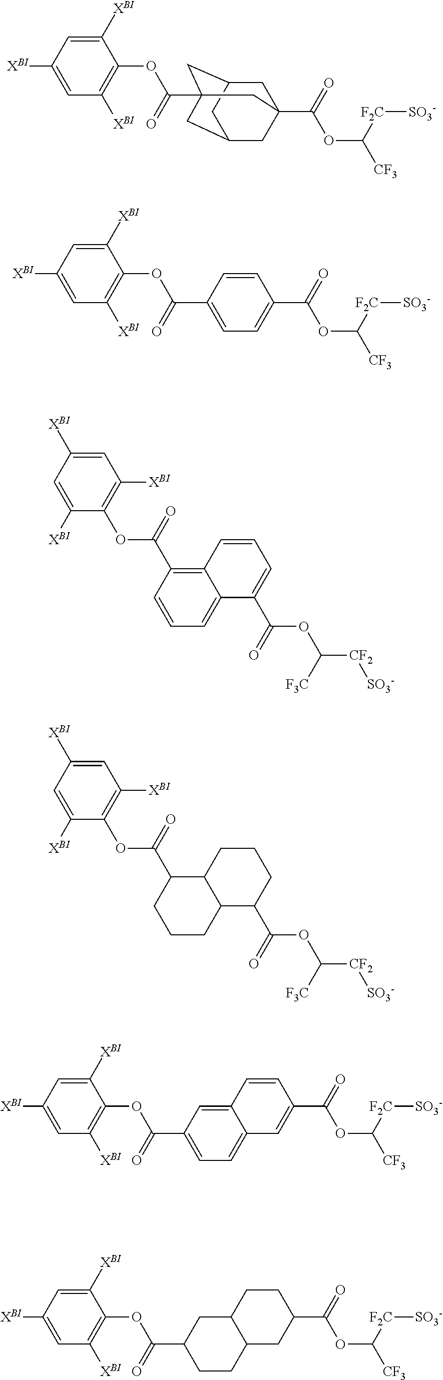

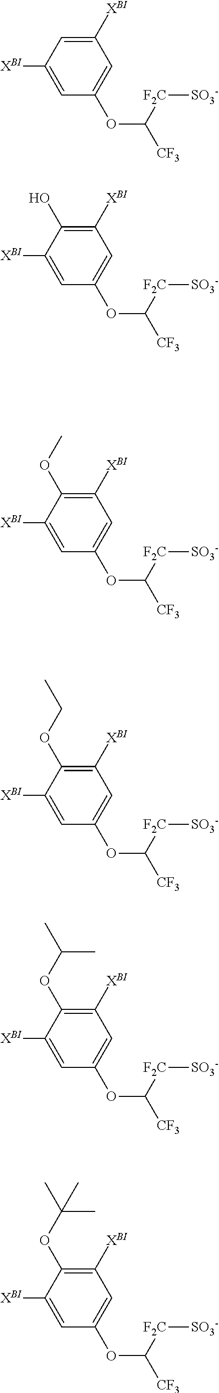

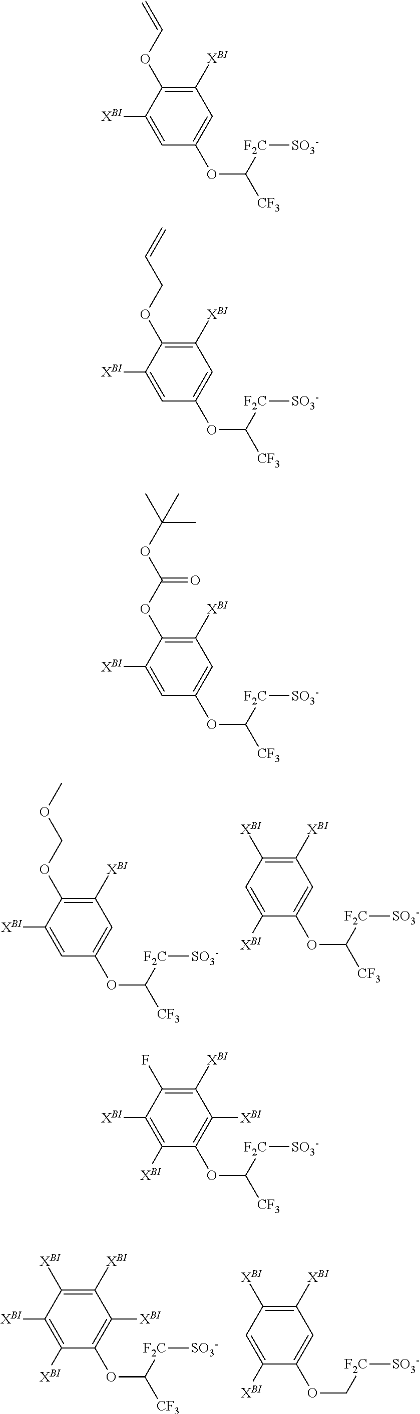

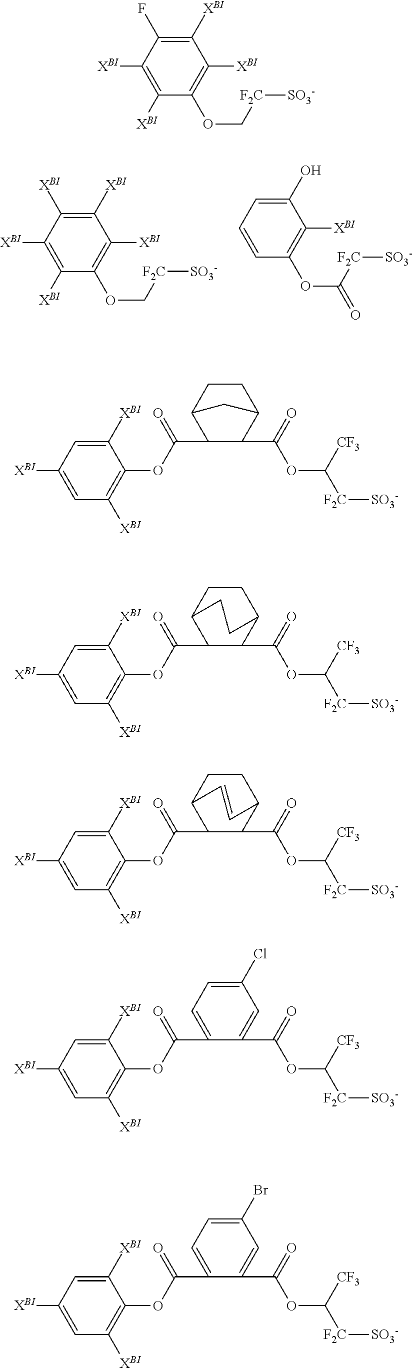

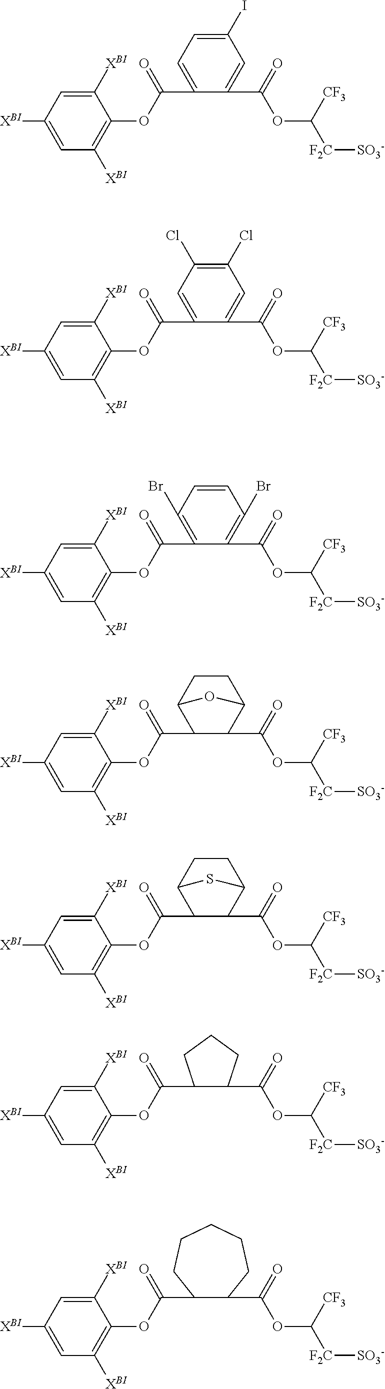

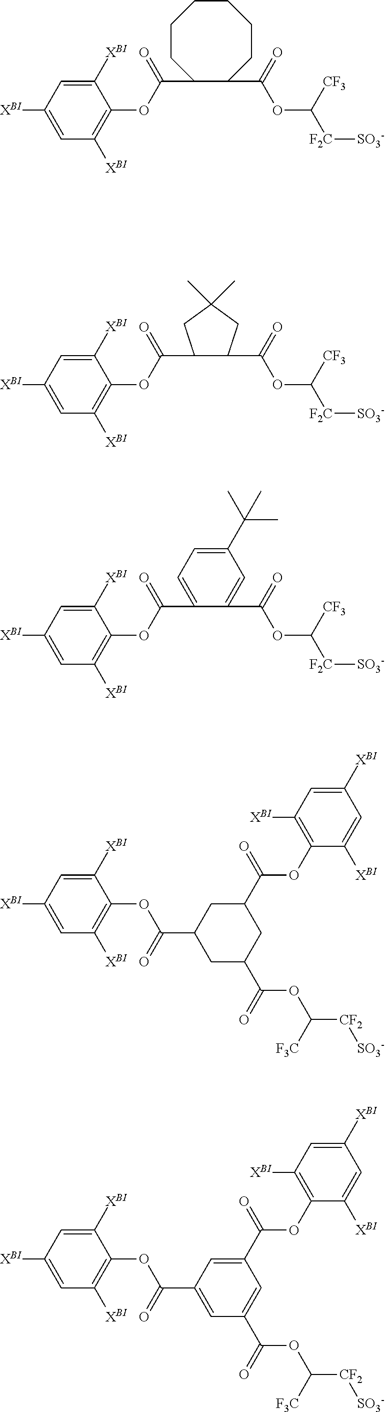

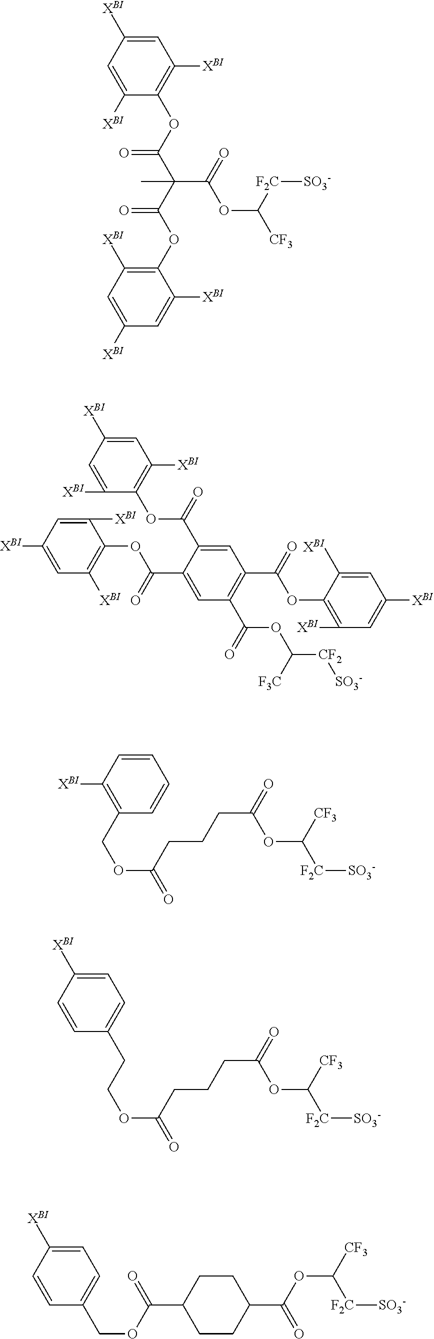

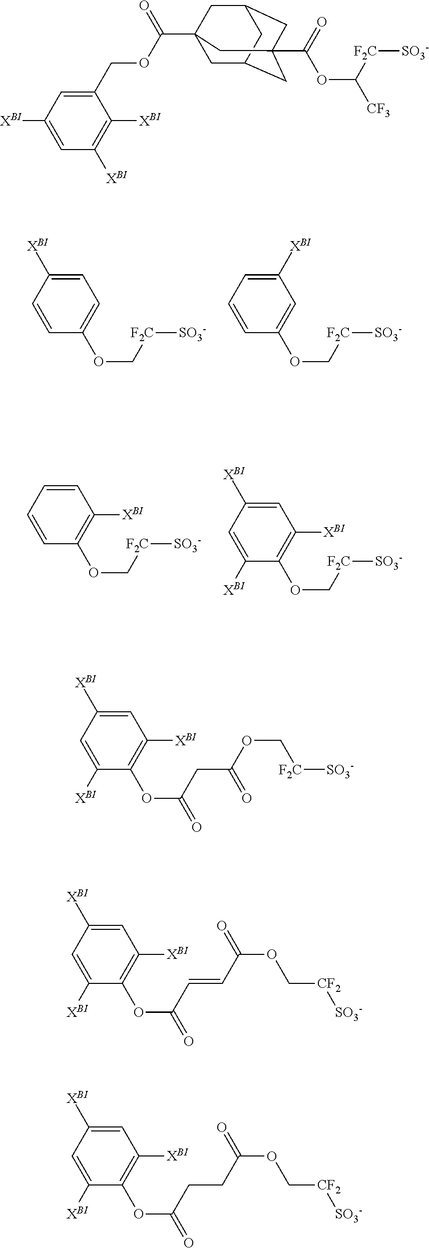

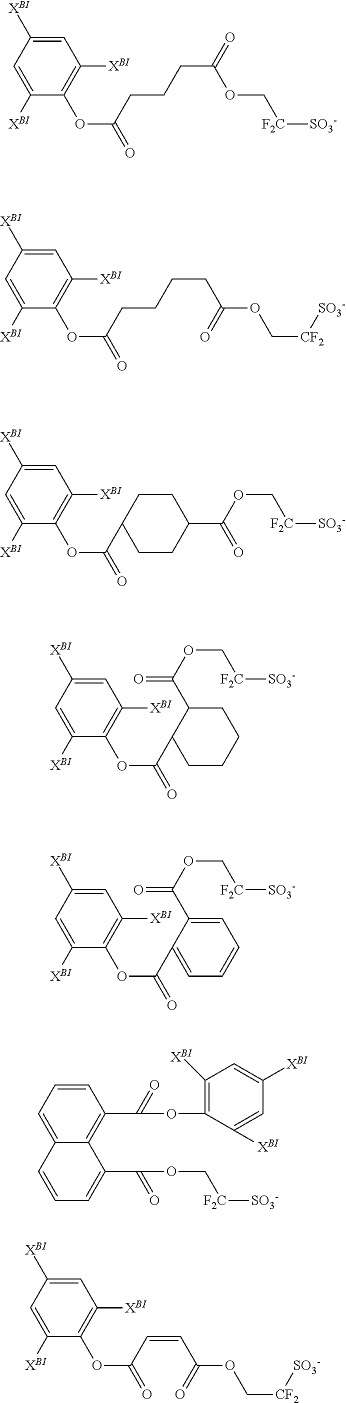

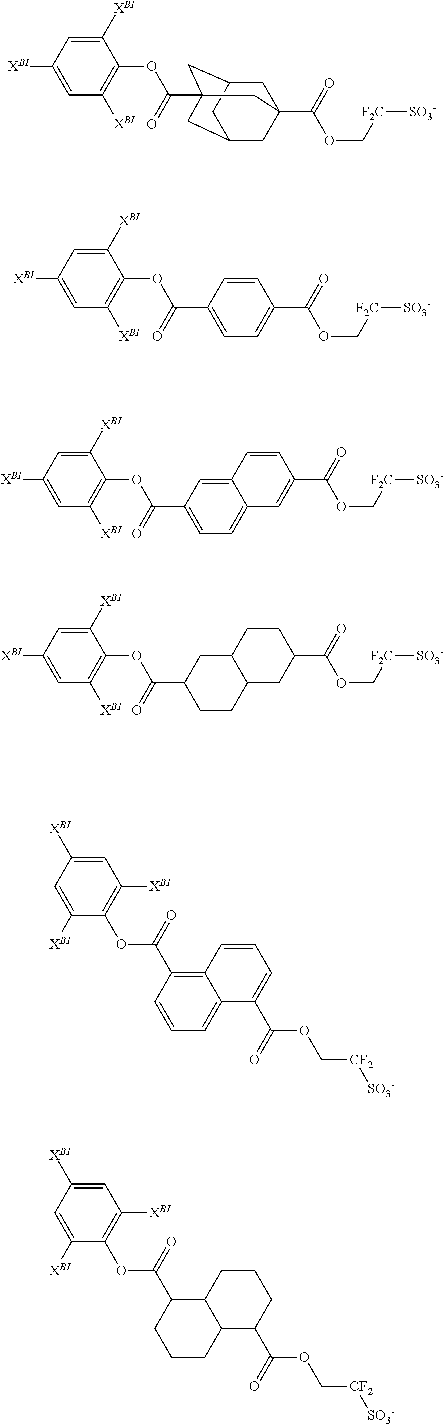

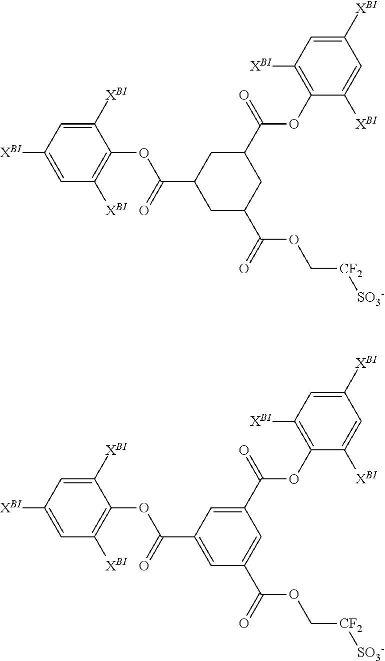

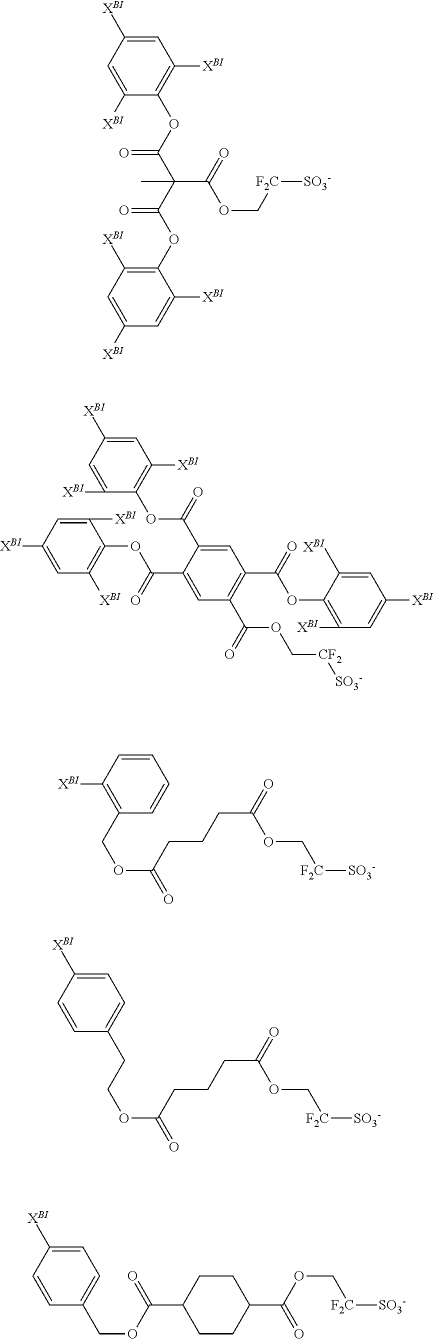

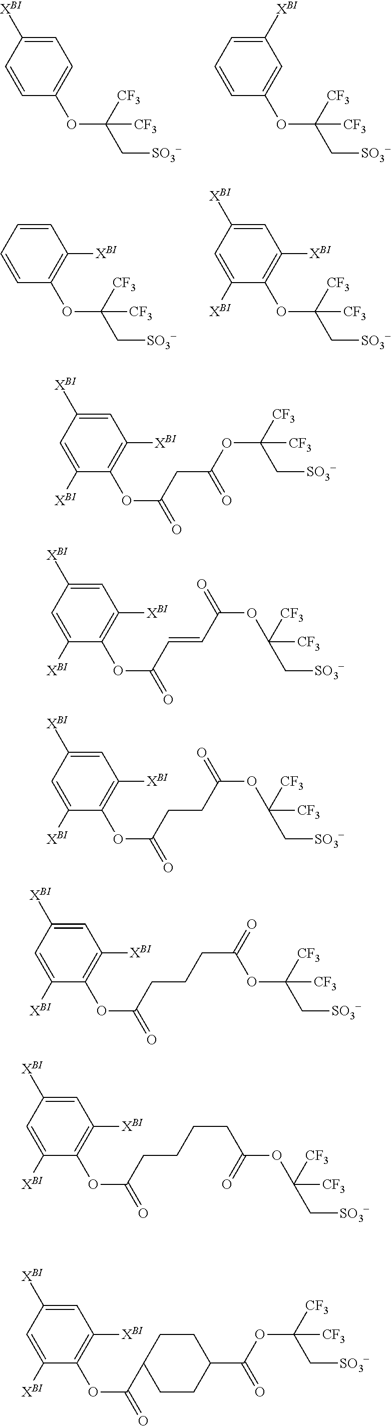

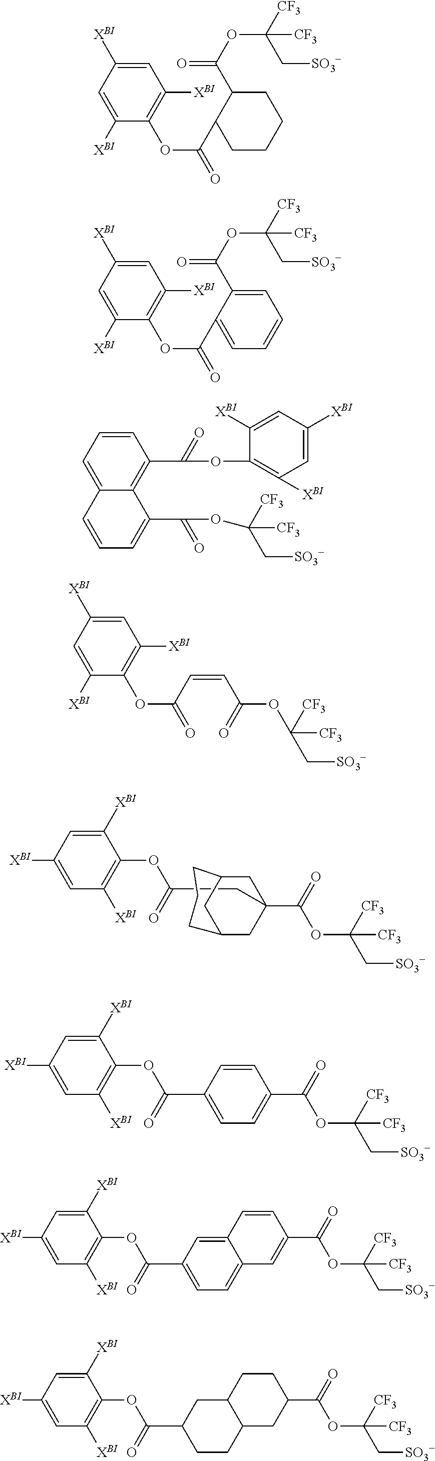

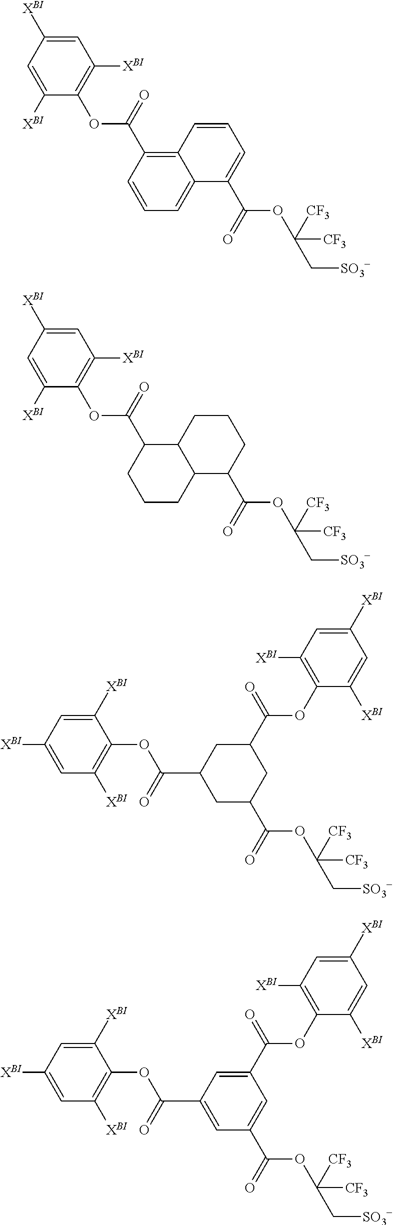

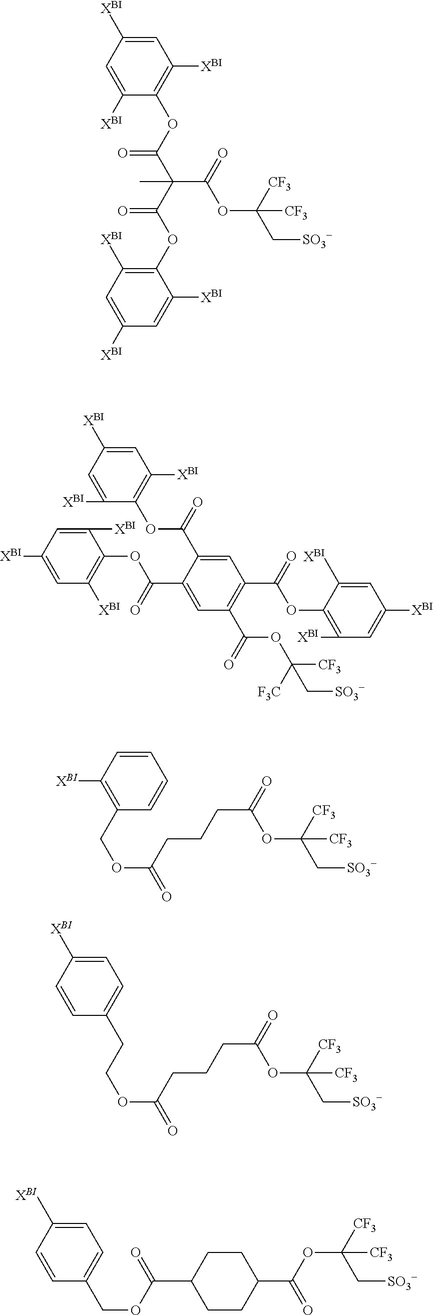

As the PAG, a sulfonium salt or iodonium salt of fluorobenzenesulfonic acid bonded to iodinated benzoic acid having formula (3-3) or (3-4) can also be used.

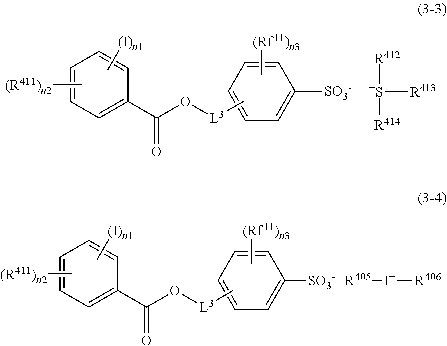

In the formulae (3-3) and (3-4), n1 is an integer of 1 to 5. n2 is an integer of 0 to 3. n3 is an integer of 1 to 4.

In the formulae (3-3) and (3-4), R⁴¹¹ is a hydroxy group, a carboxyl group, an alkoxycarbonyl group, a fluorine atom, a chlorine atom, a bromine atom, an amino group, or a C₁-C₂₀ saturated hydrocarbyl group, a C₁-C₂₀ saturated hydrocarbyloxy group, or a C₂-C₂₀ saturated hydrocarbylcarbonyloxy group, which may contain a fluorine atom, a chlorine atom, a bromine atom, a hydroxy group, an amino group, or an alkoxy group, —N(R^{411A})—C(═O)—R^{411B}, or —N(R^{411A})—C(═O)—O—R^{411B}, and R^{411A} a hydrogen atom or a C₁-C₆ saturated hydrocarbyl group. R^{411B} is a C₁-C₁₆ aliphatic hydrocarbyl group, a C₆-C₁₄ aryl group, or a C₇-C₁₅ aralkyl group, which may contain a halogen atom, a hydroxy group, a C₁-C₆ saturated hydrocarbyloxy group, a C₂-C₆ saturated hydrocarbylcarbonyl group, or a C₂-C₆ saturated hydrocarbylcarbonyloxy group.

In the formulae (3-3) and (3-4), L³ is a single bond or a C₁-C₂₀ divalent linking group, and the linking group may contain an oxygen atom, a sulfur atom, or a nitrogen atom.

In the formulae (3-3) and (3-4), Rf¹¹ is a fluorine atom or a trifluoromethyl group.

In the formulae (3-3) and (3-4), R⁴¹² to R⁴¹⁶ are each independently a halogen atom, or a C₁-C₂₀ hydrocarbyl group which may contain a heteroatom. The hydrocarbyl group may be saturated or unsaturated, and may be straight, branched, or cyclic. Specific examples thereof include those groups mentioned as the hydrocarbyl group represented by R² to R⁶ in the descriptions of formulae (M-1) and (M-2). In these hydrocarbyl groups, some or all of hydrogen atoms may be substituted with a hydroxy group, a carboxy group, a halogen atom, a cyano group, a nitro group, a mercapto group, a sultone group, a sulfo group, or a sulfonium salt-containing group, and some constituent —CH₂— may be substituted with an ether bond, an ester bond, a carbonyl group, an amide bond, a carbonate bond, or a sulfonic ester bond. R⁴⁰² and R⁴⁰³ may bond together to form a ring together with the sulfur atom to which they are bonded. In the case, examples of the ring include the same rings as those mentioned as the ring that R² and R³, taken together, form with the sulfur atom to which they are bonded, in the description of formulae (M-1) and (M-2).

Examples of the cation of the sulfonium salt having formula (3-3) include those mentioned as the sulfonium cation represented by M⁺ in formulae (a1) and (a2). Examples of the cation of the iodonium salt having formula (3-4) include those mentioned as the iodonium cation represented by M⁺ in formulae (a1) and (a2).

Examples of the anion of the onium salt having formula (3-3) or (3-4) include those shown below, but are not limited thereto.

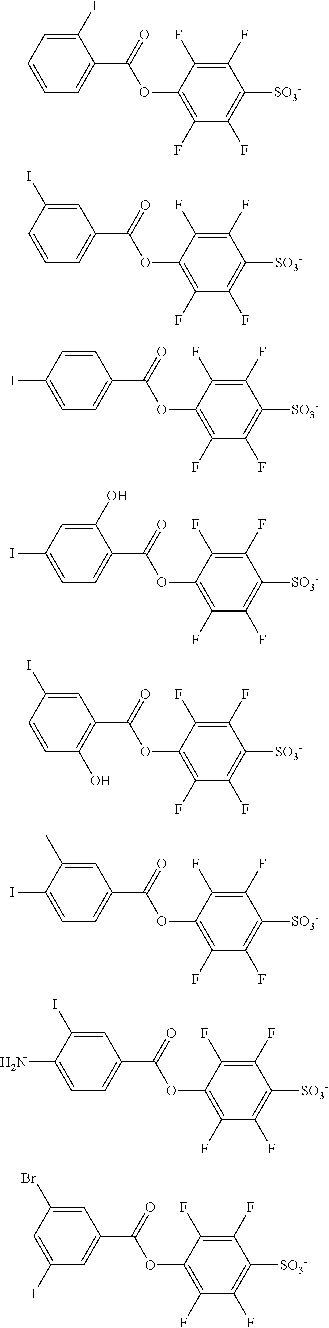

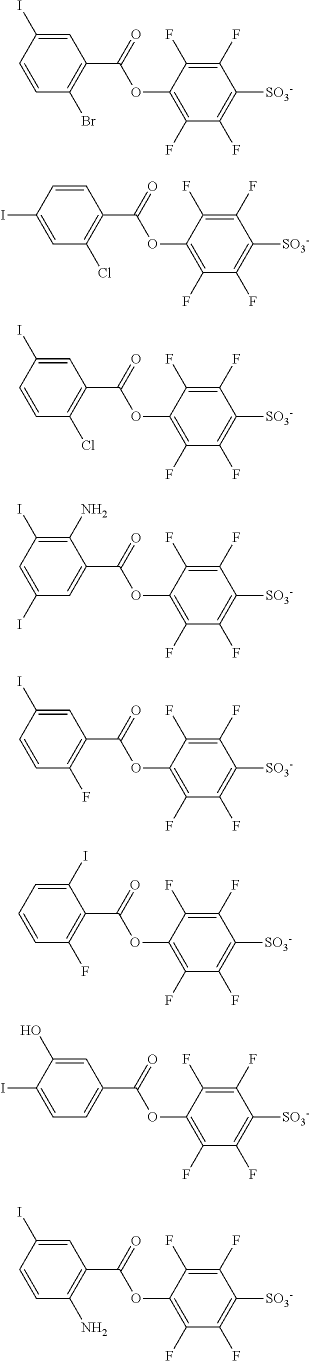

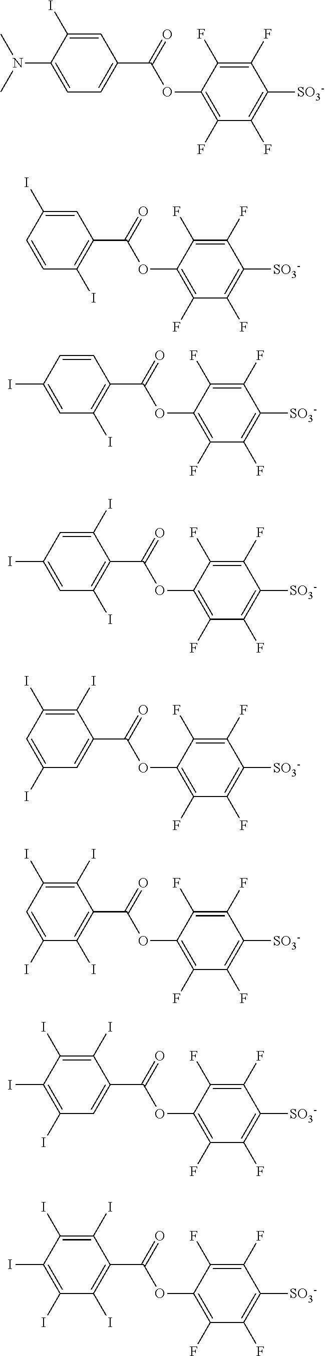

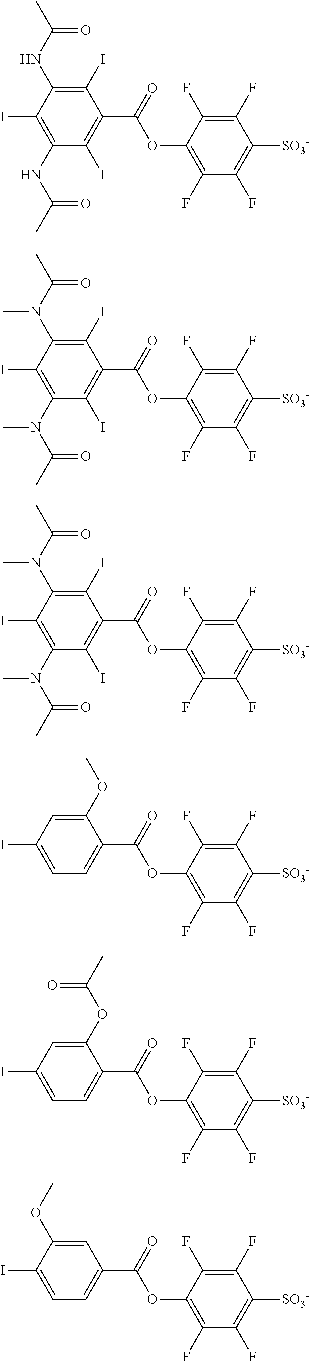

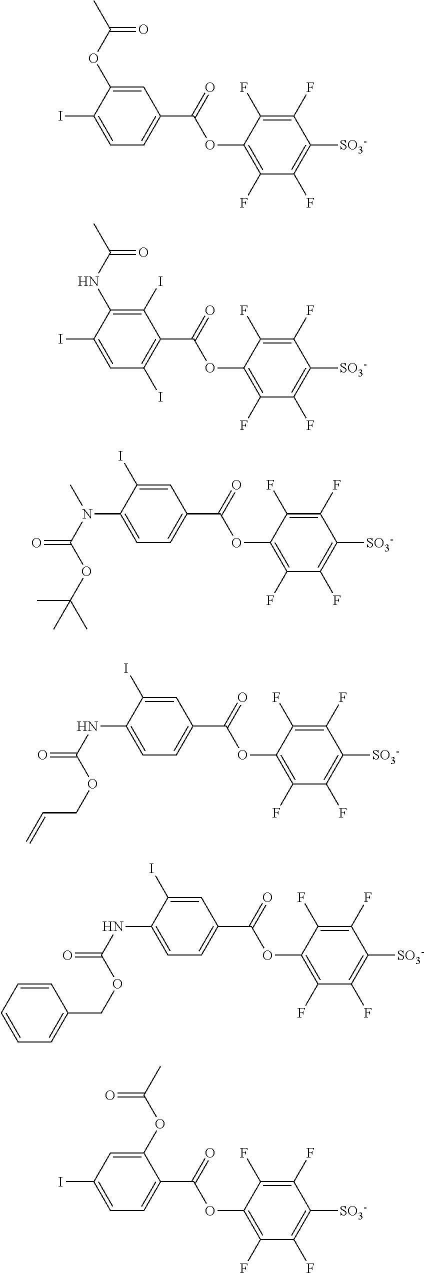

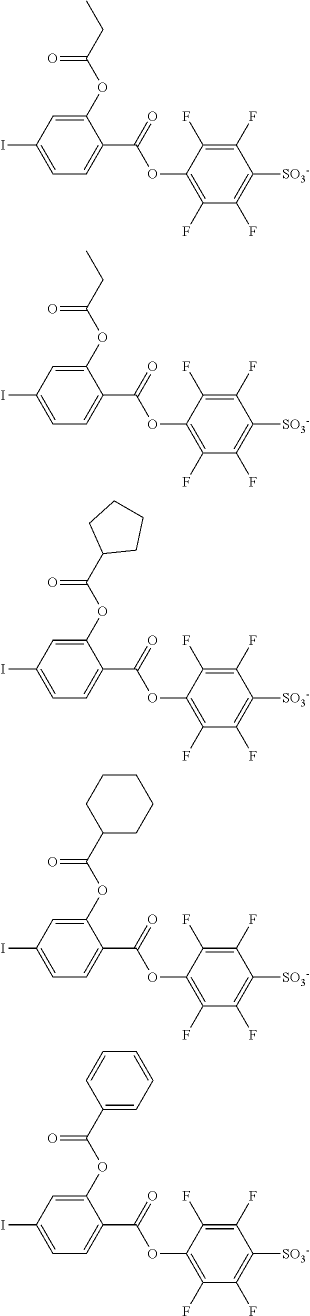

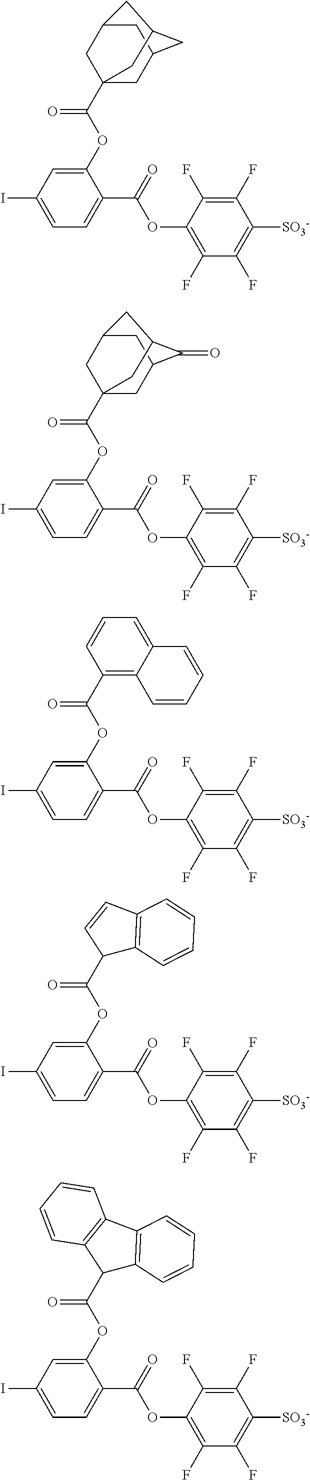

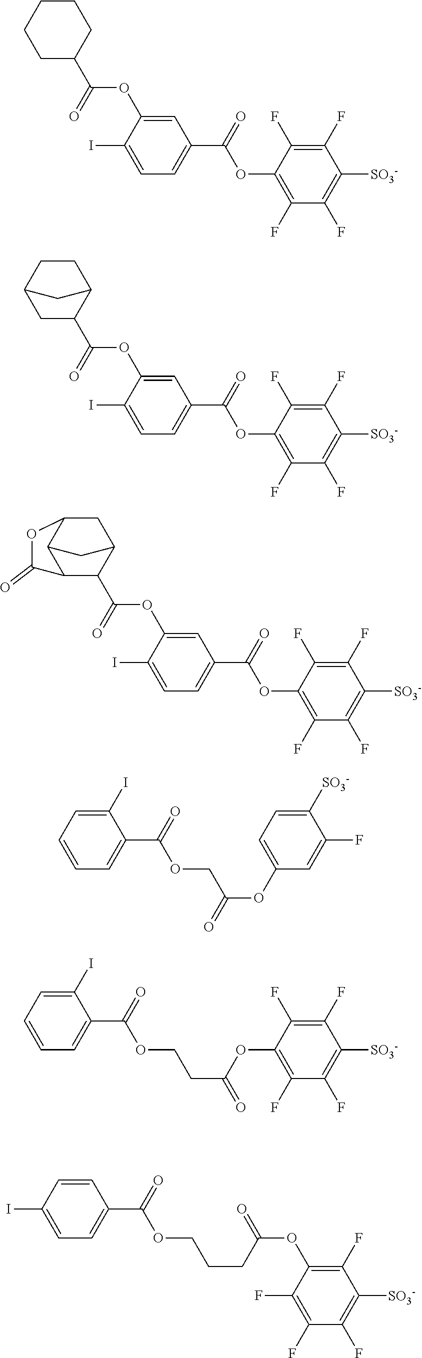

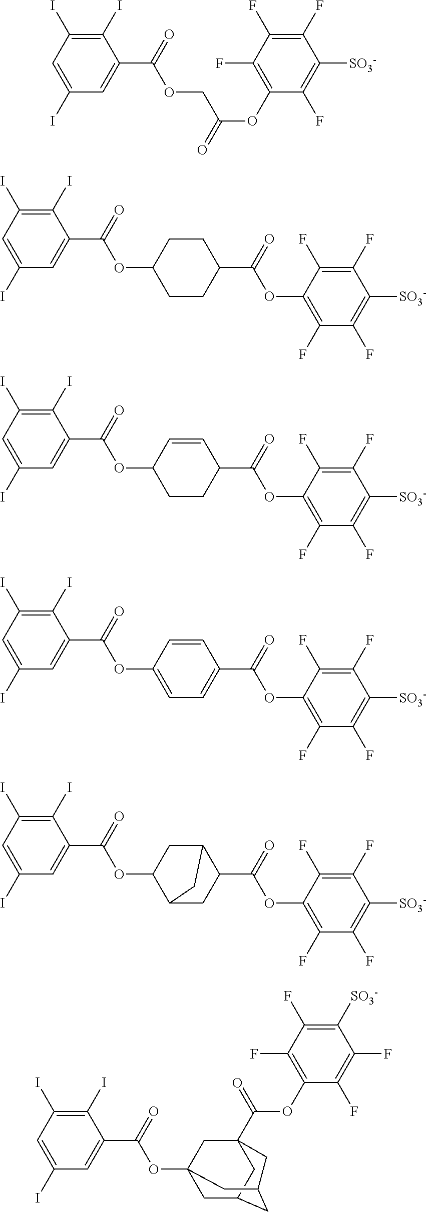

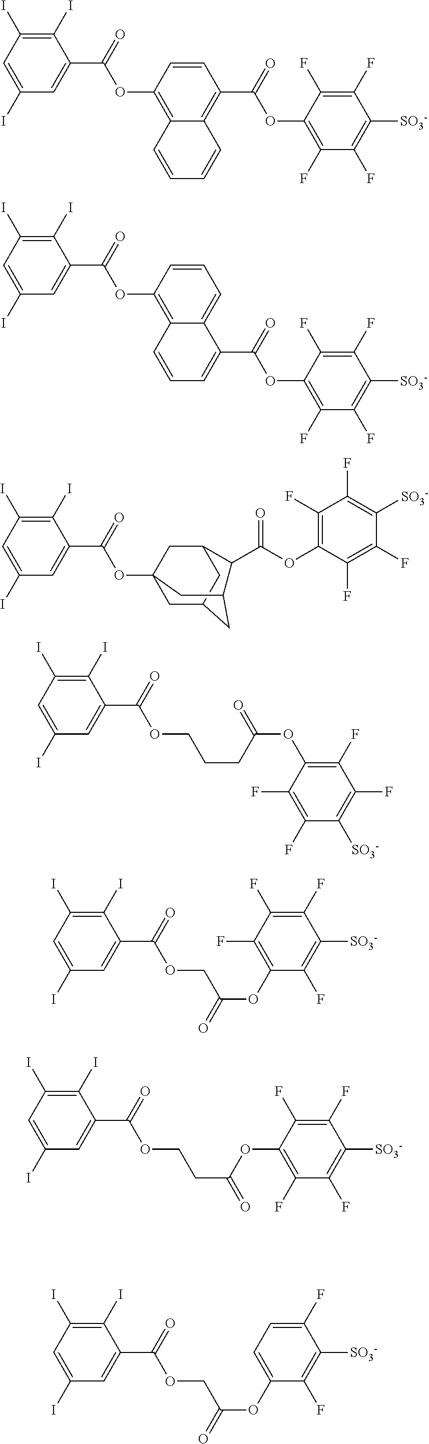

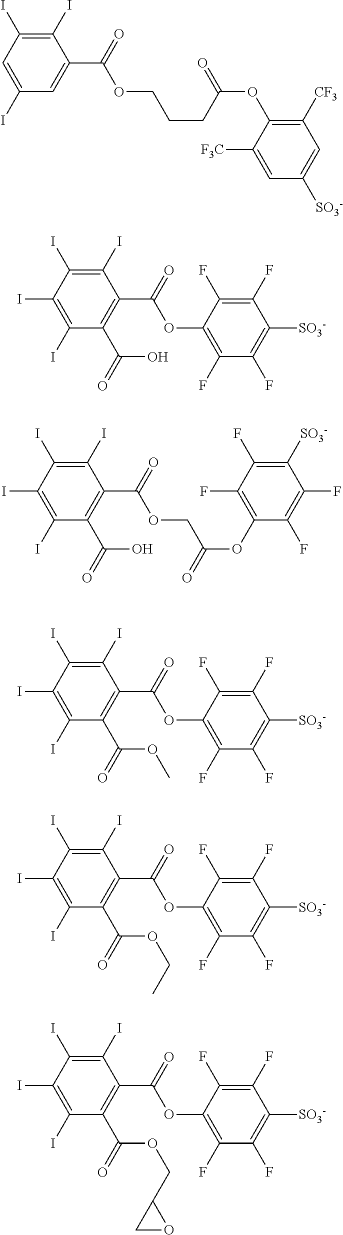

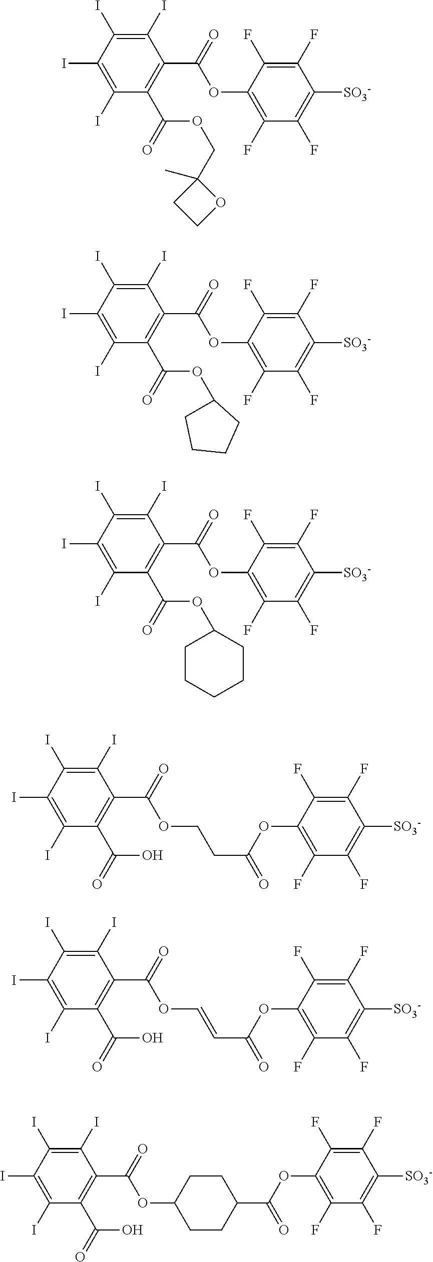

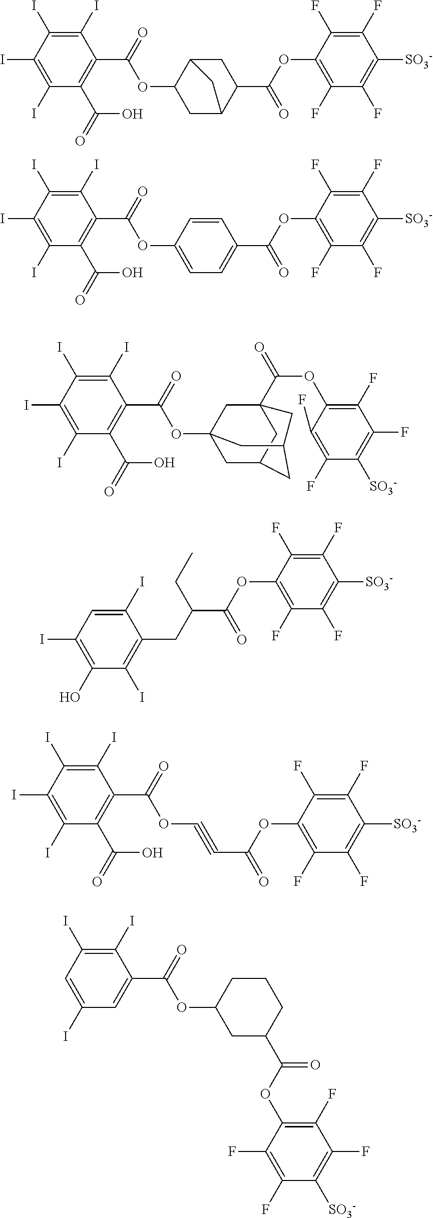

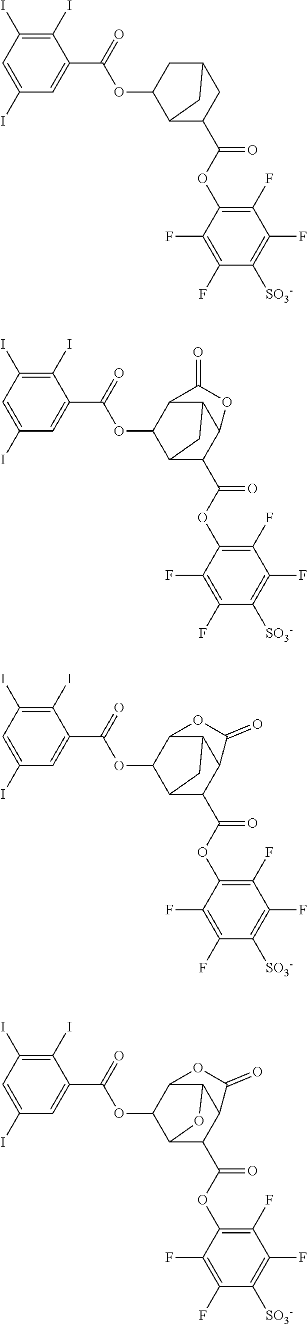

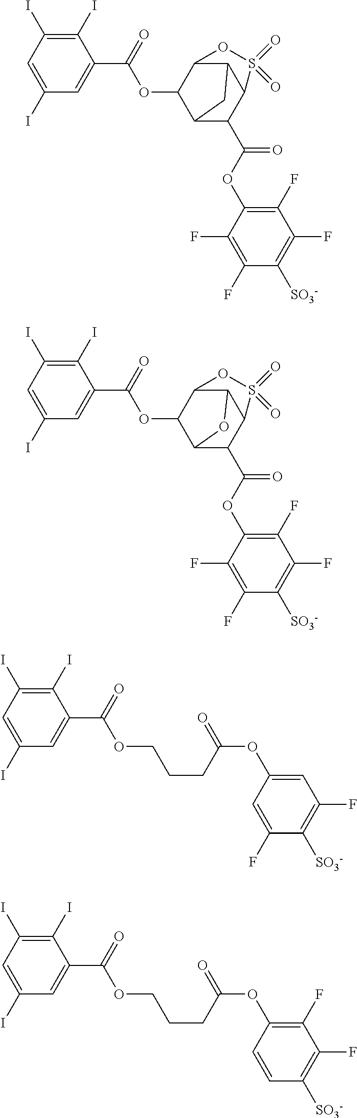

The additive acid generator is preferably added to the resist composition of the present invention in an amount of 0.1 to 50 parts by weight, and more preferably 1 to 40 parts by weight per 100 parts by weight of the base polymer. The additive acid generator may be used singly or in combination of two or more kinds thereof. If the base polymer contains the repeat units (a) and/or contains the additive acid generator, the resist composition of the present invention can function as a chemically amplified resist composition.

### [Quencher]

The resist composition of the present invention may contain a quencher. The quencher refers to a compound capable of trapping the acid generated from the acid generator in the resist composition to prevent the acid from diffusing to the unexposed region.

Examples of the quencher include conventional basic compounds. Examples of the conventional basic compounds include primary, secondary, and tertiary aliphatic amines, mixed amines, aromatic amines, heterocyclic amines, nitrogen-containing compounds having a carboxy group, nitrogen-containing compounds having a sulfonyl group, nitrogen-containing compounds having a hydroxy group, nitrogen-containing compounds having a hydroxyphenyl group, alcoholic nitrogen-containing compounds, amide derivatives, imide derivatives, and carbamate derivatives. In particular, primary, secondary, and tertiary amine compounds described in paragraphs [0146] to [0164] of JP-A 2008-111103, particularly amine compounds having a hydroxy group, an ether bond, an ester bond, a lactone ring, a cyano group, or a sulfonic ester bond, and compounds having a carbamate group described in JP 3790649 are preferred. Addition of a basic compound may be effective for further reducing the diffusion rate of the acid in the resist film or correcting the pattern profile.

Examples of the quencher also include onium salts such as sulfonium salts, iodonium salts, and ammonium salts of sulfonic acids which are not fluorinated at the α-position, carboxylic acids, or fluorinated alkoxides, as described in JP-A 2008-158339. While a sulfonic acid which is fluorinated at the α-position, imide acid, or methide acid is necessary for deprotecting the acid labile group of a carboxylic acid ester, an α-non-fluorinated sulfonic acid, a carboxylic acid, or fluorinated alcohol is released by salt exchange with an α-non-fluorinated onium salt. The α-non-fluorinated sulfonic acid, carboxylic acid, and fluorinated alcohol function as a quencher because they do not induce deprotection reaction.

Examples of such a quencher include a compound having formula (4-1) (an onium salt of an α-non-fluorinated sulfonic acid), a compound having formula (4-2) (an onium salt of a carboxylic acid), and a compound having formula (4-3) (an onium salt of an alkoxide).

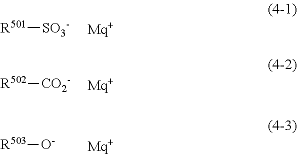

In formula (4-1), R⁵⁰¹ is a hydrogen atom or a C₁-C₄₀ hydrocarbyl group which may contain a heteroatom, exclusive of a hydrocarbyl group in which a hydrogen atom bonded to the carbon atom at the α-position of the sulfo group is substituted with a fluorine atom or a fluoroalkyl group.

The C₁-C₄₀ hydrocarbyl group represented by R⁵⁰¹ may be saturated or unsaturated, and may be straight, branched, or cyclic. Examples thereof include C₁-C₄₀ alkyl groups such as a methyl group, an ethyl group, a n-propyl group, an isopropyl group, a n-butyl group, an isobutyl group, a sec-butyl group, a tert-butyl group, a n-pentyl group, a tert-pentyl group, a n-hexyl group, a n-octyl group, a 2-ethylhexyl group, a n-nonyl group, and a n-decyl group; C₃-C₄₀ cyclic saturated hydrocarbyl groups such as a cyclopentyl group, a cyclohexyl group, a cyclopentylmethyl group, a cyclopentylethyl group, a cyclopentylbutyl group, a cyclohexylmethyl group, a cyclohexylethyl group, a cyclohexylbutyl group, a norbornyl group, a tricyclo[5.2.1.0^{2,6}]decyl group, an adamantyl group, and an adamantylmethyl group; C₂-C₄₀ alkenyl groups such as a vinyl group, an allyl group, a propenyl group, a butenyl group, and a hexenyl group; C₃-C₄₀ cyclic unsaturated aliphatic hydrocarbyl groups such as a cyclohexenyl group; C₆-C₄₀ aryl groups such as a phenyl group, a naphthyl group, alkylphenyl groups (e.g., a 2-methylphenyl group, a 3-methylphenyl group, a 4-methylphenyl group, a 4-ethylphenyl group, a 4-tert-butylphenyl group, and a 4-n-butylphenyl group), dialkylphenyl groups (e.g., a 2,4-dimethylphenyl group and a 2,4,6-triisopropylphenyl group), alkylnaphthyl groups (e.g., a methylnaphthyl group and an ethylnaphthyl group), and dialkylnaphthyl groups (e.g., a dimethylnaphthyl group and a diethylnaphthyl group); and C₇-C₄₀ aralkyl groups such as a benzyl group, a 1-phenylethyl group, and a 2-phenylethyl group.

Some or all of hydrogen atoms of the hydrocarbyl group may be substituted with a group containing a heteroatom such as an oxygen atom, a sulfur atom, a nitrogen atom, or a halogen atom, and some of —CH₂— of the hydrocarbyl group may be substituted with a group containing a heteroatom such as an oxygen atom, a sulfur atom, or a nitrogen atom, so that the group may contain a hydroxy group, a cyano group, a carbonyl group, an ether bond, an ester bond, a sulfonic ester bond, a carbonate bond, a lactone ring, a sultone ring, a carboxylic anhydride (—C(═O)—O—C(═O)—), or a haloalkyl group. Examples of the heteroatom-containing hydrocarbyl group include heteroaryl groups such as a thienyl group; alkoxyphenyl groups such as a 4-hydroxyphenyl group, a 4-methoxyphenyl group, a 3-methoxyphenyl group, a 2-methoxyphenyl group, a 4-ethoxyphenyl group, a 4-tert-butoxyphenyl group, and a 3-tert-butoxyphenyl group; alkoxynaphthyl groups such as a methoxynaphthyl group, an ethoxynaphthyl group, a n-propoxynaphthyl group, and a n-butoxynaphthyl group; dialkoxynaphthyl groups such as a dimethoxynaphthyl group and a diethoxynaphthyl group; and aryloxoalkyl groups, typically 2-aryl-2-oxoethyl groups such as a 2-phenyl-2-oxoethyl group, a 2-(1-naphthyl)-2-oxoethyl group, and a 2-(2-naphthyl)-2-oxoethyl group.

In formula (4-2), R⁵⁰² is a C₁-C₄₀ hydrocarbyl group which may contain a heteroatom. Examples of the hydrocarbyl group represented by R⁵⁰² include those groups mentioned as the hydrocarbyl group represented by R⁵⁰¹. Also included are fluorinated alkyl groups such as a trifluoromethyl group, a trifluoroethyl group, a 2,2,2-trifluoro-1-methyl-1-hydroxyethyl group, and a 2,2,2-trifluoro-1-(trifluoromethyl)-1-hydroxyethyl group; and fluorinated aryl groups such as a pentafluorophenyl group and a 4-trifluoromethylphenyl group.

In formula (4-3), R⁵⁰³ is a C₁-C₈ saturated hydrocarbyl group containing at least 3 fluorine atoms or a C₆-C₁₀ aryl group containing at least 3 fluorine atoms, and may contain a nitro group.

In formulae (4-1), (4-2), and (4-3), Mq⁺ is an onium cation. The onium cation is preferably a sulfonium cation, an iodonium cation, or an ammonium cation, and more preferably a sulfonium cation. Examples of the sulfonium cation include sulfonium cations described in JP-A 2017-219836.

A sulfonium salt of iodized benzene ring-containing carboxylic acid having formula (4-4) is also suitable for the quencher.

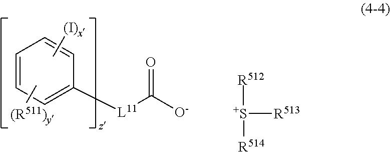

In formula (4-4), R⁵¹¹ is a hydroxy group, a fluorine atom, a chlorine atom, a bromine atom, an amino group, a nitro group, a cyano group, or a C₁-C₆ saturated hydrocarbyl group, a C₁-C₆ saturated hydrocarbyloxy group, a C₂-C₆ saturated hydrocarbylcarbonyloxy group, or a C₁-C₄ saturated hydrocarbylsulfonyloxy group, in which some or all of hydrogen atoms may be substituted with a halogen atom, —N(R^{511A})—C(═O)_R^{511B}, or —N(R^{511A})—C(═O)—O—R^{511B}. R^{511A} is a hydrogen atom or a C₁-C₆ saturated hydrocarbyl group. R^{511B} is a 6 saturated hydrocarbyl group or a C₂-C₈ unsaturated aliphatic hydrocarbyl group.

In formula (4-4), x′ is an integer of 1 to 5. y′ is an integer of 0 to 3. z′ is an integer of 1 to 3. L¹¹ is a single bond, or a C₁-C₂₀ (z′+1)-valent linking group which may contain at least one moiety selected from an ether bond, a carbonyl group, an ester bond, an amide bond, a sultone ring, a lactam ring, a carbonate bond, a halogen atom, a hydroxy group, and a carboxy group. The saturated hydrocarbyl group, the saturated hydrocarbyloxy group, the saturated hydrocarbylcarbonyloxy group, and the saturated hydrocarbylsulfonyloxy group may be straight, branched, or cyclic. Groups R⁵¹¹ may be identical or different if y′ and/or z′ is 2 or more.

In formula (4-4), R⁵¹², R⁵¹³, and R⁵¹⁴ are each independently a halogen atom, or a C₁-C₂₀ hydrocarbyl group which may contain a heteroatom. The hydrocarbyl group may be saturated or unsaturated, and may be straight, branched, or cyclic. Specific examples thereof include those groups mentioned as the hydrocarbyl group represented by R² to R⁶ in the descriptions of formulae (M-1) and (M-2).

Examples of the compound having formula (4-4) include compounds described in JP-A 2017-219836 and JP-A 2021-91666.

Another example of the quencher is a polymeric quencher described in JP-A 2008-239918. The polymeric quencher segregates at the resist film surface and thus enhances the rectangularity of the resist pattern. When a protective film is applied as is often the case in immersion lithography, the polymeric quencher is also effective for preventing a film thickness loss of the resist pattern or rounding of the pattern top.

Other useful quenchers include sulfonium salts of betaine structure as described in JP 6848776 and JP-A 2020-037544, fluorine-free methide acids as described in JP-A 2020-055797, sulfonium salts of sulfonamide as described in JP 5807552, and sulfonium salts of iodized sulfonamide as described in JP-A 2019-211751.

The quencher is preferably added to the resist composition of the present invention in an amount of 0 to 5 parts by weight, and more preferably 0 to 4 parts by weight per 100 parts by weight of the base polymer. The quencher may be used singly or in combination of two or more kinds thereof.

### Other Components

In addition to the foregoing components, the resist composition of the present invention may contain other components such as a surfactant, a dissolution inhibitor, a water repellency improver, and an acetylene alcohol.

Examples of the surfactant include those described in paragraphs [0165] to [0166] of JP-A 2008-111103. Addition of a surfactant may improve or control the coating characteristics of the resist composition. The surfactant is preferably added to the resist composition of the present invention in an amount of 0.0001 to 10 parts by weight per 100 parts by weight of the base polymer. The surfactant may be used singly or in combination of two or more kinds thereof.

In the embodiment wherein the resist composition of the present invention is of positive tone, the addition of a dissolution inhibitor may lead to an increased difference in dissolution rate between the exposed region and the unexposed region and a further improvement in resolution. Examples of the dissolution inhibitor include a compound having at least two phenolic hydroxy groups in the molecule, in which 0 to 100 mol % of all the hydrogen atoms in the phenolic hydroxy groups are substituted with acid labile groups or a compound having at least one carboxy group in the molecule, in which an average of 50 to 100 mol % of all the hydrogen atoms in the carboxy group are substituted with acid labile groups, both the compounds preferably having a molecular weight of 100 to 1,000, and more preferably 150 to 800. Examples thereof include bisphenol A, trisphenol, phenolphthalein, cresol novolac, naphthalenecarboxylic acid, adamantanecarboxylic acid, and cholic acid derivatives, in which the hydrogen atom in the hydroxy or carboxy group is substituted with an acid labile group, as described in paragraphs [0155] to [0178] of JP-A 2008-122932.

The dissolution inhibitor is preferably added to the resist composition of positive tone of the present invention in an amount of 0 to 50 parts by weight, and more preferably 5 to 40 parts by weight per 100 parts by weight of the base polymer. The dissolution inhibitor may be used singly or in combination of two or more kinds thereof.

The water repellency improver improves the water repellency of the surface of the resist film, and can be used in the topcoatless immersion lithography. Examples of preferred water repellency improvers include polymers having a fluoroalkyl group and polymers having a specific structure with a 1,1,1,3,3,3-hexafluoro-2-propanol residue, and those described in JP-A 2007-297590 and JP-A 2008-111103, for example, are more preferred. The water repellency improver should be soluble in alkaline developers and organic solvent developers. The water repellency improver having a specific structure with a 1,1,1,3,3,3-hexafluoro-2-propanol residue is well soluble in the developer. A polymer having an amino group or amine salt copolymerized as repeat units may serve as the water repellency improver and is effective for preventing evaporation of the acid during PEB, thus preventing any hole pattern opening failure after development. The water repellency improver is preferably added to the resist composition of the present invention in an amount of 0 to 20 parts by weight, and more preferably 0.5 to 10 parts by weight per 100 parts by weight of the base polymer. The water repellency improver may be used singly or in combination of two or more kinds thereof.

Examples of the acetylene alcohol include those described in paragraphs [0179] to of JP-A 2008-122932. The acetylene alcohol is preferably added to the resist composition of the present invention in an amount of 0 to 5 parts by weight per 100 parts by weight of the base polymer. The acetylene alcohol may be used singly or in combination of two or more kinds thereof.

The resist composition of the present invention may be prepared by sufficiently mixing the components to form a solution, adjusting the solution so as to meet a predetermined range of sensitivity and film thickness, and filtering the solution. The filtering step is important for reducing the number of defects in a resist pattern after development. The membrane for filtration or filter preferably has a pore size of up to 1 μm, more preferably up to 10 nm, and even more preferably up to 5 nm. As the filter pore size is smaller, the number of defects in a small size pattern is reduced. Examples of the materials of the membrane include tetrafluoroethylene, polyethylene, polypropylene, nylon, polyurethane, polycarbonate, polyimide, polyamide-imide, and polysulfone. Membranes of tetrafluoroethylene, polyethylene, and polypropylene which have been surface-modified so as to increase an adsorption ability are also useful. Unlike the membranes of nylon, polyurethane, polycarbonate, and polyimide having an ability to adsorb gel and metal ions due to their polarity, membranes of tetrafluoroethylene, polyethylene, and polypropylene which are non-polar do not have the gel/metal ion adsorption ability in themselves, but can be endowed with the adsorption ability by surface modification with a functional group having polarity. In particular, filters obtained by surface modification of membranes of polyethylene and polypropylene, in which pores of a smaller size can be formed, are effective for removing not only submicron particles, but also polar particles and metal ions. A laminate of membranes of different materials or a laminate of membranes having different pore sizes may also be used.

A membrane having an ion exchange ability are also useful. For example, an ion-exchange membrane capable of adsorbing cations acts to adsorb metal ions to thereby reduce metal impurities.

In the practice of filtration, a plurality of filters may be connected. The type and pore size of membranes in the plurality of filters may be the same or different. The filter may be disposed in a conduit between vessels. Alternatively, the filter may be disposed in a conduit between inlet and outlet ports of a single vessel so that the solution is filtered while it is circulated. The filters may be connected through serial or parallel pipes.

### [Pattern Forming Process]

The resist composition of the present invention is used in the fabrication of various integrated circuits by a well-known lithography technique. Examples of the pattern forming process include a process comprising the steps of: applying the resist composition onto a substrate to form a resist film thereon, exposing the resist film to high-energy radiation, and developing the exposed resist film in a developer.

The resist composition of the present invention is first applied onto a substrate on which an integrated circuit is to be formed (e.g., Si, SiO₂, SiN, SiON, TiN, WSi, BPSG, SOG, or organic antireflective coating) or a substrate on which a mask circuit is to be formed (e.g., Cr, CrO, CrON, CrN, MoSi₂, SiO₂, a MoSi₂ multilayer film, Ta, TaN, TaCN, Ru, Nb, Mo, Mn, Co, Ni, or an alloy thereof) by a suitable coating technique such as spin coating, roll coating, flow coating, dipping, spraying, or doctor coating so that the coating may have a thickness of 0.01 to 2 μm. The coating is prebaked on a hotplate preferably at a temperature of 60 to 150° C. for 10 seconds to 30 minutes, and more preferably at 80 to 120° C. for 30 seconds to 20 minutes to form a resist film.

The resist film is then exposed to high-energy radiation. Examples of the high-energy radiation include UV, deep-UV, EB, EUV having a wavelength of 3 to 15 nm, X-rays, soft X-rays, excimer laser, 7-rays, and synchrotron radiation. When UV, deep-UV, EUV, X-rays, soft X-rays, excimer laser, 7-rays, or synchrotron radiation is used as the high-energy radiation, the resist film is exposed thereto directly or through a mask having a desired pattern preferably at a dose of about 1 to 200 mJ/cm², and more preferably about 10 to 100 mJ/cm². When EB is used as the high-energy radiation, the resist film is exposed thereto directly or through a mask having a desired pattern preferably at a dose of about 0.1 to 300 μC/cm², and more preferably about 0.5 to 200 μC/cm². It is appreciated that the resist composition of the present invention is suitable for micropatterning using high-energy radiation such as KrF excimer laser, ArF excimer laser, EB, EUV, X-rays, soft X-rays, 7-rays, or synchrotron radiation, especially for micropatterning using EB or EUV.

After the exposure, the resist film may be baked (PEB) on a hotplate or in an oven preferably at 30 to 150° C. for 10 seconds to 30 minutes, and more preferably at 50 to 120° C. for 30 seconds to 20 minutes.

After the exposure or PEB, the resist film is developed in a developer in the form of an alkaline aqueous solution for 3 seconds to 3 minutes, preferably 5 seconds to 2 minutes by conventional techniques such as dip, puddle, and spray techniques to form a desired pattern. A preferred developer is a 0.1 to 10 wt %, preferably 2 to 5 wt % aqueous solution of tetramethylammonium hydroxide (TMAH), tetraethylammonium hydroxide (TEAH), tetrapropylammonium hydroxide (TPAH), or tetrabutylammonium hydroxide (TBAH). In the case of a positive resist composition, the resist film in the exposed region is dissolved in the developer whereas the resist film in the unexposed region is not dissolved. In this way, the desired positive pattern is formed on the substrate. In the case of a negative resist composition, inversely the resist film in the exposed region is insolubilized in the developer whereas the resist film in the unexposed region is dissolved.

A negative pattern can be obtained from the positive resist composition comprising a base polymer containing an acid labile group by effecting organic solvent development. Examples of the developer used herein include 2-octanone, 2-nonanone, 2-heptanone, 3-heptanone, 4-heptanone, 2-hexanone, 3-hexanone, diisobutyl ketone, methylcyclohexanone, acetophenone, methylacetophenone, propyl acetate, butyl acetate, isobutyl acetate, pentyl acetate, butenyl acetate, isopentyl acetate, propyl formate, butyl formate, isobutyl formate, pentyl formate, isopentyl formate, methyl valerate, methyl pentenoate, methyl crotonate, ethyl crotonate, methyl propionate, ethyl propionate, ethyl 3-ethoxypropionate, methyl lactate, ethyl lactate, propyl lactate, butyl lactate, isobutyl lactate, pentyl lactate, isopentyl lactate, methyl 2-hydroxyisobutyrate, ethyl 2-hydroxyisobutyrate, methyl benzoate, ethyl benzoate, phenyl acetate, benzyl acetate, methyl phenylacetate, benzyl formate, phenylethyl formate, methyl 3-phenylpropionate, benzyl propionate, ethyl phenylacetate, and 2-phenylethyl acetate. The organic solvent may be used singly or as a mixture of two or more kinds thereof.

At the end of development, the resist film is rinsed. The rinsing liquid is preferably a solvent which is miscible with the developer and does not dissolve the resist film. Examples of preferred solvents include alcohols having 3 to 10 carbon atoms, ether compounds having 8 to 12 carbon atoms, alkanes, alkenes, and alkynes each having 6 to 12 carbon atoms, and aromatic solvents.

Examples of the alcohols having 3 to 10 carbon atoms include n-propyl alcohol, isopropyl alcohol, 1-butyl alcohol, 2-butyl alcohol, isobutyl alcohol, tert-butyl alcohol, 1-pentanol, 2-pentanol, 3-pentanol, tert-pentyl alcohol, neopentyl alcohol, 2-methyl-1-butanol, 3-methyl-1-butanol, 3-methyl-3-pentanol, cyclopentanol, 1-hexanol, 2-hexanol, 3-hexanol, 2,3-dimethyl-2-butanol, 3,3-dimethyl-1-butanol, 3,3-dimethyl-2-butanol, 2-ethyl-1-butanol, 2-methyl-1-pentanol, 2-methyl-2-pentanol, 2-methyl-3-pentanol, 3-methyl-1-pentanol, 3-methyl-2-pentanol, 3-methyl-3-pentanol, 4-methyl-1-pentanol, 4-methyl-2-pentanol, 4-methyl-3-pentanol, cyclohexanol, and 1-octanol.

Examples of the ether compounds having 8 to 12 carbon atoms include di-n-butyl ether, diisobutyl ether, di-sec-butyl ether, di-n-pentyl ether, diisopentyl ether, di-sec-pentyl ether, di-tert-pentyl ether, and di-n-hexyl ether.

Examples of the alkanes having 6 to 12 carbon atoms include hexane, heptane, octane, nonane, decane, undecane, dodecane, methylcyclopentane, dimethylcyclopentane, cyclohexane, methylcyclohexane, dimethylcyclohexane, cycloheptane, cyclooctane, and cyclononane. Examples of the alkenes having 6 to 12 carbon atoms include hexene, heptene, octene, cyclohexene, methylcyclohexene, dimethylcyclohexene, cycloheptene, and cyclooctene. Examples of the alkynes having 6 to 12 carbon atoms include hexyne, heptyne, and octyne.

Examples of the aromatic solvents include toluene, xylene, ethylbenzene, isopropylbenzene, tert-butylbenzene, and mesitylene.

Rinsing is effective for reducing the resist pattern collapse and defect formation. However, rinsing is not essential. If rinsing is omitted, the amount of solvent used may be reduced.

A hole or trench pattern after development may be shrunk by the thermal flow, RELACS®, or DSA process. A hole pattern is shrunk by applying a shrink agent thereto, and baking the resist composition such that the shrink agent may undergo crosslinking at the resist film surface due to diffusion of the acid catalyst from the resist film during baking, and the shrink agent may attach to the sidewall of the hole pattern. The baking temperature is preferably 70 to 180° C., more preferably 80 to 170° C., and the baking time is preferably 10 to 300 seconds to remove the excess shrink agent and shrink the hole pattern.

### EXAMPLES

Hereinafter, the present invention is specifically described with reference to Synthesis Examples, Examples, and Comparative Examples, but the present invention is not limited to the following Examples.

Monomers PM-1 to PM-18, cPM-1, cPM-2, AM-1 to AM-7, and FM-1 used in the synthesis of base polymers are shown below. Monomers PM-1 to PM-14 were synthesized by ion exchange between an ammonium salt of a fluorinated benzenesulfonic acid that provides the anion shown below and sulfonium chloride that provides the cation shown below. The Mw of a polymer is determined by GPC versus polystyrene standards using a THF solvent.

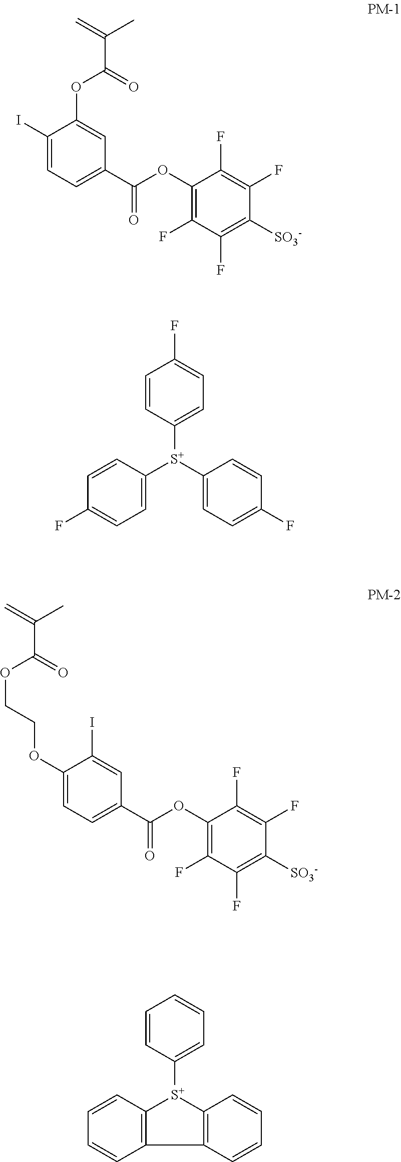

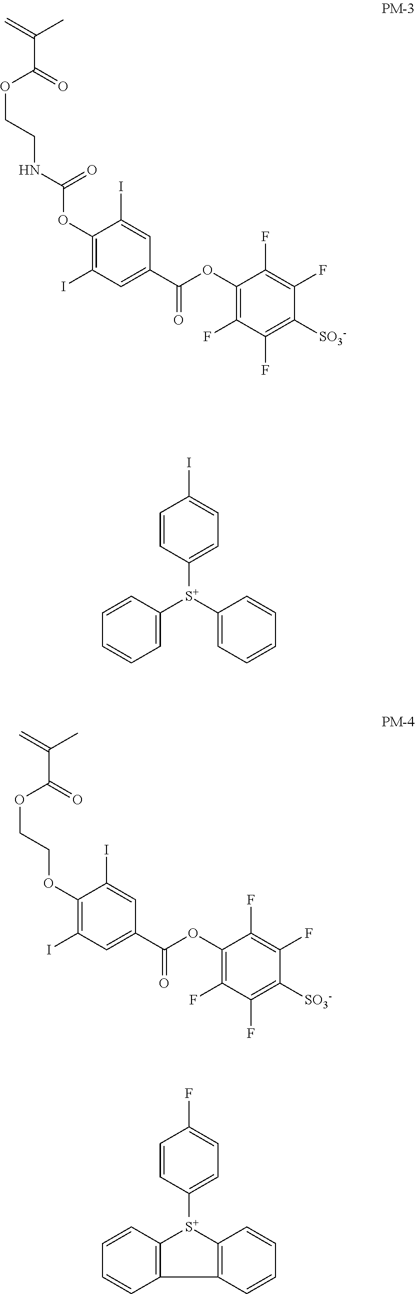

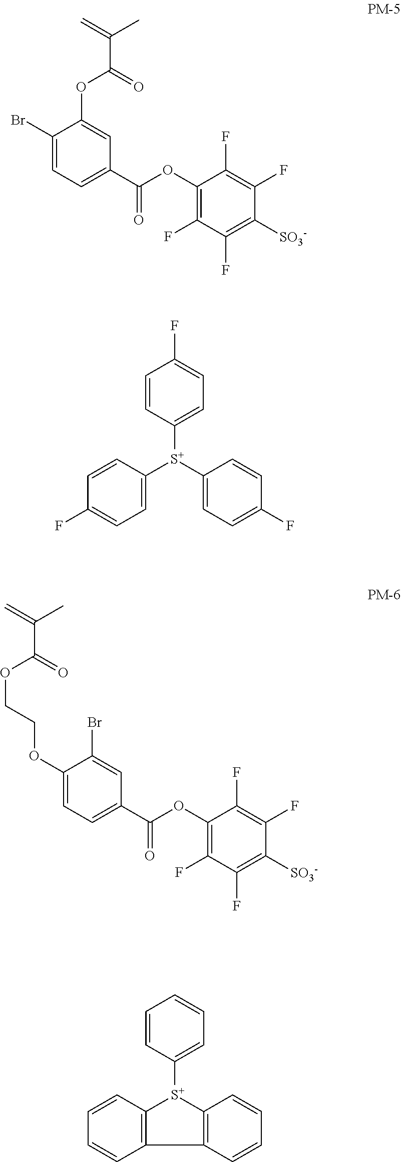

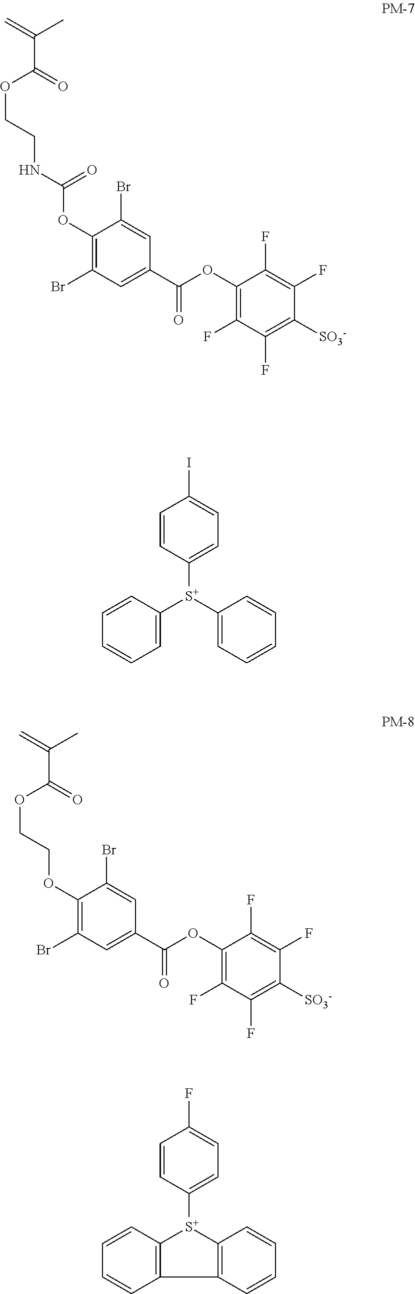

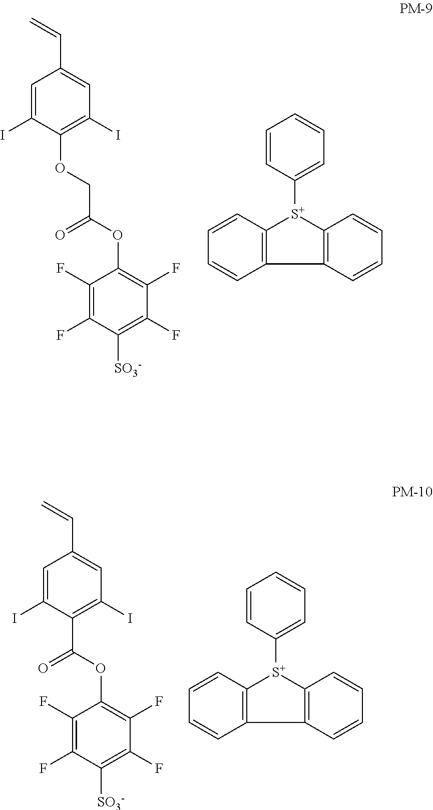

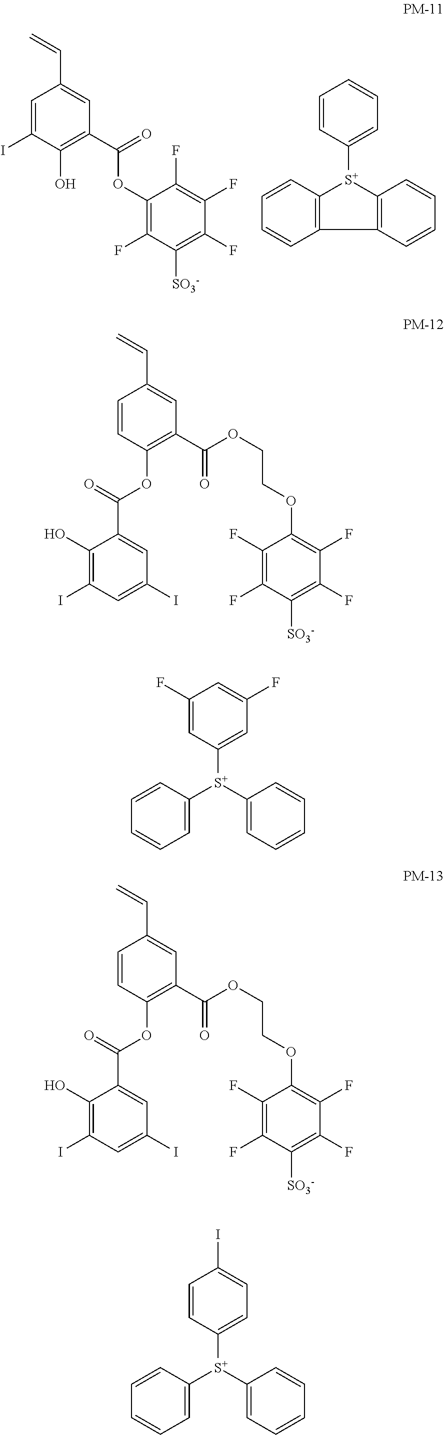

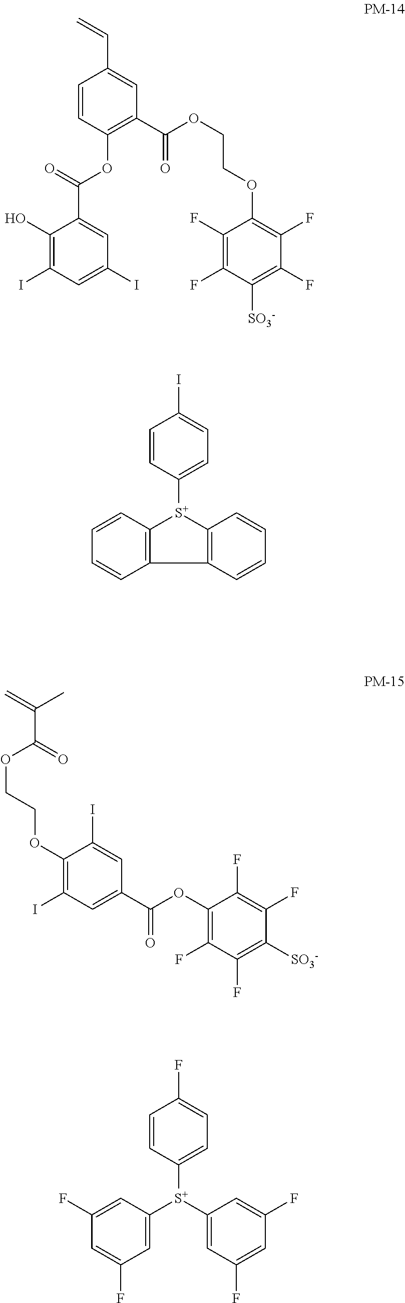

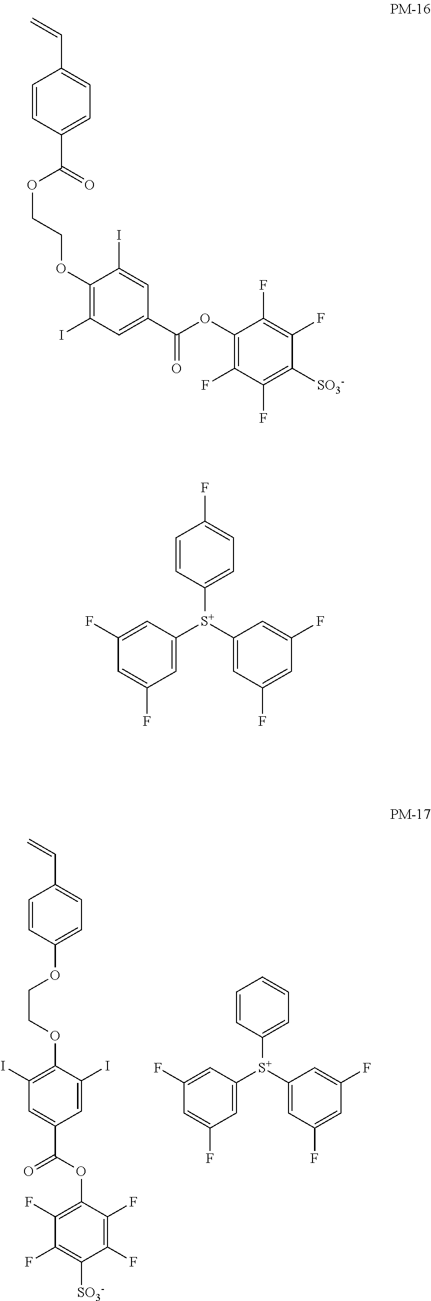

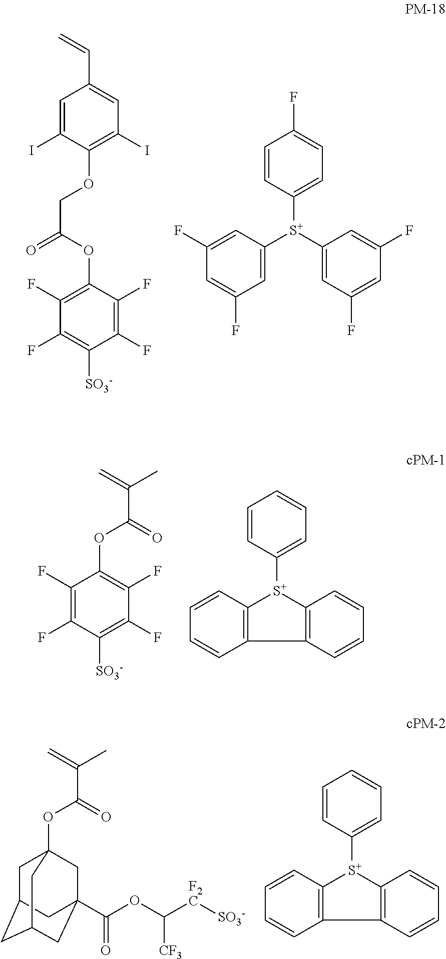

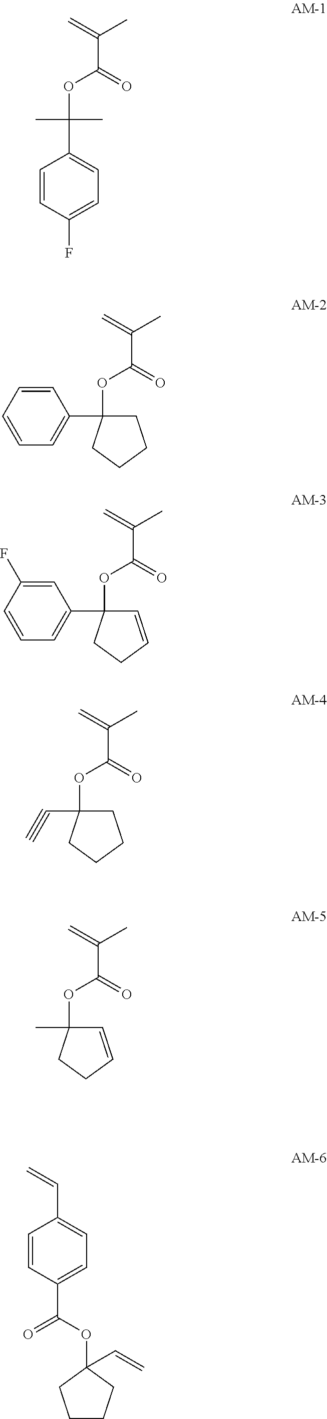

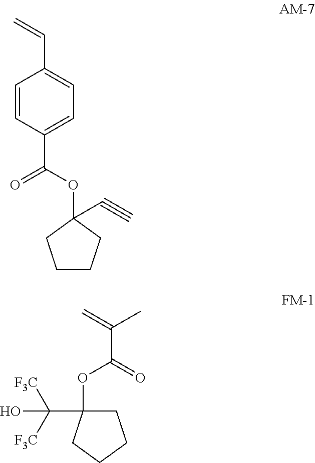

### [Synthesis Example 1] Synthesis of Polymer P-1

A 2-L flask was charged with 8.4 g of 1-methyl-1-cyclopentyl methacrylate, 4.8 g of 4-hydroxystyrene, 8.8 g of PM-1, and 40 g of a THF solvent. The reactor was cooled to −70° C. in a nitrogen atmosphere, after which vacuum pumping and nitrogen blowing were repeated three times. The reactor was warmed up to room temperature, and 1.2 g of AIBN as a polymerization initiator was added. The reactor was heated to 60° C. and the reaction was run for 15 hours. The reaction solution was poured into 1 L of IPA, and the precipitated white solid was collected by filtration. The resulting white solid was vacuum dried at 60° C., yielding Polymer P-1. Polymer P-1 was analyzed for composition by ¹³C-NMR and ¹H-NMR and for Mw and Mw/Mn by GPC.

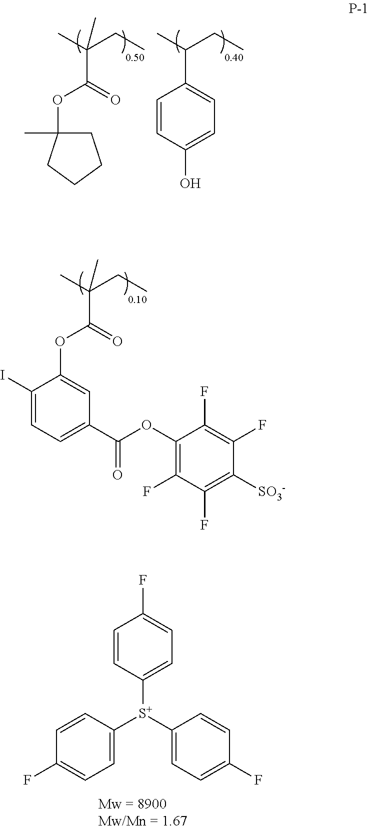

### [Synthesis Example 2] Synthesis of Polymer P-2

A 2-L flask was charged with 9.0 g of 1-vinyl-1-cyclopentyl methacrylate, 4.8 g of 3-hydroxystyrene, 8.6 g of PM-2, and 40 g of a THF solvent. The reactor was cooled to −70° C. in a nitrogen atmosphere, after which vacuum pumping and nitrogen blowing were repeated three times. The reactor was warmed up to room temperature, and 1.2 g of AIBN as a polymerization initiator was added. The reactor was heated to 60° C. and the reaction was run for 15 hours. The reaction solution was poured into 1 L of IPA, and the precipitated white solid was collected by filtration. The resulting white solid was vacuum dried at 60° C., yielding Polymer P-2. Polymer P-2 was analyzed for composition by ¹³C-NMR and ¹H-NMR and for Mw and Mw/Mn by GPC.

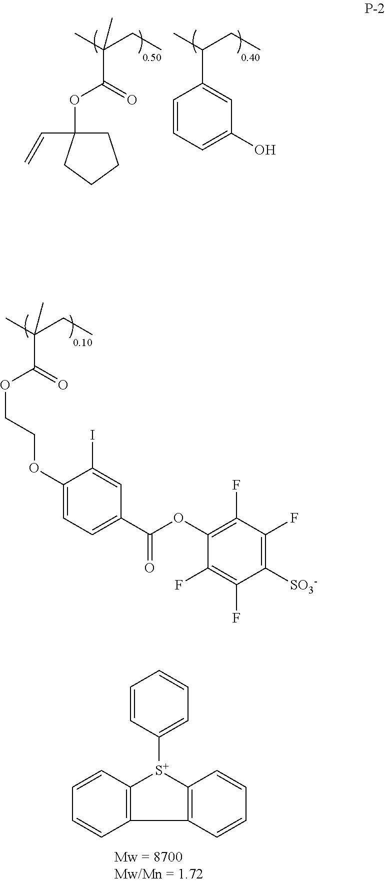

### [Synthesis Example 3] Synthesis of Polymer P-3

A 2-L flask was charged with 11.1 g of AM-1, 4.8 g of 3-hydroxystyrene, 11.6 g of PM-3, and 40 g of a THF solvent. The reactor was cooled to −70° C. in a nitrogen atmosphere, after which vacuum pumping and nitrogen blowing were repeated three times. The reactor was warmed up to room temperature, and 1.2 g of AIBN as a polymerization initiator was added. The reactor was heated to 60° C. and the reaction was run for 15 hours. The reaction solution was poured into 1 L of IPA, and the precipitated white solid was collected by filtration. The resulting white solid was vacuum dried at 60° C., yielding Polymer P-3. Polymer P-3 was analyzed for composition by ¹³C-NMR and ¹H-NMR and for Mw and Mw/Mn by GPC.

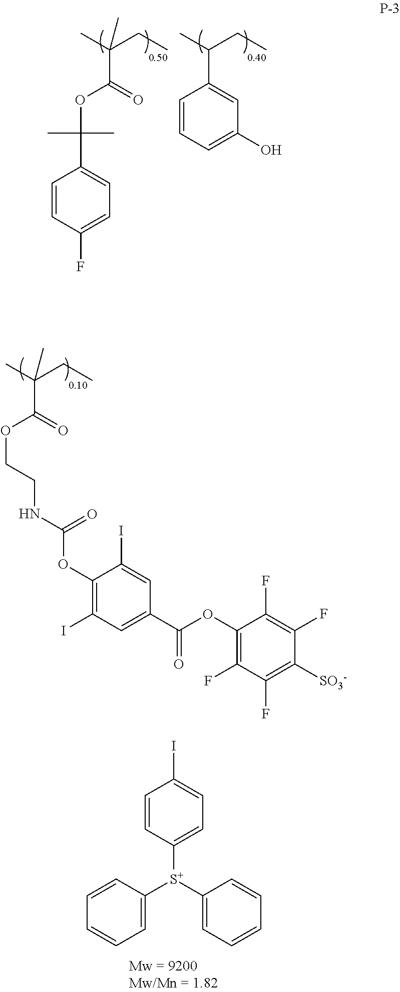

### [Synthesis Example 4] Synthesis of Polymer P-4

A 2-L flask was charged with 8.1 g of AM-2, 2.7 g of AM-4, 4.8 g of 3-hydroxystyrene, 10.1 g of PM-4, and 40 g of a THF solvent. The reactor was cooled to −70° C. in a nitrogen atmosphere, after which vacuum pumping and nitrogen blowing were repeated three times. The reactor was warmed up to room temperature, and 1.2 g of AIBN as a polymerization initiator was added. The reactor was heated to 60° C. and the reaction was run for 15 hours. The reaction solution was poured into 1 L of IPA, and the precipitated white solid was collected by filtration. The resulting white solid was vacuum dried at 60° C., yielding Polymer P-4. Polymer P-4 was analyzed for composition by ¹³C-NMR and ¹H-NMR and for Mw and Mw/Mn by GPC.

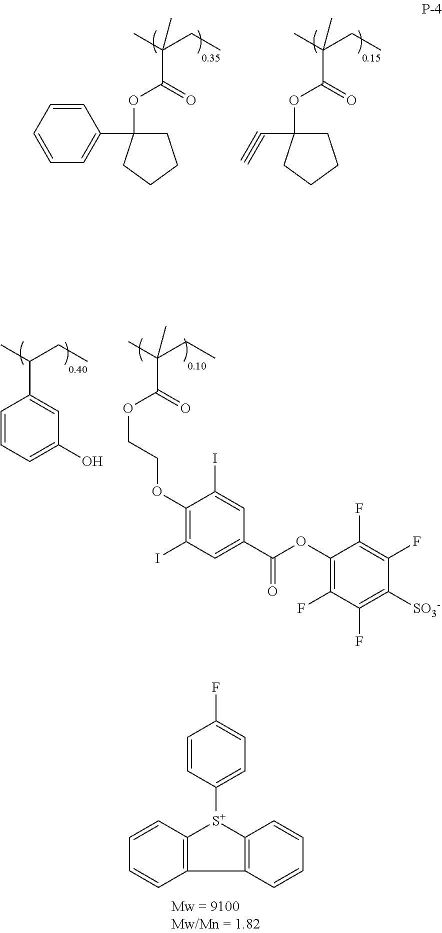

### [Synthesis Example 5] Synthesis of Polymer P-5

A 2-L flask was charged with 11.6 g of AM-3, 5.2 g of 3-hydroxystyrene, 8.3 g of PM-5, and 40 g of a THF solvent. The reactor was cooled to −70° C. in a nitrogen atmosphere, after which vacuum pumping and nitrogen blowing were repeated three times. The reactor was warmed up to room temperature, and 1.2 g of AIBN as a polymerization initiator was added. The reactor was heated to 60° C. and the reaction was run for 15 hours. The reaction solution was poured into 1 L of IPA, and the precipitated white solid was collected by filtration. The resulting white solid was vacuum dried at 60° C., yielding Polymer P-5. Polymer P-5 was analyzed for composition by ¹³C-NMR and ¹H-NMR and for Mw and Mw/Mn by GPC.

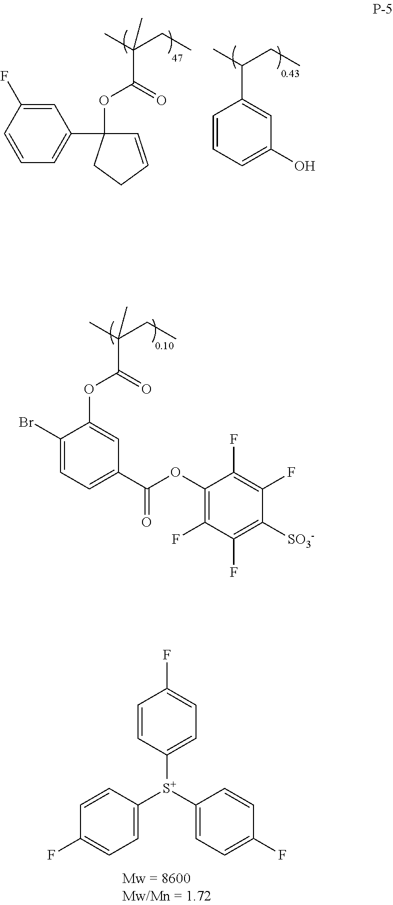

### [Synthesis Example 6] Synthesis of Polymer P-6

A 2-L flask was charged with 8.3 g of AM-5, 4.8 g of 3-hydroxystyrene, 8.2 g of PM-6, and 40 g of a THF solvent. The reactor was cooled to −70° C. in a nitrogen atmosphere, after which vacuum pumping and nitrogen blowing were repeated three times. The reactor was warmed up to room temperature, and 1.2 g of AIBN as a polymerization initiator was added. The reactor was heated to 60° C. and the reaction was run for 15 hours. The reaction solution was poured into 1 L of IPA, and the precipitated white solid was collected by filtration. The resulting white solid was vacuum dried at 60° C., yielding Polymer P-6. Polymer P-6 was analyzed for composition by ¹³C-NMR and ¹H-NMR and for Mw and Mw/Mn by GPC.

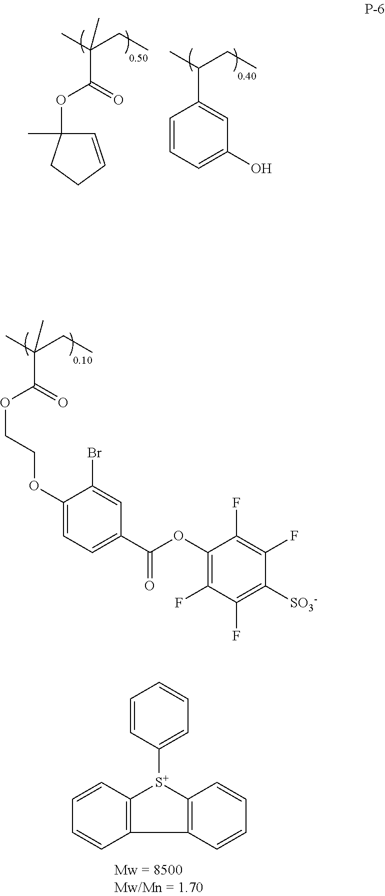

### [Synthesis Example 7] Synthesis of Polymer P-7

A 2-L flask was charged with 11.1 g of AM-1, 3.4 g of 3-hydroxystyrene, 3.2 g of the monomer FM-1, 10.7 g of PM-7, and 40 g of a THF solvent. The reactor was cooled to −70° C. in a nitrogen atmosphere, after which vacuum pumping and nitrogen blowing were repeated three times. The reactor was warmed up to room temperature, and 1.2 g of AIBN as a polymerization initiator was added. The reactor was heated to 60° C. and the reaction was run for 15 hours. The reaction solution was poured into 1 L of IPA, and the precipitated white solid was collected by filtration. The resulting white solid was vacuum dried at 60° C., yielding Polymer P-7. Polymer P-7 was analyzed for composition by ¹³C-NMR and ¹H-NMR and for Mw and Mw/Mn by GPC.

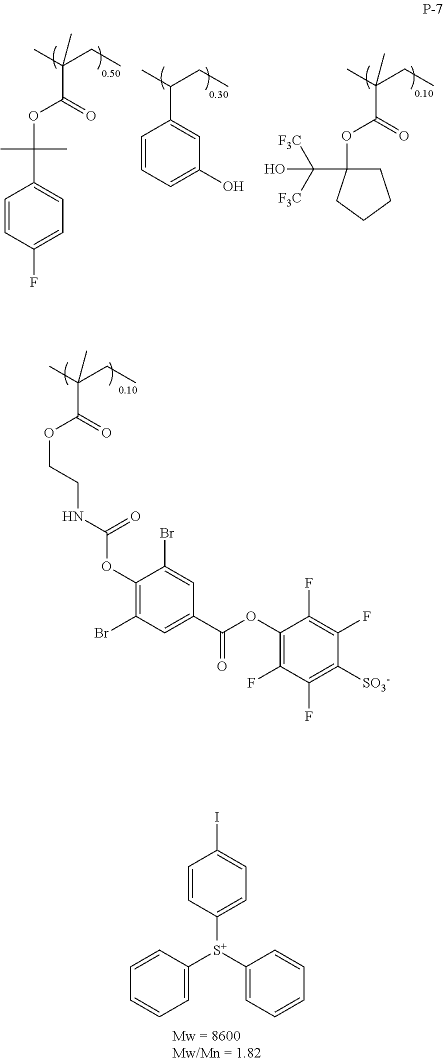

### [Synthesis Example 8] Synthesis of Polymer P-8

A 2-L flask was charged with 11.1 g of AM-1, 4.8 g of 3-hydroxystyrene, 9.1 g of PM-8, and 40 g of a THF solvent. The reactor was cooled to −70° C. in a nitrogen atmosphere, after which vacuum pumping and nitrogen blowing were repeated three times. The reactor was warmed up to room temperature, and 1.2 g of AIBN as a polymerization initiator was added. The reactor was heated to 60° C. and the reaction was run for 15 hours. The reaction solution was poured into 1 L of IPA, and the precipitated white solid was collected by filtration. The resulting white solid was vacuum dried at 60° C., yielding Polymer P-8. Polymer P-8 was analyzed for composition by ¹³C-NMR and ¹H-NMR and for Mw and Mw/Mn by GPC.

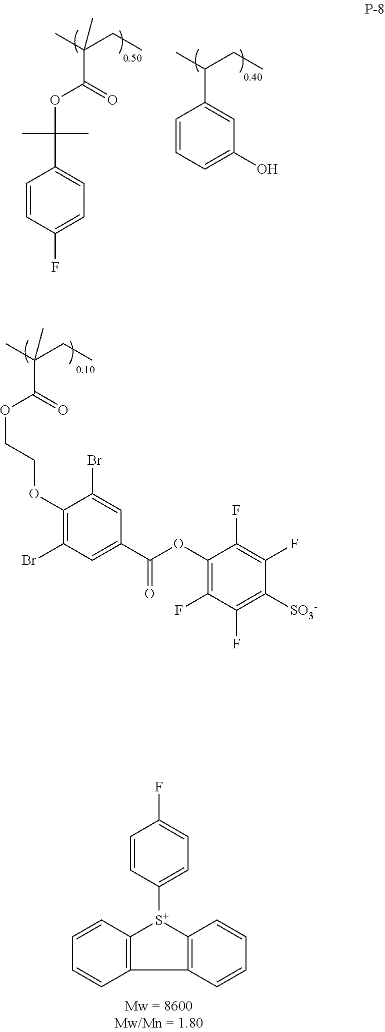

### [Synthesis Example 9] Synthesis of Polymer P-9

A 2-L flask was charged with 12.1 g of AM-6, 4.8 g of 4-hydroxystyrene, 9.2 g of PM-9, and 40 g of a THF solvent. The reactor was cooled to −70° C. in a nitrogen atmosphere, after which vacuum pumping and nitrogen blowing were repeated three times. The reactor was warmed up to room temperature, and 1.2 g of AIBN as a polymerization initiator was added. The reactor was heated to 60° C. and the reaction was run for 15 hours. The reaction solution was poured into 1 L of IPA, and the precipitated white solid was collected by filtration. The resulting white solid was vacuum dried at 60° C., yielding Polymer P-9. Polymer P-9 was analyzed for composition by ¹³C-NMR and ¹H-NMR and for Mw and Mw/Mn by GPC.

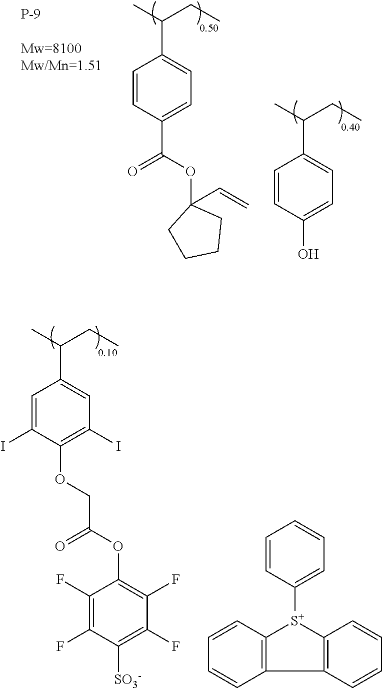

### [Synthesis Example 10] Synthesis of Polymer P-10

A 2-L flask was charged with 12.0 g of AM-7, 4.8 g of 4-hydroxystyrene, 8.9 g of PM-10, and 40 g of a THF solvent. The reactor was cooled to −70° C. in a nitrogen atmosphere, after which vacuum pumping and nitrogen blowing were repeated three times. The reactor was warmed up to room temperature, and 1.2 g of AIBN as a polymerization initiator was added. The reactor was heated to 60° C. and the reaction was run for 15 hours. The reaction solution was poured into 1 L of IPA, and the precipitated white solid was collected by filtration. The resulting white solid was vacuum dried at 60° C., yielding Polymer P-10. Polymer P-10 was analyzed for composition by ¹³C-NMR and ¹H-NMR and for Mw and Mw/Mn by GPC.

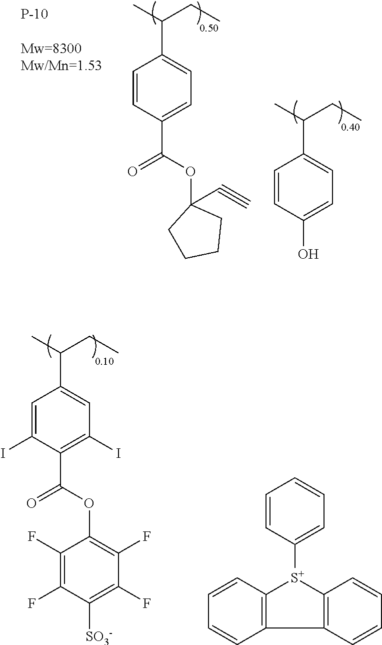

### [Synthesis Example 11] Synthesis of Polymer P-11

A 2-L flask was charged with 11.1 g of AM-1, 4.8 g of 3-hydroxystyrene, 7.7 g of PM-11, and 40 g of a THF solvent. The reactor was cooled to −70° C. in a nitrogen atmosphere, after which vacuum pumping and nitrogen blowing were repeated three times. The reactor was warmed up to room temperature, and 1.2 g of AIBN as a polymerization initiator was added. The reactor was heated to 60° C. and the reaction was run for 15 hours. The reaction solution was poured into 1 L of IPA, and the precipitated white solid was collected by filtration. The resulting white solid was vacuum dried at 60° C., yielding Polymer P-11. Polymer P-11 was analyzed for composition by ¹³C-NMR and ¹H-NMR and for Mw and Mw/Mn by GPC.

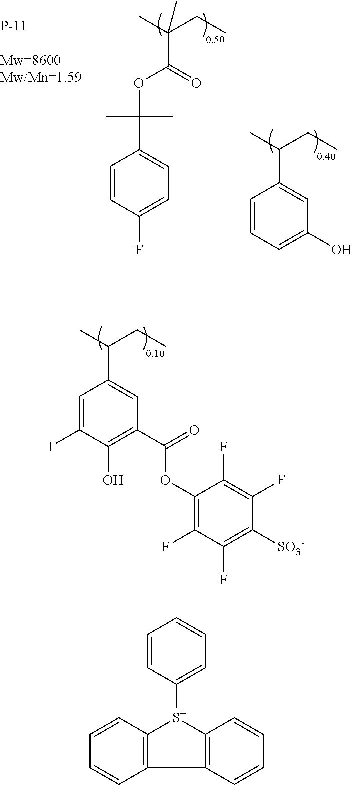

### [Synthesis Example 12] Synthesis of Polymer P-12

A 2-L flask was charged with 11.1 g of AM-1, 4.8 g of 3-hydroxystyrene, 11.1 g of PM-12, and 40 g of a THF solvent. The reactor was cooled to −70° C. in a nitrogen atmosphere, after which vacuum pumping and nitrogen blowing were repeated three times. The reactor was warmed up to room temperature, and 1.2 g of AIBN as a polymerization initiator was added. The reactor was heated to 60° C. and the reaction was run for 15 hours. The reaction solution was poured into 1 L of IPA, and the precipitated white solid was collected by filtration. The resulting white solid was vacuum dried at 60° C., yielding Polymer P-12. Polymer P-12 was analyzed for composition by ¹³C-NMR and ¹H-NMR and for Mw and Mw/Mn by GPC.

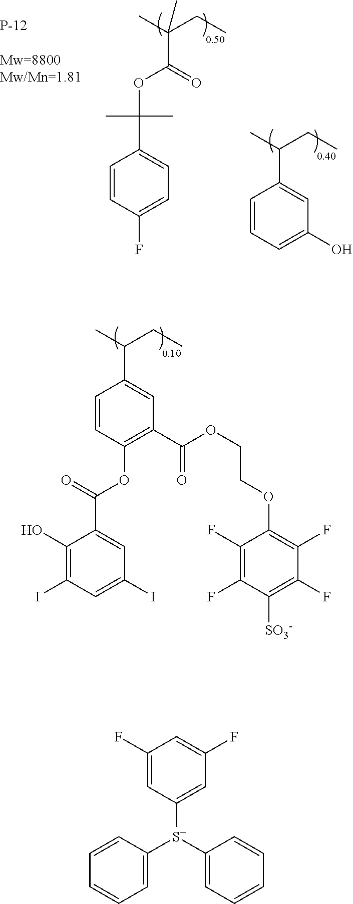

### [Synthesis Example 13] Synthesis of Polymer P-13

A 2-L flask was charged with 11.1 g of AM-1, 4.8 g of 3-hydroxystyrene, 12.0 g of PM-13, and 40 g of a THF solvent. The reactor was cooled to −70° C. in a nitrogen atmosphere, after which vacuum pumping and nitrogen blowing were repeated three times. The reactor was warmed up to room temperature, and 1.2 g of AIBN as a polymerization initiator was added. The reactor was heated to 60° C. and the reaction was run for 15 hours. The reaction solution was poured into 1 L of IPA, and the precipitated white solid was collected by filtration. The resulting white solid was vacuum dried at 60° C., yielding Polymer P-13. Polymer P-13 was analyzed for composition by ¹³C-NMR and ¹H-NMR and for Mw and Mw/Mn by GPC.

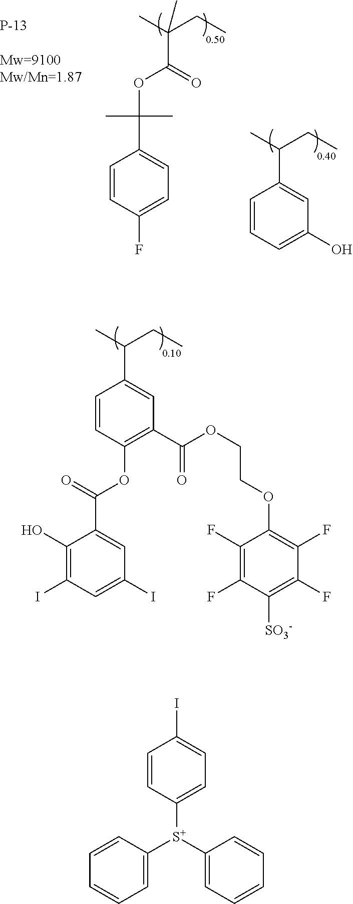

### [Synthesis Example 14] Synthesis of Polymer P-14

A 2-L flask was charged with 11.1 g of AM-1, 4.8 g of 3-hydroxystyrene, 11.9 g of PM-14, and 40 g of a THF solvent. The reactor was cooled to −70° C. in a nitrogen atmosphere, after which vacuum pumping and nitrogen blowing were repeated three times. The reactor was warmed up to room temperature, and 1.2 g of AIBN as a polymerization initiator was added. The reactor was heated to 60° C. and the reaction was run for 15 hours. The reaction solution was poured into 1 L of IPA, and the precipitated white solid was collected by filtration. The resulting white solid was vacuum dried at 60° C., yielding Polymer P-14. Polymer P-14 was analyzed for composition by ¹³C-NMR and ¹H-NMR and for Mw and Mw/Mn by GPC.

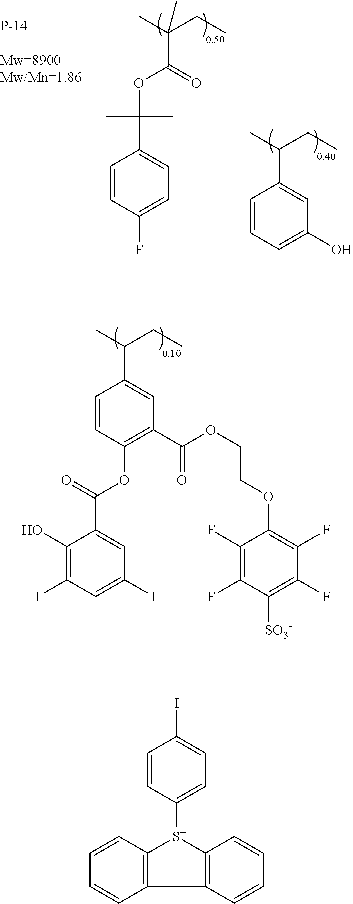

### [Synthesis Example 15] Synthesis of Polymer P-15

A 2-L flask was charged with 11.1 g of AM-1, 4.8 g of 3-hydroxystyrene, 10.8 g of PM-15, and 40 g of a THF solvent. The reactor was cooled to −70° C. in a nitrogen atmosphere, after which vacuum pumping and nitrogen blowing were repeated three times. The reactor was warmed up to room temperature, and 1.2 g of AIBN as a polymerization initiator was added. The reactor was heated to 60° C. and the reaction was run for 15 hours. The reaction solution was poured into 1 L of IPA, and the precipitated white solid was collected by filtration. The resulting white solid was vacuum dried at 60° C., yielding Polymer P-15. Polymer P-15 was analyzed for composition by ¹³C-NMR and ¹H-NMR and for Mw and Mw/Mn by GPC.

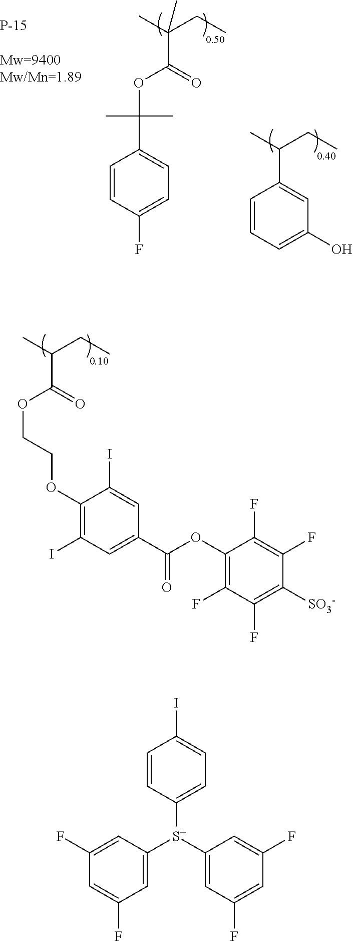

### [Synthesis Example 16] Synthesis of Polymer P-16

A 2-L flask was charged with 11.1 g of AM-1, 4.8 g of 3-hydroxystyrene, 11.4 g of PM-16, and 40 g of a THF solvent. The reactor was cooled to −70° C. in a nitrogen atmosphere, after which vacuum pumping and nitrogen blowing were repeated three times. The reactor was warmed up to room temperature, and 1.2 g of AIBN as a polymerization initiator was added. The reactor was heated to 60° C. and the reaction was run for 15 hours. The reaction solution was poured into 1 L of IPA, and the precipitated white solid was collected by filtration. The resulting white solid was vacuum dried at 60° C., yielding Polymer P-16. Polymer P-16 was analyzed for composition by ¹³C-NMR and ¹H-NMR and for Mw and Mw/Mn by GPC.

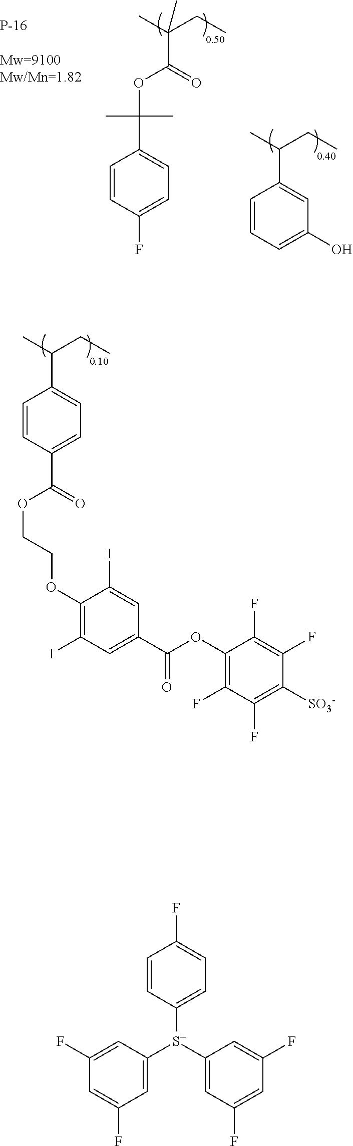

### [Synthesis Example 17] Synthesis of Polymer P-17

A 2-L flask was charged with 11.1 g of AM-1, 4.8 g of 3-hydroxystyrene, 11.0 g of PM-17, and 40 g of a THF solvent. The reactor was cooled to −70° C. in a nitrogen atmosphere, after which vacuum pumping and nitrogen blowing were repeated three times. The reactor was warmed up to room temperature, and 1.2 g of AIBN as a polymerization initiator was added. The reactor was heated to 60° C. and the reaction was run for 15 hours. The reaction solution was poured into 1 L of IPA, and the precipitated white solid was collected by filtration. The resulting white solid was vacuum dried at 60° C., yielding Polymer P-17. Polymer P-17 was analyzed for composition by ¹³C-NMR and ¹H-NMR and for Mw and Mw/Mn by GPC.

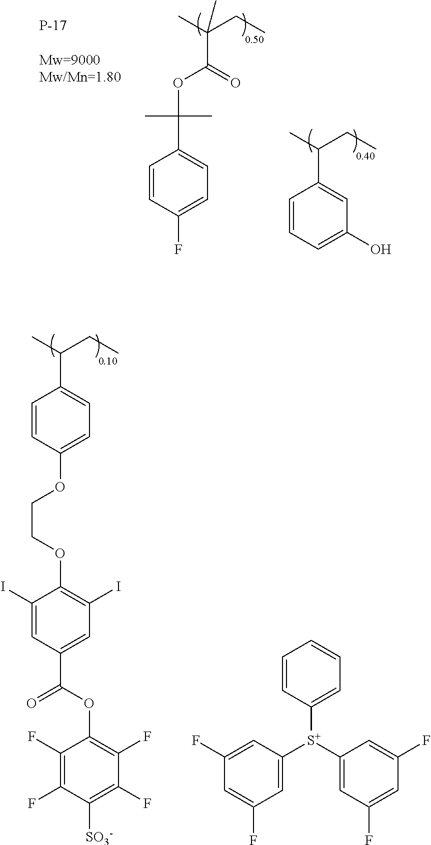

### [Synthesis Example 18] Synthesis of Polymer P-18

A 2-L flask was charged with 11.1 g of AM-1, 4.8 g of 3-hydroxystyrene, 10.1 g of PM-18, and 40 g of a THF solvent. The reactor was cooled to −70° C. in a nitrogen atmosphere, after which vacuum pumping and nitrogen blowing were repeated three times. The reactor was warmed up to room temperature, and 1.2 g of AIBN as a polymerization initiator was added. The reactor was heated to 60° C. and the reaction was run for 15 hours. The reaction solution was poured into 1 L of IPA, and the precipitated white solid was collected by filtration. The resulting white solid was vacuum dried at 60° C., yielding Polymer P-18. Polymer P-18 was analyzed for composition by ¹³C-NMR and ¹H-NMR and for Mw and Mw/Mn by GPC.

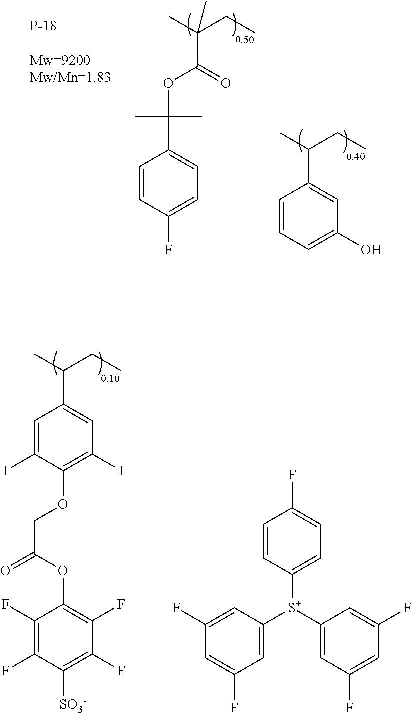

### [Comparative Synthesis Example 1] Synthesis of Comparative Polymer cP-1

Comparative Polymer cP-1 was synthesized in the same manner as in Synthesis Example 1 except that PM-1 was changed to cPM-1.

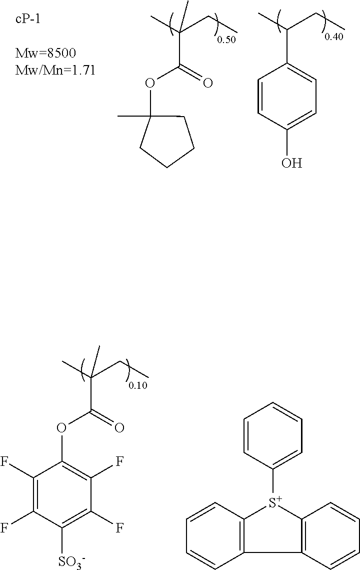

### [Comparative Synthesis Example 2] Synthesis of Comparative Polymer cP-2

Comparative Polymer cP-2 was synthesized in the same manner as in Synthesis Example 1 except that PM-1 was changed to cPM-2.

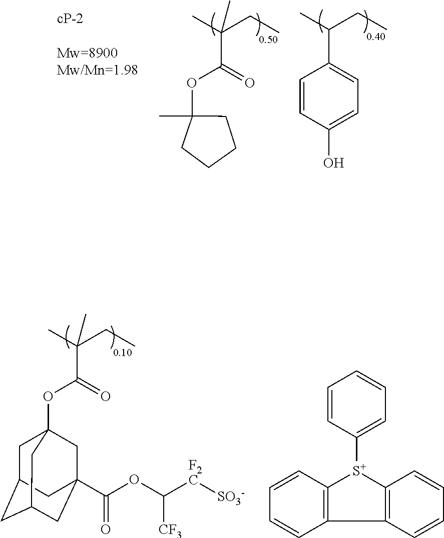

### [Examples 1 to 21 and Comparative Examples 1 and 2] Preparation and Evaluation of Resist Compositions

### (1) Preparation of Resist Compositions

A solution in which each component was dissolved with the composition shown in Table 1 was filtered through a 0.2 μm-sized filter to prepare to prepare a resist composition.

The components in Table 1 are as follows.

### Organic Solvents:

PGMEA (propylene glycol monomethyl ether acetate)
EL (ethyl lactate)
DAA (diacetone alcohol)

### Acid Generators: PAG-1 to PAG-3

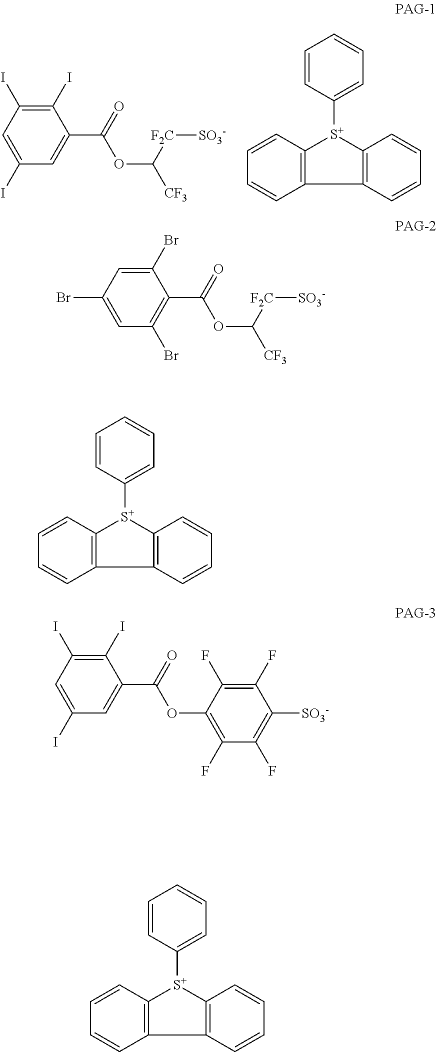

### Quenchers: Q-1 to Q-6

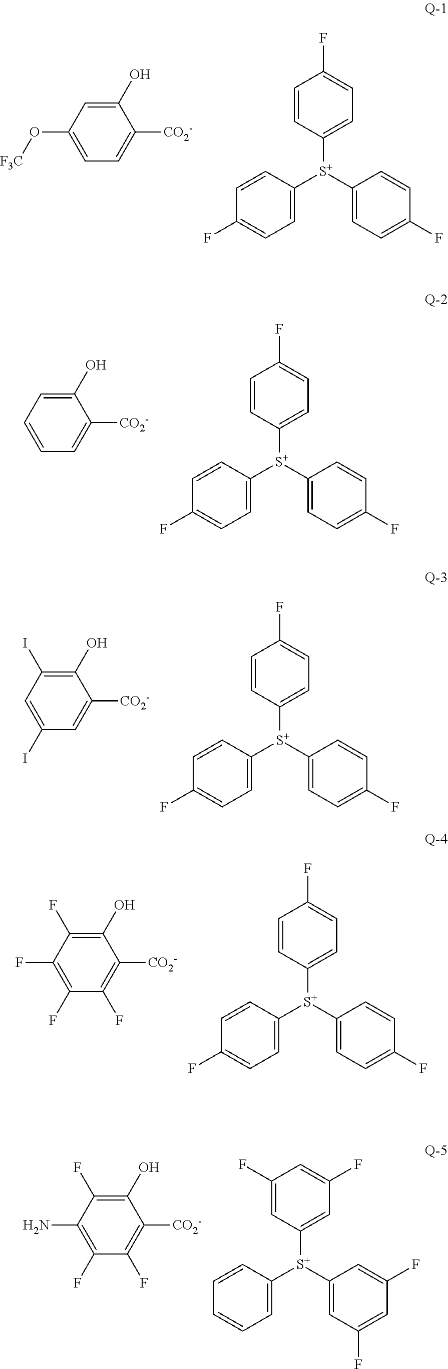

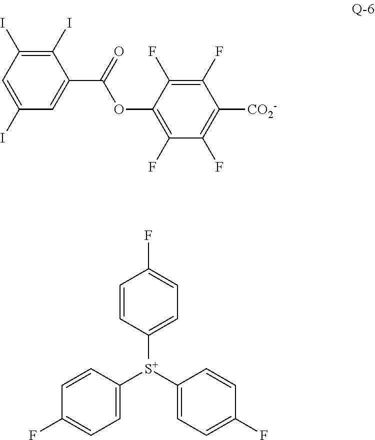

### (2) EUV Lithography Evaluation

Each of the resist compositions shown in Table 1 was applied by spin coating to a silicon substrate having a 20-nm coating of silicon-containing spin-on hard mask SHB-A940 (Shin-Etsu Chemical Co., Ltd., Si content 43 wt %) and prebaked on a hotplate at 105° C. for 60 seconds to form a 60 nm-thick resist film. Using an EUV scanner NXE3400 (ASML, NA 0.33, a 0.9/0.6, quadrupole illumination), the resist film was exposed to EUV through a mask bearing a hole pattern at a pitch of 40 nm (on-wafer size) and +20% bias. The resist film was baked (PEB) on a hotplate at the temperature shown in Table 1 for 60 seconds and developed in a 2.38 wt % TMAH aqueous solution for 30 seconds to form a hole pattern having a size of 20 nm.

The resist pattern was observed under CD-SEM (CG6300, Hitachi High-Technologies Corp.). The exposure dose that provides a hole pattern having a size of 20 nm was reported as sensitivity. The size of 50 holes printed at that dose was measured, from which a 3-fold value (3a) of the standard deviation (a) was computed and reported as CDU. The results are shown in Table 1.

TABLE 1

| | | | Acid | | | | | |
|---|---|---|---|---|---|---|---|---|
| | | Polymer | generator | Quencher | Organic solvent | PEB | Sensitivity | CDU |
| | | (pbw) | (pbw) | (pbw) | (pbw) | (° C.) | (mJ/cm²) | (nm) |
| Example | 1 | P-1 | — | Q-1 | PGMEA (500) | 100 | 28 | 2.8 |
| | | (100) | | (5.38) | EL (2000) | | | |
| | 2 | P-2 | — | Q-1 | PGMEA (500) | 95 | 28 | 2.7 |
| | | (100) | | (5.38) | EL (2000) | | | |
| | 3 | P-3 | — | Q-1 | PGMEA (500) | 95 | 27 | 2.6 |
| | | (100) | | (5.38) | EL (2000) | | | |
| | 4 | P-4 | — | Q-2 | PGMEA (2000) | 95 | 25 | 2.6 |
| | | (100) | | (4.54) | DAA (500) | | | |
| | 5 | P-5 | — | Q-3 | PGMEA (2000) | 90 | 26 | 2.5 |
| | | (100) | | (7.06) | DAA (500) | | | |
| | 6 | P-6 | — | Q-4 | PGMEA (2000) | 95 | 28 | 2.6 |
| | | (100) | | (5.26) | DAA (500) | | | |
| | 7 | P-7 | — | Q-4 | PGMEA (2000) | 95 | 27 | 2.6 |
| | | (100) | | (5.26) | DAA (500) | | | |
| | 8 | P-8 | — | Q-4 | PGMEA (2000) | 95 | 27 | 2.6 |
| | | (100) | | (5.26) | DAA (500) | | | |
| | 9 | P-9 | — | Q-4 | PGMEA (2000) | 95 | 28 | 2.8 |
| | | (100) | | (5.26) | DAA (500) | | | |
| | 10 | P-10 | — | Q-4 | PGMEA (2000) | 95 | 28 | 2.6 |
| | | (100) | | (5.26) | DAA (500) | | | |
| | 11 | P-11 | — | Q-4 | PGMEA (2000) | 95 | 27 | 2.6 |
| | | (100) | | (5.26) | DAA (500) | | | |
| | 12 | P-12 | — | Q-4 | PGMEA (2000) | 95 | 26 | 2.7 |
| | | (100) | | (5.26) | DAA (500) | | | |
| | 13 | P-13 | — | Q-4 | PGMEA (2000) | 95 | 29 | 2.5 |
| | | (100) | | (5.26) | DAA (500) | | | |
| | 14 | P-14 | — | Q-4 | PGMEA (2000) | 95 | 26 | 2.7 |
| | | (100) | | (5.26) | DAA (500) | | | |
| | 15 | P-15 | — | Q-4 | PGMEA (2000) | 95 | 28 | 2.6 |
| | | (100) | | (5.26) | DAA (500) | | | |
| | 16 | P-16 | — | Q-4 | PGMEA (2000) | 95 | 29 | 2.7 |
| | | (100) | | (5.26) | DAA (500) | | | |
| | 17 | P-17 | — | Q-4 | PGMEA (2000) | 95 | 27 | 2.7 |
| | | (100) | | (5.26) | DAA (500) | | | |
| | 18 | P-18 | — | Q-4 | PGMEA (2000) | 95 | 26 | 2.7 |
| | | (100) | | (5.26) | DAA (500) | | | |
| | 19 | P-1 | PAG-1 | Q-4 | PGMEA (2000) | 90 | 24 | 2.8 |
| | | (100) | (9.72) | (5.26) | DAA (500) | | | |
| | 20 | P-1 | PAG-2 | Q-5 | PGMEA (2000) | 90 | 23 | 2.7 |
| | | (100) | (8.31) | (5.43) | DAA (500) | | | |
| | 21 | P-1 | PAG-3 | Q-6 | PGMEA (2000) | 90 | 24 | 2.7 |
| | | (100) | (9.88) | (10.08) | DAA (500) | | | |
| Comparative | 1 | cP-1 | — | Q-1 | PGMEA (2000) | 95 | 32 | 3.2 |
| Example | | (100) | | (5.28) | DAA (500) | | | |
| | 2 | cP-2 | — | Q-1 | PGMEA (2000) | 95 | 30 | 3.0 |
| | | (100) | | (5.28) | DAA (500) | | | |

From the results shown in Table 1, it was found that a resist composition of the present invention, which comprises a base polymer containing repeat units (a) containing a substituted or unsubstituted arylsulfonic acid anion bonded to a polymer backbone having a group containing an iodine atom or a bromine atom and an onium cation, has good CDU.

Japanese Patent Application Nos. 2023-109737 and 2023-123393 are incorporated herein by reference. Although some preferred embodiments have been described, many modifications and variations may be made thereto in light of the above teachings. It is therefore to be understood that the invention may be practiced otherwise than as specifically described without departing from the scope of the appended claims.

1. A resist composition comprising a base polymer containing repeat units (a) containing a substituted or unsubstituted arylsulfonic acid anion bonded to a polymer backbone having a group containing an iodine atom or a bromine atom and an onium cation.

2. The resist composition of claim 1, wherein the repeat units (a) have formula (a1) or (a2): 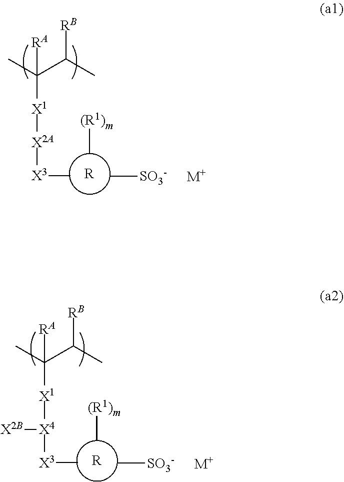
wherein m is an integer of 0 to 5,
R^{A} is a hydrogen atom or a methyl group,
R^{B} is a hydrogen atom or may bond with X¹ to form a ring,
X¹ is a single bond, a phenylene group, a naphthylene ring, an ester bond, or an amide bond,
X^{2A} is a C₁-C₂₄ divalent organic group having at least one iodine atom or bromine atom, which may have at least one selected from an oxygen atom, a nitrogen atom, and a sulfur atom,
X^{2B} is a C₁-C₁₀ monovalent organic group having at least one iodine atom or bromine atom, which may have at least one selected from an oxygen atom, a nitrogen atom, and a sulfur atom,
X³ is a single bond, an ether bond, an ester bond, a thioether bond, or a C₁-C₆ alkanediyl group,
X⁴ is a C₁-C₁₂ trivalent organic group, which may have at least one selected from an oxygen atom, a nitrogen atom, and a sulfur atom,
circle R is a C₆-C₁₀ (m+2)-valent aromatic hydrocarbon group,
R¹ is a C₁-C₁₀ saturated hydrocarbyl group, a C₆-C₁₀ aryl group, a fluorine atom, a trifluoromethoxy group, a difluoromethoxy group, a cyano group, or a nitro group, and
M⁺ is a sulfonium cation or an iodonium cation.

3. The resist composition of claim 1, wherein the base polymer further contains repeat units having formula (b1) or repeat units having formula (b2): 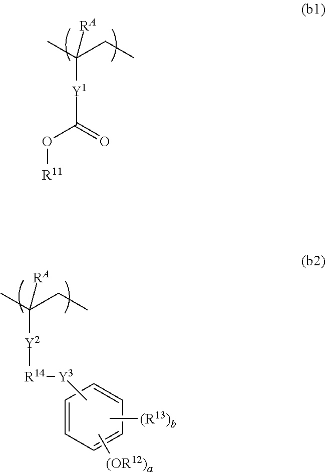
wherein R^{A} is each independently a hydrogen atom or a methyl group,
Y¹ is a single bond, a phenylene group, a naphthylene group, or a C₁-C₁₂ linking group containing at least one moiety selected from an ester bond, an ether bond, a lactone ring, a hydroxy group, and a halogen atom,
Y² is a single bond or an ester bond,
Y³ is a single bond, an ether bond, or an ester bond,
R¹¹ and R¹² are each independently an acid labile group,
R¹³ is a fluorine atom, a chlorine atom, a bromine atom, an iodine atom, a trifluoromethyl group, a cyano group, a C₁-C₆ saturated hydrocarbyl group, a C₁-C₆ saturated hydrocarbyloxy group, a C₂-C₇ saturated hydrocarbylcarbonyl group, a C₂-C₇ saturated hydrocarbylcarbonyloxy group, or a C₂-C₇ saturated hydrocarbyloxycarbonyl group,
R¹⁴ is a single bond or a C₁-C₆ alkanediyl group in which some constituent —CH₂— may be substituted with an ether bond or an ester bond, and
a is 1 or 2, and b is an integer of 0 to 4, provided that 1≤a+b≤5.

4. The resist composition of claim 3, which is a chemically amplified positive resist composition.

5. The resist composition of claim 1, further comprising an organic solvent.

6. The resist composition of claim 1, further comprising a surfactant.

7. A pattern forming process comprising the steps of: applying the resist composition of claim 1 onto a substrate to form a resist film thereon, exposing the resist film to high-energy radiation, and developing the exposed resist film in a developer.

8. The pattern forming process of claim 7, wherein the high-energy radiation is KrF excimer laser, ArF excimer laser, electron beam, or extreme ultraviolet having a wavelength of 3 to 15 nm.
